(19) United States
(12) Patent Application Publication
(10) Pub. No.: US 2026/0287884 A1
(43) Pub. Date: Sep. 24, 2026

(54) GRAVITY RESPONSIVE WOBBLE PARTICLE AND METHODS OF USE

(71) Applicant: Diametryx Inc., Cambridge, MA (US)

(72) Inventor: Michael J. NATAN, Cambridge, MA (US)

(21) Appl. No.: 19/472,271

(22) PCT Filed: Apr. 2, 2024
(86) PCT No.: PCT/US2024/022624

§ 371 Date: Oct. 3, 2025

Related U.S. Application Data
(60) Provisional application No. 63/456,988, filed on Apr. 4, 2023.
(60) Provisional application No. 63/591,002, filed on Oct. 17, 2023.
(60) Provisional application No. 63/568,325, filed on Mar. 21, 2024.

(51) Int. Cl. G02B 26/00; A63H 33/22; B82Y 20/00; G01J 3/50; G01L 1/24; G01P 13/00; G01R 33/02

(52) U.S. Cl. CPC G02B 26/007; B82Y 20/00; G01J 3/50; G01L 1/241; G01P 13/0093; G01R 33/02; A63H 33/22

(57) ABSTRACT

The present disclosure provides, in part, compositions, devices, and objects comprising gravity responsive particles (GRPs) comprising optical property-changing effects that respond to mechanical forces, methods of manufacturing the same, and uses thereof in a variety of applications.

### CROSS-REFERENCE TO RELATED APPLICATIONS

This application claims the benefit of and priority to U.S. Provisional Application No. 63/591,002, filed Oct. 17, 2023, U.S. Provisional Application No. 63/456,988, filed Apr. 4, 2023, and U.S. Provisional Application No. 63/568,325, filed Mar. 21, 2024, the entire contents of each of which are hereby incorporated by reference in their entirety.

### FIELD

The present disclosure relates to, in part, compositions, devices, and objects comprising optical property-changing particles that respond to mechanical forces, methods of preparing the same, and uses thereof.

### BACKGROUND

Property-changing materials, such as color-shifting materials, are commercially available for a wide range of applications, including “smart” windows, tattoos, and freshness indicators on perishable food items. Generally, a stimulus is required to initiate a change in the property of the material, which can be reversible or irreversible depending on the design of the material and its intended use.

Stimuli for initiating a change in property include temperature, light, electrical field, magnetic field, chemical or biochemical entity, and pressure; however, materials that respond to these stimuli have practical limitations. For example, materials that require these stimuli to affect a color change often require ancillary devices or instrumentation, such as a magnet to supply a magnetic field, a current to supply electricity, or a heating/cooling element to control temperature. Additionally, such materials require stimuli that are not present or feasible for all circumstances such as requiring heat in a cold environment, ultraviolet light in a below-ground space, or contacting the material with a fluid solution (or a gas stream) containing a molecule.

Current approaches to property-changing materials are lacking in their reversibility, i.e., the ability to revert back to an initial state. Property-changing materials are more simply engineered to be irreversible, advancing from a state “A” to a state “B” in response to a stimulus “X,” without the ability to return back to state “A”-whether in the absence of the stimulus, or in the presence of an anti-stimulus (“−X,” e.g., a current flowing in one direction as the stimulus, and in the opposite direction as anti-stimulus), or in the presence of some other stimulus “Y.” Engineering property-changing materials to possess reversibility is more challenging, where the actuation is often impractical. For example, it can take on the order of minutes for a material to change from state “A” to state “B,” and on the order of minutes to revert back to state “A;” or alternatively, the transition from state “A” to state “B” can occur on the order of seconds, but transition back to state “A” takes substantially longer (on the order of minutes to hours). For some applications this is not practical, such as when it is required that the transitions between state “A” and state “B” are roughly equivalent in time, and to be on the order of <1 sec to a few seconds.

Moreover, property-changing materials, such as with respect to color-changing materials, are limited in the number of “A” to “B” cycles that can be achieved in the material. For example, materials that respond to a biochemical/chemical stimuli, or an electrical stimuli, are suspect to both attenuation in receiving the stimuli and in attenuation of the ability to change the property of the material. For some applications, it is required that the material cycle between property-changing transitions on the order of 10³ to 10⁶ times or more.

Current color-changing materials are also limited in the availability of the transitions and effects. For example, currently engineered color-changing materials have a tendency to exhibit a finite number of transitions, typically transitioning between two colors, such as a transition from one predetermined color to a second predetermined color. Certain applications of color-changing materials require that the color-changing property can transition from a first color to any other color, even if the change is simply a change in one chromatic element (e.g., hue, saturation, brightness, intensity, color value, or chroma). However, currently engineered color-changing materials cannot accommodate such variable changes in color (e.g., a color chosen at will from more than two available colors).

Previously described property-changing materials also typically lack directionality with respect to the direction of actuation initiated by the stimulus, or more specifically the directionality of the materials in relation to the stimulus. For example, bringing a solution of magnetochromic materials (i.e., material that changes color in response to a magnetic field) contained in a thin plane within close proximity to a magnet or magnetic field can initiate a change in color. However, rotating these materials by 90 degrees (or another degree of rotation) within the plane and then bringing the now rotated plane within close proximity to the magnet/magnetic field leads to the same change in color. This is not practical for applications of property-change materials where the state change is intended to be orientation-dependent.

There remains a need for property-changing materials that exhibit reversible, color-shifting properties that can be actuated in all environments, including wide ranges of temperature, in indoor and outdoor spaces, without ancillary equipment, and can be engineered to withstand a high degree of transitions between states, maintain directionality for state changes, and can accommodate an increased repertoire of transitions and effects.

### SUMMARY

Accordingly, the present disclosure provides, in part, compositions of property-changing particles that are suitable for incorporation into a variety of materials and methods of manufacture and uses thereof. The particles, in embodiments, are about 20 nm to 10 mm in size and exhibit optical properties that change in response to mechanical forces (e.g., dynamic motion such as vibration, shaking, tilting, inversion, etc.), or other forces (e.g. gravity, magnetic field) where the particles “wobble,” revealing different optical states, and relaxing back to a stationary state via gravitational force. Thus, these gravity responsive particles, in embodiments, are dispersible in a fluid and/or applied to a surface. In embodiments, the gravity responsive particles are suitable for a variety of applications, including but not limited to: (i) consumer-goods (e.g., incorporated into packaging, woven into fibers, applied to paper/foil, etc.); (ii) for authentication and security applications; (iii) as cosmetics, tattoos, and semi-permanent makeup, (iv) as chemical or biochemical sensors; and (v) as obscurants (e.g., for use in air, in windows, mirrors, and/or doors), among other applications.

In embodiments, the present disclosure provides, in part, a gravity responsive particle (GRP) comprising a shape and a center of mass (CoM) that enables motion between a plurality of positions when a force is applied, where the shape and the CoM enables relaxation to a stationary position from the plurality of positions from gravitational force, and one or more optically active agents, where the GRP exhibits a change in an optical property from the one or more optically active agents as a function of the motion between the plurality of positions.

In embodiments, the GRP is about or at least about 20 nm to about or at least about 10 mm in size. In embodiments, the GRP is about or at least about 20 nm, about or at least about 50 nm, about or at least about 100 nm, about or at least about 200 nm, about or at least about 300 nm, about or at least about 400 nm, about or at least about 500 nm, about or at least about 600 nm, about or at least about 700 nm, about or at least about 800 nm, about or at least about 900 nm, about or at least about 1 μm, about or at least about 5 μm, about or at least about 10 μm, about or at least about 50 μm, about or at least about 100 μm, about or at least about 200 μm, about or at least about 300 μm, about or at least about 400 μm, about or at least about 500 μm, about or at least about 600 μm, about or at least about 700 μm, about or at least about 800 μm, about or at least about 900 μm, about or at least about 1 mm, about or at least about 2 mm, about or at least about 3 mm, about or at least about 4 mm, about or at least about 5 mm, or about or at least about 10 mm. In embodiments, the GRP comprises a size in a range from about 2 μm to about 2000 μm.

In embodiments, the shape comprises one or more geometries. In embodiments, the one or more geometries comprises one or more of a roly-poly shape, fin-shaped, truncated teardrop shape, champagne flute shape, wine glass shape, round-bottomed doll shape, tilting doll shape, tumbler shape, wobbly toy shape, wobble doll shape, round-bottomed toy shape, egg-shaped shape, paraboloid, prolate hemispheroid, oblate hemispheroid, hemispherical, elliptical, trigonal pyramid, pentagonal pyramid, hexagonal pyramid, a regular shape with a truncated tops, a truncated square pyramid, a truncated cone, a truncated cone where the top plane and bottom plane are not parallel.

In embodiments, the shape is a 3-dimensional shape. In embodiments, the 3-dimensional shape is concave. In embodiments, the 3-dimensional shape is convex.

In embodiments, the shape comprises a surface area ratio of a first optically active agent to a second optically active agent. In embodiments, the surface area ratio of the first optically active agent to the second optically active agent; or the surface area ratio of the second optically active agent to the first optically active agent is about or at least about 0.1, about or at least about 0.2, about or at least about 0.3, about or at least about 0.4, about or at least about 0.5, about or at least about 0.6, about or at least about 0.7, about or at least about 0.8, about or at least about 0.9, or about or at least about 1.0.

In embodiments, the shape is asymmetrical. In embodiments, the shape comprises one axis of symmetry, two axes of symmetry, three axes of symmetry, or four or more axes of symmetry. In embodiments, the shape comprises at least one plane of symmetry. In embodiments, the shape comprises glide reflection symmetry.

In embodiments, the GRP comprises an internal portion. In embodiments, the internal portion comprises a material having a singular specific gravity and/or density. In embodiments, the internal portion comprises at least two materials having different specific gravity and/or density. In embodiments, the internal portion comprises at least a portion that is hollow. In embodiments, the internal portion comprises at least a portion that comprises a gyroid infill, grid infill, cubic infill pattern, triangular infill, octet infill, lightning infill, and/or a combination thereof.

In embodiments, the GRP comprises two or more optically active agents, each exhibiting at least one distinct optical state.

In embodiments, the initial force that is applied to the GRP comprises a mechanical force that is not a gravitational force. In embodiments, the initial force that is applied to the GRP applied comprises a gravitational force.

In embodiments, the motion is a pendulum motion oscillating between the plurality of positions and the stationary position. In embodiments, the oscillating motion comprises a wobble motion comprising oscillations around a pitch axis and a yaw axis. In embodiments, the wobble motion comprises movement through the several orientations relative to a direction of a gravity force. In embodiments, the motion is a tilt displacement motion between the plurality of positions and the stationary position. In embodiments, the motion is an angular displacement motion between the plurality of positions and the stationary position. In embodiments, the motion occurs along a plane in two dimensions and/or in three dimensions.

In embodiments, the center of mass (CoM) resides below a radius of curvature. In embodiments, the center of mass (CoM) does not resides below a radius of curvature.

In embodiments, the GRP has a ratio of distance between the center of curvature and the location of vertices (μ) of about or at least about 1/8, about or at least about 1/7, about or at least about 1/6, about or at least about 1/5, about or at least about 1/4, about or at least about 2/7, about or at least about 1/3, about or at least about 3/8, about or at least about 2/5, about or at least about 3/7, about or at least about 1/2, about or at least about 4/7, about or at least about 3/5, about or at least about 5/8, about or at least about 2/3, about or at least about 5/7, about or at least about 3/4, about or at least about 4/5, about or at least about 5/6, or about or at least about 6/7.

In embodiments, the GRP comprises two optically active agents, three optically active agents, four optically active agents, or five or more optically active agents.

In embodiments, the one or more optically active agents comprise a color in the visible electromagnetic spectrum comprising an extinction, reflection, or scattering at a wavelength from about or at least about 350 nm to about or at least about 800 nm. In embodiments, the color is one or more of white, black, red, orange, yellow, green, blue, indigo, and/or violet. In embodiments, the GRP exhibits no extinction, reflection, or scattering at a wavelength from about or at least about 350 nm to about or at least about 800 nm during the stationary position or during at least a portion of the motion between the plurality of positions. In embodiments, the GRP only exhibits extinction, reflection, or scattering at a wavelength from about or at least about 350 nm to about or at least about 800 nm during the stationary position or during at least a portion of the motion between the plurality of positions.

In embodiments, the GRP exhibits a color of one or more of white, black, red, orange, yellow, green, blue, indigo, violet, or a color shade or hue therebetween.

In embodiments, the one or more optically active agents comprises a dye. In embodiments, the dye comprises one or more of Rhodamine B, Congo Red, Crystal Violet, Methylene Blue, Acridine Orange, Nile Red, Malachite Green, Eosin Y, Cresol Red, Fluorescein, and/or Indigo.

In embodiments, the one or more optically active agents comprises a pigment. In embodiments, the pigment comprises one or more of Titanium White (PW6), Zinc White (PW4), Carbon Black (PBk7), Mars Black (PBk11), Iron Oxide Red (PR101), Cadmium Red (PR108), Alizarin Crimson (PR83), Cadmium Orange (PO20), Cadmium Yellow (PY35), Lemon Yellow (PY3), Chromium Green Oxide (PG17), Phthalo Green (PG7), Ultramarine Blue (PB29), Cobalt Blue (PB28), Cerulean Blue (PB35), Prussian Blue (PB27), Burnt Sienna (PBr7), Raw Umber (PBr7), Raw Sienna (PBr7), and/or Yellow Ochre (PY43).

In embodiments, the pigment is an organic pigment. In embodiments, the pigment is an inorganic pigment.

In embodiments, the organic pigment or inorganic pigment is a white pigment. In embodiments, the white pigment is one or more of Lead white (2PbCO₃·Pb(OH)₂), kaolin, silica (SiO₂), Titanium dioxide (TiO₂/rutile and anatase), zinc oxide (ZnO), zinc sulfide (ZnS), and/or lithopone (ZnS+BaSO₄).

In embodiments, the organic pigment or inorganic pigment is a black pigment. In embodiments, the black pigment is one or more of Coal (charcoal), groutite (α-MnOOH), manganite (γ-MnOOH), hausmannite (Mn₃O₄), Carbon black, iron oxide black (Fe₃O₄), and/or spinel black (CuCr₂O₄).

In embodiments, the organic pigment or inorganic pigment is a colored pigment.

In embodiments, the colored pigment comprises a yellow pigment. In embodiments, the yellow pigment comprises one or more of Yellow ochre (α-FeOOH), auric pigment (As₂S₃), lead ochre (PbO), lead tin yellow (Pb₂SnO₄, PbSn₂SiO₇), Naples yellow (Pb(SbO₃)₂), zinc yellow (Zn₂CrO₄), Indian yellow (C₁₉H₁₆O₁₀), Iron oxide yellow (α-FeOOH), chromium titanium yellow ((Ti,Cr,Sb)O₂), nickel titanium yellow ((Ti,Ni,Sb)O₂), lead yellow (PbCrO₄), cadmium yellow (CdS), bismuth yellow (BiVO₄).

In embodiments, the colored pigment comprises a red pigment. In embodiments, the red pigment comprises one or more of Red ocher (α-Fe₂O₃), Terra di Siena (α-Fe₂O3), vermilion (HgS), lead red (Pb₃O₄), alizarin madder varnish, alizarin red (C₁₄H₈O₄), Iron oxide red (α-Fe₂O₃), molybdate red (Pb(Cr,S,Mo)O₄), cadmium red (Cd(S,Se)).

In embodiments, the colored pigment comprises a green pigment. In embodiments, the green pigment comprises one or more of Green earth (Fe silicates), Schweinfurt green (C₄H₆As₆Cu₄O₁₆), Chromium oxide green (Cr₂O₃), chromium oxide hydrate green (CrOOH), cobalt green (Co₂TiO₄).

In embodiments, the colored pigment comprises a blue pigment. In embodiments, the blue pigment comprises one or more of Lazurite (lapis lazuli), Egyptian blue (CaCuSi₄O₁₀), azurite (2CuCO₃·Cu(OH)₂), malachite (CuCO₃·Cu(OH)₂), cobalt blue (CoAl₂O₄), Cobalt blue (CoAl₂O₄), ultramarine blue: (NasAl₆Si₆O₂₄(NaSn)), iron bluea (K[FeI∥Fe∥(CN)₆]·xH₂O).

In embodiments, the colored pigment comprises a brown pigment. In embodiments, the brown pigment comprises one or more of Burnt umber (Fe₂O₃·xMnO₂), brown ocher (α-Fe₂O₃+Mn oxides), limonite (mixture of different Fe oxides).

In embodiments, the pigment is one or more of an oxide or oxide hydroxide pigment (TiO₂, ZnO, α-Fe₂O₃, α-FeOOH, γ-Fe₂O₃, Fe₃O₄, Cr₂O₃, CrOOH, PbO, PB₃O₄, Mn₃O₄, —MnOOH, S_{b2}O₃), a complex oxide pigment (CoAl₂O₄, CuCr₂O₄, Co₂TiO₄, (Ti,Ni,Sb)O₂, (Ti,Cr,Sb)O₂), a carbonate hydroxide pigment (2PbCO₃·Pb(OH)₂, 2CuCO₃·Cu(OH)₂, CuCO₃·Cu(OH)₂), a sulfide/selenide pigment (ZnS, CdS, Cd(S,Se), CdSe, γ-Ce₂S₃, HgS, As₂S₃), a chromate/molybdate pigment (PbCrO₄, Pb(Cr,S)O₄, Pb(Cr,S,Mo)O₄, ZnCrO₄, BaCrO₄, SrCrO₄), a vanadate pigment (BiVO₄, 4BiVO₄·3Bi₂MoO₆), a stannate pigment (Pb₂SnO₄, PbSn₂SiO₇, Co₂SnO₄, CoSnO₃), a phosphate pigment (Co₃(PO₄)₂), an antimonate pigment (Pb(SbO₃)₂), an arsenate pigment (Cu(AsO₃)₂), an ultramarine pigment (Na₆Al₆Si₆O₂₄(NaSₙ)), a hexacyanidoferrate/hexacyanoferrate pigment (K[Fe^{III}Fe^{II}(CN)₆]·xH₂O (x=14-16), an oxonitride pigment (CaTaO₂N, LaTaON₂), an elemental-based pigment (C, Al, Cu, Cu/Zn, Au), a spinel-based pigment, and/or a rutile-based metal pigment.

In embodiments, the inorganic pigment is one or more of a transparent effect pigment, goniochromatic pigments, pearlescent pigment, metallic pigment, interference pigment, metallic effect pigment, fluorescent pigment, luminescent pigment, phosphorescent pigment, magnetic pigment, and/or anticorrosive pigment.

In embodiments, the metallic pigment comprises one or more of aluminum, bronze, and/or copper metallic pigment.

In embodiments, the pearlescent pigment comprises one or more of mica, titanium dioxide, and/or bismuth oxychloride.

In embodiments, the fluorescent pigment comprises one or more fluorescent dye and/or pigment comprising a fluorescent mineral.

In embodiments, the phosphorescent pigment comprises zinc sulfide and/or strontium aluminate.

In embodiments, the interference pigment comprises titanium dioxide-coated mica and/or aluminum oxide-coated mica.

In embodiments, the one or more optically active agents comprises an anisotropic particle. In embodiments, the anisotropic particle comprises a nanoparticle of the one or more metals, optionally comprising a nanorod of one or more of gold (Au), silver (Au), and/or aluminum (Al).

In embodiments, the one or more optically active agents comprises a plasmonic material. In embodiments, the plasmonic material comprises a pigment, particle, foil, and/or film. In embodiments, the plasmonic material comprises a polymer-film loaded with noble metal nanoparticles.

In embodiments, the goniochromatic pigment comprises aluminum coated with magnesium fluoride embedded in chromium.

In embodiments, the GRP comprises one or more roughness features. In embodiments, the one or more roughness features is a variation in a surface smoothness that alters the degree of reflectivity of the surface at one or more wavelengths. In embodiments, the one or more roughness features is regularly or irregularly shaped. In embodiments, the one or more roughness features appears in a regular pattern and/or an irregular pattern.

In embodiments, the GRP is disposed on a surface and/or substrate. In embodiments, the surface and/or substrate is a window, computer chip, glass surface, fabric, plastic, paper, wood, construction material, and/or human or animal tissue or skin. In embodiments, the surface and/or substrate is planar or non-planar. In embodiments, the surface and/or substrate comprises at least a portion that is convex, concave, or without a well-defined shape. In embodiments, the surface and/or substrate is on an interior surface of an object, an exterior surface of an object, or both.

In embodiments, the GRP comprises one or more magnetic materials. In embodiments, the magnetic material is affixed to at least a portion of the surface of the GRP. In embodiments, the magnetic material is affixed to the top surface, optionally where the magnetic material changes the CoM relative to the curvature of radius. In embodiments, the magnetic material is ferromagnetic, ferrimagnetic, antiferromagnetic, diamagnetic, paramagnetic, superparamagnetic, and/or antiferromagnetic

In embodiments, the magnetic material comprises one or more of an inorganic, organic, carbon-based, or biomolecule-based magnetic material. In embodiments, the magnetic material comprises one or more of iron (Fe), cobalt (Co), nickel (Ni), zinc (Zn), manganese (Mn), chromium (Cr), samarium (Sm), alloys or oxides thereof; alloys, intermetallic, and/or oxides of Fe, Co, Ni, Zn, Mn, Sm; oxides are of iron, Fe2O3, FeO, and/or Fe3O4; ferrite material and/or doped materials of Co, Ni, Zn, and/or Mn:FexOy, and/or magnetitetetracyanoethylene (TCNE) salts, [Fe(C5Me5)2]+[TCNE]·-, Li[TCNE], [MnIITPP][TCNE]·(TPP=tetraphenylporphyrin), [FeII(TCNE)(NCMe)2][FeIIICl4], MnII(TCNE)I(OH2), MnII(TCNE)[C4(CN)8]1/2, Fe(TCNE)[C4(CN)8]1/2, MnII(TCNE)3/2(I3)1/2, VII[TCNE]x (x≈2), C7H5ClN3Se4, magnetic organic polymers, and polymer-bonded magnets.

In embodiments, the GRP responds to a magnetic stimulus.

In embodiments, the GRP is formulated into a foil, film, thin plastic, and/or paper substrate, material, and/or surface. In embodiments, the foil, film, thin plastic, and/or paper substrate, material, and/or surface is suitable to be affixed to, or embedded in, an object.

In embodiments, the GRP is formulated into a fiber, thread, yarn, and/or twine substrate, material, and/or surface. In embodiments, the fiber, thread, yarn, and/or twine substrate, material, and/or surface is suitable to be woven into an article of clothing, a cloth, and/or a tarp.

In embodiments, the GRP is formulated into a fluid, suspension, ink, liquid film, and/or adhesive substrate, material, and/or surface. In embodiments, the fluid, suspension, ink, liquid film, and/or adhesive substrate, material, and/or surface is suitable to be applied to an object.

In embodiments, the surface and/or substrate comprises indentations and/or divots. In embodiments, the indentations and/or divots are arranged in an array. In embodiments, the GRP is disposed in and/or on the indentations and/or divots.

In embodiments, the surface and/or substrate comprises pillars, posts, and/or stops. In embodiments, the GRP is disposed in and/or on the pillars, posts, and/or stops. In embodiments, the surface and/or substrate comprises one or more grooves. In embodiments, the GRP is disposed in and/or on the one or more grooves.

In embodiments, the GRP is positioned between a first substrate and a second substrate. In embodiments, at least one of the first substrate and the second substrate comprises a material that is transparent to at least a portion of the visible electromagnetic (EM) spectrum. In embodiments, the material comprises glass, quartz, plastic, polyethylene terephthalate, polycarbonate, polymethyl methacrylate (acrylic), polyethylene, polyurethane, polypropylene, thermoplastic elastomers (TPE), acrylonitrile butadiene styrene (ABS), epoxies and epoxy-based photoresists, hydrogels, cyclic olefin copolymer (COC) cyclic olefin polymer (COP), poly dimethyl siloxane (PDMS), poly ether ester ketone (PEEK), polyetherimide (ULTEM) and/or nylon. In embodiments, the material comprises a thickness of about or at least about 50 nm, is about or at least about 100 nm, is about or at least about 500 nm, about or at least about 1 μm, is about or at least about 10 μm, is about or at least about 100 μm, about or at least about 1 mm, about or at least about 5 mm, or about or at least about 10 mm.

In embodiments, the GRP changes color as a function of the motion.

In embodiments, the GRP comprises at least a first surface with a shape that is complementary to a shape of a second surface of the GRP.

In embodiments, the surface and/or substrate comprises one or more a lubricant, surface treatment, coating, and/or polishing agent; or at least one of the first substrate and the second substrate comprises one or more a lubricant, surface treatment, coating, and/or polishing agent. In embodiments, the one or more lubricant, surface treatment, coating, and/or polishing agent comprises polytetrafluoroethylene (PTFE), hydroxylated self-assembled monolayers, vitreous enamel, ceria (cerium oxide), ceramics, anodized metals, and/or silica.

In embodiments, disclosed herein is a gravity responsive particle (GRP) comprising a shape and a center of mass (CoM) that enables motion between a plurality of positions when a force is applied, where the shape and the CoM enables relaxation to a stationary position from the plurality of positions from gravitational force, and one or more optically active agents, where the GRP exhibits a change in an optical property of the one or more optically active agents as a function of the motion between the plurality of positions, and where the GRP comprises one or more fin-shaped portions above the CoM.

In embodiments, disclosed herein are subsets of gravity responsive particles (GRPs), called sawtooth gravity responsive particles (sGRPs) comprising a shape comprising a center of mass (CoM) that resides at or below a radius of curvature that when a force is applied to tilt the sGRP between a tilt angle of 0° to θ_{crit}, the shape enables motion between a plurality of positions of 0° to θ_{crit}, where θ_{crit} is a critical angle, tilting past which results in movement of the sGRP to an equilibrium position on a side surface that is distinct from an upright equilibrium position, and one or more optically active agents, where the sGRP exhibits a change in an optical property of the one or more optically active agents as a function of relaxation to the equilibrium position on the side surface.

In embodiments, the side surface of a sGRP is configured to rest on a side surface of a second sGRP comprising a congruent shape and/or a different shape (e.g., like a “sawtooth” configuration of resting particles when viewed from particular viewing angles). In embodiments, the motion between the plurality of positions of 0° to θ_{crit} is an angular displacement. In embodiments, the 0° angle is relative to a plane passing through the center of mass (CoM) and perpendicular to a surface the sGRP is resting upon.

In embodiments, the motion resembles or is substantially similar to an oscillating motion or a tilt displacement. In embodiments, the oscillating motion comprises a pendulum motion oscillating between the plurality of positions. In embodiments, the oscillating motion comprises a wobble motion comprising oscillations around a pitch axis and a yaw axis. In embodiments, the wobble motion comprises movement through a plurality of orientations relative to a direction of the force. In embodiments, the motion occurs along a plane in two dimensions and/or in three dimensions.

In embodiments, the critical angle (θ_{crit}) of a sGRP is about or less than about 5°, about or less than about 10°, about or less than about 15°, about or less than about 20°, about or less than about 25°, about or less than about 30°, about or less than about 35°, about or less than about 40°, about or less than about 45°, about or less than about 50°, about or less than about 55°, about or less than about 60°, about or less than about 65°, about or less than about 70°, or about or less than about 75°, relative to the plane passing through the center of mass (CoM) and perpendicular to a surface the sGRP is resting upon.

In aspects, the present disclosure provides, in part, methods of manufacturing GRPs, as described herein. In embodiments, methods herein comprise generating a particle from one or more substrate materials, the particle comprising a shape and a center of mass (CoM) that enables motion between a plurality of positions when a force is applied, where the shape and the CoM enables the particle to relax to a stationary position from the plurality of positions from gravitational force.

In embodiments, generating the particle comprises forming the particle by assembling, gluing, screwing, and/or affixing of two or more components; injection molding, and/or micro-injection molding; self-assembly, adsorption, coacervation, and/or mixing; polymerization, extrusion, and/or manipulation of polymers; additive manufacturing, CNC machining (Computer Numerical Control machining), urethane casting, microcontact printing, dip pen lithography, beam pen lithography, photolithography, e-beam lithography, and/or 3D printing.

In embodiments, generating the particle comprises forming the particle by injecting molten plastic, metal, and/or polymer-based material into a mold cavity.

In embodiments, generating the particle comprises forming the particle by 3D printing. In embodiments, 3D printing comprises performing one or more of fused deposition modeling (FDM), fused filament fabrication (FFF), stereolithography (SLA), two photon polymerization, multi-photon lithography, selective laser sintering (SLS), binder jetting (BJ), direct energy deposition (DED), digital light process (DLP), liquid crystal display (LCD), polymer jetting (PolyJet), multi-jet fusion (MJF), direct metal laser sintering (DMLS), electron beam melting (EBM), laminated object manufacturing (LOM), continuous liquid interface production (CLIP), electron beam melting, and digital light processing (DLP).

In embodiments, the one or more substrate materials comprises one or more metals and/or ceramics.

In embodiments, the one or more substrate materials comprises one or more thermally responsive polymers and/or resins. In embodiments, the one or more thermally responsive polymers and/or resins comprise one or more of poloxamers, polycarbonate and/or polycarbonate-like polymers (e.g., polycarbonate-like translucent/clear (ACCURE 60), FormLabs Grey resin, etc.), polyamide (polyamide 12 (PA12), Nylon 12, glass-filed polyamide such as PA12 40% glass-filled back), photoresins (e.g., UPNANO UpPhoto 2-photon resin), styrene-butadiene block copolymers, polymethylmethacrylate, polybutylmethacrylate, plasticized polyvinyl chloride, plasticized nylon, plasticized polyethylene terephthalate, polyethylene, polyacrylonitrile, polychlorotrifluoroethylene, poly-4,4′-isopropylidenediphenylene carbonate, polyethylene vinyl ester, polyvinyl chloride-diethyl fumarate, poly(1,4-isoprene) (PI), polystyrene (PS), poly(tert-butyl methacrylate) (PtBA), amino-terminated poly(butadinene) (PBNH₂-37k), poly(ferrocenyl dimethylsilane) (PFeS), amino-terminated poly(butadinene) (PBNH₂-14k), poly(methyl methacrylate) (PMMA), amino-terminated polystyrene (PSNH₂), and combinations thereof.

In embodiments, generating the particle comprises forming Janus particles and/or Ashura particles comprising the one or more substrate materials. In embodiments, the one or more substrate materials comprises one or more of poly(tert-butyl acrylate)-poly(3-(triethoxysilyl) propyl methacrylate) (PtBA-PTPM), polystyrene latex polymer, carboxylated latex polymer, aminated latex polymer, colored polystyrene polymer (dye-infused and/or pigment-infused), colored polystyrene-based carboxylated latex polymer (dye-infused and/or pigment-infused), fluorescent polystyrene-based polymers, fluorescent polystyrene-based carboxylated latex polymers, fluorescent aminated polystyrene-based polymer, surfactant-free polystyrene, carboxylated surfactant-free polymer, polymethyl methacrylate (PMMA) latex polymer, and/or divinylbenzene (DVB)-crosslinked polystyrene latex polymer.

In embodiments, the particle and/or one or more substrate materials comprises an internal portion. In embodiments, the internal portion comprises a material having a singular specific gravity and/or density. In embodiments, the internal portion comprises at least two materials having different specific gravity and/or density. In embodiments, the term “specific gravity” refers to the ratio of a material's density with that of water. In embodiments it is the ratio of a material's density with that of water at 4° C. (where it is most dense and is taken to have the value 999.974 kg/m³), and is therefore a relative quantity with no units. In embodiments, the term “density” refers to the mass per unit volume of a material. In embodiments, density has the SI unit of kg/m3 and is an absolute quantity for each material.

In embodiments, the internal portion comprises at least a portion that is hollow and/or porous. In embodiments, the internal portion comprises at least a portion that comprises a gyroid infill, grid infill, cubic infill pattern, triangular infill, octet infill, lightning infill, and/or a combination thereof.

In embodiments, methods herein comprise doping the one or more substrate materials with a denser material. In embodiments, the denser material is infused, embedded, or otherwise placed into a bottom portion of the particle.

In embodiments, generating the particle comprises joining at least two substrate materials, where the two substrate materials differ in density.

In embodiments, the one or more substrate materials is transparent to at least a portion of the visible electromagnetic (EM) spectrum. In embodiments, the one or more substrate materials comprises glass, quartz, plastic, polyethylene terephthalate, polycarbonate, polymethyl methacrylate (acrylic), polyethylene, polyurethane, polypropylene, thermoplastic elastomers (TPE), acrylonitrile butadiene styrene (ABS), epoxies and epoxy-based photoresists, hydrogels, cyclic olefin copolymer (COC) cyclic olefin polymer (COP), poly dimethyl siloxane (PDMS), poly ether ester ketone (PEEK), polyetherimide (ULTEM) and/or nylon. In embodiments, the one or more substrate materials comprises a thickness of about or at least about 50 nm, is about or at least about 100 nm, is about or at least about 500 nm, about or at least about 1 μm, is about or at least about 10 μm, is about or at least about 100 μm, about or at least about 1 mm, about or at least about 5 mm, or about or at least about 10 mm.

In embodiments, methods of manufacturing GRPs comprise disposing one or more optically active agents onto and/or into the particle and/or the one or more substrate materials. In embodiments, the one or more substrate materials is porous, and one or more optically active agents is disposed therein. In embodiments, disposing the one or more optically active agents comprises painting, airbrushing, dip coating, abrading, and/or roughening one or more surfaces of the GRP. In embodiments, disposing the one or more optically active agents comprises printing the particle with one or more colored printing materials. In embodiments, the one or more colored printing materials comprises a resin, polymer, particles, and/or plastic.

In embodiments, the particle comprises two or more optically active agents, each exhibiting at least one distinct optical state. In embodiments, the one or more optically active agents comprise a color in the visible electromagnetic spectrum comprising an extinction, reflection, or scattering at a wavelength from about or at least about 350 nm to about or at least about 800 nm. In embodiments, the color is one or more of white, black, red, orange, yellow, green, blue, indigo, violet, and a color shade or hue therebetween.

In embodiments, the one or more optically active agents comprises a dye. In embodiments, the dye comprises one or more of Rhodamine B, Congo Red, Crystal Violet, Methylene Blue, Acridine Orange, Nile Red, Malachite Green, Eosin Y, Cresol Red, Fluorescein, and/or Indigo.

In embodiments, the one or more optically actives agent comprises a pigment. In embodiments, the pigment comprises one or more of Titanium White (PW6), Zinc White (PW4), Carbon Black (PBk7), Mars Black (PBk11), Iron Oxide Red (PR101), Cadmium Red (PR108), Alizarin Crimson (PR83), Cadmium Orange (PO20), Cadmium Yellow (PY35),Lemon Yellow (PY3), Chromium Green Oxide (PG17), Phthalo Green (PG7), Ultramarine Blue (PB29), Cobalt Blue (PB28), Cerulean Blue (PB35), Prussian Blue (PB27), Burnt Sienna (PBr7), Raw Umber (PBr7), Raw Sienna (PBr7), and/or Yellow Ochre (PY43).

In embodiments, the pigment is an organic pigment. In embodiments, the pigment is an inorganic pigment.

In embodiments, the organic pigment or inorganic pigment is a white pigment. In embodiments, the white pigment is one or more of Lead white (2PbCO₃·Pb(OH)₂), kaolin, silica (SiO₂), Titanium dioxide (TiO₂/rutile and anatase), zinc oxide (ZnO), zinc sulfide (ZnS), and/or lithopone (ZnS+BaSO₄).

In embodiments, the organic pigment or inorganic pigment is a black pigment. In embodiments, the black pigment is one or more of Coal (charcoal), groutite (α-MnOOH), manganite (γ-MnOOH), hausmannite (Mn₃O₄), Carbon black, iron oxide black (Fe₃O₄), and/or spinel black (CuCr₂O₄).

In embodiments, the organic pigment or inorganic pigment is a colored pigment.

In embodiments, the colored pigment comprises a yellow pigment. In embodiments, the yellow pigment comprises one or more of Yellow ochre (α-FeOOH), auric pigment (As₂S₃), lead ochre (PbO), lead tin yellow (Pb₂SnO₄, PbSn₂SiO₇), Naples yellow (Pb(SbO₃)₂), zinc yellow (Zn₂CrO₄), Indian yellow (C₁₉H₁₆O₁₀), Iron oxide yellow (α-FeOOH), chromium titanium yellow ((Ti,Cr,Sb)O₂), nickel titanium yellow ((Ti,Ni,Sb)O₂), lead yellow (PbCrO₄), cadmium yellow (CdS), bismuth yellow (BiVO₄).

In embodiments, the colored pigment comprises a red pigment. In embodiments, the red pigment comprises one or more of Red ocher (α-Fe₂O₃), Terra di Siena (α-Fe₂O₃), vermilion (HgS), lead red (Pb₃O₄), alizarin madder varnish, alizarin red (C₁₄H₈O₄), Iron oxide red (α-Fe₂O₃), molybdate red (Pb(Cr,S,Mo)O₄), cadmium red (Cd(S,Se)).

In embodiments, the colored pigment comprises a green pigment. In embodiments, the green pigment comprises one or more of Green earth (Fe silicates), Schweinfurt green (C₄H₆As₆Cu₄O₁₆), Chromium oxide green (Cr₂O₃), chromium oxide hydrate green (CrOOH), cobalt green (Co₂TiO₄).

In embodiments, the colored pigment comprises a blue pigment. In embodiments, the blue pigment comprises one or more of Lazurite (lapis lazuli), Egyptian blue (CaCuSi₄O₁₀), azurite (2CuCO₃·Cu(OH)₂), malachite (CuCO₃·Cu(OH)₂), cobalt blue (CoAl₂O₄), Cobalt blue (CoAl₂O₄), ultramarine blue: (Na₆Al₆Si₆O₂₄(NaSn)), iron bluea (K[FeIIIFeII(CN)₆]·xH₂O).

In embodiments, the colored pigment comprises a brown pigment. In embodiments, the brown pigment comprises one or more of Burnt umber (Fe₂O₃·xMnO₂), brown ocher (α-Fe₂O₃+Mn oxides), limonite (mixture of different Fe oxides).

In embodiments, the pigment is one or more of an oxide or oxide hydroxide pigment (TiO₂, ZnO, α-Fe₂O₃, α-FeOOH, γ-Fe₂O₃, Fe₃O₄, Cr₂O₃, CrOOH, PbO, PB₃O₄, Mn₃O₄, —MnOOH, Sb₂O₃), a complex oxide pigment (CoAl₂O₄, CuCr₂O₄, Co₂TiO₄, (Ti,Ni,Sb)O₂, (Ti,Cr,Sb)O₂), a carbonate hydroxide pigment (2PbCO₃·Pb(OH)₂, 2CuCO₃·Cu(OH)₂, CuCO₃·Cu(OH)₂), a sulfide/selenide pigment (ZnS, CdS, Cd(S,Se), CdSe, γ-Ce₂S₃, HgS, As₂S₃), a chromate/molybdate pigment (PbCrO₄, Pb(Cr,S)O₄, Pb(Cr,S,Mo)O₄, ZnCrO₄, BaCrO₄, SrCrO₄), a vanadate pigment (BiVO₄, 4BiVO₄·3Bi₂MoO₆), a stannate pigment (Pb₂SnO₄, PbSn₂SiO₇, Co₂SnO₄, CoSnO₃), a phosphate pigment (Co₃(PO₄)₂), an antimonate pigment (Pb(SbO₃)₂), an arsenate pigment (Cu(AsO₃) 2), an ultramarine pigment (NasAl₆Si₆O₂₄(NaSₙ), a hexacyanidoferrate/hexacyanoferrate pigment (K[Fe^{III}Fe^{II}(CN)₆]·xH₂O (x=14-16)), an oxonitride pigment (CaTaO₂N, LaTaON₂), an elemental-based pigment (C, Al, Cu, Cu/Zn, Au), a spinel-based pigment, and/or a rutile-based metal pigment.

In embodiments, the inorganic pigment is one or more of a transparent effect pigment, goniochromatic pigment, pearlescent pigment, metallic pigment, interference pigment, metallic effect pigment, fluorescent pigment, luminescent pigment, phosphorescent pigment, magnetic pigment, and/or anticorrosive pigment.

In embodiments, the metallic pigment comprises one or more of aluminum, bronze, and/or copper metallic pigment. In embodiments, the pearlescent pigment comprises one or more of mica, titanium dioxide, and/or bismuth oxychloride. In embodiments, the fluorescent pigment comprises one or more fluorescent dye and/or pigment comprising a fluorescent mineral. In embodiments, the phosphorescent pigment comprises zinc sulfide and/or strontium aluminate. In embodiments, the interference pigment comprises titanium dioxide-coated mica and/or aluminum oxide-coated mica.

In embodiments, the one or more optically active agents comprises an anisotropic particle. In embodiments, the anisotropic particle comprises a nanoparticle of the one or more metals, optionally comprising a nanorod of one or more of gold (Au), silver (Au), and/or aluminum (AI).

In embodiments, the one or more optically active agents comprises a plasmonic material. In embodiments, the plasmonic material comprises a pigment, particle, foil, and/or film. In embodiments, the plasmonic material comprises a polymer-film loaded with noble metal nanoparticles.

In embodiments, the goniochromatic pigment comprises aluminum coated with magnesium fluoride embedded in chromium.

In embodiments, the one or more substrate materials and/or the particle comprises one or more roughness features. In embodiments, the one or more roughness features is a variation in the smoothness of a surface of the particle that alters a degree of reflectivity of the surface at one or more wavelengths. In embodiments, the one or more roughness features is regularly or irregularly shaped. In embodiments, the one or more roughness features appears in a regular pattern and/or an irregular pattern. In embodiments, methods comprise applying the one or more roughness features to a surface of the particle by abrading and/or roughening the particle.

In embodiments, methods comprise formulating the GRP into a foil, film, thin plastic, and/or paper substrate, material, and/or surface. In embodiments, the foil, film, thin plastic, and/or paper substrate, material, and/or surface is suitable to be affixed to, or embedded in, an object.

In embodiments, methods comprise formulating the GRP into a fiber, thread, yarn, and/or twine substrate, material, and/or surface. In embodiments, the fiber, thread, yarn, and/or twine substrate, material, and/or surface is suitable to be woven into an article of clothing, a cloth, and/or a tarp.

In embodiments, methods comprise formulating the GRP into a fluid, suspension, ink, liquid film, and/or adhesive substrate, material, and/or surface. In embodiments, the fluid, suspension, ink, liquid film, and/or adhesive substrate, material, and/or surface is suitable to be applied to an object.

In aspects, the present disclosure provides, in part, sensors (or biosensors) for detecting one or more analytes in a sample comprising a plurality of particles disposed onto a reaction membrane (comprising any gravity responsive particles described herein), a sample pad configured to receive a volume of the sample and flow the sample over the reaction membrane, where each of the plurality of particles are conjugated to one or more mass detection labels configured to bind the one or more analytes, and as the sample is flowed over the plurality of particles on the reaction membrane, the one or mass detection labels binds the one or more analytes in the sample, causing a shift in the mass of the plurality of particles, which results in a movement in the plurality of particles, and where the movement elicits a change in an optical property proportional to the binding of the one or more analytes. In embodiments, the sensor is a lateral flow biosensor.

In embodiments, the change in the optical property of the sensor is a change in color (e.g., colorimetric sensor). In embodiments, the movement is a tipping onto a stable equilibrium distinct from an upright equilibrium (e.g., due to a mass shift from binding).

In embodiments, the sensor further comprises a plurality of control particles disposed onto the reaction membrane, wherein the plurality of control particles comprise one or more mass detection labels and is i) not configured to bind the one or more analytes that the plurality of particles bind, and ii) provide a control signal, optionally wherein the control signal is the same as the change in optical property of the plurality of particles. In embodiments, the first color is green and the second color is red; or wherein the first color is red and the second color is green. In embodiments, the plurality of particles and/or the plurality of control particles comprise fins, detents, or grooves that increase a surface area for binding.

In embodiments, the one or more mass detection labels comprises one or more of an antibody, antibody-format binding molecule, metal oxide particle, and metal particle. In embodiments, the one or more mass detection labels comprise an antibody or antibody-format molecule. In embodiments, the antibody or antibody-format molecule comprises one or more of a monoclonal antibody, polyclonal antibody, antibody fragment, Fab, Fab′, Fab′-SH, F(ab′)2, Fv, single chain Fv (scFv), diabody, nanobody, linear antibody, bispecific antibody, multi-specific antibody, chimeric antibody, humanized antibody, human antibody, and fusion protein comprising an antigen-binding portion of an antibody.

In embodiments, the metal comprises one or more of as gold (Au), silver (Ag), platinum (Pt), nickel (Ni), iron (Fe), palladium (Pd), tungsten (W), tantalum (Ta), osmium (Os), iridium (Ir), lead (Pb), BaTiO₃, SnO₂, PbO₂, and TiO₂.

In embodiments, the one or more mass detection labels comprise a dimension of about or at least about 10 nm, about or at least about 20 nm, about or at least about 30 nm, about or at least about 40 nm, about or at least about 50 nm, about or at least about 60 nm, about or at least about 70 nm, about or at least about 80 nm, about or at least about 90 nm, about or at least about 100 nm, about or at least about 120 nm, about or at least about 140 nm, about or at least about 160 nm, about or at least about 180 nm, about or at least about 200 nm, about or at least about 300 nm, about or at least about 400 nm, about or at least about 500 nm, about or at least about 1,000 nm, about or at least about 2,000 nm, or about or at least about 3,000 nm.

In embodiments, the one or more mass detection labels are attached to the plurality of particles and/or the plurality of control particles using a biomolecular capture film and/or biotin-streptavidin linkage. In embodiments, the biomolecular capture film comprises a thickness of about or at least about 1 nm, about or at least about 2 nm, about or at least about 3 nm, about or at least about 4 nm, about or at least about 5 nm, about or at least about 10 nm, about or at least about 20 nm, about or at least about 30 nm, about or at least about 50 nm, about or at least about 100 nm, about or at least about 200 nm, about or at least about 500 nm, about or at least about 1 μm, about or at least about 2 μm, or about or at least about 10 μm.

In embodiments, the sensor further comprises a conjugate pad connecting the sample pad with the reaction membrane and/or an absorbent pad at the end of the reaction membrane opposite of the sample pad.

In embodiments, the one or more analytes comprise one or more of a protein, peptide, nucleic acid, DNA, RNA, lipid, sugar, metabolite, cell, capsid, antigen, biomarker, ionic species, heavy metal, bacterium, virus, and pathogen.

In embodiments, the sample comprises one or more of blood, sera, plasma, bone marrow, lymph, saliva, sputum, mucus, respiratory or nasal secretion, oropharyngeal swab, nasopharyngeal swab, oral swab, ductal lavage, bronchoalveolar lavage, cerebrospinal fluid, skin swab, vaginal swab, gastric juice, ascites, peritoneal fluid, pleural fluid, gynecological fluids, pus, perspiration, tears, urine, stool; homogenized biopsy, tissue, or cell sample; a tumor sample; a water sample; a sample of foodstuffs and/or surfaces for storing or preparing foodstuffs, beverages, homogenized animal products intended for consumption, samples taken from a surface that is used for preparing food, and soil samples.

In embodiments, the plurality of particles and/or the plurality of control particles are arranged in an array on the reaction membrane, optionally wherein the array comprises one or more lines on the reaction membrane visible by human vision.

In aspects, the present disclosure provides, in part, methods of authenticating an object using a detectable gravity responsive particle (GRP) signal, the method comprising providing an object comprising an array of particles (comprising any gravity responsive particle disclosed herein), applying a force to the array of particles to cause a movement in the array of particles which elicits a change in an optical property in the array of particles, and detecting the change in the optical property as a function of the movement of the array of particles.

In embodiments, the object comprises paper, plastic, glass, metal, fabric, wood, a window, an electronic device, a computer chip, construction materials, and/or human or animal tissue or skin. In embodiments, the object comprises documentation, optionally paper currency.

In embodiments, the object surface comprises one or more regions that are substantially planar, non-planar, convex, concave, or without a well-defined shape. In embodiments, the array of particles are located on a surface and/or substrate on an interior surface of the object and/or on an exterior surface of the object.

In embodiments, the force used in the method comprises gravity, mechanical force, or magnetic force. In embodiments, applying the force comprises moving the object relative to the direction of gravity and/or applying a magnetic field.

In embodiments, the change in the optical property comprises a change in one or more color in the visible electromagnetic spectrum comprising an extinction, reflection, or scattering at a wavelength from about or at least about 350 nm to about or at least about 800 nm. In embodiments, wherein the one or more color comprises one or more of white, black, red, orange, yellow, green, blue, indigo, violet, or a color shade or hue therebetween. In embodiments, the change in optical property is detectable by human vision.

In embodiments, the array of particles is arranged in a pattern, optionally comprising one or more shape, symbol, letter, number, picture, image, or message; and/or wherein the change in the optical property that is detected is substantially in the arrangement of the array of particles.

In embodiments, detecting the change in the optical property comprises using one or more of a camera, spectrometer, filter, window, grating, beam splitter, polarizer, collimator, birefringent element, prism, bandpass filter, aperture, or lens to detect an optical signal emanating from the object. In embodiments, the detecting is performed as a function of the movement and as a function of time. In embodiments, the method further comprises comparing the change in the optical property to a standard signal, wherein the comparison verifies the authenticity of the object.

In aspects, the present disclosure provides, in part, electromagnetic vibrational energy capture device comprising one or more gravity responsive particle (e.g., as described herein) which comprises a shape and a center of mass (CoM) that enables motion between a plurality of positions when a force is applied and a magnet material, wherein the magnet on the GRP moves as a function of the motion between the plurality of positions, and one or more coils configured to induct an electric current, where the one or more GRPs is arranged relative to the one or more coils such that the motion between the plurality of positions from the applied force inducts an electrical current in the one or more coils, converting the force applied to the one or more GRPs into the electric current. In embodiments, the shape and the CoM of the one or more GRPs enables relaxation to a stationary position from the plurality of positions from gravitational force.

In embodiments, the magnetic material comprises a magnet (e.g., a permanent magnet), optionally affixed to the top, bottom, and/or side of the one or more GRPs. In embodiments, the electromagnetic vibrational energy capture device comprises one coil for each GRP, or two or more coils for each GRP. In embodiments, the force comprises gravity or a mechanical force, optionally wherein the mechanical force is agitation, shaking, vibration, or tilting.

In embodiments, the motion of the one or more GRPs causes movement of each magnet into and out of the one or more coils, optionally wherein the movement into the one or more coils induces a positive current, and movement out of the one or more coils induces a negative current, or wherein the movement into the one or more coils induces a negative current, and movement out of the one or more coils induces a positive current.

In embodiments, the electromagnetic vibrational energy capture device further comprises a housing that contains the one or more GRPs and the one or more coils. In embodiments, the electromagnetic vibrational energy capture device comprises an array of GRPs arranged relative to an array of coils.

In embodiments, the electromagnetic vibrational energy capture device further comprises one or more elements in electric communication with the one or more coils configured to store an electrical charge from the electrical current inducted in the one or more coils. In embodiments, the one or more elements comprises one or one batteries.

### DESCRIPTION OF THE DRAWINGS

FIGS. 1A-1P depict illustrative, non-limiting diagrammatic representations of macroscale figurines that exhibit physical behaviors relating to gravity responsive particles (GRPs) described herein. FIGS. 1A-1H depict typical designs of “roly-poly” toys, also called Nevalyashka dolls, wobble toys, tilting dolls, or bobo dolls. FIGS. 1I-1L depict conceptual line drawings of various roly-poly toys illustrating relevant physical features, including a center of mass that is low to the surface the toy balances upon, where the toy is composed of an upper material that has a lower specific gravity than the bottom material.

FIG. 2 depicts an illustrative, non-limiting schematic of the physical principles of motion of a prototypical roly-poly toy as it relates to GRPs described herein. Position A relates to a vertical plane of mechanical equilibrium, position B relates to a vertical plane of mechanical instability, where the arrow indicates the direction of the gravitational force, F, m₁ is a material having a mass of lower specific gravity (i.e., density), m₂ is a material having a mass of higher lower specific gravity, and C is the center of mass (CoM; also known as the centroid or center of gravity). When the toy is tilted (i.e., moved from position A to position B), the CoM is lifted slightly above its original position (also becoming offset relative to the vertical, y). When the toy is released, the force of gravity acts on the CoM, generating a torque that makes the toy roll back and forth until it comes to rest at position A.

FIG. 3 depicts an illustrative, non-limiting schematic of a gravity responsive particle (GRP). The scale bar relates to the relative size of the GRP on the order of about 20 nm to about 2 mm, where the top part is comprised of an optically active material having color A, and the bottom part is comprised of an optically active material having color B.

FIG. 4 depicts an illustrative, non-limiting diagrammatic representation a series of GRPs. At stationary equilibrium, the observer sees optical property “A,” where upon mechanical agitation (i.e., shaking) the observer can see a mix of optical property “A” and “B,” until the GPRs relax due to a restoring force from gravity to return to the stationary equilibrium.

FIGS. 5A-5I depict illustrative, non-limiting diagrammatic representations of GRP shapes. The shading indicates different optically active materials in the GRP, which can have the equivalent or different densities (specific gravities).

FIGS. 6A-6E depict illustrative, non-limiting diagrammatic representations of GRP shapes. FIG. 6A depicts a paraboloid in cross-section. FIG. 6B depicts an oblate hemispheroid in cross-section. FIG. 6C depicts a prolate hemispheroid in cross-section. FIG. 6D depicts a 3-dimensional (3D) rendering of an oblate hemispheroid particle, and FIG. 6E depicts a 3D rendering of a prolate hemispheroid particle.

FIGS. 7A-7F depict illustrative, non-limiting diagrammatic representations of GRP shapes with varying degrees of symmetry and density.

FIGS. 8A-8J depict illustrative, non-limiting diagrammatic representations of geometries for a top portion of GRPs. FIGS. 8A, 8B, and 8C depict conical GRP particles of varying dimensions with respect to a bottom part hemisphere (also shown). FIGS. 8D, 8E, and 8F depict GRP particles having square pyramidal top portions, each with different ratio of height to width. FIGS. 8G, 8H, 8I, and 8J depict GRP particles having top parts as a square pyramid with each face having a different optical property depicted by varying patterns, with FIG. 8H being a 90° counterclockwise rotated view relative to FIG. 8G; FIG. 8I being a 90° counterclockwise rotated view relative to FIG. 8H; FIG. 8J being a 90° counterclockwise rotated view relative to FIG. 8I; and FIG. 8G being a 90° counterclockwise rotated view relative to FIG. 8I.

FIGS. 9A-9H depict illustrative, non-limiting diagrammatic representations of geometries for a top portion of a GRP. FIG. 9A depicts a trigonal pyramid, FIG. 9B depicts a pentagonal pyramid, FIG. 9C depicts a hexagonal pyramid, FIG. 9D depicts a truncated square pyramid, FIG. 9E depicts a truncated cone, FIG. 9F depicts a truncated cone with non-parallel faces; FIG. 9G depicts an example of a shape with no planes of symmetry but possessing a glide axis of symmetry; and FIG. 9H depicts is an example of a 3D shape with no symmetry.

FIGS. 10A-10E depict illustrative, non-limiting diagrammatic representations of porous substrates for GRPs. FIG. 10A depicts 4 different 2-dimensional (2D) renderings of porosity; FIG. 10B depicts a quasi-symmetric cylindrical cross-section of a porous object; FIG. 10C depicts a porous solid with 3D porosity; FIG. 10D depicts a porous hemispherical bottom part of a GRP; FIG. 10E depicts a side view of a GRP having varying porosity.

FIGS. 11A-11D depict diagrammatical representations of a 3D computer-aided design (CAD) model of a fin-shaped GRP prototype viewed from various angles. FIGS. 11A-11B depict the model from an upper right view, with shadowing on a horizontal surface to illustrate the prototype's orientation, e.g., on a horizontal surface. FIG. 11C depicts a side profile view of the prototype. FIG. 11D depicts a top-down view, where the center circle represents a flat top face, as view from the top.

FIGS. 12A-12C depict illustrative, non-limiting diagrammatic representations of side views of GRPs having varied optical properties, where shading/patterns denote surfaces and/or parts of the GRP having separate optical properties.

FIG. 13 depicts an illustrative, non-limiting diagrammatic representation of the motion of an array of GRPs having side-to-side variation in optical properties. The labels at the right of each panel indicate the degree and direction of GRP tilt (with Equilibrium corresponding to 0°/vertical).

FIG. 14 depicts an illustrative, non-limiting schematic of the geometrical features of a GRP. The lower part of the GRP is an oblate hemispheroid having a vertex at position B, while the upper part is a prolate hemispheroid having a vertex at position A, with μ (a dimensionless constant between 0 and 1) chosen to be μ=2/3, and position c being the point where the center of curvature of both vertices is located.

FIG. 15 depicts a graphical representation of the height of the center of mass from a plane (h) as a function of the tilt angle from equilibrium (θ) for a doubly critical GRP (c=center of mass) of FIG. 13 (with μ=2/3); θ=0 corresponds to the GRP positioned with B in contact with the plane.

FIG. 16 depicts a non-limiting, diagrammatic representation of the motion of a doubly critical GRP having μ=2/3 as depicted in FIG. 14.

FIGS. 17A-17C depict non-limiting, diagrammatical representations of doubly critical GRPs, each being an STL image depicting a geometry having μ=4/9 (FIG. 17A), μ=15/23 (FIG. 17B), and μ=2/5 (FIG. 17C).

FIGS. 18A-18E depict non-limiting, diagrammatical representations of Gömböc-shaped GRPs. FIG. 18A depicts a photographic image of a macroscale Gömböc object and a comparison of stability(S) and instability (I) relative to a prototypical roly-poly toy; FIGS. 18B, 18C, 18D, and 18E depicts STL images of a single Gömböc GRP in different orientations.

FIG. 19 depicts a non-limiting flowchart of a classification of colorants for GRPs.

FIG. 20 depicts a non-limiting flowchart of a classification of inorganic pigments for GRPs.

FIGS. 21A-21G depict non-limiting, diagrammatical representations of GRPs exhibiting the differential extinction of anisotropic plasmonic particles. FIG. 21A depicts a transmission electron microscopy (TEM) image of anisotropic gold (Au) nanorods having dimensions of roughly 10 nm×50 nm, scale bar is 50 nm. FIG. 21B depicts a graph describing the optical extinction of 10 nm×50 nm Au nanorods in aqueous solution. FIG. 21C depicts a GRP having a single layer of anisotropic plasmonic metal nanorods. FIG. 21C depicts a GRP having multiple layers of anisotropic metal nanorods. FIG. 21E depicts a GRP with anisotropic metal nanorods disposed on the outer surface of the particle. FIG. 21F depicts the optical properties of GRPs shown in FIG. 21D at a stationary equilibrium configuration. FIG. 21G depicts the optical properties of GRPs shown in FIG. 21D in a tilted configuration after agitation.

FIGS. 22A-22B depict non-limiting, diagrammatical representations of plasmonically surface-coupled GRPs. FIG. 22A depicts a GRP positioned on a material with plasmonic properties, where the GRP has plasmonic materials at or near the top. The GRP has optical properties that change as a function of position, such that the plasmonic materials at or near the top moves nearer the plasmonic material of the surface the GRPs as disposed on. FIG. 22B depicts a GRP having plasmonic material on or nearer the bottom/side (i.e., tilting surface) portion, such that tilting brings the plasmonic material in very close proximity or in contact with the plasmonic surface the GRPs are disposed on.

FIGS. 23A-23B depict non-limiting, diagrammatical representations of GRPs incorporating goniochromatic pigments at a stationary equilibrium position (FIG. 23A) and after being tilted (FIG. 23B).

FIGS. 24A-24D depict non-limiting, diagrammatical representations of GRPs with varying degrees of surface roughness features. FIG. 24A depicts randomly spaced roughness features disposed on the side(s) of a GRP. FIG. 24B depicts regularly spaced roughness features on the side(s) of a GRP. FIG. 24C depicts an array of GRPs at equilibrium, having smooth tops and roughness features on the sides, leading to an observed higher reflectivity from the smooth top surface. FIG. 24D depicts the array of GRPs of FIG. 23C being tilted, revealing a less reflective orientation due to the roughness features.

FIGS. 25A-25E depict non-limiting, diagrammatical representations of GRPs placed into a substrate having indentations. FIG. 25A depicts a GRP disposed onto a substrate having an indentation, and FIG. 25B depicts motion of a GRP disposed within an indentation. FIG. 25C depicts a linear array of GRPs disposed within indentations. FIG. 25C depicts a top view of an array of indentations that appear on the surface of a substrate where GRPs can be disposed. FIG. 25E depicts a side view of a substrate having an indentation containing multiple GRPs.

FIGS. 26A-26E depict non-limiting, diagrammatical representations of GRPs placed into arrays of indentations. FIG. 26A depicts a top view assembly of GRPs into a 3×3 array of indentations. FIG. 26B and FIG. 26C are top views of regular 4×4 and 2×2 arrays, respectively. FIG. 26D depicts a top view of a 4×1 array, and FIG. 26E depicts a top view of an irregular array (i.e., with no symmetry).

FIGS. 27A-27C depict non-limiting, diagrammatical representations of GRPs placed into arrays of indentations on a 2D substrate which can be assembled into 3D objects. FIG. 27A depicts a regular 8×8 array of the 4×4 arrays shown in FIG. 26C. FIG. 27B depicts an assembly of arrays of 4×4 arrays, as shown in FIG. 26C, and 4×1 arrays (as shown in FIG. 26D, and rotated by 180°) to form a capital letter T. FIG. 27C depicts an irregular assembly of 9 arrays, as shown in FIGS. 26A-26E. Each of the 2D arrangements of GRPs shown in FIGS. 27A-27C can optionally be folded along the lines shown to be assembled into 3-dimensional objects.

FIGS. 28A-28M depict non-limiting, diagrammatical representations of structures for placing arrangements of GRPs onto surfaces. FIGS. 28A, 28B, and 28C depict arrangements of posts (i.e., stops or detents) of variable heights (as compared to a reference GRP in FIG. 28D) where GRPs can be placed in between, or on top of. FIGS. 28E, 28F, and 28G depict arrangements of variable spacings between posts; and FIGS. 28H, 28I, 28J, and 28K depict different shapes of posts. FIG. 28L depicts a GRP positioned on a surface between posts such that the vertex of the bottom part contacts the same surface as the four posts.

FIG. 28M depicts a GRP positioned on top of posts such that the vertex of the bottom part is not in contact with the surface to which the posts are disposed on.

FIGS. 29A-29F depict non-limiting, diagrammatical representations of structures for placing arrangements of GRPs onto surfaces. FIG. 29A depicts 4 GRPs having square pyramidal top portions (e.g., as illustrated in FIG. 8G-8J) arranged on a surface between a 3×3 array of square posts (i.e., stops or detents).

FIG. 29B depicts the top view of GRP arrangements as shown in FIG. 29A. FIGS. 29C-29F depict top views of the tilted GRPs of FIG. 29A. Gray arrows indicate the direction of the tilt, and patterned faces of the square pyramid indicate different optical properties.

FIGS. 30A-30F depict non-limiting, diagrammatical representations of substrate surfaces for placing arrangements of GRPs. FIG. 30A depicts a planar substrate without grooves. FIGS. 30B and 30C depict substrates with parallel, rounded grooves. FIG. 30D depicts a side view of a substrate with variable types of grooves, where w is the groove width, x is the space between grooves, and d is the groove depth. FIG. 30E depicts scanning electron microscopy (SEM) images of 4 different grooved surfaces varying the w, x, and d parameters, each with a scale bar equal to 100 microns. FIG. 30F depicts five different groove spacings (x).

FIGS. 31A-31D depict non-limiting, diagrammatical representations of patterns of grooved substrates for arranging GRPs. FIG. 31A depicts linear, parallel grooves; FIG. 31B depicts circular/spiral grooves; FIG. 31C depicts parallel, sinusoidal grooves; and FIG. 31D depicts grooves in the form of letters.

FIG. 32 depicts a non-limiting, diagrammatical representation of an array of GRPs positioned in linear, parallel, square grooves of a substrate.

FIGS. 33A-33F depict non-limiting, diagrammatical representations of patterns of GRPs arrays positioned within a top and bottom substrate. FIG. 33A depicts an array of GRPs with an opaque bottom substrate, a transparent top substrate, and two supports as spacers between the top and bottom substrate. FIG. 33B depicts a close-up view of a bottom substrate containing indentations (left), and posts (right) for positioning the GRPs. FIG. 33C depicts the array of GRPs in a tilted configuration with top and bottom substrates of FIG. 33A. FIG. 33D depicts an array of the GRPs, as shown in FIG. 33B, with a transparent top substrate and a transparent bottom substrate. FIG. 33E depicts an array of GRPs, as shown in FIG. 33D, in a tilted configuration, illustrating that an observer looking through either the top substrate or the bottom substrate will observe different optical properties as the GRPs move. FIG. 33F depicts arrays of the doubly-stable GRPs, as described in FIGS. 14-16, with transparent top and bottom substrates, illustrating that, as the GRPs tilt between stable states, that observers looking through the top and bottom substrates will see opposite sides of the GRPs in each state, revealing different optical properties.

FIGS. 34A-34F depict non-limiting, diagrammatical representations of GRPs designed to be close-packed patterns into arrays. GRPs designed to be positioned in closely-packed arrangements when tilted with shorter/fatter GRPs (as shown in FIG. 34A), and taller/thinner configurations (as shown in FIG. 34B). FIG. 34C depicts a GRP not designed to tightly pack when tilted. FIG. 34D depicts a substrate covered with the closely-packed tilted GRPs of FIG. 34A; FIG. 34E depicts a substrate covered with the GRPs of FIG. 34C. FIG. 34F depicts a close-up view of the substrates in FIGS. 34D and 34E.

FIGS. 35A-35C depict non-limiting, diagrammatical representations of GRPs designed to have equivalent shape, but with differing compositional densities and centers of mass (CoM). FIG. 35A depicts a GRP with higher center of mass and comprising denser material (α), with higher center of mass and less dense material (β), with lower center of mass and more dense material (γ), and lower center of mass and less dense material (δ). FIG. 35B depicts GRPs α, β, and C to which an equal amount of work (i.e., energy transfer to the GRP) has been applied. FIG. 35C depicts GRPs α, β, and γ tilted to the same extent.

FIGS. 36A-36D depict diagrammatical representations of a 3D computer-aided design (CAD) model of a fin-shaped GRP prototype at various angles. FIGS. 36A-36B depict the model from an upper right view, with shadowing on a horizontal surface to illustrate the prototype's orientation, e.g., on a horizontal surface. FIG. 36C depicts a side profile view of the prototype. FIG. 36D depicts a top-down view, where only the flat, horizontal square top is visible, as view from the top.

FIGS. 37A-37D depicts STL images of a 3D model at various angles of the sGRP prototype of FIGS. 36A-36C. FIGS. 37A and 37B depict the model from a view to its upper right, with a shadow on a horizontal surface to illustrate the design's orientation. FIG. 37C shows the side view of the design straight on. FIG. 37D shows the top-down view, which only has the horizontal square top visible.

FIGS. 38A-38D depict diagrammatical representations of a 3D computer-aided design (CAD) model of a GRP prototype at various angles. FIGS. 38A and 38B depict the model from a view relative to the upper right, with shadowing on a horizontal surface to illustrate the prototype's orientation, e.g., on a horizontal surface. FIG. 38C depicts a side profile view of the prototype illustrating hollowed sections. FIG. 38D depicts a top-down view, with each of the vertical rectangles showing three flat surfaces of the upper half's walls, as view from the top.

FIGS. 39A-39D depicts images of a 3D model at various angles of an sGRP prototype. FIGS. 39A and 39B depict the model from a view to its upper right, with a shadow on a horizontal surface to illustrate the design's orientation. FIG. 39C shows the side view of the design straight on. FIG. 39D shows the top-down view, with each of the vertical rectangles showing the three flat surfaces of the upper half's walls.

FIGS. 40A-40D depicts images of a 3D model at various angles of an sGRP. FIGS. 40A and 40B depict the model from a view to its upper right, with a shadow on a horizontal surface to illustrate the design's orientation. FIG. 40C shows the side view of the design straight on. FIG. 40D shows the top-down view, with each of the three center vertical rectangles showing the three flat surfaces of the upper half's walls.

FIGS. 41A-41D depict non-limiting diagrammatic representations of the motion of sawtooth GRPs (sGRPs). The sGRP used for this model is that of FIG. 40. In FIG. 41A, the sGRP is at equilibrium, with its bottom point in contact with the surface. FIG. 41B shows the critical angle (θ_{crit}) at which the behavior of the sGRP changes. FIG. 41C shows the normal rocking/wobbling behavior of the sGRP when tipped to angles less than the critical angle (θ<θ_{crit}), eventually returning to the same equilibrium as shown in FIG. 41A. FIG. 41D shows the behavior when the sGRP is tipped past the critical angle (θ>θ_{crit}); now there are two points of contact between the sGRP and surface and the particle rests on its side.

FIG. 42 depicts a non-limiting, diagrammatic representation of GRPs packed into an array, tilted such that the sides of a given GRP are in contact with an adjacent GRP, with the tops of the GRPs generating a sawtooth pattern.

FIG. 43 depicts a non-limiting, diagrammatical representation of shapes of particles formed by particle extrusion. Particles appear as “peanut,” “snowman,” or “pear” shapes.

FIGS. 44A-44B depict non-limiting, diagrammatical representations of non-spherical, polystyrene latex particles. FIG. 44A depicts “snowmen”-shaped polystyrene latex particles of varying sizes and size ratios between lobe sizes, where each lobe is composed of a different material. FIG. 44B depicts a representative light microscopy image of snowmen-shaped polystyrene latex particles of uniform, 15 μm size.

FIG. 45 depicts a non-limiting, diagrammatical representation of a 3D printed substrate for holding GRPs having approximately a 169 nm thickness.

FIGS. 46A-46I depict non-limiting, diagrammatical representations of a GRP prototype designed for fabrication by 3D printing. FIGS. 46A-46C depict views of a 3D computer-aided design (CAD) model of the GRP. FIG. 46D depicts the key dimensions of the GRP, with a height of 1.92 mm, a width at the top portion of 0.8 mm, and a width at the boundary of the top portion and the bottom portion of 1.6 mm. FIG. 46E depicts a gyroid pattern to remove material/density from a top portion of the GRP, and FIG. 46F depicts a cross hatch pattern to remove material/density from a GRP. FIGS. 46G, 46H, and 46I depict three different orientations for printing the GRP of, from left to right: top, middle, and side part of the GRP contacting a glass substrate used for 3D printing.

FIGS. 47A-47D depict non-limiting, diagrammatical representations of titled side view and top views of arrangements of GRPs with bottom and top substrates and posts. FIG. 47A depicts an array of 3×3 posts on a transparent bottom substrate. FIG. 47B depicts the assembly of FIG. 47A, with 4 GRPs placed between the posts. FIG. 47C depicts the assembly of FIG. 47B onto which a transparent substrate has been placed by contacting the posts. FIG. 47D depicts the assembly of FIG. 47C, in which the GRPs are tilted.

FIG. 48 depicts non-limiting, diagrammatic representations of stable and unstable GRPs. The images are chronological moving left to right representing time with the arrows. The top images depict a stable GRP with a center of mass below the radius of curvature. The bottom images depict an unstable GRP with a high center of mass above the radius of curvature. The arrows and labels in between the top and bottom images indicate the effects of raising and lowering the center of mass relative to the radius of curvature.

FIG. 49 depicts non-limiting, diagrammatic representations of stable and unstable GRPs. These images show the same effect as in FIG. 48, highlighting how adding mass on top of the GRP shifts the center of mass and the response to gravity. Added mass is represented with a dark gray bar on the GRP in the bottom row with the higher center of mass.

FIGS. 50A-50C depicts a non-limiting, diagrammatic representations of a side view of a GRP with a line at the radius of curvature delineating top (above the radius of curvature) and bottom (below the radius of curvature) sections of the GRP. FIG. 50B is a table outlining how adding or subtracting mass to the top and bottom of a GRP affects its center of mass. FIG. 50C is a table outlining how adding or subtracting mass to the top or bottom of a GRP through a sandwich or competitive immunoassay that incorporates mass-based labels impacts the center of mass of the GRP.

FIG. 51 depicts non-limiting, diagrammatic representations of a surface-confined sandwich immunoassay in the presence of a target analyte, with the capture antibodies attached to the surface, and with a detection antibody labelled with a dense mass particle.

FIG. 52 depicts non-limiting, diagrammatic representations of a surface-confined competitive immunoassay, with the capture antibodies attached to the surface, and with a dense mass label attached to a surrogate target.

FIG. 53 depicts non-limiting, diagrammatic representations of a side view of a lateral flow test strip. The droplet represents the sample and buffer with an arrow pointing to the sample pad. There are stable GRPs at equilibrium at the test line and control line.

FIGS. 54A-54I depict non-limiting, diagrammatic representations of elements of a lateral flow sandwich immunoassay test strip. FIG. 54A depicts a detection antibody conjugated to a mass label. FIG. 54B shows the target analyte. FIG. 54C shows a capture antibody, and FIG. 54D shows a control antibody. FIGS. 54E-54G show the device through an illustrative test process. FIG. 54E shows the test strip with a pipette applying a small volume to the test strip. The test line (left) has GRPs with capture antibodies attached to their top section, and the control line (right) has GRPs with control antibodies immobilized on their top section. FIG. 54F shows the sample with target added to the sample pad. FIG. 54G shows the result after the sample has flowed through the test region (with the capture antibody) and control regions (with the control antibody). FIG. 54H shows the sandwich immune complex at the test line after a sample containing target has flowed past. FIG. 54I shows the result at the control line after the sample has flowed past.

FIGS. 55A-55C depict non-limiting, diagrammatic representations of a lateral flow test strip incorporating GRPs with a negative test result. FIG. 55A shows the test strip from a top-down view with a light grey test line (left) and a dark grey control line (right). FIGS. 55B and 55C show the same test with three individual GRPs outlined as they may appear on the test strip, with FIG. 55B showing a top-down view, and FIG. 55C showing a magnified view from a slightly upwards angle.

FIGS. 56A-56B depict non-limiting, diagrammatic representations of a lateral flow test strip incorporating GRPs with a negative test result. FIG. 56A shows the test strip from a slightly upwards view and FIG. 56B shows the same test strip from a top-down view. Both the control line and test line have two columns of 10 GRPs. All GRPs are at equilibrium on the test line showing only the top grey color in the top-down view, while all of the GRPs on the control line are tipped to their right or left revealing their dark bottom color.

FIGS. 57A-57C depict non-limiting, diagrammatic representations of a lateral flow test strip incorporating GRPs with a positive test result. FIG. 57A shows the test strip from a top-down view with a dark grey test line and control line. FIGS. 57B and 57C show the same test with three individual GRPs outlined as they would look if on the test. FIG. 57B shows the test from the same top-down view as FIG. 57A, and FIG. 57C shows a closer up view from a slightly upwards angle. On both the test line and the control line the GRPs have tipped, some to the left and some to the right, revealing their darker bottom color, indicating a positive result.

FIG. 58 depicts a non-limiting, diagrammatic representation of a side view of a finned GRP with a coating (represented as a curvy line and white space) on the fins.

FIG. 59 depicts a non-limiting, diagrammatic representation of a side view of a finned GRP with a coating (represented as a curvy line and white space) on the bottom surface of the GRP.

FIG. 60 depicts a non-limiting, diagrammatic representation of a side view of a finned GRP with a coating (represented as a curvy line and white space) on the top and bottom surfaces of the GRP.

FIGS. 61A-61H depict non-limiting, diagrammatic and photographic representations of various GRPs. FIGS. 61A and 61E depict photographs of two 3D printed GRPs. FIGS. 61B-61D and 61F-61H depict STL images of 3D models (viewed from an upwards right angle) of the various GRPs.

FIGS. 62A-62C depict non-limiting, diagrammatic representations of three different GRPs of various shapes, each functionalized with two or more materials with different optical signals. The different optical signals are denoted by the various optical channels (e.g., ch 1, ch 2, and ch 3) on each GRP.

FIG. 63 depicts a non-limiting, diagrammatic representation of a side view of a detector and an optical element reading an optical signal emanating from a GRP.

FIGS. 64A-64E depict non-limiting, diagrammatic representations of optical signatures as a function of time. FIG. 64A depicts a constant (high) signal. FIG. 64B depicts a constant (low) signal. FIG. 64C depicts a decaying signal. FIG. 64D depicts a signal that initially peaks and falls with relaxation. FIG. 64E depicts a signal that falls and then rises.

FIG. 65 depicts a non-limiting, diagrammatic representation of Faraday's law.

FIGS. 66A-66C depict non-limiting, diagrammatic representations of a side-view of a GRP with a magnetic top at various positions with respect to a coiled wire. FIG. 66A shows the GRP at equilibrium where magnet does not enter the coil. FIG. 66B shows the GRP tipped to the right with the magnet inside of the coil and FIG. 66C shows the GRP tipped to the left with the magnet far from the coil.

FIGS. 67A-67C depict non-limiting, diagrammatic representations of a side-view of a GRP with a magnetic top at various positions with respect to a coiled wire on both sides. FIG. 67A shows the GRP at equilibrium where the magnet is not within either coil. FIGS. 67B-67C show the GRP tipped to the right and to the left respectively where in both directions the magnet enters one of the coils.

FIG. 68 depicts a non-limiting, diagrammatic representation of a 2×2 array of four GRPs with magnetic tops at equilibrium with coiled wires on either side of each toy.

FIG. 69 depicts images of four GRPs. The ruler tick marks along the top of the image represent millimeter marks. The GRPs are painted two different colors, where the painted surfaces are either split vertically (two GRPs on the left) or split horizontally (two GRPs on the right). The top two particles are tipped on their side, while the bottom two particles are upright.

FIGS. 70A-70O depict images of a GRP, as imaged from a top view. FIG. 70A depicts the GRP fully tilting from stationary equilibrium in a first direction (e.g., to the right) and showing a first surface painted with a first optical agent (e.g., the lighter color). FIG. 70B depicts the GRP tiling back the opposite direction (e.g., to the left) and showing a second surface painted with a second optical agent (e.g., the darker color). Each of FIGS. 70A-70I depict chronological images taken over a 9.35 second time course showing various points in the directional change in the wobble cycle until resting at stationary equilibrium in FIG. 70I.

FIGS. 71A-71D depict diagrammatical representations of a 3D computer-aided design (CAD) model of a GRP prototype at various angles. FIGS. 71A and 71B depict the model from a view relative to the upper right, with shadowing on a horizontal surface to illustrate the prototype's orientation, e.g., on a horizontal surface. FIG. 71C depicts a side profile view of the prototype. FIG. 71D depicts a top-down view, with each of the vertical rectangles showing three flat surfaces of the upper half's walls, as view from the top.

FIGS. 72A-72I depict images of a GRP, as imaged from a top view. FIG. 72A depicts the GRP fully tilting from stationary equilibrium in a first direction (e.g., to the right) and showing a first surface painted with a first optical agent (e.g., the lighter color). FIG. 72B depicts the GRP tiling back the opposite direction (e.g., to the left) and showing a second surface painted with a second optical agent (e.g., the darker color). Each of FIGS. 72A-72I depict chronological images taken over a 4.9 second time course showing various points in the directional change in the wobble cycle until resting at stationary equilibrium in FIG. 72I.

FIGS. 73A-73C depict diagrammatical representations of a 3D computer-aided design (CAD) model of a GRP prototype at various angles. FIG. 73A depicts the model from a ¾ view, with shadowing on a horizontal surface to illustrate the prototype's orientation, e.g., on a horizontal surface. FIG. 73B depicts a side profile view of the prototype. FIG. 73C depicts a top-down view, where the center circle represents a flat top face, as view from the top.

FIGS. 74A-74I depict images of a GRP, as imaged from a top view. FIG. 74A depicts the GRP being tilted (e.g., using forceps) from a stationary equilibrium in a first direction (e.g., to the right) and showing a first surface painted with a first optical agent (e.g., the darker color). FIG. 74B depicts the GRP tiling back the opposite direction (e.g., to the left) once released from the forceps, showing a second surface painted with a second optical agent (e.g., the lighter color). Each of FIGS. 74A-74I depict chronological images taken over a 3.35 second time course showing various points in the directional change in the wobble cycle until resting at stationary equilibrium in FIG. 74I.

FIG. 75 depicts an image of a GRP prototype fabricated by 3D printing. Tick marks at the top of are millimeter marks. The GRP prototype is 0.7 mm in diameter, with the middle GRP placed on its side, and the left and right GRPs are upright and viewed from their tops.

FIG. 76 depicts an image of the GRP prototype from FIG. 76 (right) in comparison to GRP prototype shown in FIGS. 73A-73C and FIGS. 74A-74I. Tick marks at the top of are millimeter marks. The GRP prototype (left) is 4.8 mm in diameter, and the GRP prototype (right) is 0.7 mm in diameter, or approximately 5-fold smaller in size. Both prototypes have the same design, but 3D-printed at different scales.

FIGS. 77A-77C depict images of the fin-shaped GRP prototype of FIGS. 11A-11D. The images were captured via a dual 12 MP wide-angle camera (f/1.8 aperture). FIG. 77A shows the prototype from a front upward angle. FIG. 77B shows the prototype's side view taken with the prototype resting on a horizontal surface. FIG. 77C depicts a top-down view of the prototype.

FIGS. 78A-78C depict images of the fin-shaped GRP prototype of FIGS. 36A-36D. The particles were 3D-printed using a using a Multi Jet Fusion (MJF) 3D printer with polyamide 12 40% glass-filled back (PA12; Nylon 12). The images were captured via a dual 12 MP wide-angle camera (f/1.8 aperture). FIG. 78A shows the prototype from a front upward angle. FIG. 78B shows the prototype's side view taken with the prototype resting on a horizontal surface. FIG. 78C depicts a top-down view of the prototype.

FIGS. 79A-79C depict images of the fin-shaped GRP prototype of FIGS. 36A-36D. The particles were 3-D printed using a stereolithography (SLA) method using polycarbonate-like translucent/clear (ACCURA 60). The images were captured via a dual 12 MP wide-angle camera (f/1.8 aperture). FIG. 79A shows the prototype from a front upward angle. FIG. 79B shows the prototype's side view taken with the prototype resting on a horizontal surface. FIG. 79C depicts a top-down view of the prototype.

FIGS. 80A-80H depict images of the fin-shaped GRP of FIGS. 79A-79C with its top painted with a thin layer acrylic paint shown oscillating in motion chronologically from a top-down view. FIG. 80A shows the prototype's ability to be fully tipped to its right by a pair of tweezers, where FIGS. 80B-80G shows the prototype wobble to its sides, oscillating in a back-and-forth throughout its full 7.07 second wobble cycle until it rests at equilibrium in FIG. 80H.

FIGS. 81A-81C depict images of the sGRP of FIGS. 37A-37D with a broad flat top to configured to prevent the sGRP from oscillating after tilting past a critical angle. FIGS. 81A-81B show the prototype from two different front right upward angles. FIG. 81C shows the prototype's side view.

FIGS. 82A-82C depict images of the 3-D printed sGRP prototype of FIGS. 39A-39D with one set of detents configured to catch the sGRP on its side after tilting past a critical angle. FIG. 82A shows the prototype from a front upward angle. FIG. 82B shows the prototype's side view taken while the prototype is turned on its flat side from above. FIG. 82C shows the prototype from a front upward angle with the prototype tipped on its right side stabilized by its jagged edge.

FIGS. 83A-83C depict images of the 3-D printed sGRP prototype of FIGS. 40A-40D with two sets of detents configured to catch the sGRP on its side after tilting past a critical angle. FIG. 83A shows the prototype from a front upward angle. FIG. 83B shows the prototype's side view taken while the prototype is turned on its flat side from above. FIG. 83C shows the prototype from a front upward angle with the prototype tipped on its right side stabilized by its upper jagged edge.

FIGS. 84A-84H depict images of the motion of the sGRP of FIGS. 79A-79C with a broad flat top having one side painted with a thin layer of acrylic paint and a medium sized magnet on its top, where the magnet adds enough mass to lift the center of mass above the radius of curvature. The images are shown chronologically from a top-down view. FIG. 84A depicts the prototype at rest on its left side. FIGS. 84B-84D show a magnet moving across from left to right, slightly above the prototype, here as it moves, the magnetic force tilts the prototype until its critical angle, as seen in FIG. 84D, after which the prototype tips over to its right side where it remains at rest without the presence of a magnet. FIGS. 84E-84H show this process with the magnet moving the prototype from right to left, moving the magnet until it sits at rest once again on its left side in FIG. 84H.

FIGS. 85A-85I depict images of a fin-shaped GRP prototype with its top painted with a thin layer acrylic paint with a lightweight magnet affixed to the top portion. FIG. 85A shows that the paint and magnet possess a mass small enough that the center of mass of the GRP stays below the radius of curvature and the prototype stays upright at equilibrium. FIGS. 85B-85D show the particle drawn to its left side using a magnet; as the magnet was moved across the prototype from right to left, it tipped the to the left side. FIG. 85E shows the magnet being withdrawn; in the absence of a magnetic field, the particle demonstrates the expected oscillating wobble motion, as shown in FIGS. 85F-85H, coming to rest at an upright equilibrium as shown in FIG. 85I.

FIGS. 86A-86F depict photographic images from a top-down view of a fin-shaped GRP with its top painted with one thin layer of acrylic paint shown oscillating in motion chronologically. FIG. 86A shows the GRP at rest. FIG. 86B shows the GRP fully tipped to its right by a pair of tweezers. FIGS. 86C-86E shows the oscillatory motion resulting from removal of the tweezers from the tipped GRP of FIG. 86B. FIG. 86F shows the GRP after return to equilibrium.

FIGS. 87A-87C depict images of the fin-shaped GRP of FIGS. 86A-86F with four additional layers of acrylic white paint painted on its top (to yield a total of five layers). As shown in FIG. 87A-87C, the added mass of optical agent (paint) on the top surface of the prototype was enough to change the GRP's center of mass relative to its radius of curvature, such that when tilted from equilibrium far enough from its center, the prototype titled and rested on its side, unable to wobble back to an upright equilibrium position, e.g., as illustrated in FIG. 87C.

FIGS. 88A-88F depict non-limiting images of a GRP with a painted top from an upwards forwards angle. FIGS. 88B-88F show various screenshots from a video taken from a top-down view used to track the color change of a GRP throughout its movement cycle.

FIGS. 89A-89C depict three illustrative graphical representations of the mean pixel value as a function of time from a top-down view made from three different replicate videos of the same GRP put into motion three different times. The vertical dashed lines are included as guidelines to facilitate comparison between the three graphs.

FIGS. 90A-90C depicts three illustrative graphical representations of the mean pixel value as a function of time from a top-down view made from three different-shaped GRPs put into motion. The vertical dashed lines are included as guidelines to help facilitate comparison between the three graphs.

### DETAILED DESCRIPTION

The present disclosure provides, in part, compositions of and/or comprising gravity responsive particles (GRPs) comprising a shape and a center of mass (CoM) that enables motion between a plurality of positions when a force is applied, where the shape and the CoM enables relaxation to a stationary position from the plurality of positions from gravitational force, where the GRP includes at least a first optically active agent such that the GRP exhibits a change in an optical property of the first optically active agent as a function of the motion between the plurality of positions.

In embodiments, the initial force that is applied to a GRP to enable motion is not a gravitational force, but rather a mechanical force originating from an individual, machine, device, etc. For example, the initial force is a sudden, one-time jerk, where this mechanical action/force, which is not gravity, causes the GRPs to tilt (and then re-establish equilibrium via multiple pendulum tilts) with no additional action. In such a case, in embodiments, the restoring force is gravity.

Alternatively, in embodiments, the initial force that is applied to a GRP to enable motion is a gravitational force, e.g., such as when an individual or device turns, flips, tilts, or otherwise moves a GRP relative to the gravitational force, causing the GRP to move. For example, the GRP can be tiled, where the initial force is gravity; however, the particles will not move, wobble, and/or re-establish equilibrium until the substrate is tilted back to the horizontal. In such a case, in embodiments, the restoring force, or “back tilting,” is gravity.

In embodiments, the GRP (or surface/substrate positioned thereon) is slowly tilted back to the horizontal where there is no wobbling or pendulum action, but rather an exact re-tracing of the path on the initial tilt. In embodiments, the GRP (or surface/substrate positioned thereon) is rapidly tilted back to horizontal, where the GRP could exhibit some degree of wobbling. In embodiments, the GRP (or surface/substrate positioned thereon) is rapidly tilted an even, or equivalent, amount in the direction opposite from an initial tilt from the initial force. In such a case, in embodiments, there will be one complete wobble, where the GRP will be pointed the opposite direction. In embodiments, the GRP will remain fixed (in the 180 degrees opposite orientation), until there is a 3^{rd} tilt.

In embodiments, the term “gravity responsive particle” or “GRP” refers to a particle that exhibits optical behavior that changes depending on movement relative to gravitational force. In embodiments, the terms “gravity” and “gravitational force,” as used herein, refer to the earth's gravitational field that applies force to objects with stored potential energy to return them to a motionless state.

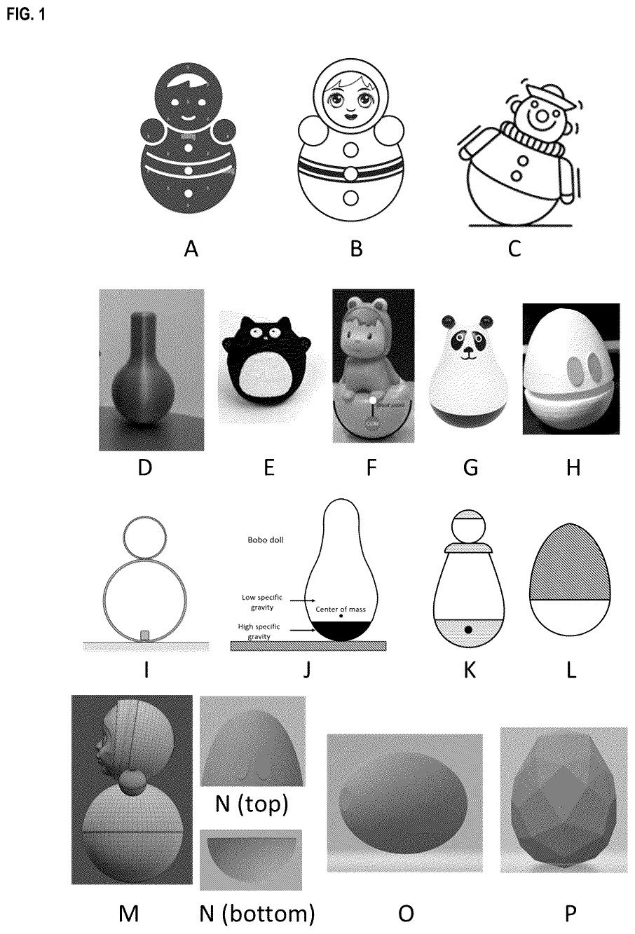

The optical property-changing GRPs, in embodiments, are suitable for incorporation into a variety of materials and methods of use. The GRPs, in embodiments, are about 20 nm to about 10 mm in size and exhibit optical properties that change in response to mechanical forces (e.g., dynamic motion such as vibration, shaking, tilting, inversion, etc.), where the particles “wobble” like a “roly-poly doll” (e.g., as illustrated in FIGS. 1A-1P, 2, 4, 13, 16, 21G, 22A-22B, 23B, 25B, 33C, 33E, 33F, 35B-35C, 41C-41D, 48, 49, 70A-70I, 72A-72I, 74A-74I, 80A-80H, 84A-84H, 85A-85I, 89A-89C, and 90A-90C) revealing different optical states, and relax back to a stationary state via the friction of gravitational force. The GRPs, in embodiments, can be dispersed in a fluid and/or applied to a surface. In embodiments, the GRPs are suitable for a variety of applications, including but not limited to: (i) consumer-goods (e.g., incorporated into packaging, woven into fibers, applied to paper/foil, etc.); (ii) for authentication and security applications; (iii) as cosmetics, tattoos, and semi-permanent makeup, (iv) as obscurants (e.g., for use in windows, mirrors, and/or doors), among other applications.

### Macroscopic Object Behavior

The present disclosure provides, in embodiments, an optical property-changing (e.g., color-shifting), micro-scale particle that resembles a macroscopic object known as “roly-poly toys.” As used herein, in embodiments, a “roly-poly toy,” as referred to as a “round-bottomed doll,” “tilting doll,” “tumbler,” “wobbly man,” or “wobble doll,” is a round-bottomed object, generally resembling an egg-shaped object, that tends to right itself when pushed at an angle, and does so in seeming contradiction to how it would be expected to fall. The object, in embodiments, is typically hollow with a weight inside the bottom hemisphere, where the placement of the weight is such that the object has a center of mass below the center of the hemisphere, such that any tilting raises the center of mass. When such an object is pushed over, in embodiments, it wobbles for a time while it seeks to return to the stationary upright orientation, which has an equilibrium at the minimum gravitational potential energy.

There is a wide-ranging nomenclature for objects that behave in this manner, including in non-limiting examples, “roly-poly toys,” “tilting dolls,” “wobble toys,” “Nevalyashka,” “bobo dolls,” “Daruma dolls,” and WEEBLES (Hasbro, Inc.). These objects are available in many shapes (e.g., hemispherical, egg-shaped, etc.) and sizes, e.g., typically with dimensions on the scale of a centimeter to several meters in height. For simplicity herein, in embodiments, this class of objects with dimensions greater than 2 millimeters (mm) are referred to as “macroscopic roly-poly toys” (MRPT). FIGS. 1A-1P depict several non-limiting examples of MRPTs.

FIGS. 1A-1C illustrate three non-limiting examples of MRPTs, where the bottom portion of each is a hemisphere, or near hemisphere shape, which enables the object to move about a surface, while the top portion can vary. FIGS. 1D-1H illustrate five non-limiting examples of MRPTs, where the bottoms of some are hemispherical (e.g., FIG. 1H is egg-shaped), and the height dimension of MRPT can be several times the width dimension. FIGS. 1I-1L illustrate 4 non-limiting examples of MRPTs, where FIG. 1I depicts a design resembling a “snowman” shape, with a small square weight positioned within the MRPT at the bottom of the lower (larger) sphere. FIG. 1J depicts a MRPT with an aspect ratio of about 3:1, where the height dimension is approximately 3 times the width, showing a high specific gravity (density) material below the object's center of mass (CoM), and a low specific gravity material in the upper part of the object. FIG. 1K depicts a MRPT showing a more complex shape, whereas and FIG. 1L shows a simplified egg shape. FIGS. 1M-1P illustrate a series of four non-limiting examples of MRPTs as stereolithography (STL) renderings. FIG. 1N shows two parts that are to be connected by a fastener, screw, adhesive, and the like, where the object can be made of two or more different materials that are affixed together during or after manufacturing processes. FIG. 1P illustrates a MRPT showing a generally egg-shape, but is faceted, providing a more complex symmetry.

The physics of MRPT dynamics and movement are well documented. For example, the dynamics of motion for egg-shaped and/or hemispheroid MRPTs has been described in MILLS, A, “Balancing eggs,” Phys. Educ., Vol. 49, No. 2, 2014: pp. 176-179; DE, S, “On static equilibrium of a hemispheroid,” The Mathematical Gazette, Vol. 98, No. 541, 2014: pp. 73-78; HONG, “Seeing balancing toys graphically and gravitationally,” Phys. Educ., Vol. 51, 013003, 2016:3 pages; HONG, “Stable equilibria of elliptic roly-poly toys,” Eur. J. Phys., Vol. 37, 06200, 2016:5 pages; and DE, S, “Weebles Only Wobble But Eggs Fall Down”, Mathematics Magazine, Vol. 90, No. 2, 2017: pp. 99-107, each of which are hereby incorporated by reference in their entirety.

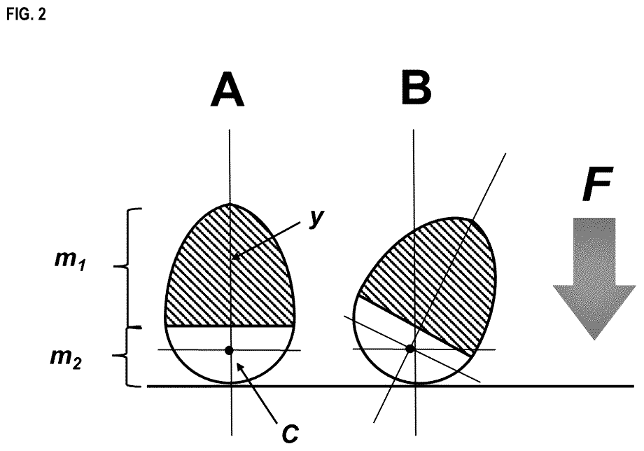

In embodiments, the physics involved in the motion of GRPs on the micrometer or nanometer scale herein is comparable to the physics of motion of MRPTs, for example as illustrated in FIG. 2, where position A is the position of mechanical equilibrium, position B is a position of mechanical instability, with the arrow indicating the direction of the gravitational force F, m₁ is a mass of lower density (e.g., a lower specific gravity material), m₂ is a mass of higher density (e.g., a higher specific gravity material), and C is the center of mass CoM (also known as the centroid or center of gravity). In embodiments, when the MRPT is tilted (e.g., moved from position A to position B), the CoM (C) is lifted slightly above its original position (also becoming offset relative to the vertical position y), and when the MRPT is released, the force of gravity acts on the CoM, generating a torque that makes the MRPT roll back and forth (e.g., oscillating like a pendulum along either a single plane, or via multiple planes, i.e., “wobbling”) until it relaxes to stationary rest back to position A.

Alternatively, in embodiments, the physics involved in the motion of GRPs on the micrometer or nanometer scale herein can be compared the physics of motion of MRPTs, for example as described in DE, 2017, where MRPT is at stable equilibrium in the upright position—in contrast to an actual egg where the upright position is one of unstable equilibrium. In embodiments, for any “solid the revolution” with a convex vertex where the center of mass is located on its symmetry axis, an upright position of standing over a horizontal plane is an equilibrium position. From a physical perspective, in embodiments, the equilibrium is stable if the object returns to this equilibrium position when released from a slight tilt. Accordingly, in embodiments, if the object deviates away further from equilibrium when released from a slight tilt, the equilibrium is unstable. In embodiments, this principle dictates that if at the equilibrium position, the vertical height of the center of mass from the horizontal plane is smaller than or greater than the radius of curvature of the solid's contour at the vertex, then the equilibrium will be stable or unstable, respectively. For purposes of clarity herein, in embodiments, the vertex is the position where the MRPT meets the horizontal plane or surface where the object rests. As stated in De, 2017, considering the equilibrium position of a solid of revolution resting on its vertex over a horizontal plane; at this position, if the vertical height of the center of mass from the plane is smaller than or larger than the radius of curvature of the solid's contour at its vertex, the equilibrium will be stable or unstable, respectively. In embodiments, when the center of mass is exactly at the radius of curvature at the vertex, where the equilibrium position of a solid of revolution resting on its vertex over a horizontal plane, then the equilibrium is critical due to the fact that the vertical height of the center of mass from the plane is equal to the radius of curvature of the solid's contour at its vertex, thus the equilibrium will be stable or unstable if at the vertex the radius of curvature itself is a local minimum or a maximum, respectively.

### Gravity Responsive Particles (GRPs)

The present compositions and methods find use in embodiments of gravity responsive particle (GRPs). In embodiments, GRPs herein include a shape and a center of mass (CoM) that enables motion between a plurality of positions when a force is applied, where the shape and the CoM enables relaxation to a stationary position from the plurality of positions from gravitational force, and at least a first optically active agent and a second optically active agent, where the GRP exhibits a change in an optical property between the first optically active agent and the second optically active agent as a function of the motion between the plurality of positions.

The motion of GRPs, in embodiments, is governed by and/or relates to the physics of MRPTs described herein; however, GRPs differ from their macroscopic counterparts (MRPTs) in several respects. For example, in embodiments, (1) they are microscale, with dimension less than or equal to about 10 mm. GRP sizes, in embodiments, can be of sub-millimeter dimensions, i.e., on the micron scale in one or more dimensions, and can also be of nanoscale dimensions, i.e., with one or more dimensions less than 1 micron (1 μm). GRPs can be as small as under about 20 nanometers (nm) in all dimensions. Due to their size, in embodiments, (2) GRPs can be dispersed, suspended, or otherwise dissolved in fluid and can be applied to a substrate. For example, in embodiments, GRPs can be prepared into a solution and applied directly to adhere as an array of particles on a substrate material. Another differentiation of GRPs is that, in embodiments, (3) actuation of GRPs is accomplished by mechanical agitation (e.g., applying a force, such as tilting, rotating, shaking, jarring, etc.) of the substrate, which can occur in any direction. And, in embodiments, (4) the tilting or relaxation to equilibrium of GRPs involves observable changes in optical properties. These optical properties, in embodiments, include changes in color and/or appearance, including changes in chromatic elements such as a color's hue, saturation, brightness, intensity, color value, and/or chroma. In embodiment, the tilting or relaxation to equilibrium of GRPs includes changes in fluorescence intensity.

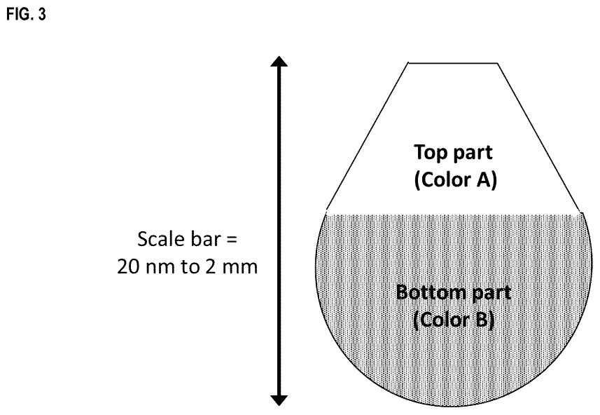

In reference to FIG. 3, a non-limiting illustration of a single GRP is shown, where the scale bar indicates that a single GRP can be as small as 20 nm in dimension, or as large as 2 mm. In embodiments, GRPs can be about or at least about 20 nm to about or at least about 10 mm in size. In embodiments, the GRP is about or at least about 20 nm, about or at least about 50 nm, about or at least about 100 nm, about or at least about 200 nm, about or at least about 300 nm, about or at least about 400 nm, about or at least about 500 nm, about or at least about 600 nm, about or at least about 700 nm, about or at least about 800 nm, about or at least about 900 nm, about or at least about 1 μm, about or at least about 5 μm, about or at least about 10 μm, about or at least about 50 μm, about or at least about 100 μm, about or at least about 200 μm, about or at least about 300 μm, about or at least about 400 μm, about or at least about 500 μm, about or at least about 600 μm, about or at least about 700 μm, about or at least about 800 μm, about or at least about 900 μm, about or at least about 1 mm, about or at least about 2 mm, about or at least about 3 mm, about or at least about 4 mm, about or at least about 5 mm, or about or at least about 10 mm. In embodiments, the GRPs has dimensions in a range from about 2 μm to about 200 μm. In embodiments, the GRPs has dimensions in a range from about 20 nm to about 200 nm, about 200 nm to about 1 μm, about 1 μm to about 10 μm, about 10 μm to about 100 μm, about 100 μm to about 1 mm, or about 1 mm to about 10 mm.

As shown in FIG. 3, in embodiments, the GRP can have a top part and a bottom part, each with a different optical property, such as a distinct color. In FIG. 3, for purposes of non-limiting illustration, the top part of the GRP is shown as white (Color A), and the bottom part as gray-shaded crosshatch (Color B); in embodiments, this white and gray-shaded crosshatch can correspond to any color, such as white, black, red, orange, yellow, green, blue, indigo, violet, or any other known color or hue.

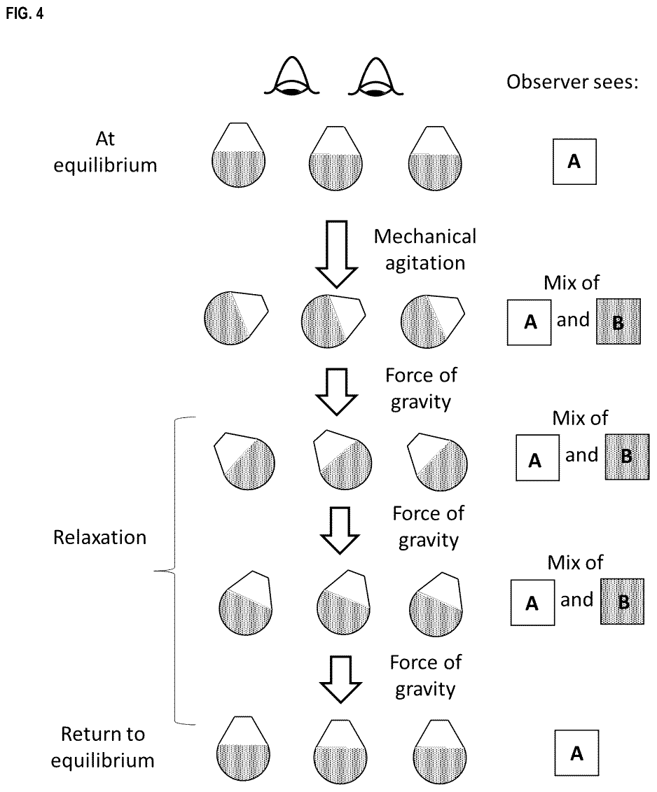

In reference to FIG. 4, GRPs (e.g., as arranged in an array) can function to reveal different optical states as they move through a plurality of positions. In embodiments, at equilibrium, the GRPs are at rest, and an observer viewing the particle array (e.g., at a perpendicular angle) observes the top portions of individual GRPs (in FIGS. 3-4, this corresponds to Color “A”). Still in reference to FIG. 4, in embodiments, after and/or during a period of mechanical agitation (e.g., shaking, tilting, jerking, perturbation, among the application of other types of physical force), the GRPs move away from this resting equilibrium, where the observer sees the GRP move through a plurality of positions—where the GRP is viewed from its side(s) (e.g., tilted), where the observer sees a combination of Color “A” and Color “B.” As described herein, forces acting on the GRP will move it from the equilibrium position, where it will teeter or wobble (like the movement of pendulum), revealing to the observer a change in optical property (e.g., color, brightness, etc.). During this period of movement, in embodiments and as illustrated in FIG. 4, the observer can observe a mixture of Color “A” and Color “B” in varying proportions, until the GRP relaxes via gravity (after cessation of mechanical turbulence) to stationary equilibrium at which point the observer will once again only view the top color of the GRPs, i.e., Color “A.” In embodiments, two regimes of optical changes can be observed: (1) during the application of force, and (2) during the gravity-induced wobble.

### Shapes and Geometries of GRPs

In embodiments, the GRP can have a variety of shapes and geometries. In embodiments, the GRP is constructed of one or more different geometries, assembled into one or more shapes. In embodiments, GRPs can adopt shapes/geometries that include regular polygons, as well as other regular and irregular shapes. In embodiment, the one or more geometries includes one or more of a roly-poly shape, truncated teardrop shape, mushroom shape, champagne flute shape, wine glass shape, round-bottomed doll shape, tilting doll shape, tumbler shape, wobbly toy shape, wobble doll shape, round-bottomed toy shape, egg-shaped shape, paraboloid, prolate hemispheroid, oblate hemispheroid, hemispherical, elliptical, trigonal pyramid, pentagonal pyramid, hexagonal pyramid, a regular shape with a truncated tops, a truncated square pyramid, a truncated cone, a truncated cone where the top plane and bottom plane are not parallel.

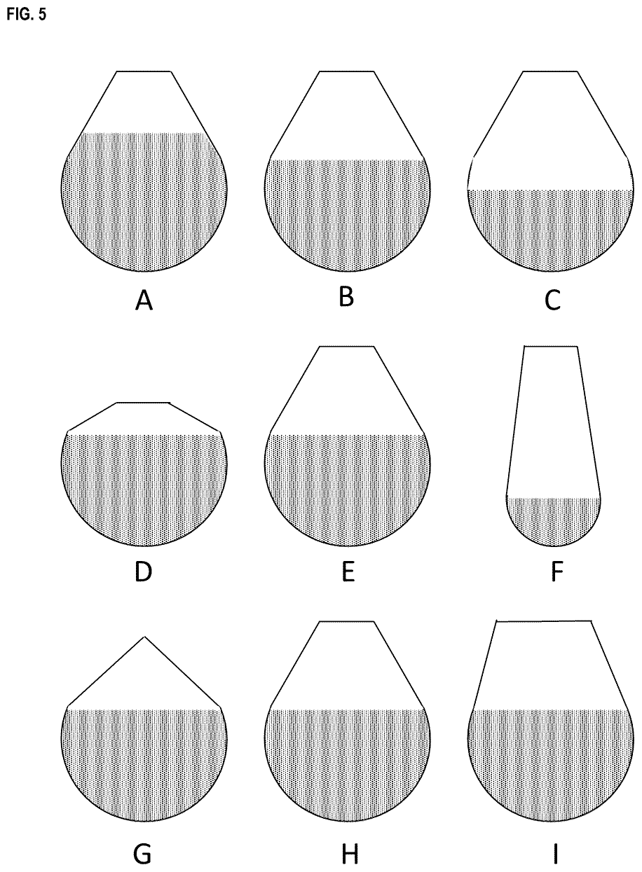

In embodiments, the shape is a 3-dimensional (3D) shape/geometry, where the 3D shape/geometry can be concave and/or convex, or have portions that are concave or convex. For example, in embodiments, the GRP shown in FIGS. 3-4 can be described as a truncated teardrop. In embodiments, GRPs can have variations of shapes, as illustrated in FIGS. 5A-5I. For instance, in non-limiting examples, FIGS. 5A, 5B, 5E, and 5H, each resemble the shape shown in FIG. 3.

The GRP, in embodiments, has a surface area ratio between the first optically active agent and the second optically active portion. In embodiments, surface area ratio of a first optical agent to a second optical agent, e.g., the white area and grey shaded area of FIGS. 5A-5I can be altered to tune the “sensitivity” of the optical property change, such as how much force is necessary to tilt the GRPs to exhibit a color change, or for how long the bottom or top color are observed during movement. For example, in embodiments, the bottom part (grey shaded) of FIG. 5A is larger, while in FIG. 5C the grey shaded region is much smaller, where a larger tilt angle is necessary for the GRPs in FIG. 5C to reveal the grey shaded region to the observer. In embodiments the shape/geometry of each GRP contributes to controlling the optical property change, for example as shown in FIG. 5D, where the GRP top portion is truncated, whereas in FIG. 5F the shape is more like a champagne flute, where each design can have a different propensity to change color from any given force. In embodiments the GRP can be manufactured with differing shape/geometry to adjust, increase, and/or decrease the viewing angle and/or packing distance for GRPs in observing optical property changes, for example as shown in FIG. 5G, where the top part terminates at a point allowing color change to not be obscured by the upper portion of a nearby GRP as the particles tilt, whereas in FIG. 5I the top part is broader like a wine glass.

In embodiments, the surface area ratio of the first optically active agent to the second optically active agent, and likewise the surface area ratio of the second optically active agent to the first optically active agent can be about or at least about 0.1, about or at least about 0.2, about or at least about 0.3, about or at least about 0.4, about or at least about 0.5, about or at least about 0.6, about or at least about 0.7, about or at least about 0.8, about or at least about 0.9, or about or at least about 1.0.

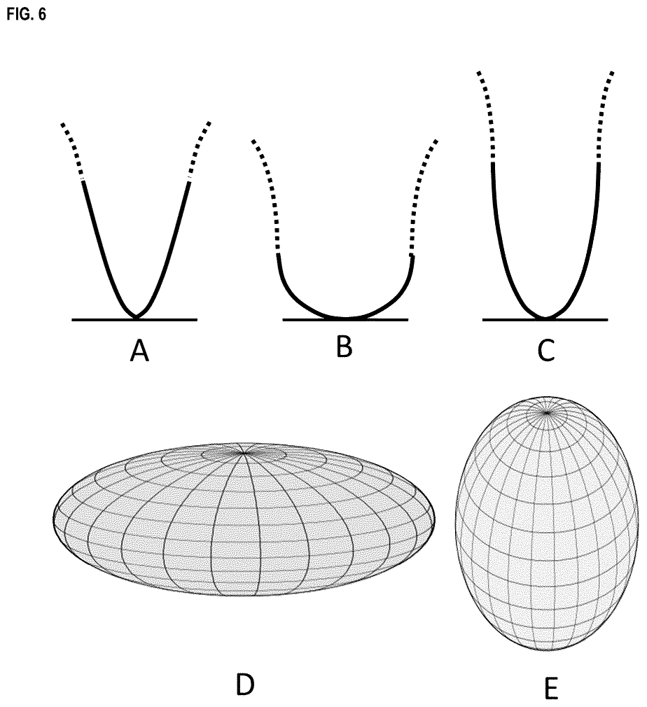

While FIGS. 5A-5I demonstrates the variation of the shape/geometry of a top portion of a GRP, in embodiments, there is flexibility in shape/geometry of the bottom portion of the GRP, provided the criteria for stability and movement are met. For instance, in reference to FIGS. 6A-6E, the contours of three solids of revolution resting on their vertices over a horizontal plane are shown. In embodiments, the vertex and the bounding surface comprises and/or is a portion of a paraboloid (e.g., as shown in FIG. 6A), a prolate hemispheroid (e.g., as shown in FIG. 6B), and/or an oblate hemispheroid (e.g., as shown in FIG. 6C). In embodiments, GRPs can adopt 3D oblate and prolate shapes, e.g., as shown in FIGS. 6D-6E.

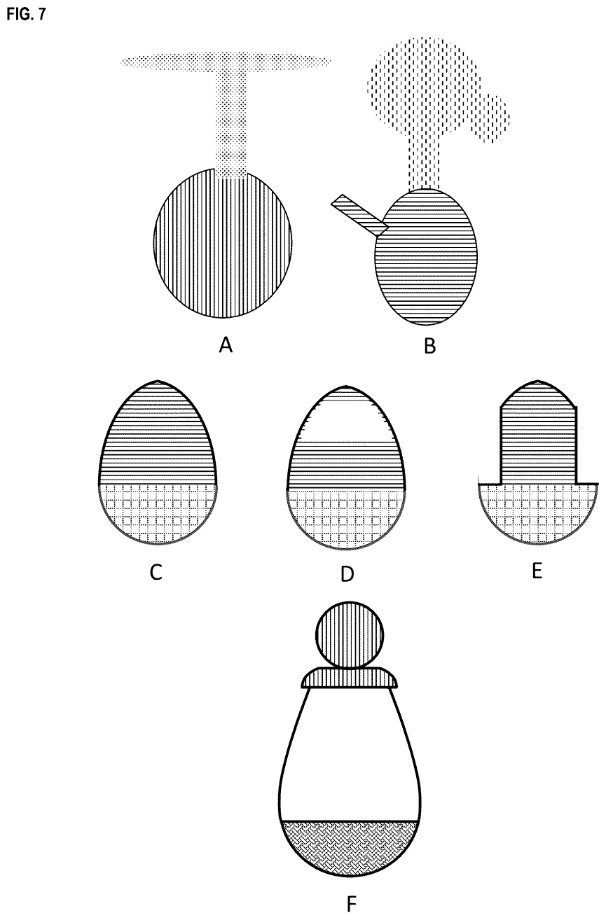

In embodiments, the GRP has a shape that does not have an axis and/or plane of symmetry (i.e., is asymmetrical). Alternatively, in embodiments, the GRP has a shape that has one axis of symmetry, two axes of symmetry, three axes of symmetry, or four or more axes of symmetry. The GRP, in embodiments, has a shape that includes at least one plane of symmetry. The GRP, in embodiments, has a shape that includes glide reflection symmetry. For instance, in embodiments and as shown in FIG. 7A, the top part is T-shaped, while the bottom part is egg-shaped, exhibiting degrees of symmetry via vertical axes/planes. In embodiments, as shown in FIG. 7B, both the top and bottom parts have protrusions that break symmetry (without altering the basic functionality).

The GRP, in embodiments, has a 3D shape that includes an internal portion. In embodiments, the internal portion includes a material having a singular specific gravity and/or density. In embodiments, the internal portion includes at least two materials, each having a specific gravity and a density. In embodiments, the two or more materials have different specific gravity and/or density. For example, in embodiments and in reference to FIGS. 7A-C and 7E, the GRP can have a “standard” egg shape (or a portion that resembles an egg shape), where the different patterns relate to different materials of the internal portion, and where these materials can be different materials having distinct specific gravity and/or density, or can be the same material with varying degrees of packing, porosity, etc., which alters their specific gravity and/or density. In embodiments, the internal portion can have at least a portion that is hollow. For example, in embodiments and in reference to FIGS. 7D and 7F, the GRP can have a “standard” egg shape (or a portion that resembles an egg shape), and have an internal portion that is hollow (denoted by the white), where this internal portion is inside a top portion (e.g., as shown in FIG. 7D), within a middle portion (e.g., as shown in FIG. 7D), or within a bottom portion. In embodiments, there are multiple hollow regions in the top, middle, bottom, and/or combinations thereof. In reference to FIG. 7E, in embodiments, the GRP has a mismatch in the continuity of shape between a top portion and a bottom portion (e.g., an indent or step), while still demonstrating the “roly-poly” behavior described herein.

In embodiments, the GRP has more than two optical states (e.g., colors) and/or is comprised of more than two materials. For example, in embodiments and in reference to FIG. 7F, the GRP has 3 different regions of colors (depicted by vertical lines, white, and crosshatched), and incorporates at least 3 different shapes (wine glass, disc, and sphere). In embodiments, the GRP can be manufactured to exhibit any number of colors/states, be made of any number of materials, and/or have any number of shapes/geometries.

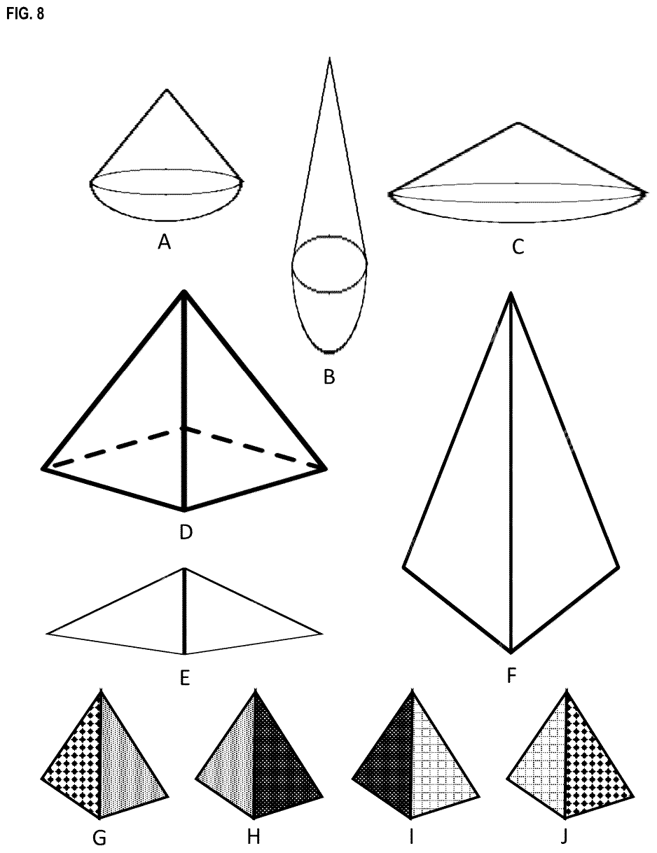

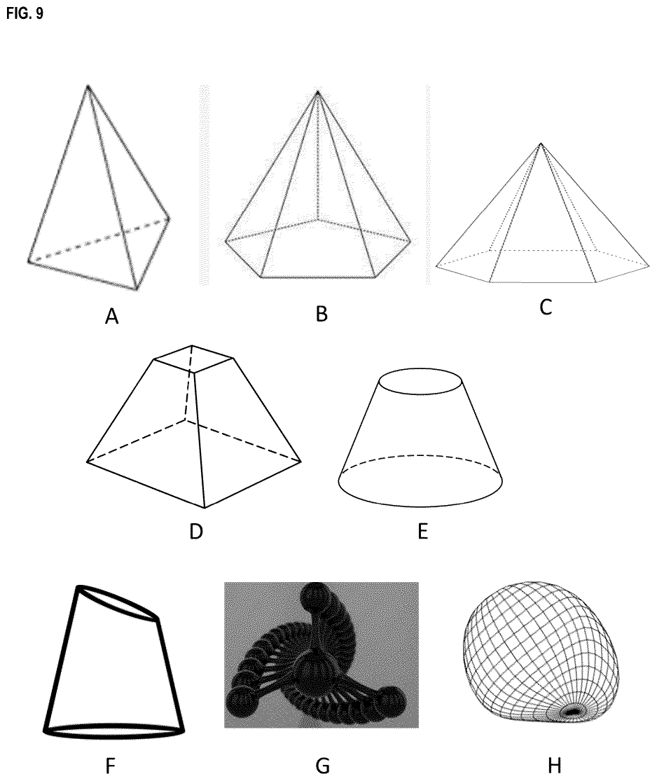

In reference to FIGS. 8A-8J, in embodiments, are non-limiting examples of colors/states, materials, and/or shapes/geometries for a top portion of a GRP. For example, FIGS. 8A-8C illustrate conical shapes of varying dimensions with respect to a hemispherical bottom portion of a GRP, where FIG. 8A shows an approximate 1:1 ratio of height:width; FIG. 8B an approximate 1:3 ratio of height:width; and FIG. 8C shows an approximate ratio of <1 to 1 for height:width, where the width is larger than the height. In non-limiting embodiments, for instance as illustrated in FIGS. 8D-8F, the top portion can be a square pyramid shape, having different ratios of height to width, and having distinct materials and/or optical properties, for example each of the images of FIGS. 8D-8F can be related by 90 degree rotation about a vertical axis, where the square pyramid has 4 different colors/states. In embodiments, GRPs with such a configuration would show 4 different colors/states as a function of their movement, e.g., as shown in FIGS. 8G-8J. In reference to FIGS. 9A-9H, in embodiments, GRPs can be manufactured to have a variety of shapes, geometries, and degrees of symmetry. For example, in embodiments, the GRP as shown in FIG. 9A can have a trigonal pyramid shape; a pentagonal pyramid shape (e.g., as shown in FIG. 9B); a hexagonal pyramid shape (e.g., as shown in FIG. 9C). In embodiments, the GRP has one or more portions that is a truncated regular polygon, for instance in non-limiting examples, a truncated square pyramid (e.g., as shown in FIG. 9D), or a truncated cone (e.g., as shown in FIG. 9E). In embodiments, the GRP has one or more portions that is a truncated polygon with one or more angled surfaces that reduce symmetry relative to a regular polygon, such as the truncated cone depicted in FIG. 9F, where the top plane and bottom plane are not parallel. In embodiments, for example as shown in FIG. 9G, GRPs include shapes/geometries that have no planes of symmetry, but do have a glide reflection symmetry, i.e., symmetry operation comprising reflection coupled to translation. In embodiments, GRPs and arrays thereof have shapes that do not have symmetry, for example as shown in FIG. 9H, which is an example of a 3D shape with no symmetry. In embodiments, GRPs have the shape in FIG. 9H, which is a convex shape—meaning there are no indentations—but GRPs can equally be concave, with one or more indentions or indented surfaces.

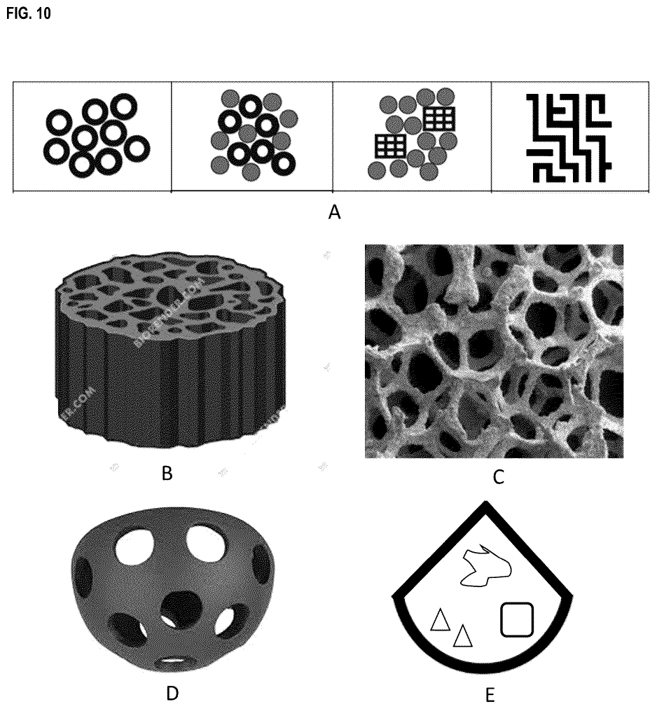

In embodiments, GRPs are solid and have only external-facing surfaces that are accessible to a solid, liquid, or gas. Alternatively, the GRPs have an accessible internal area, or one or more regions of porosity. For example, in embodiments, and in reference to FIGS. 10A-10E, illustrative, non-limiting diagrammatic representations of porosity are depicted. FIG. 10A depicts four different 2-dimensional (2D) renderings of porosity; FIG. 10B depicts a quasi-symmetric cylindrical cross-section of a porous object; FIG. 10C depicts a porous solid with 3D porosity; FIG. 10D depicts a porous hemispherical bottom part of a GRP; and FIG. 10E depicts a side view of a GRP having varying porosity.

In embodiments, there are many ways to control the spatial distribution of mass in a GRP such that the center of mass (CoM) lies below the radius of curvature; one approach is to introduce pores or hollow areas in the top portion of the GRP to lessen its density relative to the bottom portion (e.g., as shown in FIG. 10). In embodiments, the porosity within a GRP is used to adjust the mass of one or more part of a GRP. For example, in embodiments, if the GRP depicted in FIG. 3 is not stable due to the positioning of center of mass above to the radius of curvature, adding porosity to the top section (i.e. removing mass) can lower the center of mass to a point below the radius of curvature.

In embodiments, porosity is also be used to increase the surface area of part or all of a GRP. This increase in surface area, in embodiments, is exploited to increase the number of substances attached to the surface of a GRP. For example, in embodiments and with reference to FIG. 3, the surface area of the top part (color A) is that of a truncated cone. However, in embodiments, if the top part comprises a more complex shape (e.g., adopting 3D porosity such as that depicted in FIG. 10C), the surface area is increased.

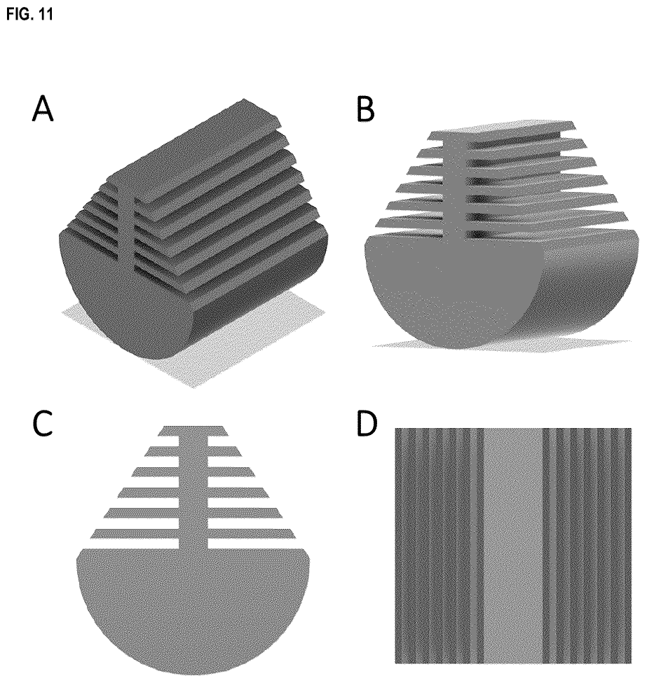

In embodiments, an alternative approach to increasing surface area by porosity is to increase the external surface area by adding structures such as “fins,” detents, or protrusions. For example, in embodiments and in reference to FIG. 11, the design of a GRP is illustrated where fins have been added by removal of six trapezoidal cross-sectioned volumes on each side of the top section of the GRP. In embodiments, the resulting GRP is not porous, but the fins in the top section give that portion of the GRP increased surface relative to a GRP of the same shape but with no fins (e.g., in comparison to the GRP of FIG. 3).

### Motion and Function

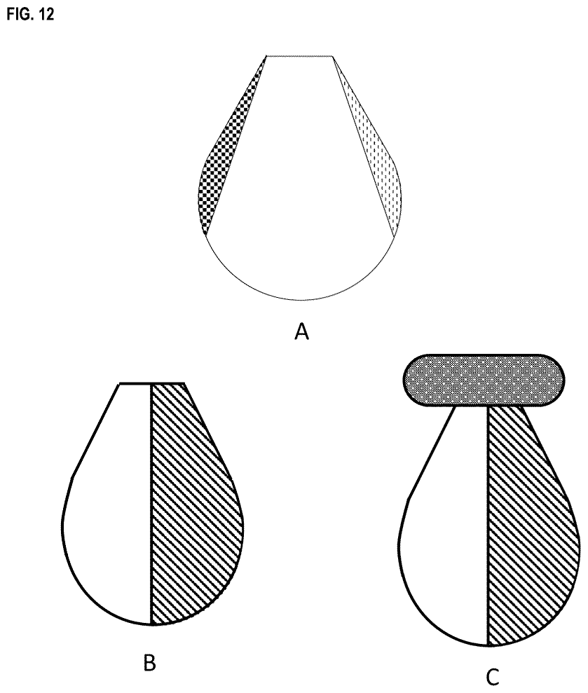

As described above in FIGS. 3-4, the variation in optical properties (e.g., color) of GRPs are shown as emanating from the top portion and bottom portion; however, in embodiments, the optical properties are not confined to the top portion and bottom portion of the GRP. For example, in embodiments and as shown in FIGS. 12A-12C, three possible GRP structures are illustrated in which surfaces other than the top portion and bottom portion have specific optical properties (e.g., colored surfaces). In reference to FIG. 12A, in embodiments, the GRP has differing optical properties disposed on its sides, e.g., the left side of the GRP is shown to be a first color (indicated by a dark crosshatch), while the right side of the GRP is shown to be a second color (indicated by a light crosshatch), where this coloration pattern does not extend to the top or bottom of the GRP, or to other parts like the front side or back side. In reference to FIG. 12B, in embodiments, a GRP is shown with two halves, one half of the object has a particular optical property (e.g., a first color), and the other half has a particular optical property (e.g., a second color). In embodiments, the GRP is constructed such that it has multiple optical properties—with a different property on multiple surfaces—for example as shown in FIG. 12C, where the GRP of is capped with a disc of a third color. In such a case, in embodiments, the GRP exhibits an optical property (e.g., a first color) at stationary equilibrium (e.g., at rest), exhibits a second optical property (e.g., a second color) as tilted in a first direction, and exhibits a third optical property (e.g., a third color) as tilted in a direction opposite of the first direction.

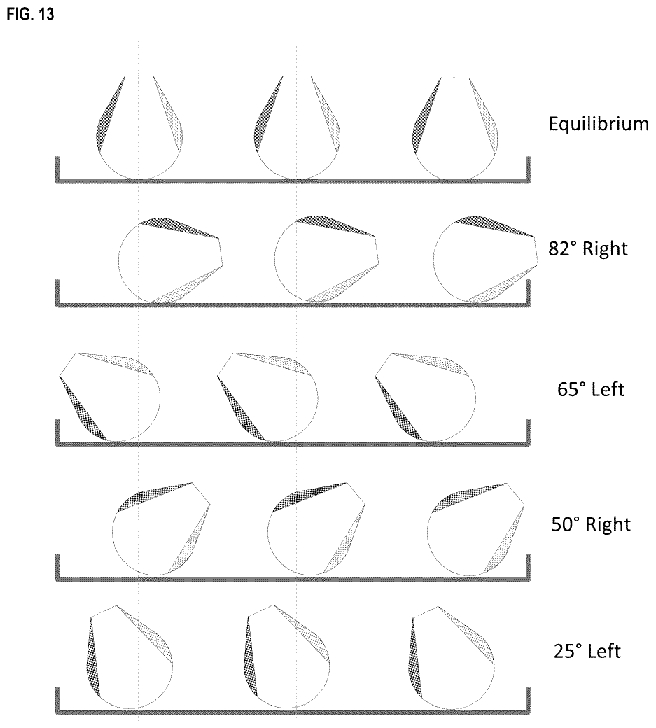

In reference to FIG. 13, in embodiments, an array of GRPs can be positioned such that they exhibit a variety of optical properties, such as changing colors, as they move through a plurality of positions. For example, in embodiments, GRPs at equilibrium (FIG. 13, top panel) are all aligned so that the dark crosshatched surfaces are facing a first direction, and the light grey surfaces are facing the opposite direction. In embodiments, when a force is applied to the GRPs, they tilt to the right (e.g., as shown in FIG. 13, second panel, as an 82° tilt to the right). Once the force is removed or ceases, in embodiments, the force of gravity moves the particle, first past the equilibrium position, wobbling back to the opposite direction (e.g., as shown in FIG. 13, third panel, as a 65° tilt to the left), and then again to the right (e.g., as shown in FIG. 13, fourth panel, as a 50° tilt to the right), and then back to the left (e.g., as shown in FIG. 13, fourth panel, as a 25° tilt to the left). These transitions in movements, in embodiments, can occur on the order of seconds, where GRPs can be have sizes where the transition between, for example color states, occurs within 500 seconds, 100 seconds, 10 seconds, 1 second, 10⁻¹ seconds (tenths of a second), or even 10⁻² seconds (hundreds of a second). In embodiments, a complete plurality of movements (i.e., from an initial force/stimulus until the return to a stationary equilibrium) can occur within 500 seconds, 100 seconds, 10 seconds, 1 second, 10⁻¹ seconds (tenths of a second), or even 10⁻² seconds (hundreds of a second).

Generally, in embodiments, the motion of the GRP mimics that of a pendulum, oscillating past the equilibrium position in increasingly smaller increments, until the equilibrium position is re-instated, exhibiting different optical states with each movement until rest. In embodiments, the motion of the GRP is a pendulum motion oscillating between the plurality of positions and the stationary position. In embodiments, the motion is a tilt displacement motion between the plurality of positions and the stationary position. In embodiments, the motion is an angular displacement motion between the plurality of positions and the stationary position. In embodiments, the motion occurs along a plane in two dimensions and/or in three dimensions. In embodiments, the center of mass (CoM) resides below a radius of curvature during movement. In embodiments, the oscillating motion comprises a wobble motion, where the wobble motion comprises oscillations around a pitch axis and a yaw axis. In embodiments, the wobble motion comprises movement through the several orientations relative to a direction of a force gravity.

In embodiments, GRPs discussed herein have one stable position (e.g., stationary equilibrium configuration); however, GRPs can also have multiple stable equilibria. For example, each of the faces of a cube are stable, and if a cube on a plane is stood on a point or an edge on a plane and then released, it will reorient (e.g., fall) such that one face is in contact with the plane. Once the face of the cube is touching the plane, there is no accessible “pendulum action.” In embodiments, there are several shapes/geometries of such objects, i.e., containing multiple stable and unstable configurations that GRPs can have.

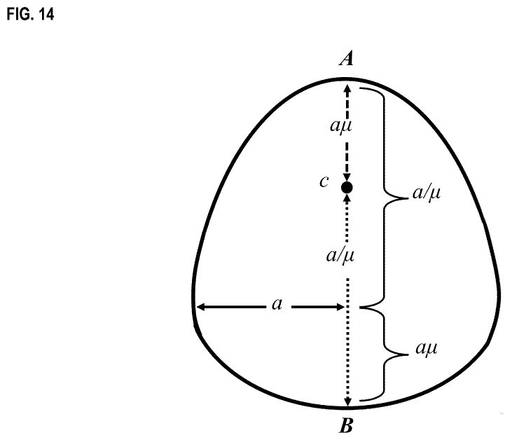

In embodiments, a GRP can have two (or more) stable or quasi-stable equilibrium points (e.g., stationary resting positions), for example, as shown as a “double critical roly-poly object” (e.g., as shown in FIG. 14). In embodiments, this GRP has a top portion that is a prolate spheroid with a vertex at position A, and a bottom portion that is an oblate spheroid with a vertex at position B, with both hemispheres sharing a common point for the center of curvature (c), and where μ is a dimensionless constant that dictates the overall object shape. In embodiments, when the center of mass is between B and c, then a stable equilibrium is achieved with B in contact with the incident plane (i.e., the configuration shown in FIG. 14), and the upright position on A becomes unstable. Conversely, in embodiments, when the center of mass is between A and c, the upright position on A becomes a stable equilibrium while the upright position on B becomes an unstable equilibrium. In embodiments, when the center of mass is exactly at point c, both configurations—A in contact with the plane, B in contact with the plane—are stable.

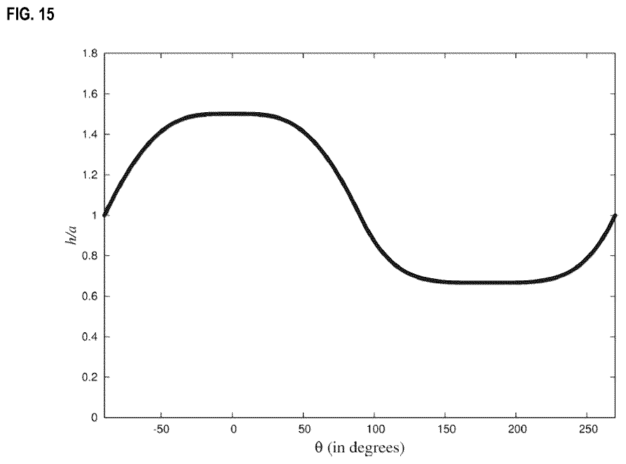

In reference to FIG. 15, a plot demonstrating the relationship between h (i.e., the height of the center of mass from the incident plane) and the tilt angle from equilibrium (θ) for a GRP with μ=2/3 (e.g., for a shape shown in FIG. 14) is shown. In embodiments, such a shape exhibits a behavior where, according to the plot, θ=0° corresponds to the GRP standing on vertex B, and θ=180° corresponds to the GRP standing on vertex A. In embodiments, such a GRP will behave, as described in the function shown in FIG. 15, such that small perturbations in tilt angle will not significantly impact the point of contact, as indicated by the flat portion of the function near both 0° and 180°. In embodiments, and continuing in reference to the function of FIG. 15, sufficiently large perturbations in tilt angle (θ) will cause transition from one equilibrium position to the other, causing a change in optical property during the transition.

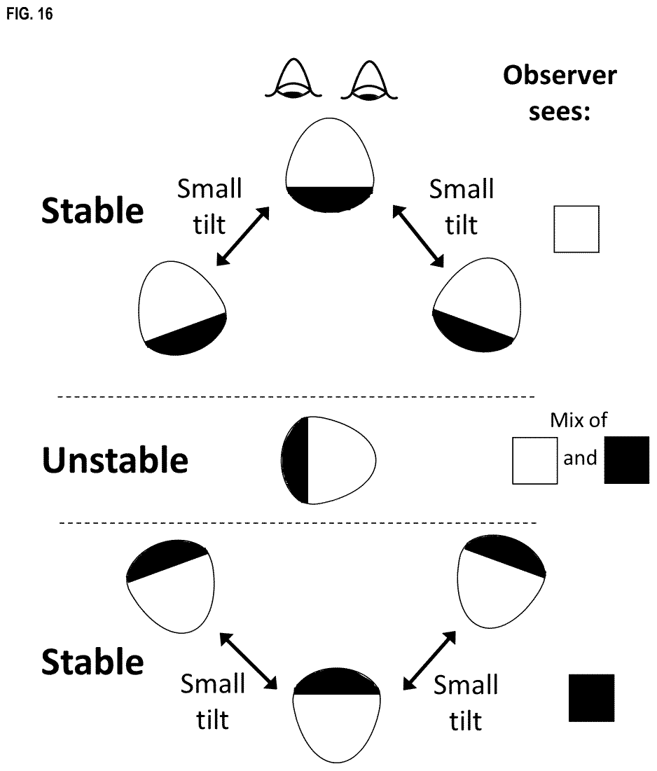

This behavior is illustrated in FIG. 16, where, in embodiments, a GRP with μ=2/3, with a top portion (containing a first color and a vertex, A, colored white), and with a bottom portion (containing a second color and a vertex, B, colored black). In embodiments, small perturbations lead to small tilts with either A or B remaining in contact with the plane and will not lead to a change in color for the observer—the GRP will tilt, but will remain on either plateau shown in FIG. 15, where the observer will see either the color white or the color black as shown (recognizing that these portions of the GRP could be any color). In embodiments, a perturbation sufficiently large to tilt the GRP to an unstable configuration will lead the observer to temporarily see a mix of the two colors (i.e., where a mixture of white and black for an array of sufficiently small GRPs would appear as gray), followed by relaxation to a stable, stationary point (with the first color or the second color appearing in the end).

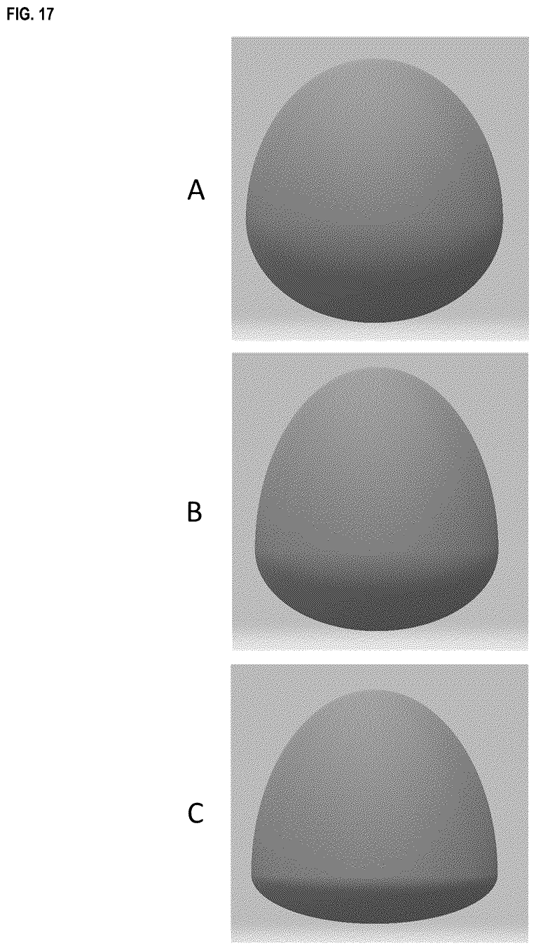

In embodiments, u refers to a dimensionless constant between 0 and 1 that relates to a ratio of distance between the center of curvature and the location of vertices of the GRP, where the vertices relate to points on the surface of the GRP where the GRP can rest at a stationary equilibrium (see, e.g., FIG. 14). In embodiments, the GRP can have a shape with a variety of values for μ. For example, in embodiments, FIGS. 17A-17C shows computer-aided design images (STL format) of GRPs having three different u values. In embodiments, each value of u leads to a different position for c, and consequently results in different properties for the special case when the center of mass is at, for example, in FIG. 17C where μ=2/5, this configuration is more stable under certain conditions than a GRP having μ=15/23 (FIG. 17B), and even more so than a GRP having μ=4/9 (FIG. 17A), requiring a greater perturbation of tilt angle than both to lead to an unstable configuration and thus a change in optical property.

In embodiments, the GRP has a ratio of distance between the center of curvature and the location of one or more vertices (e.g., μ) with a value of about or at least about 0, about or at least about 0.1, about or at least about 0.2, about or at least about 0.3, about or at least about 0.4, about or at least about 0.5, about or at least about 0.6, about or at least about 0.7, about or at least about 0.8, about or at least about 0.9, or about or 1.0. In embodiments, the GRP has a μ value that is conveniently represented as a fraction (e.g., a ratio), where the value of μ is about or at least about 1/8, about or at least about 1/7, about or at least about 1/6, about or at least about 1/5, about or at least about 1/4, about or at least about 2/7, about or at least about 1/3, about or at least about 3/8, about or at least about 2/5, about or at least about 3/7, about or at least about 1/2, about or at least about 4/7, about or at least about 3/5, about or at least about 5/8, about or at least about 2/3, about or at least about 5/7, about or at least about 3/4, about or at least about 4/5, about or at least about 5/6, or about or at least about 6/7.

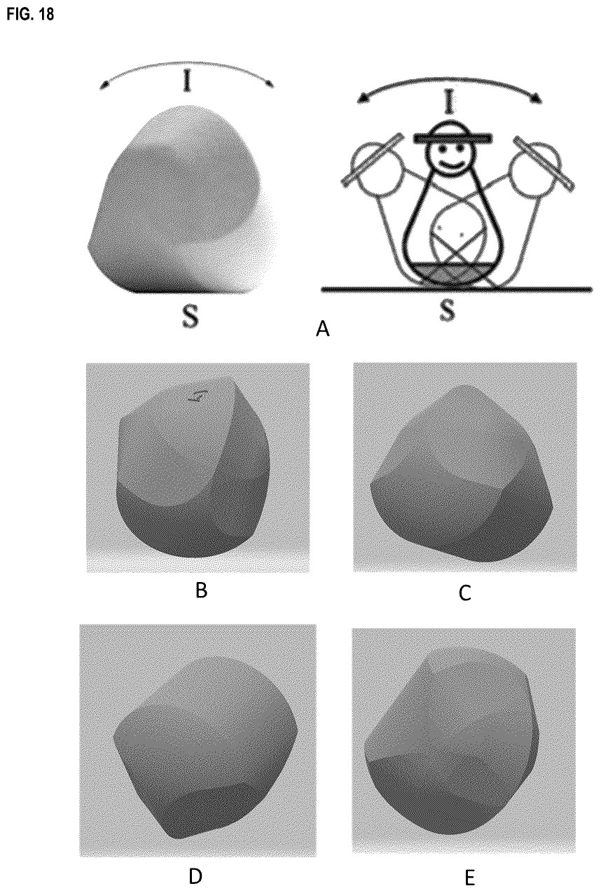

In embodiments, GRPs resemble a macroscale shape adapted from an object having a shape referred to as “Gömböc,” which is the first known physical example of a class of convex three-dimensional homogeneous bodies (called mono-monostatic) that, when resting on a flat surface, have one stable and one unstable point of equilibrium, e.g., as shown in FIGS. 18A-18E. For example, FIG. 18A shows a macroscale Gömböc and compares its points of stable and unstable equilibria to that of a, where the stable equilibrium(S), if placed on a horizontal surface in an arbitrary position, the Gömböc returns to the stable equilibrium point. While MRPTs rely on a center of mass below the radius of curvature (often achieved by the addition of a weight to the bottom part), the Gömböc consists of homogenous material, thus the shape itself accounts for self-righting. In embodiments, the GRP has a center of mass (CoM) that resides below a radius of curvature like a typical MRPT; alternatively, in embodiments the GRP has a CoM that does not necessarily reside below the radius of curvature like in a Gömböc. In embodiments, the single unstable equilibrium point (l) of the Gömböc GRP is on the side opposite of the stable equilibrium point. In embodiments, the GRP can balance on this position; however, a slight disturbance would cause the GRP to move (e.g., like a pencil balanced on a sharpened tip). In embodiments, the GRP has a shape that resembles a Gömböc shape, for example as illustrated in various STL images for a Gömböc-shaped GRP, e.g., as shown in FIGS. 18B, 18C, 18D, and 18E).

### Optically Active Agents

GRPs described herein, in embodiments, have optical properties that change as a function of the movement of the GRP; GRPs thus confer the optical changing properties to materials to which they are applied, arranged on, and/or assembled into. In embodiments, the terms “optical agent” or “colorant” refers to a chemical entity that has an optical property, including absorbing, reflecting, and/or scattering any wavelength(s) of radiation in the visible spectrum, i.e., from about 380 nm to about 800 nm in wavelength. In embodiments, an optical agent or colorant possesses a color, brightness, fluorescence, reflectance, etc., that is detectable by human vision. In embodiments, an optical agent or colorant is a pigment, dye, stain, fluorophore, and/or is a combination one two or more of any category.

Optical properties as described herein, in embodiments, refer to an object's ability to exhibit absorption, emission, reflectance, scattering, and/or interference properties with relation to electromagnetic radiation (e.g., light) within the visible electromagnetic spectrum having a wavelength of approximately 350 nm to about 800 nm; these properties include color, fluorescence, luminescence, and/or phosphorescence, among other properties, that are observable based on electromagnetic wave (light) spectral properties.

In embodiments, the GRP does not exhibit an extinction, reflection, or scattering at one or more wavelengths (e.g., from about or at least about 350 nm to about or at least about 800 nm) during the stationary position or during at least a portion of the motion between the plurality of positions. In embodiments, the GRP only exhibits an extinction, reflection, or scattering at one or more wavelengths (e.g., from about or at least about 350 nm to about or at least about 800 nm) during the stationary position or during at least a portion of the motion between the plurality of positions. For example, GRPs are “invisible” when actuated (e.g., undergoing movement from a force), or “invisible” until actuated. In embodiments, such GRPs are constructed using materials such as polycarbonate-like translucent/clear (e.g., ACCURE 60). In embodiments, the “invisible” quality refers to the GRPs being translucent or otherwise not visible such that the object's optical properties (e.g., color, scattering, reflection, etc.) are observable through the GRP arrangement on the surface of the object. Such a quality, in embodiments, is observable through various angles of visibility relative to the object depending upon the viewing angle and the arrangement of the GRPs on the surface.

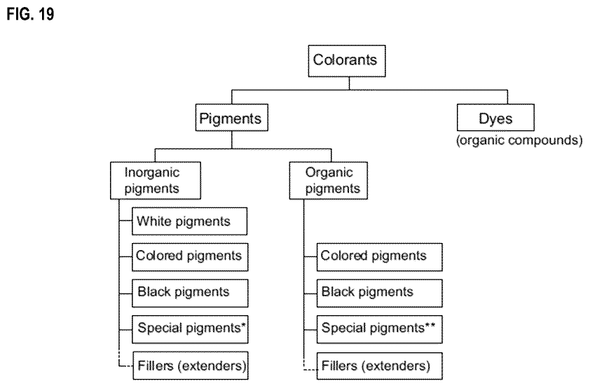

In embodiments, the optical property is color. The color, in embodiments, includes one or more of white, black, red, orange, yellow, green, blue, indigo, violet, and/or a color share or hue therebetween. In embodiments, the color originates from a colorant, for instance in non-limiting examples, various colorants as illustrated in FIG. 19. In embodiments, the colorant includes one or more of a dye, pigment, and/or material that exhibit color-related structural effects.

In embodiments, the GRP exhibits one or more colors, where the one or more colors are conferred from one or more dyes incorporated into the GRP. The dye, in embodiments, includes Rhodamine B, Congo Red, Crystal Violet, Methylene Blue, Acridine Orange, Nile Red, Malachite Green, Eosin Y, Cresol Red, Fluorescein, and/or Indigo.

In embodiments, the GRP exhibits one or more colors, where the one or more colors are conferred from one or more pigments incorporated into the GRP. In embodiments, the GRP incorporates a colored pigment, including in non-limiting examples, one or more of Titanium White (PW6), Zinc White (PW4), Carbon Black (PBK7), Mars Black (PBk11), Iron Oxide Red (PR101), Cadmium Red (PR108), Alizarin Crimson (PR83), Cadmium Orange (PO20), Cadmium Yellow (PY35), Lemon Yellow (PY3), Chromium Green Oxide (PG17), Phthalo Green (PG7), Ultramarine Blue (PB29), Cobalt Blue (PB28), Cerulean Blue (PB35), Prussian Blue (PB27), Burnt Sienna (PBr7), Raw Umber (PBr7), Raw Sienna (PBr7), and/or Yellow Ochre (PY43), where the symbols in parentheses (e.g., PB29 for Ultramarine Blue) are the Pigment Color Index numbers widely used in art and elsewhere to classify colors of paint.

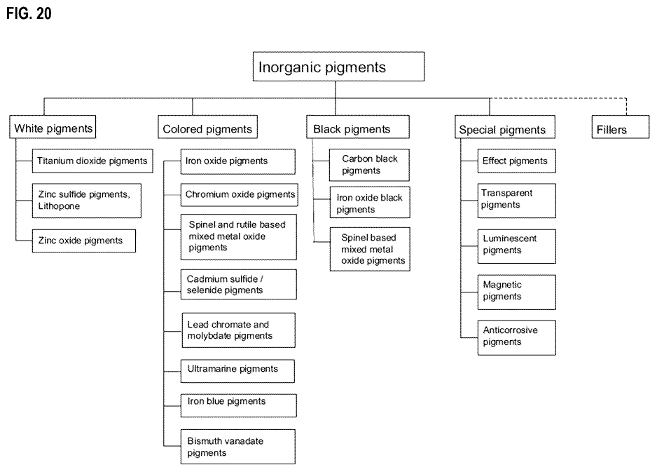

In embodiments, GRPs can incorporate colorants, including pigments, for example as shown in FIG. 20, and as described in PFAFF, “The world of inorganic pigments,” Chem Texts, Vol. 8, No. 15, 2022:17 pages, the entirety of which is hereby incorporated by reference. In embodiments, the pigment is an organic pigment. In embodiments, the pigment is an inorganic pigment. In embodiments, the pigment is an organic or inorganic dye.

In embodiments, the GRP exhibits one or more colors, where the one or more colors are conferred from a pigment with a chemical composition as described in one or more of Table 1 and/or Table 2. In embodiments, the GRP comprises one or more optical agents selected from Table 1 and/or 2, exhibits one or more colors from optical agents selected from Table 1 and/or 2, or the one or more colors are conferred from a pigment or chemical-color pair with a chemical composition as described in Table 1 and/or Table 2.

TABLE 1
Illustrative chemical compositions for GRP colorants.

| Illustrative | |
|---|---|
| Chemical Class | Illustrative Pigments |
| Oxide, oxide hydroxide | TiO₂, ZnO, α-Fe₂O₃, α-FeOOH, γ-Fe₂O₃, Fe₃O₄, Cr₂O₃, CrOOH, |
| | PbO, PB₃O₄, Mn₃O₄, —MnOOH, Sb₂O₃ |
| Complex oxide | CoAl₂O4, CuCr₂O₄, Co₂TiO₄, (Ti, Ni, Sb)O₂, (Ti, Cr, Sb)O₂ |
| Carbonate hydroxide | 2PbCO₃•Pb(OH)₂, 2CuCO₃•Cu(OH)₂, CuCO₃•Cu(OH)₂ |
| Sulfide, selenide | ZnS, CdS, Cd(S, Se), CdSe, γ-Ce₂S₃, HgS, As₂S₃ |
| Chromate, molybdate | PbCrO₄, Pb(Cr, S)O₄, Pb(Cr, S, Mo)O₄, ZnCrO₄, BaCrO₄, SrCrO₄ |
| Vanadate | BiVO₄, 4BiVO₄•3Bi₂MoO₆ |
| Stannate | Pb₂SnO₄, PbSn₂SiO₇, Co₂SnO₄, CoSnO₃ |
| Phosphate | Co₃(PO₄)₂ |
| Antimonate | Pb(SbO₃)₂ |
| Arsenate | Cu(AsO₃)₂ |
| Ultramarine | Na₆Al₆Si₆O₂₄(NaSₙ) |
| Hexacyanidoferrate; | K[Fe^{III}Fe^{II}(CN)₆]•xH₂O (x = 14-16) |
| hexacyanoferrate | |
| Oxonitride | CaTaO₂N, LaTaON₂ |
| Element | C, Al, Cu, Cu/Zn, Au |

TABLE 2
Illustrative color-chemical pairs as colorants for GRPs.

| Illustrative | |
|---|---|
| Color | Illustrative Chemical |
| White | Lead white (2PbCO₃•Pb(OH)₂), kaolin, silica (SiO₂), Titanium dioxide (TiO₂/rutile and |
| | anatase), zinc oxide (ZnO), zinc sulfide (ZnS), lithopone (ZnS + BaSO₄) |
| Black | Coal (charcoal), groutite (α-MnOOH), manganite (γ-MnOOH), hausmannite (Mn₃O₄), |
| | Carbon black, iron oxide black (Fe₃O₄), spinel black (CuCr₂O₄) |
| Yellow | Yellow ochre (α-FeOOH), auric pigment (As₂S₃), lead ochre (PbO), lead tin yellow |
| | (Pb₂SnO₄, PbSn₂SiO₇), Naples yellow (Pb(SbO₃)₂), zinc yellow (Zn2CrO₄), Indian |
| | yellow (C₁₉H₁₆O₁₀), Iron oxide yellow (α-FeOOH), chromium titanium yellow |
| | ((Ti, Cr, Sb)O₂), nickel titanium yellow ((Ti, Ni, Sb)O₂), lead yellow (PbCrO₄), cadmium |
| | yellow (CdS), bismuth yellow (BiVO₄) |
| Red | Red ocher (α-Fe₂O₃), Terra di Siena (α-Fe₂O₃), vermilion (HgS), lead red (Pb₃O₄), |
| | alizarin madder varnish, alizarin red (C₁₄H₈O₄), Iron oxide red (α-Fe₂O₃), molybdate |
| | red (Pb(Cr, S, Mo)O₄), cadmium red (Cd(S, Se)) |
| Green | Green earth (Fe silicates), Schweinfurt green (C₄H₆As₆Cu₄O₁₆), Chromium oxide green |
| | (Cr₂O₃), chromium oxide hydrate green (CrOOH), cobalt green (Co₂TiO₄) |
| Blue | Lazurite (lapis lazuli), Egyptian blue (CaCuSi₄O₁₀), azurite (2CuCO₃•Cu(OH)₂), |
| | malachite (CuCO₃•Cu(OH)₂), cobalt blue (CoAl₂O₄), Cobalt blue (CoAl₂O₄), |
| | ultramarine blue: (Na₆Al₆Si₆O₂₄(NaSn)), iron blue^{a} (K[Fe^{III}Fe^{II}(CN)₆]•xH₂O) |
| Brown | Burnt umber (Fe₂O₃•xMnO₂), brown ocher (α-Fe₂O₃ + Mn oxides), limonite (mixture of |
| | different Fe oxides) |
| Special Color | transparent effect pigment, goniochromatic pigments (aluminum coated with |
| Effects | magnesium fluoride embedded in chromium), pearlescent pigment (mica, titanium |
| | dioxide, bismuth oxychloride), metallic pigment (aluminum, bronze, copper metallic |
| | pigment), interference pigment (titanium dioxide-coated mica, aluminum oxide-coated |
| | mica), metallic effect pigment, fluorescent pigment (fluorescent dye, fluorescent |
| | mineral), luminescent pigment, phosphorescent pigment (zinc sulfide, strontium |
| | aluminate), magnetic pigment, and/or anticorrosive pigment |

In embodiments, the GRP includes an organic and/or inorganic pigment that is a white pigment. In embodiments, the white pigment is one or more of Lead white (2PbCO₃·Pb(OH)₂), kaolin, silica (SiO₂), Titanium dioxide (TiO₂/rutile and anatase), zinc oxide (ZnO), zinc sulfide (ZnS), and/or lithopone (ZnS+BaSO₄).

In embodiments, the GRP includes an organic and/or inorganic pigment that is a black pigment. In embodiments, the black pigment is one or more of Coal (charcoal), groutite (α-MnOOH), manganite (γ-MnOOH), hausmannite (Mn₃O₄), Carbon black, iron oxide black (Fe₃O₄), and/or spinel black (CuCr₂O₄).

In embodiments, the GRP includes an organic and/or inorganic pigment that is a colored pigment.

In embodiments, the colored pigment is a yellow pigment, including in non-limiting examples, one or more of Yellow ochre (α-FeOOH), auric pigment (As₂S₃), lead ochre (PbO), lead tin yellow (Pb₂SnO₄, PbSn₂SiO₇), Naples yellow (Pb(SbO₃)₂), zinc yellow (Zn₂CrO₄), Indian yellow (C₁₉H₁₆O₁₀), Iron oxide yellow (α-FeOOH), chromium titanium yellow ((Ti,Cr,Sb)O₂), nickel titanium yellow ((Ti,Ni,Sb)O₂), lead yellow (PbCrO₄), cadmium yellow (CdS), bismuth yellow (BiVO₄).

In embodiments, the colored pigment is a red pigment, including in non-limiting examples, one or more of Red ocher (α-Fe₂O₃), Terra di Siena (α-Fe₂O₃), vermilion (HgS), lead red (Pb₃O₄), alizarin madder varnish, alizarin red (C₁₄H₈O₄), Iron oxide red (α-Fe₂O₃), molybdate red (Pb(Cr,S,Mo)O₄), cadmium red (Cd(S,Se)).

In embodiments, the colored pigment is a green pigment, including in non-limiting examples, one or more of Green earth (Fe silicates), Schweinfurt green (C₄H₆As₆Cu₄O₁₆), Chromium oxide green (Cr₂O₃), chromium oxide hydrate green (CrOOH), cobalt green (Co₂TiO₄).

In embodiments, the colored pigment is a blue pigment, including in non-limiting examples, one or more of Lazurite (lapis lazuli), Egyptian blue (CaCuSi₄O₁₀), azurite (2CuCO₃·Cu(OH)₂), malachite (CuCO₃·Cu(OH)₂), cobalt blue (CoAl₂O₄), Cobalt blue (CoAl₂O₄), ultramarine blue: (Na₆Al₆Si₆O₂₄(NaSn)), iron blue^{a} (K[Fe^{III}Fe^{II}(CN)₆]·xH₂O).

In embodiments, the colored pigment is a brown pigment, including in non-limiting examples, one or more of Burnt umber (Fe₂O₃·xMnO₂), brown ocher (α-Fe₂O₃+Mn oxides), limonite (mixture of different Fe oxides).

In embodiments, the GRP includes an organic and/or inorganic pigment that includes one or more of an oxide or oxide hydroxide pigment (TiO₂, ZnO, α-Fe₂O₃, α-FeOOH, γ-Fe₂O₃, Fe₃O₄, Cr₂O₃, CrOOH, PbO, PB₃O₄, Mn₃O₄, —MnOOH, Sb₂O₃), a complex oxide pigment (CoAl₂O₄, CuCr₂O₄, Co₂TiO₄, (Ti,Ni, Sb)O₂, (Ti,Cr,Sb)O₂), a carbonate hydroxide pigment (2PbCO₃·Pb(OH)₂, 2CuCO₃·Cu(OH)₂, CuCO₃·Cu(OH)₂), a sulfide/selenide pigment (ZnS, CdS, Cd(S,Se), CdSe, γ-Ce₂S₃, HgS, As₂S₃), a chromate/molybdate pigment (PbCrO₄, Pb(Cr,S)O₄, Pb(Cr,S,Mo)O₄, ZnCrO₄, BaCrO₄, SrCrO₄), a vanadate pigment (BiVO₄, 4BiVO₄.3Bi₂MoO₆), a stannate pigment (Pb₂SnO₄, PbSn₂SiO₇, Co₂SnO₄, CoSnO₃), a phosphate pigment (Co₃(PO₄)₂), an antimonate pigment (Pb(SbO₃)₂), an arsenate pigment (Cu(AsO₃)₂), an ultramarine pigment (Na₆Al₆Si₆O₂₄(NaSn)), a hexacyanidoferrate/hexacyanoferrate pigment (K[FeIIIFeII(CN)₆]·xH₂O (x=14-16)), an oxonitride pigment (CaTaO₂N, LaTaON₂), an elemental-based pigment (C, Al, Cu, Cu/Zn, Au), a spinel-based pigment, and/or a rutile-based metal pigment.

In embodiments, the optically active agent includes an organic and/or inorganic pigment that is a “special effect pigment,” including in non-limiting examples, transparent effect pigments, goniochromatic pigments, pearlescent pigments, metallic pigments, interference pigments, metallic effect pigments, fluorescent pigments, luminescent pigments, phosphorescent pigments, magnetic pigments, and/or anticorrosive pigments.

In embodiments, the optically active agent includes one or more metallic pigments. Metallic pigments, in embodiments, create a metallic effect by reflecting light, producing a shiny or glossy finish. In embodiments, the one or more metallic pigments include aluminum, bronze, and/or copper.

In embodiments, the optically active agent includes one or more pearlescent pigments. Pearlescent pigments, in embodiments, produce a pearly, iridescent effect by reflecting light in a diffused manner. In embodiments, the one or more pearlescent pigments include mica, titanium dioxide, and/or bismuth oxychloride.

In embodiments, the optically active agent includes one or more fluorescent pigments. Fluorescent pigments, in embodiments, emit light when exposed to UV light (e.g., absorbance), producing bright (e.g., emission), resulting in vivid coloration. In embodiments, the one or more fluorescent pigments include fluorescent dyes and/or pigments made from fluorescent minerals.

In embodiments, the optically active agent includes one or more phosphorescent pigments. Phosphorescent pigments, in embodiments, absorb light and emit it slowly over time, producing a glowing effect. In embodiments, the one or more phosphorescent pigments include zinc sulfide and/or strontium aluminate.

In embodiments, the optically active agent includes one or more interference pigments. Interference pigments, in embodiments, produce a unique, shimmering effect by reflecting light in different directions, depending on the angle of viewing. In embodiments, the one or more interference pigments include titanium dioxide-coated mica and/or aluminum oxide-coated mica.

In embodiments, the optically active agent exhibits optical effects observed that arise from structural colors. Structural color, in embodiments, arises from the physical structure of a material rather than from pigments or dyes. This phenomenon is observed in nature, where it is responsible for the vivid colors seen, for example, in peacock feathers, butterfly wings, and many other organisms. Structural color arises from the interference and diffraction of light waves as they interact with microscopic or nanoscopic structures within a material. These structures, in embodiments, can be arranged in layers, patterns, or other geometries on the surface of GRPs that affect the way light is reflected, transmitted, or absorbed, resulting in a wide range of colors that can be iridescent, directional, and/or polarized.

In embodiments, the optically active agent exhibits optical property-changing effects due to the use of the mechanism of color, or changes in color, via plasmonics. Plasmonic materials, in embodiments, can control and manipulate light at the nanoscale and, by extension using engineered materials, to the micron scale, millimeter scale, and larger. Plasmonics, in embodiments, includes the interaction between light and metal surfaces, nanostructures, and/or nanoparticles. In embodiments, plasmonics focuses on the behavior of surface plasmons, which are collective oscillations of electrons in metals excited by light. In embodiments, the GRP includes one or more optically active agents using plasmonics involving the propagation, confinement, and manipulation of surface plasmon polaritons (SPPs). SPPs, in embodiments, are electromagnetic waves that arise from the coupling between photons and surface plasmons.

In embodiments, the GRP includes one or more optically active agents that is an anisotropic particle. In embodiments the anisotropic particle is a nanoparticle of one or more metals. In embodiments, the nanoparticle of the one or more metals comprises a nanorod of one or more of gold (Au), silver (Au), and/or aluminum (Al). In embodiments, the optically active agent is one or more anisotropic noble metal nanoparticles having plasmonic properties. In embodiments, the GRP comprises an optically active agent including an anisotropic particle having a shape including, but not limited to, rods, star shapes, discs, core-shell particles, hollow particles, prisms, hemispheres, and/or cubes, pyramids. In embodiments, the GRP comprises an optically active agent including an anisotropic particle exhibiting anisotropy due to an asymmetric organization of symmetric particles, for instance in non-limiting examples being a string of very closely-spaced 2, 3, 4, 5 or more spherical particles.

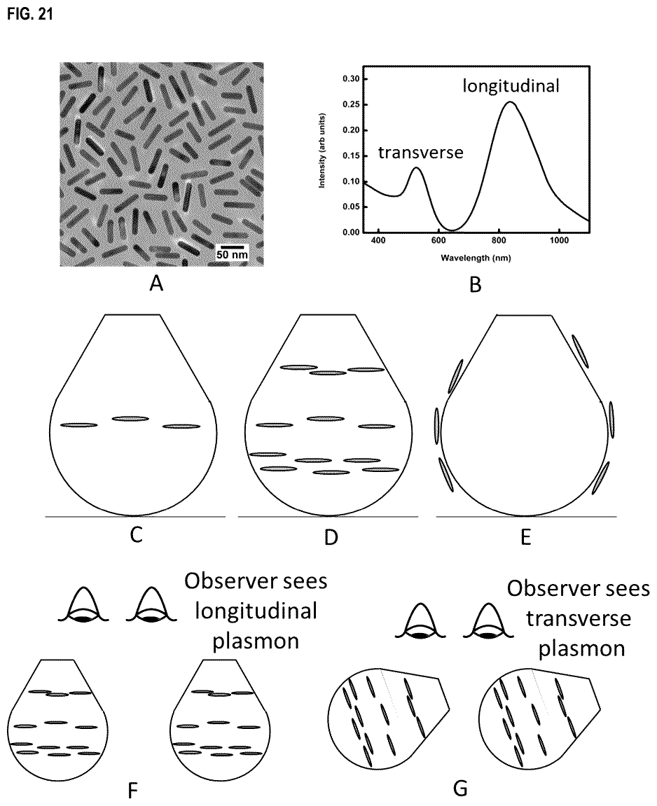

The optically active agent, in embodiments, includes anisotropic gold (Au) nanorods. For example, in reference to FIGS. 21A-21G, in embodiments, the GRP contains an optically active agent that includes one or more Au nanorods, which produce changing optical properties as the GRP moves. In embodiments, the Au nanorods are approximately 50 nm in length and 10 nm in width, for example as shown by transmission electron microscopy in FIG. 21A. In embodiments, metal nanorods of a variety of lengths and widths can be used, for instance in non-limiting examples, the dimensions can be about or at least about 5 nm, about or at least about 10 nm, about or at least about 15 nm, about or at least about 20 nm, about or at least about 25 nm, about or at least about 30 nm, about or at least about 40 nm, about or at least about 50 nm, about or at least about 60 nm, about or at least about 70 nm, about or at least about 80 nm, about or at least about 90 nm, about or at least about 100 nm, about or at least about 200 nm, about or at least about 300 nm, about or at least about 400 nm, about or at least about 500 nm, or about or at least about 1000 nm or more.

In embodiments, the optically active Au nanorods (and similar nanorods containing, in part, or in full Au, Ag, Al, among other plasmonic metals) exhibit optical properties that are favorable for incorporation into GRPs. For example, in embodiments and in reference to FIG. 21B, the transverse mode—when the electromagnetic irradiation impinges on the ends of the nanorods—has a maximum extinction at around 520 nm, while the longitudinal plasmon—when the electromagnetic irradiation impinges on the longitudinal axis of the particle—is of lower energy, with a peak at around 810 nm. Thus, in embodiments, use of Au nanorods where an observer is viewing the Au nanorods, e.g., on a planar glass slide (such as how the particles appear is in FIG. 21A) and irradiated from above, the longitudinal modes are excited, and the surface appears blue. in embodiments, use of Au nanorods where an observer that is viewing the same surface, where the surface is rotated by 90°, such that the irradiation impinges on the ends of the rods, the transverse modes are excited, and a burgundy red color is observed.

In embodiments and in reference to FIG. 21C, a layer of metal nanorods are incorporated into a GRP resting at stationary equilibrium on a plane, with the long axes parallel to plane. In embodiments, the layer of nanorods (among other shapes) can be located on the top portion of the GRP, at the bottom portion, and/or located any other place inside and/or on the surface of the GRP, for example in non-limiting embodiments, FIG. 21D illustrates a GRP with multiple layers of nanorods distributed throughout. Those skilled in the art, with the benefit of this filing in its entirety, will understand that although three layers are illustrated, the number of layers of anisotropic metal nanoparticles could be any integral number of layers, the metals used can be any metal that exhibits anisotropic optical properties, and the sizes of the nanoparticles can be any size that would be compatible with GRPs described herein. In embodiments, the particles do not appear in a discrete layer, but are continuously (or discontinuously) dispersed within the GRP, for example where the GRP is composed of a transparent substrate, with metal nanoparticles disposed therein. Likewise, the anisotropic particles do not need to be confined to the interior of the particle, for example in embodiments, FIG. 21E shows rods adsorbed to, bound, and/or affixed to the outer surface of the GRP.

In embodiments, and in reference to FIG. 21F, while an observer views GRPs at equilibrium as, they will see the longitudinal plasmon (or conversely the transverse plasmon if disposed in that direction). In embodiments were Au nanorods are used, this equilibrium with longitudinal plasmon surface will appear blue (i.e., if the anisotropic nanoparticles are those shown in FIG. 21A). In embodiments, when the GRP is tilted, as shown in FIG. 21G, the observer will see the transverse mode, where for example if Au nanorods are used, the color will change to burgundy (or red or pink, depending on the particle concentration). In embodiments, with respect to the GRP shown in FIG. 21E, switching the orientation of the metal nanorods will reverse the color change, where at equilibrium, the observer will see burgundy/red/pink, and when tilted, the observer will see blue.

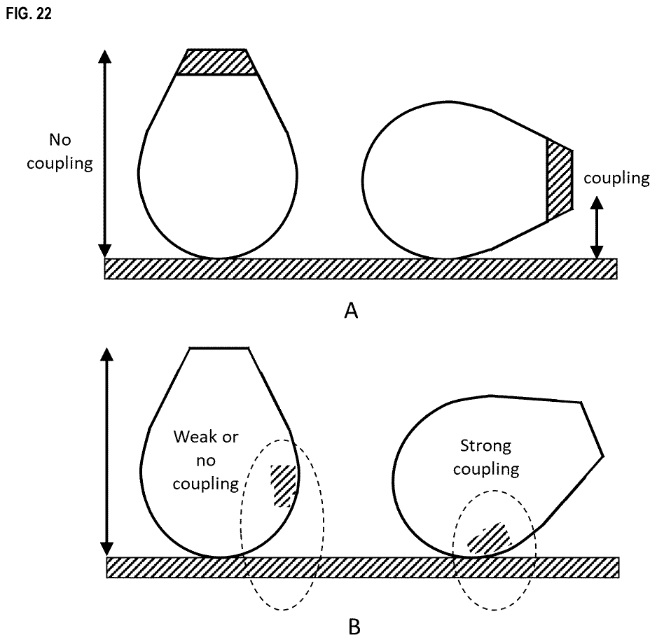

In embodiments, the optically active agent is a material that has plasmonic properties, for example as illustrated in FIGS. 22A-22B. In embodiments, the material is confined to the surface of the GRP and is a metal and/or propagates an optical property along the surface of a metal (depending on the geometry of the metal and the properties of the surrounding medium). In embodiments, there is plasmonic coupling between the GRP and surface/substrate on which it is disposed on, applied to, infused in, and/or placed on. In embodiments, the optically active agent is a plasmonic material that is or includes a continuous or discontinuous thin noble metal films and/or a surface that incorporates or contains plasmonic particles.

For example, in embodiments, the optically active agent is a polymer-film loaded with noble metal nanoparticles. As shown in FIG. 22A, in embodiments, the optically active agent is a plasmonic material, particle, foil, and/or film form of noble metal nanoparticles on or near the top portion of the GRP. In embodiments, the exact distance dependence of coupling between the optically active plasmonic materials depends on the size and shape, where the optical coupling is diminished exponentially with distance between surfaces. For instance, in embodiments, a GRP of roughly 1 μm in size, any coupling between the top of the GRP and the surface it is disposed on is zero. However, in reference to FIG. 22A, in embodiments, when the GRP is tilted due to mechanical force, the plasmonic materials are brought in close enough proximity to be optically coupled, where the optical properties change such that an observer can perceive a change in color, reflectance, brightness, or some other optical property. In embodiments, and in reference to FIG. 22B, the GRP can have disposed thereon an optically active agent with plasmonic material on or nearer a bottom/side (i.e., tilting surface) portion, such that tilting brings the plasmonic optically active agent in proximity or in contact with the plasmonic surface the GRPs are disposed on, resulting in a change of optical property. In embodiments, the degree of coupling is proportional to the change in color, reflectance, brightness, or some other optical property. In embodiments, the observed optical properties are the not sum of the independent optical properties of each material.

In embodiments, the optically active agent includes one or more goniochromatic materials and/or pigments. Goniochromatic materials/pigments, also known as gonioapparent or goniospectral materials/pigments, in embodiments, are materials/pigments that exhibit assorted colors or hues depending on the viewing angle or illumination direction. In embodiments, this effect is due to the presence of microscopic structures or surface features that cause light to be scattered and diffracted in a way that creates assorted colors when viewed from different angles. In embodiments, the color and appearance of goniochromatic materials/pigments is highly directional and changes dramatically as the viewing angle changes, and/or as the angle of light incidence changes. In embodiments, the one or more goniochromatic materials and/or pigments includes aluminum coated with magnesium fluoride embedded in chromium. In embodiments, the one or more goniochromatic materials and/or pigments includes silica-coated mica.

In embodiments, the goniochromatic pigment is CHROMAFLAIR (Viavi Solutions, pigments composed of thin, multi-layered flakes that have crystal structures that gives color-shifting properties). In embodiments, the GRP includes one or more portions incorporated with CHROMAFLAIR coating or ink, creating a color-shifting effect that varies with the angle of observation (e.g., as the GRP moves). In embodiments, the optically active agent is CHROMAFLAIR Green/Purple 190 (Viavi Solutions, pigment with a green face traveling though purple (at) 45° to magenta and gold). In embodiments, the goniochromatic pigment is a “color travel pigment” (such as XIRONA, Merck KgaA (Darmstadt, Germany)), including the specific pigments Nordic Sunset, Magic Mauve, Kiwi Rose, Caribbean Blue, Volcanic Fire, Golden Sky, Le Rouge, Volcanic Sparks, and Moonlight Sparks.

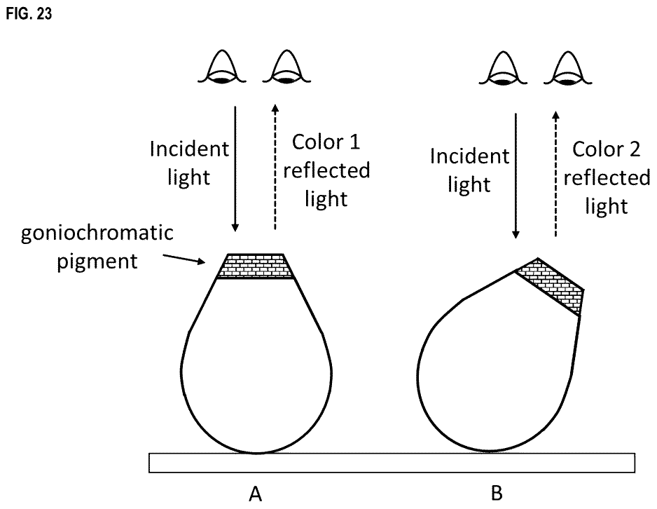

With reference to FIGS. 23A-23B, in embodiments, the GRP can incorporate a goniochromic pigment. In embodiments and with reference to FIG. 23A, when such a GRP is at equilibrium, with the goniochromatic material at or near the top portion of the GRP, and with fixed incident light perpendicular to and irradiating GRP (or array of GRPs, among other arrangements), the baseline color (e.g., “Color 1”) is observed. In embodiments, as the GRP is tilted, e.g., as shown in FIG. 23B, a different color(s) (e.g., “Color 2”) is observed, achieving a goniochrometric effect without the observer having to move. Typically, where goniochromic coloration is used (e.g., as car paint or in cosmetics), the observer must move to see a change in color; however, in embodiments, the observer can stay at a fixed angle, while the GRP exhibits changing colors.

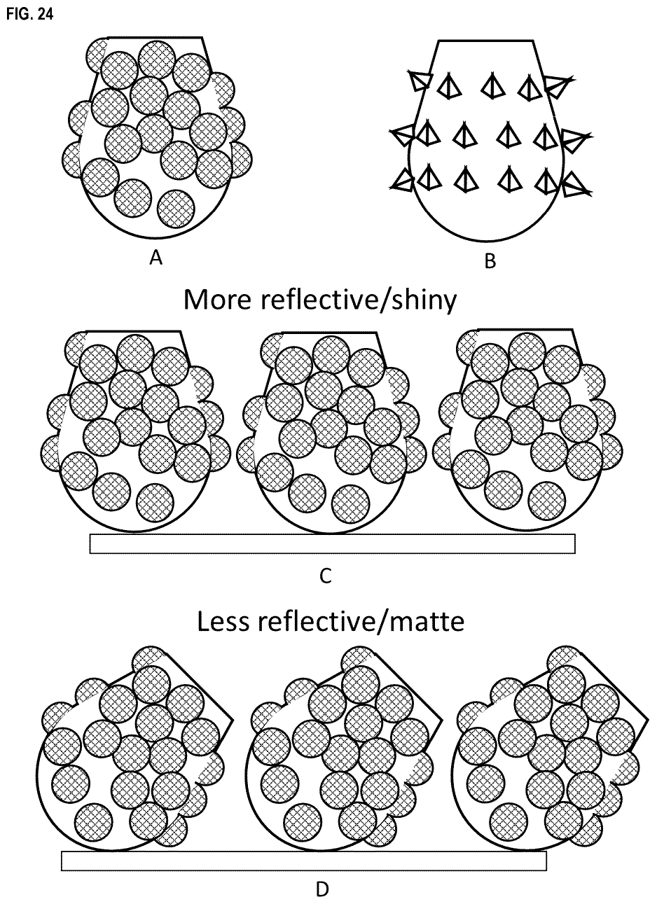

In embodiments, the GRP has a uniform color, but the differences in optical properties seen by the observer upon the tilting and/or pendulum action of GRPs results from differences in reflectivity. For example, in embodiments and in reference to FIGS. 24A-24D, GRPs can exhibit differences in reflectivity due to alterations in surface roughness from “roughness features,” or differences in the smoothness of the GRP surface. The roughness features, in embodiments, can be on any surface(s) of the GRP, the roughness features can be regularly and/or irregularly shaped, and the roughness features can appear in a regular pattern (e.g., even spaced in a repeating pattern) and/or irregular pattern (e.g., randomly spaced), and/or a combination of these configurations. As illustrated in FIG. 24A, in embodiments, the roughness features are “bumps,” or similar structured and/or unstructured roughness features. Such roughness features, in embodiments, can be confined to a top portion of a GRP, on a side portion of a GRP, and/or on a bottom portion of a GRP. In embodiments, the roughness features are placed depending on the overall shape of the GRP. In reference to FIG. 24B, the individual roughness features are structured as a pyramidal shapes; however, roughness features can take any shape, including in non-limiting examples, hemispheres, prisms, pyramids, saw tooths, teardrops, or any other 3D shape exhibiting one or more symmetrical feature, or non-symmetrical feature. As shown in FIG. 24B, in non-limiting embodiments, the roughness features can be organized in regular patterns, such as three circles of pyramids running laterally about the GRP.

Those skilled in the art, with the benefit of this disclosure in its entirety, will appreciate the full spectrum of organization of the pattern/features possible on the surface of GRPs and/or as optically active agents. Additionally, those skilled in the art, with the benefit of this disclosure in its entirety, will appreciate that unstructured or structured roughness features, either in a random or non-random configuration, can intrinsically result from the methods of manufacture described herein to create such GRPs.

In reference to FIG. 24C, in embodiments, GRPs with roughness features at stationary equilibrium, having roughness on the side portions, but not on the top portions will appear as a smoother, more reflective surface at equilibrium. But when perturbed, e.g., as shown in FIG. 24D, in embodiments, as the GRPs are tilted, the roughness features are exposed to the observer, where the rougher, less reflective surfaces of the GRPs will results in a color-changing effect.

### Substrates and Arrangement of GRPs

In embodiments, GRPs are associated with a surface or substrate. In embodiments, GRPs can be added directly to surfaces and/or substrates such as windows, computer chips, glass surfaces, fabrics, plastics, paper, wood, construction materials, and/or human or animal tissue/skin, among other surfaces and/or substrates. In embodiments, the substrate is planar or non-planar. In embodiments, the substrate has a simplex or complex geometry, and is, in part or in whole, convex, concave, or without a well-defined shape. Likewise, in embodiments, the GRPs are associated with a simple, complex, regular, and/or irregular shape. In embodiments, the GRPs appear in one or more different regions of a surface and/or substrate of an object. In embodiments, the GRPs are added to a surface/substrate on the interior of an object, the exterior or an object, or both.

In embodiments, the total surface area of GRPs disposed and/or applied onto a surface or substrate can have a footprint measuring in microns, e.g., 2.1×1.5 microns (or 315 μm²), or in meters, e.g., 20×21 meters (or 420 m²). In embodiments, the total surface area of GRPs disposed and/or applied onto a surface or substrate can have a footprint of about or at least about 100 μm², about or at least about 200 μm², about or at least about 300 μm², about or at least about 400 μm², about or at least about 500 μm², about or at least about 1,000 μm², about or at least about 10,000 μm², about or at least about 100,000 μm², about or at least about 106 μm², about or at least about 10 mm², about or at least about 1 cm², about or at least about 10 cm², about or at least about 100 cm², about or at least about 1,000 cm², about or at least about 1 m², about or at least about 2 m², about or at least about 3 m², about or at least about 4 m², about or at least about 5 m², about or at least about 10 m², about or at least about 20 m², about or at least about 50 m², about or at least about 100 m² or more.

In embodiments, GRPs are formulated into a foil, film, thin plastic, and/or paper substrate, material, and/or surface. In embodiments, the GRPs are associated with a substrate that is then applied to another object (i.e., indirectly); for example, GRPs can be associated with a piece of paper that is then glued to packaging (i.e., as a label). In embodiments, GRPs (e.g., sufficiently small in size) can be applied to paper or foil, (e.g., wrapping paper, stationary, packaging, instructions, cardboard, etc.), and the like, to generate a layer of GRPs that can be affixed to a surface (e.g., onto a parcel, envelope, or box to be shipped, gift wrapping, etc.), where the GRPs will change optical properties (e.g., color) as a function of the viewing angle and/or movement of the surface.

In embodiments, GRPs are formulated into a fiber, thread, yarn, and/or twine substrate, material, and/or surface. In embodiments, the fiber, thread, yarn, and/or twine is fashioned into an article of clothing, a cloth, tarp, or other covering. In embodiments, GRPs can be associated with a thread woven into or otherwise applied to another object. In embodiments, GRPs can be associated with objects through the use of foils or plastics, for example as a standalone or in threads, sheets, or rolls. In embodiments, GRPs (e.g., sufficiently small in size) can be embedded into a thread, fiber, yarn, twine, etc., which can be woven into an article of clothing, cloth, and/or tarp, where, as the article of clothing, cloth, and/or tarp is moved, the thread, fiber, yarn, twine, etc. will change its optical properties (e.g., color) as a function of the viewing angle and/or movement of the article.

In embodiments, GRPs are formulated into a fluid, suspension, ink, liquid film, and/or adhesive substrate, material, and/or surface. In embodiments, the fluid, suspension, ink, liquid film, and/or adhesive substrate, material, and/or surface is suitable to be applied to an object, e.g., as a paint, ink, liquid film, etc. that can be painted onto a surface of an object, where, as the object is moved, the paint, ink, etc. will change its optical properties (e.g., color) as a function of the viewing angle and/or movement of the article.

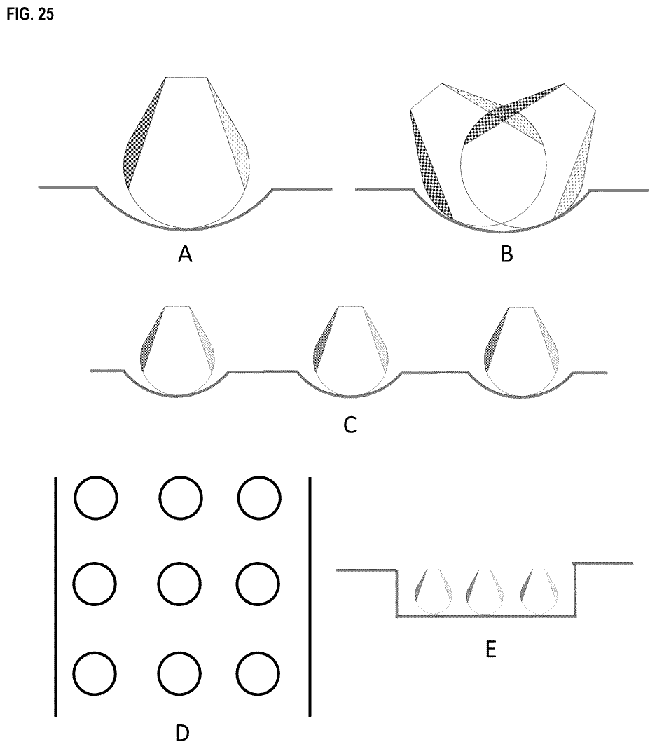

In embodiments, where GRPs are associated with substrates—either directly or indirectly—it can be advantageous to control their position. In embodiments, the position is controlled through indentations (or divots) on the substrate. For example, in reference to FIG. 25A, in embodiments, a GRP can be cradled into an indentation such with a curved shape. In embodiments, for example as shown in FIG. 25B, GRPs held in the indentation can tilt and move while remaining confined within the indentation. In embodiment, GRPs can be positioned neatly into arrays using individual indentations or divots positioned on the material or object, as shown in FIG. 25C. This pattern of placement can result in the surface of the object appearing, in embodiments, as illustrated in FIG. 25D, which shows a top view of an array of 3×3 indentations on a surface. In embodiments, and in reference to FIG. 25E, several GRPs can be placed into a single divot/indentation, for example at least 2, 3, or more separate GRPs can be placed into a single divot/indentation.

In embodiments, a surface or substrate can have any number of indentations (depending on the size of the GRPs to use and the surface area to be covered), for example the surface or substrate can have as few as one, or as many as 10⁹ indentations or more. In embodiments, the indentation spans an entire surface, in which case such a surface could be considered like a shallow tray. In embodiments, such a shallow tray can contain about or at least about 2, about or at least about 3, about or at least about 4, about or at least about 5, about or at least about 6, about or at least about 7, about or at least about 8, about or at least about 9, about or at least about 10, about or at least about 100, about or at least about 1,000, about or at least about 10,000, about or at least about 100,000, about or at least about 10⁶, or about or at least about 10⁹ or more GRPs.

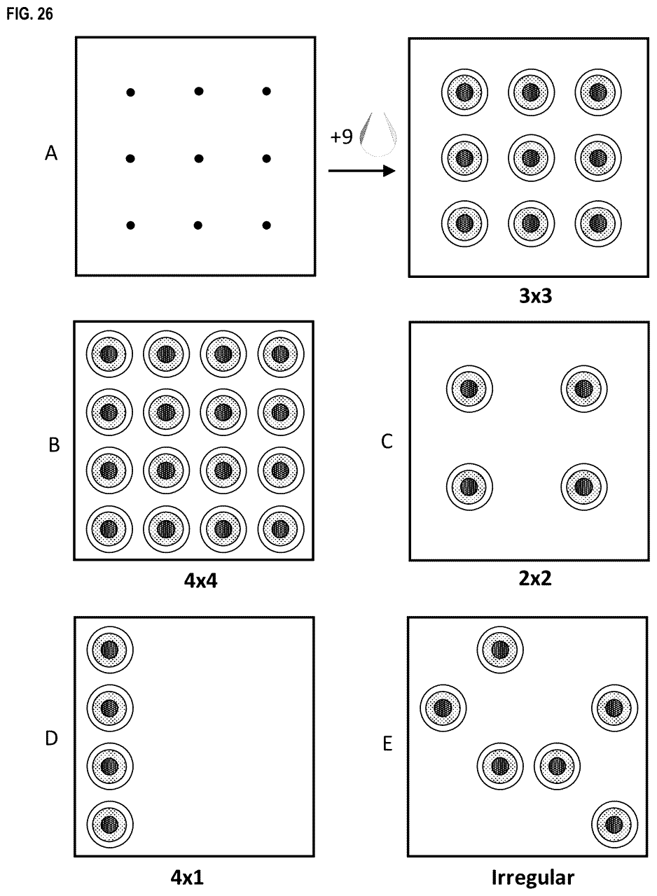

In embodiments, indentations serve to organize and/or place GRPs; for example, as shown in FIG. 26A, 9 GRPs are added to a substrate with 9 evenly spaced indentations in a 3×3 pattern, where the 9 GRPs settle in the lowest energy configuration, which is one in each of the 9 indentations. Alternatively, in embodiments, an excess of GRPs relative to the number of indentations could be added, with subsequent removal of the GRPs not associated with indentations. In embodiments, the spacing between and pattern of indentations is adjustable, for example, as shown in FIG. 26B, is shown a regular 4×4 array of indentations for a total of 16 indentations in the same area as were the 9 shown in FIG. 26A. Likewise, in embodiment and as shown in FIG. 26C, there are 4 indentations within the same area. In embodiments, the array of GRPs and/or indentation pattern, for example as shown in FIGS. 26A, 26B, and 26C, are symmetrical, where rotation by 90° or 180° yields the same pattern. In embodiments, for example as shown in FIG. 26D, the arrangement can be confined to only a portion of a material/object, such as a 4×1 array, where all indentations in the given area are along a line on the left edge of the material/object. In embodiments, for example as shown in FIG. 26E, the pattern of indentations in a given area are irregular, with no elements of symmetry.

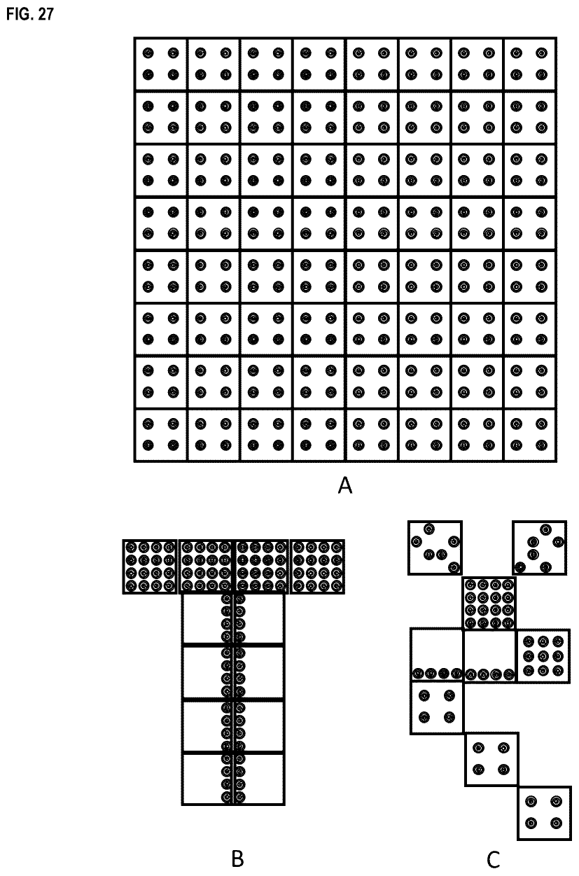

The indentations on a substrate, in embodiments, can assume any pattern on the microscopic or macroscopic scale. In embodiments, and as shown in FIG. 27A, a top view of a regular 8×8 array of the 4×4 arrays shown in FIG. 26B is illustrated; this substrate can contain a total of 1,024 GRPs in 1,024 indentations, but the number of indentations and the number of GRPs with indentations can be scaled up to the millions or in the billions. Organization of GRPs can follow a specific pattern of indentations, for example in embodiments and as shown in FIG. 27B, an assembly of four of the 4×4 arrays shown in FIG. 26B and eight of the 4×1 arrays FIG. 26D, with four of the latter being rotated by 180°, can be used to form a pattern in the shape of the letter T. In embodiments, and as shown in FIG. 27C, 9 of the arrays in FIGS. 26A-26E are assembled to form an irregular pattern, i.e., exhibiting no elements of symmetry. In embodiments, a material/substrate can have a 2D shape for placing GRPs into indentations, where the final overall shape of the material/substrate is 3D, for example with the 2D substrates of FIGS. 27A-27C to be folded along the lines of the individual squares to make a 3D object.

In embodiments, an alternative approach to organize GRPs on surfaces, substrates, or objects is through the use of pillars, posts, stops, and the like. For example, in embodiments, these elements, among other similar protrusions, including objects emanating from a surface (as opposed to indentations within it) can be used to hold GRPs in place on a substrate/surface. In embodiments, the material/substrate is more suited to the use of posts to affix GRPs to a surface, substrate, and/or material with an array of posts or pillars than to create a pattern of divots or indentations.

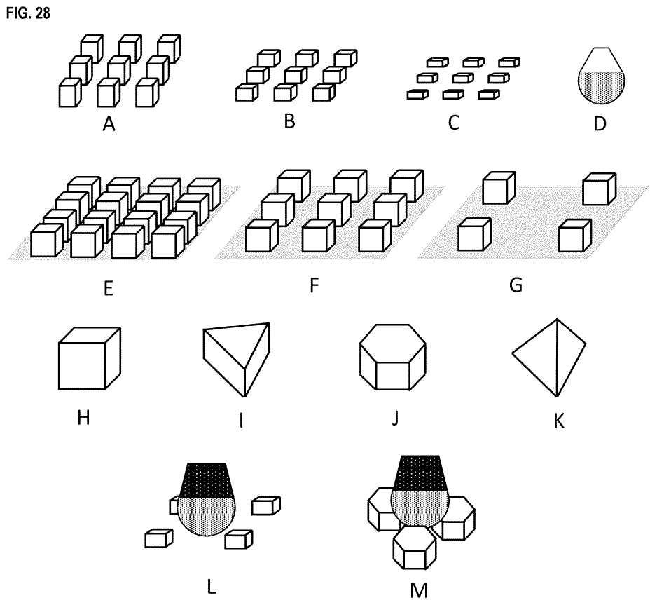

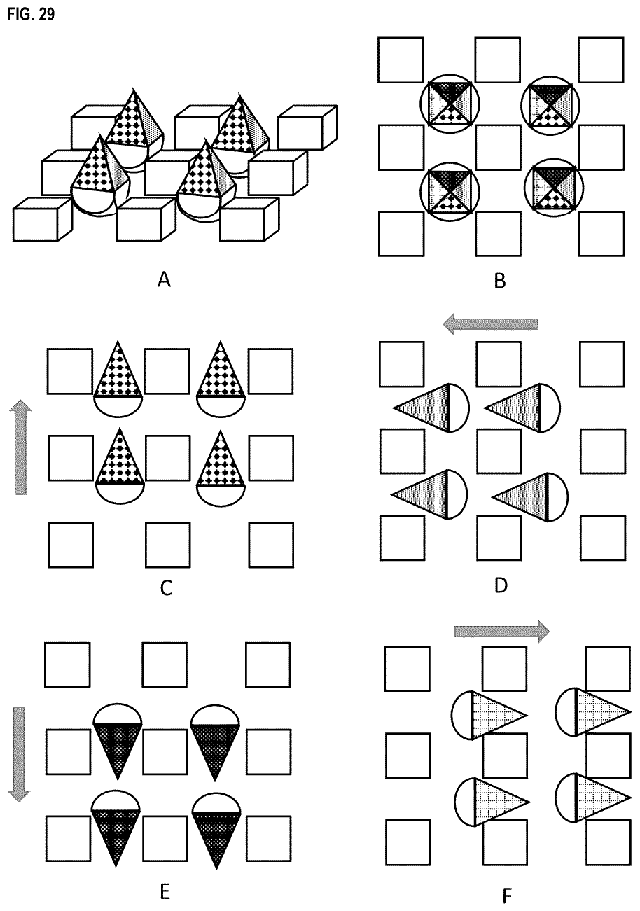

In reference to FIGS. 28A-28M and 29A-29F, the concept of the use of posts to place/hold GRPs onto a surface is illustrated. For instance, in non-limiting embodiments, FIGS. 28A, 28B, and 28C show 3×3 arrays of posts with different heights, with a representative GRP shown in FIG. 28D for comparison of scale. In embodiments, the posts can be a range of heights relative to the GRP, for example the posts can be about or at least about 1% of the height of the GRP, about or at least about 5% as high, about or at least about 10% as high, about or at least about 15% as high, about or at least about 25% as high, about or at least about 30% as high, about or at least about 35% as high, about or at least about 40% as high, about or at least about 45% as high, about or at least about 50% as high, about or at least about 60% as high, about or at least about 80% as high, or at least about 120% high or more, or any percentage in between. In embodiments, the posts are very densely spaced, for example as shown in FIG. 28E, or relatively moderately spaced as in FIG. 28F, or widely spaced as in FIG. 28G. In embodiments, the posts are made to conform to any shape, i.e., such as cubes as shown in (e.g., as shown in in FIG. 28H), triangular prisms (e.g., as shown in in FIG. 28I), hexagonal prisms (e.g., as shown in in FIG. 28J), and/or trigonal pyramids (e.g., as shown in in FIG. 28K). In embodiments, the posts are cylinders, disks, hemispheres, and/or any other shape and/or combinations of shapes, such as hemispheres and cubes. Depending on the size of the posts relative to the GRP and the spacing between the posts, in embodiments, the GRP can rest at equilibrium in between posts such that the GRP contacts the surface or substrate, e.g., as shown in FIG. 28L with a GRP between four smaller rectangular prism-shaped posts, or GRPs can rest on top of posts such that the vertex of the bottom part of the GRP is not in direct contact with the substrate, e.g., as illustrated in FIG. 28M with a GRP at rest between three hexagonal prisms, but not in contact with the surface.

In embodiments, posts, pillars, stops, and the like, on the surface of a material/substrate can be used to constrain the directions of motion or tilt of a GRP disposed therein or thereon. For example, in embodiments and as shown in FIG. 29A, a tilted side view is illustrated for an array of four GRPs with square pyramid tops (e.g., as shown in FIGS. 8G-8J) in between a regular 3×3 array of rectangular prismatic posts. The top view of such an arrangement of GRPs at equilibrium is shown in FIG. 29B. In embodiments, each face of the top part of the GRPs has a different optical property (e.g., a different color). In embodiments, the GRPs are organized in identical initial orientations. In embodiments, the position and/or height of the posts dictate the maneuverability of the GRPs, such as the distance the GRPs can tilt, as it can only tile between the posts. In embodiments, for example as shown in FIGS. 29C-29F, the regular spacing and symmetry of the posts allows tilting in only four directions (i.e., the four directions in between the rectangular prismatic posts, each direction 90° rotated relative to the other). In embodiments, for example with the GRPs with square pyramid top portions of FIGS. 29A-29F, each face of the pyramid can be a different color, leading to a situation where the observer views a completely different color, or set of colors, depending on which direction tilt is initiated between the posts.

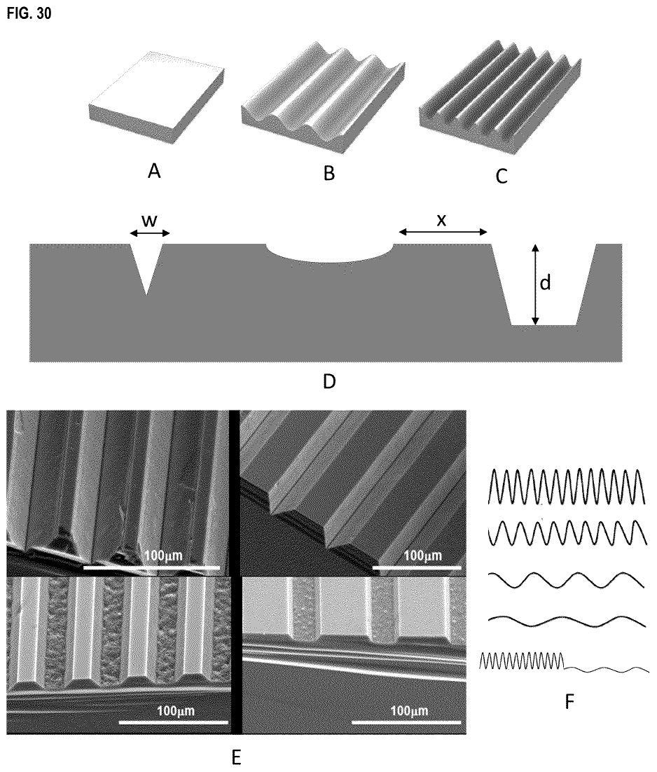

In embodiments, as an alternative to indentations, posts, pillars, and/or stops, grooves in the surface of a material/substrate can be used as an organizing motif for GRPs, e.g., as shown in FIGS. 30-32. For example, as illustrated in FIGS. 30A-30C, in embodiments, FIG. 30A shows a planar surface (i.e., no grooves), FIGS. 30B and 30C show surfaces with a series of parallel, linear grooves, where the grooves can be quasi-hemispherical (e.g., as shown in FIG. 30B), the grooves can be more parabolic (e.g., as shown in FIG. 30C), or the grooves can take on any concave shape. For example, FIG. 30D shows a side view of a substrate with grooves, where in embodiments, three exemplary types of grooves are illustrated: triangular, elliptical (ellipse-shaped), and trapezoidal. In embodiments, grooves can be engineered such that the width (w) of a groove, the depth (d) of the groove, and the spacing (x) in between adjacent grooves can each be varied to further modulate the placement, arrangement, and function of GRPs disposed on substrates/materials.

In embodiments, and in reference to FIG. 30E, scanning electron microscopy (SEM) images illustrate four different grooved surfaces of substrates, where the scale bar is equal to 100 μm, and thus GRPs disposed into such grooves would be approximately 10-50 μm in size. In embodiments, substrates can have linear, parallel grooves, the groove shape (width, depth), and spacing that can be finely adjusted. In embodiments, and in reference to FIG. 30F, variations in spacing frequency of grooves can be used on substrates/materials, with a non-limiting example of five different examples illustrated: the top four frequencies illustrating a uniform groove spacing (and depth) across the substrate, while the bottom surface shows two different groove types with a series of closely-spaced and deeper grooves (to the left) and a series of more widely-spaced and shallower grooves (to the right).

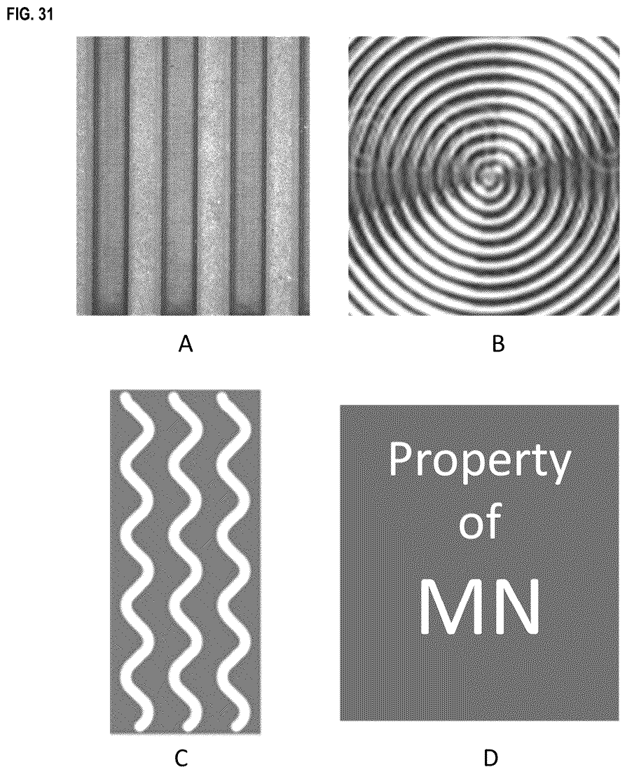

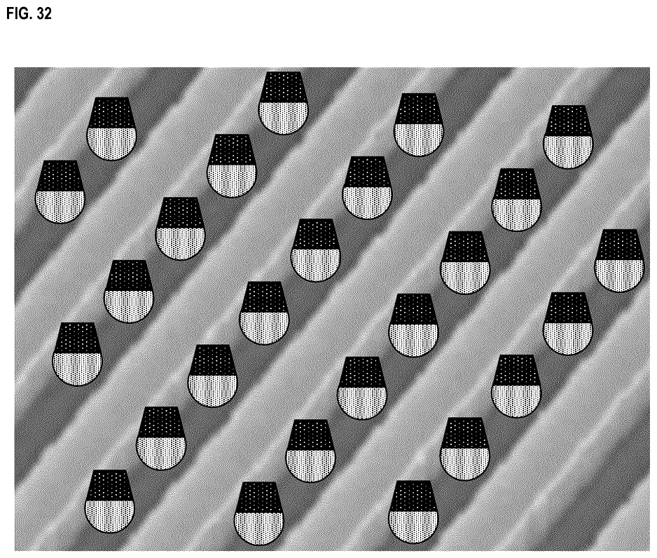

In embodiments, and in reference to FIGS. 31A-31D, variations in patterns of grooves can be used for substrates/materials. For example, in embodiments, linear, parallel grooves can be employed (e.g., as shown from the top in FIG. 31A), the groove pattern can be spiral (e.g., as shown from the top in FIG. 31B), or the grooves can be sinusoidal, though still parallel (e.g., as shown from the top in FIG. 31C). In embodiments, for example as shown in FIG. 31D, grooves can take on the shape of letters, numbers, pictures, etc., across the substrate, where GRPs disposed thereon can convey messages, words, numbers, images, and the like. In reference to FIG. 32, in embodiments, GRPs can be organized on a substrate containing grooves (in this case, rectangular grooves in a linear, parallel pattern), where indents, posts, and the like can be further added into the grooves to hold GRPs in place and/or control tilting behavior. In embodiments, any pattern of grooves is possible, where the groove patterns can be customized to a particular application, user, and/or object.

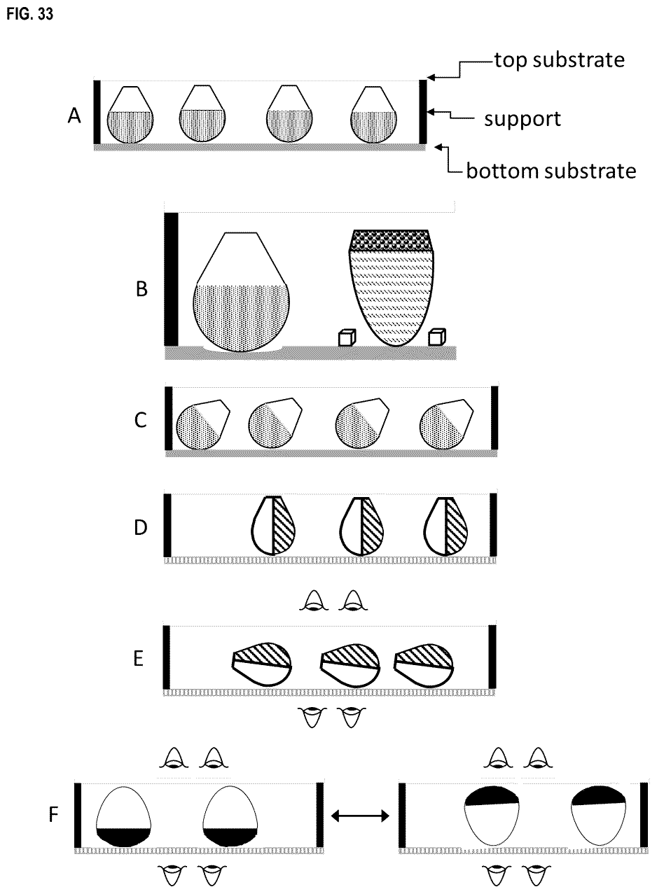

In embodiments, GRPs maintain their orientations without falling out of the material, substrate, and/or objects they are affixed to are moved. For example, in embodiments, if an object is tipped upside down, the GRPs do not fall out. This can be achieved, in embodiments, by positioning or “sandwiching” GRPs between two substrates, e.g., as shown in FIG. 33A, where a partly or fully transparent top substrate is placed over the GRPs such that they can move without falling out of place. In embodiments, applications involving viewing differences in optical states (e.g., changes in color), the top substrate is partly or fully transparent. In embodiments, examples of substrates transparent in the visible EM spectrum include glass, quartz, plastic, polyethylene terephthalate, polycarbonate, polymethyl methacrylate (acrylic), polyethylene, polyurethane, polypropylene, thermoplastic elastomers (TPE), acrylonitrile butadiene styrene (ABS), epoxies and epoxy-based photoresists, hydrogels, cyclic olefin copolymer (COC) cyclic olefin polymer (COP), poly dimethyl siloxane (PDMS), poly ether ester ketone (PEEK), polyetherimide (ULTEM), and/or nylon. In embodiments, the substrate can be a polymer or plastic film as the top substrate to maintain GRP position without obscuring optical properties. In embodiments, the top substrate is thin (e.g., 100 nm thickness) or is thicker (e.g., 2 mm thickness), provided that sufficient transparency of the material is achieved. In embodiments, transparent the material is about or at least about 50 nm thick, is about or at least about 100 nm thick, is about or at least about 500 nm, about or at least about 1 μm thick, is about or at least about 10 μm thick, is about or at least about 100 μm thick, about or at least about 1 mm thick, about or at least about 5 mm thick, or about or at least about 10 mm thick.

In embodiments, GRPs can move through a plurality of positions without falling out of the substrate, surface, and/or material disposed thereon. This can be achieved, in embodiments, by leaving a space for the GRPs to wobble where the top substrate does not directly contact the top surface of the GRPs, and where supports or spacers that are roughly the same height as the GRPs (but slightly taller) are placed between the top and bottom substrates. In embodiments, there can be any integral number of supports/spacers placed between substrates, including by not limited to, 1, 2, 3, 4, 5, 10, 100, 1,000, 10⁶, or more supports/spacers associated with any given array of GRPs on a substate or object. For example, in embodiments, the posts of FIG. 29 can serve a dual purpose-both maintaining the proper spacing for arrays of GRPs, and also serving as supports between top and bottom substrates (or top substrate and object surface, if the GRPs are directly contacting the object). In embodiments, the supports are opaque, semi-transparent, or transparent, and can comprise the same material as used for the bottom substrate, the same material as used for the top substrate, or any other material. In embodiments, the bottom substrate has any number of supports and/or separate indentations or posts, e.g., as shown in FIG. 33B. In embodiments, the structures of indentations/supports between substrates, as shown FIGS. 33A and 33B, allow GRPs to adopt the full range of motion (e.g., tilting) upon application of force, e.g., as shown in FIG. 33C.

In embodiments, the bottom substrate holding a GRP in position is transparent or semi-transparent, e.g., where advantageous depending on the application and the types of GRPs used. In embodiments, the transparent substrate can be any thickness, such as in the nanometer range, the micron range, or the millimeter range. For example, in embodiments, an array of the GRPs from FIG. 13 can be disposed such that there is a transparent top and bottom substrate, e.g., as shown in FIG. 33D, which enables an observable optical property-changing effect upon tilting, e.g., as illustrated in FIGS. 33E and 33F. In embodiments, in such an arrangement, an observer looking through the top substrate of FIG. 33E, where the GRPs are tilted to the left, will see a state or color associated with right side of the GRPs at equilibrium, while an observer looking through the bottom substrate will see the state or color associated with the left side of the GRPs.

In embodiments, by adjusting the overall thickness of the assembly of FIGS. 33D and 33E to approximately match the thickness of an object of interest (e.g., a paper, film, thin plastic, etc.), the GRP array can be incorporated, woven, and/or placed into the object of choice, such that the optical effects on both sides are observable. In embodiments, the suitable thickness for such an object is between 0.01 mm and 10 mm. For instance, in non-limiting embodiments, for a sheet of paper, film, thin plastic, etc., that is intended to be approximately 1.0 mm thick, one could use the assembly illustrated in FIG. 33D, with GRPs of roughly 0.6 mm in height, and transparent top and bottom substrates that are roughly 0.2 mm in thickness.

In embodiments, GRPs (e.g., such as the two-state GRPs of FIGS. 14-16) can be positioned (e.g., in arrays) with a transparent top substrate and a transparent bottom substrate, where the GRPs can be observed in the two stable configurations, as illustrated in FIG. 33F. In this instance, in embodiments, observers from the top and bottom will see opposite effects, where initially, the top observer will see the part colored white in the illustration, and the observer looking through the bottom will see the part colored black in the illustration. Upon agitation, in embodiments, GRPs will wobble through the unstable state to the other stable equilibrium, where the observer looking through the top substrate will see the parts of the GRP colored black in the illustration, while the observer looking through the bottom will see the parts of the GRPs colored white. This assembly, in embodiments, can be incorporated into objects, e.g., such as into objects having a thickness between 0.1 mm and 10 mm such that both effects can be seen.

### Controlling the Functional Effects of GRPs

In embodiments, GRPs can adopt a variety of orientations (e.g., tilt, revolve, tip, etc.) and exhibit one or more different optical states (e.g., different colors), relative to being at rest (e.g., at stationary equilibrium). In embodiments, a variety of mechanisms are used to control the optical states and the changing between them. For example, in embodiments, depending on the size and shape of an individual GRP, and the number and spacing of GRPs on a given substrate, the magnitude of the effect is tunable to be greater or smaller.

In embodiments, different optical states (e.g., colors) can be illustrated using color hex codes, also known as hexadecimal color codes, which are ways to represent colors in web design and graphics. In embodiments, color hex codes include a six-character alphanumerical combination, where each color has its own unique code. For example, considering the GRPs in FIG. 13, the color on the left side of the GRPs can be burgundy (hex code #800020), and the color on the right side can be royal blue (hex code #4169e1). In embodiments, if there are a large number of GRPs on a substrate, and/or if the GRPs are densely packed or closely-spaced, an observer might see burgundy or royal blue as the GRPs tilt back and forth. However, in embodiments, if the spacing is great and/or the number of GRPs is small, the observer might see pink (hex code #FFC0CB) or light blue (hex code #ADD8E6).

Alternatively, in embodiments, GRPs can be positioned into a surface and controlled such that a ratio of GRPs exhibit a first color and a second color, at a specific time, resulting in a blend of these first two colors to exhibit a third color. For example, in embodiments, GRPs can have alternated blue sides and yellow sides, positioned onto a substrate such that as the GRPs move, they can exhibit a green color overall, from the blending of blue and yellow.

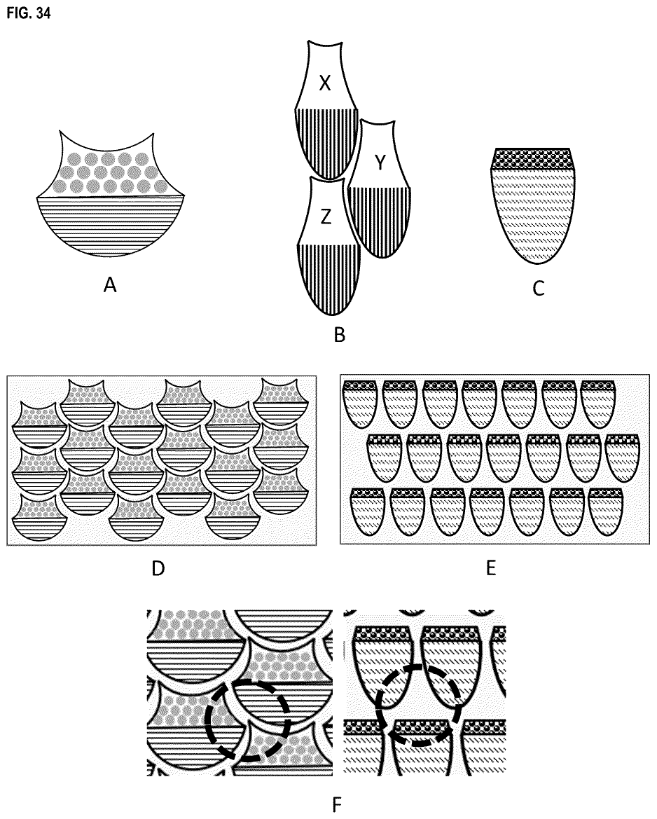

In addition to the number and spacing of GRPs, in embodiments, the shape of the GRP can also impact the optical states (e.g., color): for example, certain shapes of GRPs can fill space better than others. For example, in embodiments, the GRP of FIG. 34A depicts the side view of a GRP design for close packing, in which the top portion has a curvature with a top surface being complementary to a bottom surface of the bottom portion such that, when tipped, the effective surface area is maximized. Likewise, in embodiments, the curvature of the sides of the GRP can be complementary to the curvature of the sides of the bottom. In embodiments, a variety of shapes are possible where only one shape needs to be complementary to the bottom surface, for example, and as shown in FIG. 34B, a top view of three tipped GRPs where the top is complementary in shape to the bottom. In embodiments, it can be seen that in this tipped configuration, Y is close to and packs with the right side of tipped GRP X; likewise, the top surface of the top portion of tipped GRP Z is close to and packs with the bottom surface of the tipped GRP X.

In embodiments, the GRP illustrated in FIG. 34C does not enable similarly close of packing like the GRPs illustrated in FIGS. 34A and 34B, which can be observed by a comparison of FIG. 34D (which shows the top view of a substrate with an array of the tipped GRPs of FIG. 34A) with FIG. 34E, which shows the same substrate covered with the tipped GRPs shown in FIG. 34C. In embodiments, the percentage of the substrate area covered by the GRPs in FIG. 34D is greater than that of FIG. 34E, owing to a design that more efficiently fills space in tipped/tilted configurations. The dashed circles in FIG. 34F magnify the close spacing available to the GRP of FIG. 34A vs. that in FIG. 34C. Thus, in embodiments, the colors and/or effects observed from the substrate shown in FIG. 34D would exceed those available to the substrate in FIG. 34E. In embodiments, GRPs with complementary contouring and/or shaping, e.g., as illustrated in FIGS. 34A-34B, can be positioned onto a substrate or material horizontally (e.g., positioned side-by-side in an array) and/or stacked vertically.

For MRPTs, the physical force required to initiate a motion or tilt, i.e., applying force to the top of the doll to displace the doll from its equilibrium position. The tilted MRPT has stored potential energy from the work done in lifting its CoM. When the toy is released, the force of gravity acts on the CoM, eventually slowing the movement and restoring the MRPT to stationary equilibrium. The amount of work required to tilt the MRPT depends both on the mass of the object (i.e., increasing mass requiring additional work) and the amount of displacement (i.e., greater tilt angles requiring more work due to greater displacement of the CoM). For GRPs, in embodiments, the physics is identical to MRPT, with one difference. For MRPT, the frictional force between the bottom of the object and the surface upon which it sits is largely negligible: i.e., the toy can operate both on a smooth floor or on a rug. However, for GRPs of certain dimensions, in embodiments, frictional force has a larger role and cannot be ignored. For example, in embodiments, a 20-nm sized GRP on a substrate would experience some degree friction, and as a general rule, the smaller the object, the greater the impact of friction upon its movement.

In embodiments, there are a number of mechanisms used to mitigate the impact of friction on the movement of a GRP. These include but are not limited to, in embodiments, (a) adding a lubricant between the GRP and the substrate, (b) surface treatments and/or coatings (e.g., TEFLON, polytetrafluoroethylene (PTFE), hydroxylated self-assembled monolayers, vitreous enamel, etc.), (c) polishing (e.g., with ceria (cerium oxide), etc.), (d) choosing materials with lower coefficients of friction (e.g., ceramics, anodized metals, silica, etc.), and/or (e) increasing the dimensions of the GRP to minimize the impact of friction. In embodiments, the substrate/material uses a combination of factors to reduce, mitigate, or otherwise control the impacts of friction on a GRP. In embodiments, the substrate and/or or material housing one or more GRPs uses one or more friction-mitigation mechanisms described herein.

In embodiments, another difference between MRPTs and GRPs is in the application of the force to initiate movement. In embodiments, the tendency is for force to be applied to single, individual MRPTs to tilt them, while in the case of GRPs, they are found in arrays (e.g., or covering a surface area) where it is impractical to apply force to a single particle; rather, the force to initiate tilting is applied to most or all of the GRPs on a particular substrate, material, or object. For example, in embodiments, the tilting of a set of GRPs on a paper substrate could be actuated by a jerking, shaking, tilting, slanting, leaning, listing, bending, tipping, or angular motion applied to the paper in a particular orientation and/or in a particular direction. Alternatively, in embodiments, the motion can be considered a vibration, rocking, jolting, convulsing, jarring, oscillating, twisting, swinging, rattling, wobbling, trembling, quivering, rattling, bumping, quivering, agitation, waggling, or any other form of physical disturbance or disturbances that causes the GRPs to move. In embodiments, the force(s), action(s), and/or stimulus required to initiate a tilt of a GRP could be applied manually, i.e., by hand, or with the use of an instrument (e.g., a shake, actuator, motor, etc.), or by a combination of manual and machine-based actions. For example, in embodiments, a human could manipulate a substrate with a handheld device that causes the substrate to vibrate. In embodiments, GRPs can arranged/positioned such that they undergo optical property changes from force applied by the operation of a handheld device, e.g., such as a massage gun that produces vibration, e.g., as used by physical therapists. In embodiments, any handheld device can be suitable for initiating color-changing properties of GRPs, including in non-limiting examples power tools, carpentry devices, physical therapy devices, laboratory equipment, and the like. Likewise, in embodiments, the force required to initiate tilt of a GRP could be active (deliberate shaking) or passive (vibrations from walking, for example).

In embodiments, the work carried necessary to move a GRP from equilibrium to a particular position (which is then stored in the form of potential energy until the GRP is released) is proportional both to the mass of the GRP and to distance to which the center of mass has been displaced. In embodiments, the mass depends on the density and architecture of the GRP, while the distance displaced upon movement (e.g., tilting) varies inversely with the distance between the CoM and the contact or pivot point at equilibrium. In other words, in embodiments, the lower the CoM (the closer it is to the contact or pivot point), the great the displacement for tipping to a given angle. In embodiments, it requires more work to tip a GRP with a lower center of mass.

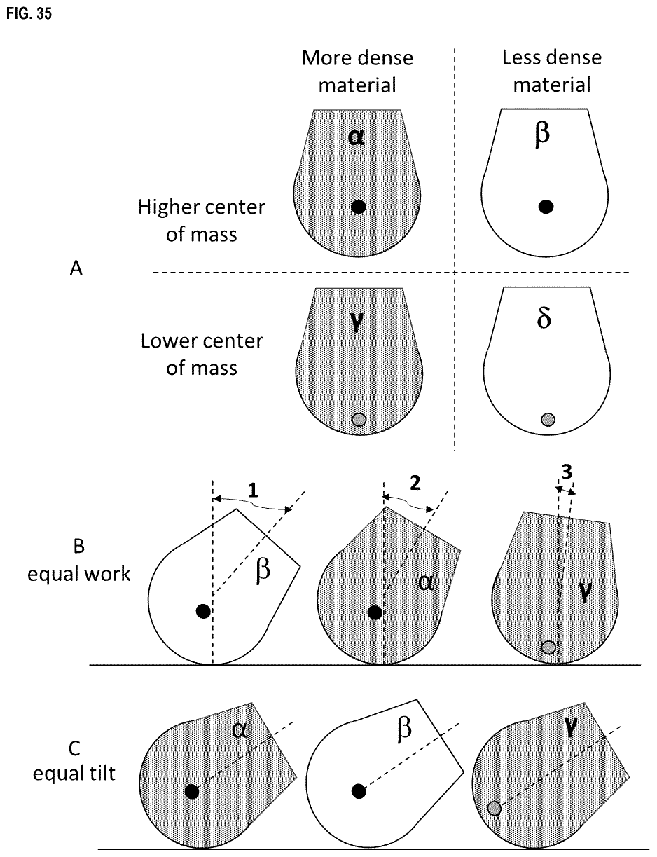

In embodiments, each of these factors have several important operational ramifications, which can dictate the form and function of the GRP, as well as its application. For example, in embodiments and in reference to FIG. 35A, four different GRPs (α, β, γ, and δ) are illustrated, each having a unique combination of compositional density (higher or lower density) and having a different center of mass position (higher or lower to the surface disposed thereon). In embodiments, and in reference to FIG. 35B, the effect of applying an equal, small force to GRP β, α, and γ is shown (where, in this case, “small force” is construed to mean not enough to tilt any of the GRPs to their maximum extent). In embodiments, GRPs with both lower density and higher CoM, for example as represented by GRP β, require the least amount of inputted energy to initiate a tilt, and thus tilts to the largest degree (angle 1). In embodiments, GRPs with lower CoM and higher density, for example as represented by GRP γ, require the most energy to tilt, where the observed tilt, angle 3, is the smallest. In embodiments, GRPs with higher CoM and greater density material, for example as represented by GRP α, would lead to an intermediate level of tilt (angle 2). Thus, in embodiments, the operational properties of GRPs can be tuned by adjusting the mass, density, selection of materials, and/or center of mass. More specifically, in embodiments, arrays of GRPs on substrates can be designed to tilt with application of greater force or by application of lesser force, as per the requirements of the application or the user.

In embodiments, and with reference to FIG. 35C, another scenario is illustrated, where a force is applied that is substantial enough to tilt each of the GRPs shown (α, β, γ) to a maximal extent, where prior to release of the GRPs (i.e., their return back toward equilibrium), they have stored potential energy, which is proportional to g (a constant at 9.8 m/s²), the mass, and the displacement of the center of mass (Δh). In embodiments, as illustrated in FIG. 35C, GRP γ has the greatest stored potential energy, GRP β has the least, and GRP α has an intermediate level between the other two. As the GRPs return to equilibrium, in embodiments, their potential energy is converted to kinetic energy. In embodiments, the kinetic energy is proportional to mass (kinetic energy=½ mv², where m=mass and v=velocity), such that the observed velocity will depend solely on Δh. Thus, in embodiments, and in reference to FIG. 35C, GRP γ will oscillate between states (e.g., colors) the fastest, while GRP α and GRP β will oscillate at a slower speed.

In embodiments, the modulation of friction on GRPs can be used to speed up or slow down the motion of the GRPs, and can provide the damping force that ultimately causes the GRPs to reattain the equilibrium configuration after a tilt is induced. In embodiments, the ability to control mass, mass distribution, shape, and/or friction between GRPs and the substrate provides numerous handles to vary optical effects beyond variations in color.

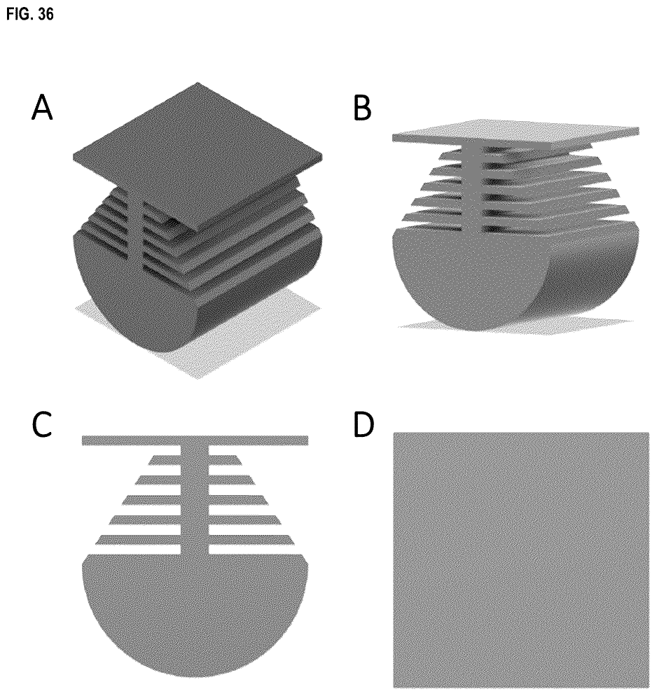

In embodiments, one or more fins, or fin-shaped protrusions can be engineered into the GRP design to modify its motion. For example, in non-limiting embodiments, fin-shaped GRPs are illustrated in FIG. 11 and FIG. 36. In contrast to the GRP of FIG. 11, in which each successive fin in the top part of the particle is smaller than one below it, the GRP of FIG. 36 has a top fin that is wider than all the others. In embodiments, the one or more fins at the top of the GRP such as that in FIG. 36 do not allow the particle to fully topple over, e.g., the GRP does not find a resting equilibrium on its side. In embodiments, a GRP with one or more fins can wobble to the sides more quickly, but wobble back to a stationary upright position more slowly due to energy transfer from the fin into the surface the GRP rests upon due to the larger diameter top portion, e.g., the top can contact the surface and slow down, for example as illustrated in the GRP in FIG. 36.

In embodiments, another attribute of the large, flat top fin of the particle in FIG. 36 is that its width exceeds the width of the bottom segment of the particle. This is clearly seen in the side view of FIG. 36C, and especially of the top view of FIG. 36D, where only the top (square) fin of the particle is seen, obstructing the view of the bottom of the particle.

In embodiments, when an array of “large top fin” GRPs as described in FIG. 36, where the large square flat top is color A, and the remainder of the particle is color B, are arrayed on a surface of color A, the GRPs are not visible at equilibrium, because color B (under the large top fin) cannot be seen, and only become visible when in wobble motion, revealing parts of the GRP of color B. Likewise, in embodiments, when an array of “large top fin” GRPs as described in FIG. 36, where the large square flat top is color A, and the remainder of the particle is color B, are arrayed on a surface of color B, the GRPs are visible at equilibrium, because color A (the large top fin) can be seen against the surface background of B. However, during the wobble motion, such GRPs become partly or fully invisible.

### Magnetic GRPs

In embodiments, and in reference to, for example, FIG. 3, FIG. 12, and FIG. 36, GRPs herein can include one or more magnetic particles and/or magnetic materials. In embodiments, a “magnetic particle” or “magnetic material” as used herein is composed of any suitable known material that responds to a magnetic field.

In embodiments, the magnetic material includes magnetic particles and/or magnetic material having a variety of magnetic qualities, including one or more of being ferromagnetic, ferrimagnetic, antiferromagnetic, diamagnetic, paramagnetic, superparamagnetic, and/or antiferromagnetic.

In embodiments, the magnetic material and/or particles are composed of magnetic material, including in non-limiting examples, iron (Fe), cobalt (Co), nickel (Ni), zinc (Zn), manganese (Mn), chromium (Cr), samarium (Sm), and the like, including chemical derivatives thereof. Typical derivatives, in embodiments, include alloys or oxides of metals, e.g., alloys, intermetallic, and/or oxides of Fe, Co, Ni, Zn, Mn, Sm, or any combination thereof. In embodiments, the oxides are of iron, e.g., Fe₂O₃, FeO, or Fe₃O₄. In embodiments, the magnetic particles are composed of ferrite material or of doped materials, including in non-limiting examples of one or more of Co, Ni, Zn, or Mn:FexOy.

In embodiments, the magnetic material and/or particles are composed of organic, carbon-based, and/or biomolecule-based magnetic material including, for instance in non-limiting examples, one or more of tetracyanoethylene (TCNE) salts, [Fe(C₅Me₅)₂]⁺[TCNE]·⁻, Li[TCNE], [Mn^{I}TPP][TCNE]· (TPP=tetraphenylporphyrin), [Fe^{I}(TCNE)(NCMe)₂][Fe^{III}Cl₄], Mn^{II}(TCNE)I(OH₂), Mn^{II} (TCNE)[C₄(CN)₈]_{1/2}, Fe(TCNE)[C₄(CN)₈]_{1/2}, Mn^{II}(TCNE)_{3/2}(I₃)_{1/2}, V^{II}[TCNE]ₓ (x≈2), C₇H₅ClN₃Se₄, magnetic biopolymers.

In embodiments, the magnetic material includes or comprises a magnetite. In embodiments, a magnetite is a biodegradable, biocompatible, non-toxic molecule that has can be used as an imaging contrast agent (e.g., an MRI contrast agent). In embodiments, other magnetic particles, such as red and/or black iron oxides (Fe₂O₃, FeO, and/or Fe₃O₄) can also be used.

In embodiments, the magnetic material acts as an optical agent.

In embodiments, the magnetic material is a transparent magnetic material. In embodiments, transparent magnetic materials are a class of materials that exhibit both transparency to visible light and magnetic properties. In embodiments, the transparent magnetic material of HYSPs can include materials used in other applications, such as optoelectronics, magneto-optical devices, and transparent electronics, for example as described in: Loste, et al., “Transparent polymer nanocomposites: An overview on their synthesis and advanced properties,” Progress in Polymer Science (2018), doi.org/10.1016/j.progpolymsci.2018.10.003; Kobayashi, et al., “Optically Transparent Ferromagnetic Nanogranular Films with Tunable Transmittance,” Sci Rep, Vol. 6, No. 34227, 2016, doi.org/10.1038/srep34227; Babu, et al., “Indium oxide: A transparent, conducting ferromagnetic semiconductor for spintronic applications,” Journal of Magnetism and Magnetic Materials (2016), doi.org/10.1016/j.jmmm.2016.05.007, Chavan, et al., “A Brief Review of Transparent Conducting Oxides (TCO): The Influence of Different Deposition Techniques on the Efficiency of Solar Cells,” Nanomaterials Vol. 13, No. 1226, 2023, doi.org/10.3390/nano13071226; Ye, et al., “Research and Progress of Transparent, Flexible Tin Oxide Ultraviolet Photodetector,” Crystals, 2021, Vol. 11, No. 1479. doi.org/10.3390/cryst11121479; Gul S, et al., “A Comprehensive Review of Magnetic Nanomaterials Modern Day Theranostics,” Front. Mater. Vol. 6, No, 179, 2019, doi: 10.3389/fmats.2019.00179; Rita Polícia, et al., “Transparent Magnetoelectric Materials for Advanced Invisible Electronic Applications,” Adv. Electron. Mater. 2019, 1900280, doi.org/10.1002/aelm.201900280, each of which is hereby incorporated by reference in their entirety.

In embodiments, transparent magnetic materials include the family of diluted magnetic semiconductors (DMS) or oxide-based transparent magnetic materials. In embodiments, DMS are formed by introducing a small concentration of magnetic ions, such as transition metal ions, into a semiconductor matrix, where the magnetic properties arise from the interaction between the magnetic ions and the host lattice. In embodiments, oxide-based transparent magnetic materials are typically composed of a transparent oxide matrix (e.g., indium tin oxide) doped with magnetic ions.

In embodiments, other types of transparent magnetic particles and materials include those based on iron oxide nanoparticles, such as magnetite (Fe₃O₄) and maghemite (γ-Fe₂O₃), which can be engineered to have a transparent nature while retaining their magnetic properties. In embodiments, magnetic stimuli-responsive elements include ferrite nanoparticles, like cobalt ferrite (CoFe₂O₄) or nickel ferrite (NiFe₂O₄), which can be synthesized in a way to achieve transparency. In embodiments, magnetic stimuli-responsive elements include rare earth iron garnets, such as yttrium iron garnet (Y₃Fe₅O₁₂), which can exhibit a strong magneto-optical effect while maintaining a degree of transparency. In embodiment, additional examples of transparent magnetic particles and materials include Sn-doped In₂O₃, FeSiB (Fe_{72.5}Si_{12.5}B₁₅), and Fe₉Co₅Al₁₉F₆₇. In embodiments, transparent magnetic particles and materials can be incorporated into polymers to form particles or beads that are suitable for the structures described herein.

In embodiments, the magnetic material includes magnetite (e.g., Fe₃O₄) alongside or in place of a number of components, e.g., including metals (e.g., magnetic elements, such as iron, nickel, cobalt, chromium, and/or manganese) and/or magnetic organic polymers (see, e.g., Rajca et al., “Magnetic Ordering in an Organic Polymer,” Science, 294, 2001: pp. 1503-1505, the entirety of which is hereby incorporated by reference). In embodiments, the particles can be composed of 100% metal oxide (e.g., magnetite), or can be composites including other components, e.g., including polymers, polymer-bonded magnets, and/or polymers comprising chromophores.

In embodiments, the magnetic material includes a magnetic bead. In embodiments, the GPR includes multiple magnetic particles contained within a polymer bead, e.g., polystyrene. In embodiments, the magnetic material is a spherical magnetic bead, or a spherical polymer-based bead with one or more magnetic particles contained therein.

In embodiments, magnetic material (e.g., particles) are magnetized, e.g., capable of being attached to iron (e.g., can project their own magnetic field), and are capable of producing a magnetic field outside themselves, either naturally or by induction. In embodiments, a magnetic field can be induced in the particles, e.g., during manufacture and/or after use, such as by exposing the particles to a strong magnetic field, e.g., an electromagnet.

In embodiments, the magnetic field (e.g., magnetic flux density) created is from about or at least about 200 gauss to about or at least about 25,000 gauss (10,000 gauss=1 Tesla). In embodiments, the magnetic field is about or at least about 200 gauss, about or at least about 500 gauss, about or at least about 800 gauss, about or at least about 1,000 gauss, about or at least about 2,500 gauss, about or at least about 12,500 gauss, about or at least about 15,000 gauss, about or at least about 20,000 gauss, or about or at least about 25,000 gauss. In embodiments, the magnetic particles retain the ability to project a magnetic field, i.e., they can become permanent magnets. In embodiments, the particles can lose the ability to produce a magnetic field over time, and a field can be re-induced by re-application of a strong magnetic field.

Magnetic particles can be prepared using any method known to those of skill in the art. For example, in embodiments, magnetic particles are formed by precipitation methods, high temperature methods, or other methods known to those skilled in the art. In embodiments, the magnetic particles can be fabricated by mechanical milling, supercritical CO₂-based precipitation of magnetite/polymer microparticles, or micelle synthesis. After fabrication, in embodiments, the particles can be sorted for size and quality, e.g., by centrifugation or filtration. A number of magnetic particles are commercially available, for example in embodiment, from Ademtech, 33600 Pessac, France; Bangs Laboratories, Inc., Fishers, IN, U.S.A.; Pea Ridge Iron Ore Co., Sullivan, MO, U.S.A.; Quantum Magnetics, Division of Clemente Associates, Inc., Madison, CT, U.S.A.; among others. In embodiments, magnetic particles can be sterilized using methods known in the cart, e.g., heat, chemical, or radiation sterilization.

In embodiments, the GRP has at least a portion of the surface coated with a magnetic material, such as on at least a portion of the top part or bottom part of the GRP as depicted in FIG. 3 or the top fin of the GRP of FIG. 36. In embodiments, the GRP magnetic materials are incorporated into at least a portion of the volume of the particle, such as the shaded portions of the GRPs depicted in FIGS. 12A, 12B, and 12C. In embodiments, a GRP incorporating a magnetic material on its interior or exterior responds to a magnetic field. In embodiments, the magnetic field is used to move or tilt the GRPs away from equilibrium, reset the GRPs to equilibrium, or otherwise alter the center of mass relative to the radius of curvature.

In embodiments, the GRP responds to a magnetic stimulus (e.g., application of a magnetic field). In embodiments, the mechanical force as used herein is a magnetic field. For example, in embodiments, GRPs move, tilt, wobble, etc., in response to a magnetic field applied using a magnet, electromagnet, or other means of applying a magnet. In embodiments, the application of a magnetic stimulus or magnetic field is used to reset the GRPs to a resting equilibrium state. In embodiments, the application of a magnetic stimulus or magnetic field is used to move or otherwise manipulate the movement of the GRPs (e.g., tilt to a particular angle, hold at a particular position, etc.).

### Hollow GRPs

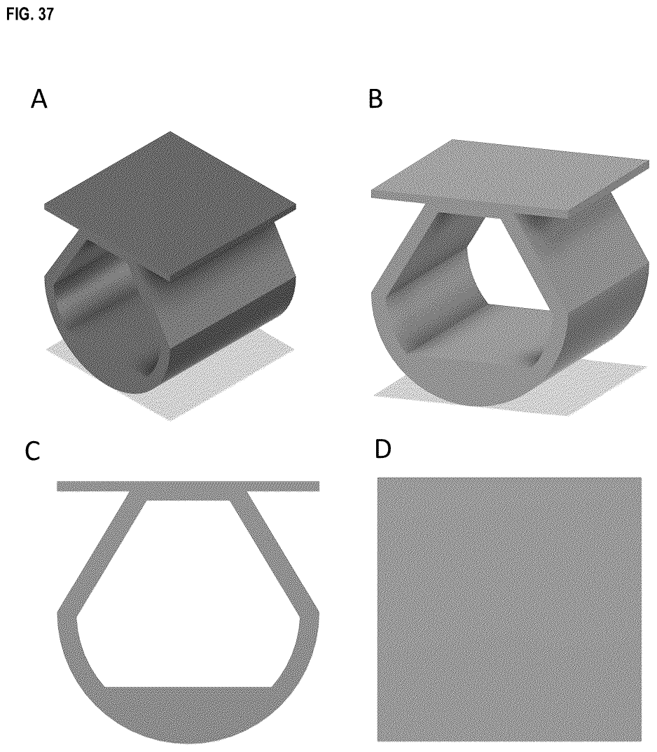

In embodiments, an approach to adjust the center of mass of GRPs is to render certain sections heavy (by addition of mass) or lighter (by removal of mass). In embodiments, one approach to the latter is to maintain the general cross-sectional shape of GRPs in the absence of interior mass, e.g., to have one or more hollow regions. In embodiments, and in reference to FIGS. 37A-37D, a hollow GRP with a flat top. In embodiment, the GRP has one or more hollow regions spanning the bottom and/or top sections. In embodiments, the addition of flat top (e.g., similar to the GRP of FIG. 36) adds mass above the radius of curvature, raising the center of mass, but this is more than offset by the loss in mass from the hollow section, such that the resulting GRP has a stable wobble characteristic.

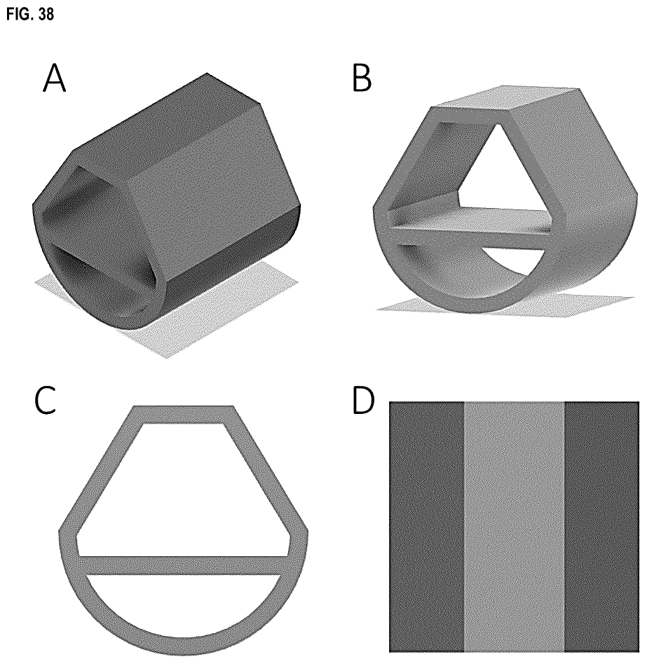

In embodiments, GRPs have two or more hollow regions. For example, in embodiments and in reference to FIGS. 38A-38D, a hollow GRP is pictured with two distinct hollow regions. In embodiments, the GRP, e.g., of FIG. 38, has a solid “bar” of mass at or near the radius of curvature, with hollow sections above and below it. In embodiments, the bar adds structural integrity to the GRP. In embodiments, the two hollow regions are sufficient to render the center of mass below the radius of curvature, making the GRP have a stable wobble characteristic.

### Sawtooth GRPs

In aspects, described herein are subsets of gravity responsive particles (GRPs) referred to herein as “sawtooth gravity responsive particle(s)” or “sGRP(s).” The sGRP, in embodiments, is about 20 nm to 10 mm in size and exhibits optical properties that change in response to mechanical or other forces (e.g., dynamic motion such as vibration, shaking, tilting, inversion, gravity, etc.), where the particles “wobble,” revealing different optical states, relaxing back to a stationary state via gravitational force through particle wobble angles. In embodiments, sGRPs find use in the same compositions and methods as GRPs, such as being dispersible in a fluid and/or applied to a surface.

In embodiments, sGRPs include “sawtooth elements,” or side and/or surface features, e.g., such as one or more sawtooth, detent, fin, or fin-shaped protrusion to provide sawtooth motion. In embodiments, one or more fins, detents, or fin-shaped protrusions are engineered into the sGRP design to modify its motion. In embodiments, the one or more fins, detents, or fin-shaped protrusions are placed above, below, or alongside the center of mass relative to the curvature of radius. In embodiments, the one or more the one or more fins, detents, or fin-shaped protrusions are added along the bottom of the sGRP, such as along a curved portion of the sGRP useful for tilting, wobbling, or oscillating motion.

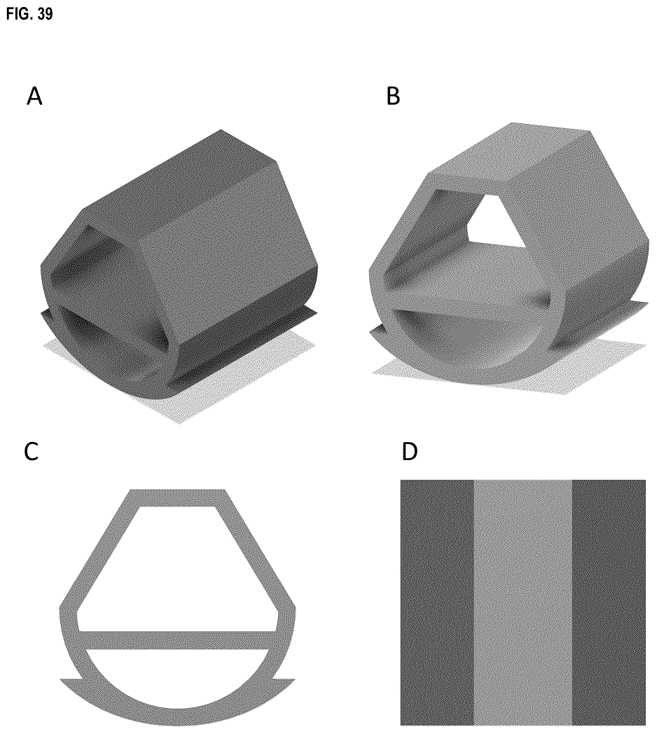

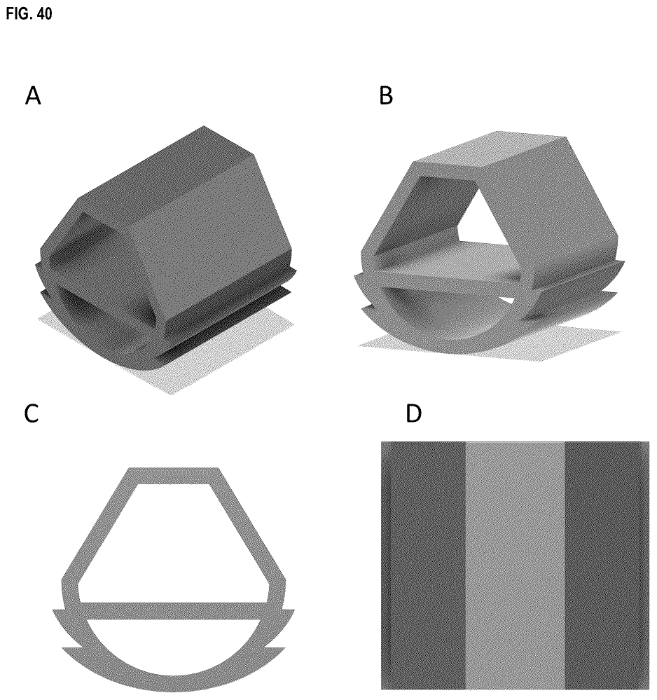

In embodiments and in reference to FIGS. 39A-39D and FIGS. 40A-40D, illustrative sawtooth GRPs (sGRPs) are shown. In embodiments, sGRPs, e.g., both of the sGPRs of FIG. 39 and FIG. 40, have the same interior “two-hollow” structure of the GRP of FIG. 39; however, there is one sawtooth element added to each side of the sGRP of FIG. 39, and two sawtooth elements added to each side of the sGRP of FIG. 40.

In embodiments, the number of sawtooth elements in a sGRP is an even number, such as 2, or 4, or 6, or 8, or 10, or 12, or 14, or 16, or 18, or 20, or 24, or 28, or 32, or 36, or 40, or 50, or 60, or 70, or 80, or 90, or 100, or and even number more than 100. In embodiments, the number of sawtooth elements in an sGRP is an odd number, such as 1, or 3, or 5, or 7, or 9, or 11, or 13, or 15, or 17, or 21, or 25, or 31, or 37, or 41, or 51, or 61, or 71, or 81, or 91, or 101, or an odd number larger than 101. In embodiments, an odd number of sawtooth elements on a sGRP enables uneven tilt motion behavior, where a sGRP rests on the side with the sawtooth element if tilted past the critical angle, whereas free wobble motion is enabled through the other degrees of motion.

In embodiments, the detent or sawtooth present on one or more sides acts as a physical catch to prevent motion once the sGRP tilts far enough to the side and prevent oscillating motion. In embodiments, the sGRP has one detent on each side, e.g., as shown in FIG. 39, or two or more detents on each side, e.g., as shown in FIG. 40.

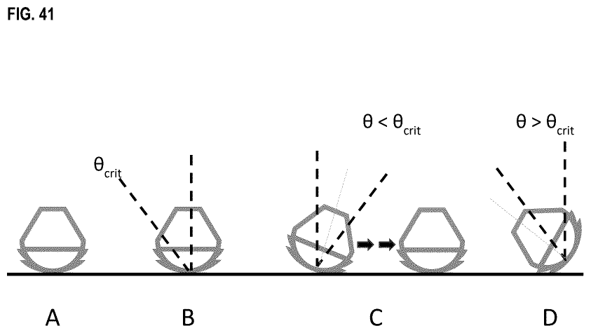

In embodiments, an sGRP includes a shape and a center of mass (CoM) that resides below a radius of curvature that, when a force is applied to tilt the sGRP between a tilt angle of 0° to θ_{crit}, the shape enables motion between a plurality of positions of 0° to θ_{crit}, where θ_{crit} is a critical angle, tilting past which results in movement of the sGRP to an equilibrium position on a side surface that is distinct from an upright equilibrium position. In embodiments and in reference to FIGS. 41A-41D, the illustrative motion of sawtooth GRPs (sGRPs) with respect to θ_{crit} is illustrated. In embodiments and in reference to FIG. 41A, a sGRP (with four detents or sawtooth elements, two on each side) is shown in an equilibrium position on a planar surface. In embodiments, FIG. 41B illustrates the θ_{crit} of the sGRP of FIG. 41A, measured relative to the vertical (i.e. a tilt of 0°, corresponding to the sGRP at equilibrium). For purposes of clarity, in embodiments, the θ_{crit} is drawn only to the left side of the sGRP, but because there are sawtooth elements on both sides of the sGRP, there is another critical angle on the right side at −θ_{crit}. In embodiments, FIG. 41C depicts a situation where an sGRP is tilted to an angle, the absolute value of which is <θ_{crit}; in this case, the gravity-induced wobble occurs as if there were no sawtooth elements or detents, and the sGRP comes to rest at the upright equilibrium. In embodiments, FIG. 41D illustrates a situation where a sGRP is tilted to an angle, the absolute value of which is >θ_{crit}, where the sGRP is at a second equilibrium position distinct from the upright equilibrium position because, in contrast to the sGRPs depicted in FIGS. 41A-41C and the stable GRPs of FIGS. 3, 14, etc. in which there is only one point of contact between the particle and the surface, the sGRP of FIG. 41D has two points of contact to the surface (in this case, each of the sawtooth elements).

In embodiments, sGRPs have at least one upright equilibrium (e.g., rest standing up), where the sGRP adopts wobble motion when tilted between 0° and θ_{crit}. In embodiments, sGRPs have a first equilibrium and at least a second equilibrium position different from the first equilibrium.

In embodiments, the motion resembles an oscillating motion or a tilt displacement. In embodiments, the oscillating motion comprises a pendulum motion oscillating between the plurality of positions. The oscillating motion, in embodiments, includes a wobble motion comprising oscillations around a pitch axis and a yaw axis. In embodiments, the wobble motion includes a movement through a plurality of orientations relative to a direction of the force. In embodiments, the motion occurs along a plane in two dimensions and/or in three dimensions.

In embodiments, the critical angle (θ_{crit})—or the angle past which tilting results in the sGRP falling to rest on its side—is between about 5° to about 75° relative to the plane passing through the center of mass (CoM) and perpendicular to a surface the sGRP is resting upon. In embodiments, the critical angle (θ_{crit}) is about or less than about 5°, about or less than about 10°, about or less than about 15°, about or less than about 20°, about or less than about 25°, about or less than about 30°, about or less than about 35°, about or less than about 40°, about or less than about 45°, about or less than about 50°, about or less than about 55°, about or less than about 60°, about or less than about 65°, about or less than about 70°, about or less than about 75°, including any angles therebetween.

In embodiments, the sGRP has a ratio of distance between the center of curvature and the location of vertices (μ) of about or at least about 1/8, about or at least about 1/7, about or at least about 1/6, about or at least about 1/5, about or at least about 1/4, about or at least about 2/7, about or at least about 1/3, about or at least about 3/8, about or at least about 2/5, about or at least about 3/7, about or at least about 1/2, about or at least about 4/7, about or at least about 3/5, about or at least about 5/8, about or at least about 2/3, about or at least about 5/7, about or at least about 3/4, about or at least about 4/5, about or at least about 5/6, or about or at least about 6/7.

In embodiments, the sGRP is configured for motion that resembles an oscillating motion or a tilt displacement, as described for GRPs herein. In embodiments, the oscillating motion comprises a pendulum motion oscillating between the plurality of positions. In embodiments, the oscillating motion comprises a wobble motion comprising oscillations around a pitch axis and a yaw axis. In embodiments, the wobble motion comprises movement through a plurality of orientations relative to a direction of the force. In embodiments, the motion occurs along a plane in two dimensions and/or in three dimensions.

In embodiments, the side protrusion of a sGRP is useful to transfer the tilting kinetic energy into the surface upon which the sGRP sits to slow down the motion of the sGRPs, e.g., to act as a damping force.

In embodiments, the sGRP has a top portion that extends outward from the 0° plane that extends perpendicularly through the CoM into the resting surface. In embodiments, the sGRP is used as a catch to enable the particle to fully topple over, finding a resting equilibrium on its side. In embodiments, a sGRP with one or more fins can wobble to the sides more quickly, transfer energy from the fin into the surface the sGRP rests upon due to the larger diameter top portion contacting the surface, stopping the sGRP on its side.

In reference to FIG. 13, in embodiments, an array of sGRPs are positioned such that they exhibit a variety of optical properties, such as changing colors, as they move through a plurality of positions. For example, in embodiments, sGRPs at equilibrium (FIG. 13, top panel) are all aligned so that the dark crosshatched surfaces are facing a first direction, and the light grey surfaces are facing the opposite direction. In embodiments, when a force is applied to the sGRPs, the sGRP is free to tilt to the right and left to a degree between 0° and θ_{crit} (e.g., as shown in FIG. 13, second panel, as an 82° tilt to the right). Once the force is removed or ceases, in embodiments, the force of gravity moves the particle, first past the equilibrium position, wobbling back to the opposite direction between 0° and θ_{crit} (e.g., as shown in FIG. 13, third panel, as a 65° tilt to the left), and then again to the right between 0° and θ_{crit} (e.g., as shown in FIG. 13, fourth panel, as a 50° tilt to the right), and then back to the left between 0° and θ_{crit} (e.g., as shown in FIG. 13, third panel, as a 25° tilt to the left), with a decay in tilt angle due to friction. These transitions in movement, in embodiments, occur on the order of seconds, where sGRPs have sizes such that the transition between, for example color states, occurs in with 10 seconds, 1 second, 10⁻¹ seconds (tenths of a second), or even 10⁻² seconds (hundreds of a second). In embodiments, a complete plurality of movements (i.e., from an initial force/stimulus until the return to a stationary equilibrium) occur within 100 seconds, 10 seconds, 1 second, 10⁻¹ seconds (tenths of a second), or even 10⁻² seconds (hundreds of a second).

Generally, in embodiments, the motion of the sGRP within the range of tilt displacement of 0° and θ_{crit} mimics that of a pendulum, oscillating past the upright equilibrium position in increasingly smaller increments, until the upright equilibrium position is re-instated, potentially exhibiting different optical states with each movement until rest. In embodiments, the motion of the sGRP is a pendulum motion oscillating between the plurality of positions and the stationary position. In embodiments, the motion is a tilt displacement motion between the plurality of positions and the stationary position. In embodiments, the motion is an angular displacement motion between the plurality of positions and the stationary position. In embodiments, the motion occurs along a plane in two dimensions and/or in three dimensions. In embodiments, the center of mass (CoM) resides at or above a radius of curvature during movement. In embodiments, the oscillating motion comprises a wobble motion, where the wobble motion comprises oscillations around a pitch axis and a yaw axis. In embodiments, the wobble motion comprises movement through the plurality of orientations relative to a direction of a force gravity.

In embodiments, forces great enough to tilt sGRPs past the critical angle (θ_{crit}) result in the sGRP tipping onto its side, revealing the optical property imbued on that side. In such embodiments, tipping past the critical angle (θ_{crit}) moves the center of mass above the radius of curvature, tipping the sGRP onto its side, and establishing a resting equilibrium on that side.

In embodiments, sGRPs discussed herein have at least two stable positions (e.g., stationary configurations)—e.g., an upright stationary equilibrium and at least one stable side equilibrium. For example, each of the faces of a cube are stable, and if a cube on a plane is stood on a point or an edge on a plane and then released, it will reorient (e.g., fall) such that one face is in contact with the plane. Once the face of the cube is touching the plane, there is no accessible “pendulum action.” In embodiments, sGRPs have shapes/geometries of such objects, i.e., containing multiple stable and unstable configurations.

In embodiments, the sGRP has a shape that allows tipping onto a first side, but does not allow tipping onto a second side, where the optical property change (e.g., a color change) only occurs when the sGRP experiences a tilt displacement past the critical angle in a singular direction.

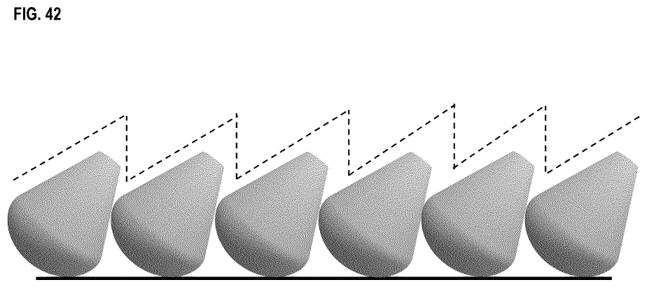

In embodiments, gravity-responsive particles (GRP) or sawtooth gravity responsive particles (sGRP) are organized such that in a tilted state, a sawtooth pattern emerges among the particles. In embodiments, the side surface of a GRP is configured to rest on a side surface of a second GRP comprising a congruent shape and/or a different shape. In embodiments, each GRP rests on its side on top of a surface of the next GRP, for example as illustrated in FIG. 42, which depicts a diagrammatical representation of the side view of an array of GRPs placed atop a planar surface, where the GRPs are tilted to one side, and where the tilt of the GRP is constrained by contact to the adjacent GRP in the direction of the tilt, generating a sawtooth pattern of the tops of the tilted particles (as depicted by the dashed line).

### Methods of Manufacturing Gravity Responsive Particles (GRPs) and Sawtooth GRPs

The present disclosure provides, in embodiments, methods of manufacturing GRPs. In embodiments, the GRPs satisfy at least two criteria: 1) it includes physical properties (e.g., a shape, center of mass (CoM), etc.) that enables “wobble” behavior/movement, and 2) one or more optical properties where the optical properties change as a function of movement/viewing angle by an observer after stimulation (e.g., mechanical perturbation). In embodiments, all methods relating to the manufacture of GRPs relate to sGRPs.

In embodiments, methods of manufacture of sGRPs include generating subsets of particles that satisfies at least two criteria: 1) it includes physical properties (e.g., a shape, center of mass (CoM) that resides at or above a radius of curvature, etc.) that enables “wobble” behavior/movement between a tilt angle of 0° to θ_{crit}, and 2) one or more optical properties where the optical properties change as a function of movement/viewing angle by an observer after stimulation (e.g., mechanical perturbation).

In embodiments, methods of manufacture herein include steps to generate a particle that satisfies the fundamental physical properties of a MRPT, on a scale of size in the range of approximately 20 nm to about 10 mm. In embodiments, the CoM resides below the radius of curvature when the particle is at rest on a surface (e.g., at stationary equilibrium on a horizontal surface). In embodiments, the shape of the generated particle has curvature (e.g., a GRP with a very flat/wide bottom will not appreciably wobble, independent of the location of the center of mass). In embodiments, exemplary shapes of particles for GRPs are shown in FIGS. 7F, 12A, 14, 18A, 34, and 36.

In embodiments, methods herein include generating a particle that has a center of mass that resides below the radius of curvature. In embodiments, GRPs that do not meet these physical constraints, when tipped, will settle onto its side (i.e., will not “wobble,” but will “irreversibly” adopt a stationary equilibrium). There are a number of ways to satisfy this criterion involving shape, CoM, and density. For example, in embodiments, a GRP can include a single material (e.g., plastic and/or metal) that has a single density, and the location of the CoM below the radius of curvature, which can be accomplished solely through shape. In embodiments, MRPTs fit into this category, for example as depicted in FIGS. 1D-1H, and likewise, GRPs depicted here in also meet this criterion, e.g., FIGS. 3, 29A, 34A. Alternatively, in embodiments, a GRP can comprise a single material, but exhibit non-uniform density through the inclusion of a void space, e.g., as shown in FIG. 37B. Thus, in embodiments, a GRP with a partially or fully hollowed-out top portion will lower the CoM. In embodiments, this method has the effect of “subtracting” mass from the top portion of the GRP.

Another approach, in embodiments, includes the inverse strategy, namely adding mass to the bottom portion of the GRP. In embodiments, this adds a bona fide second material to the GRP composition (in contrast with the subtraction approach, where the “second material” is air trapped inside the hollowed space). In embodiments, there are two approaches to increasing the mass of the bottom portion of a GRP: 1) doping of one material, and/or 2) using two or more different materials. For example, in embodiments, one could incorporate impurities, particles, flakes, spheroids, etc., of a denser material (e.g., lead oxide, tungsten carbide, barium sulfate, tantalum, iron oxide, gold, gold nanoparticles, among other dense materials) as a dispersion (e.g., into the bottom portion) of a GRP made of a single material.

For example, in embodiments, such a composition could be acrylonitrile butadiene styrene (ABS) on the top portion of a GRP, and 5% by volume iron oxide incorporated into ABS in the bottom portion. Another approach, in embodiments, is to use different materials for a top portion and a bottom portion, with the denser material to be in the bottom portion. For example, in embodiments, the top portion is made using a polymer, like polypropylene (density=0.86 g/cc), and the bottom portion is made with a polymer, like phenolic resins (density=2.0 g/cc), such that the bottom portion is approximately 2 times denser.

In embodiments, the one or more substrate materials used for generating the GRP is porous. In embodiments, a combination of a less dense top portion and a denser bottom portion can be combined with the introduction of porosity in the top portion to further move the CoM to below the radius of curvature.

In embodiments, GRPs comprise non-continuous solid materials, e.g., such as solid materials having pores, crevasses, cracks, and other gaps in material, for example as illustrated in FIG. 10. In embodiments, the pores are useful for conferring optical properties, e.g., such as blending or mixing in one or more colorants into the pores. In embodiments, the pores are useful for adding or removing materials from the inside of a GRP. In embodiments, the pores are beneficial to adjust specific gravity or density in the top portion, bottom portion, and/or both portion, which can be used adjust the position of the CoM. This, in embodiments, can ensure that the fundamental physics of MRPT objects is satisfied, as described herein, and additionally, can be used to adjust the speed at which the GRP moves or wobbles, as shown in FIG. 4.

In reference to FIG. 10A, in embodiments, four different non-limiting two-dimension cross-sectional patterns of porosity for a solid substrate material are shown. In embodiments, the pattern of porosity can be in the form of any specific or random pattern (e.g., can have symmetry, uniformity of size, etc.). For example, in embodiments, a semi-regular pattern of porosity is shown in FIG. 10B, where the directions of the pores are parallel to the cylinder axis. Alternatively, in embodiments and as shown in FIG. 10C, the porosity can be random in three dimensions. In embodiments, the porosity is confined to a single part of the GRP, for example as shown for a hemispherical bottom portion in FIG. 10D, or as shown in FIG. 10E for a GRP comprising an egg-shaped bottom portion and a cone-shaped top portion. In embodiments, the top portion and/or the bottom portion can exhibit varying degrees of porosity. In embodiments, the porosity introduced into a substrate material can be used to dispose one or more optically active agents thereon and/or therein.

In embodiments, generating the particle of the GRP includes a shape that allows motion associated with stimulating a GRP to induce tilting is that some or all of the induced motion must lead to a change in optical state, e.g., such as a change in the color seen by an observer. In non-limiting embodiments, FIGS. 4, 12, 14, 21C-21G, 22A-22B, 23A-23B, 24A-24D, 29A-29F, and 33A-33F depict examples of suitable shapes for designs for GRPs. In embodiments, the wobbling motion and color-changing are orthogonal to one another, where the substrate material(s) used to generate a shape conducive to the motion can also have intrinsic optical properties (e.g., colors). For example, in embodiments and in reference to FIG. 3, the top portion can be composed of a material with “Color A,” and the bottom portion can be composed of a material having “Color B.” In embodiments, the lower density material does not have to correspond to the top portion/“Color A.”

In non-limiting embodiments, FIGS. 5A-5I, 7A-7I, 12A-12C, 14A, 17A-17C, 18A-18E, 21C-21E, 22A-22B, 23A-23B, 24A-24D, 34A-34C, 36A-36D, 37A-37D, 38A-38D, 39A-39D, and 40A-40D depict examples of suitable shapes for designs for GRPs or sGRPs.

In embodiments, methods of manufacturing GRPs includes a number of fabrication techniques used to generate particles on size scales from millimeters through microns down to nanometer dimensions. In embodiments, these methods include in non-limiting examples: (i) assembly of two or components (e.g., gluing, screwing, affixing a top portion and a bottom portion; or a left portion and a right portion), (ii) injection molding, micro-injection molding, or similar techniques which involve a mold or cast; (iii) by chemical or physical methods including but not limited to self-assembly, adsorption, coacervation, and/or mixing; (iv) polymerization, extrusion, and/or manipulation of polymers; (v) additive manufacturing, also known as 3D printing, (vi) microfluidic and other flow-related methods; (vii) photolithographic techniques; (viii) microcontact printing, (ix) other lithographic techniques such as beam pen lithography; among other (x) miscellaneous methods.

In embodiments, the one or more substrate materials used for generating GRPs includes one or more thermally responsive polymers and/or resins. In embodiments, the one or more thermally responsive polymers and/or resins comprise one or more of poloxamers, polycarbonate and/or polycarbonate-like polymers (e.g., polycarbonate-like translucent/clear (ACCURE 60), FormLabs Grey resin, etc.), polyamide (polyamide 12 (PA12), Nylon 12, glass-filed polyamide such as PA12 40% glass-filled back), photoresins (e.g., UPNANO UpPhoto 2-photon resin), styrene-butadiene block copolymers, polymethylmethacrylate, polybutylmethacrylate, plasticized polyvinyl chloride, plasticized nylon, plasticized polyethylene terephthalate, polyethylene, polyacrylonitrile, polychlorotrifluoroethylene, poly-4,4′-isopropylidenediphenylene carbonate, polyethylene vinyl ester, polyvinyl chloride-diethyl fumarate, and combinations thereof.

In embodiments, generating the GRPs includes micro-injection molding, which is a manufacturing process used to create small, high-precision plastic parts. In embodiments, the process involves injecting molten plastic, metal, and/or polymer-based material into a mold cavity, which can be designed to the exact specifications of the desired part, or portions thereof. In embodiments, the mold is then cooled, and the part is removed from the mold. In embodiments, the technique typically produces parts that are on the scale of micrometers to a few millimeters in size. In embodiments, micro-injection molding is used for its high accuracy, repeatability, and efficiency, making it a suitable choice for mass production of small parts. Injection molding processes are used in a variety of industries, including in medical, electronics, and automotive industries, where small, complex parts are needed. Non-limiting examples of parts made by micro-injection molding include micro gears and other small mechanical parts for use in watches, cameras, and other precision devices or instruments, microfluidic devices for use in medical and laboratory applications, small components for electronic devices, such as micro connectors, micro switches, and micro lenses for cameras, small medical implants such as hearing aid components, and miniature automotive components, such as gears, valves, and connectors, used in engines and other mechanical systems. Thus, in embodiments, methods of manufacturing GRPs and substrates, surfaces, and/or materials for GRPs can use techniques for making any of the above objects.

Alternatively, in embodiments, chemical techniques such as coacervation can be used to generate the particles. Coacervation, in embodiments, is a process in which two or more polymers are mixed together in a solution and undergo phase separation to form two distinct phases. In embodiments, one phase is rich in polymer, while the other phase is depleted in polymer and mostly contains solvent. Coacervation, in embodiments, is used to produce microspheres or microcapsules, which are small, spherical particles that can be used for drug delivery, encapsulation, and other applications. During coacervation, in embodiments, the polymers undergo a process of self-assembly, where they form complex structures through non-covalent interactions such as electrostatic forces, hydrogen bonding, and van der Waals forces. The resulting microspheres or microcapsules can be tailored to have specific properties such as size, shape, and composition, making them useful in a variety of fields. In embodiments, generating the particles can include a combination of coacervation and molding parts for GRPs.

In embodiments, generating particles for GRPs includes the chemical method of click chemistry, a class of simple, atom-economy reactions commonly used for joining two molecular entities of choice. Click reactions, in embodiments, occur in a single vessel, are not sensitive to water, generate minimal byproducts, and are “spring-loaded”—characterized by a high thermodynamic driving force that quickly and irreversibly drives the reaction to high yield of a single reaction product, with high reaction specificity (in some cases, with both regio- and stereo-specificity). In embodiments, generating particles for GRPs includes other chemical methods well-known (especially in life sciences) for joining two entities together including in non-limiting examples, streptavidin-biotin coupling, maleimide-based reactions, and carbodiimide-based reactions.

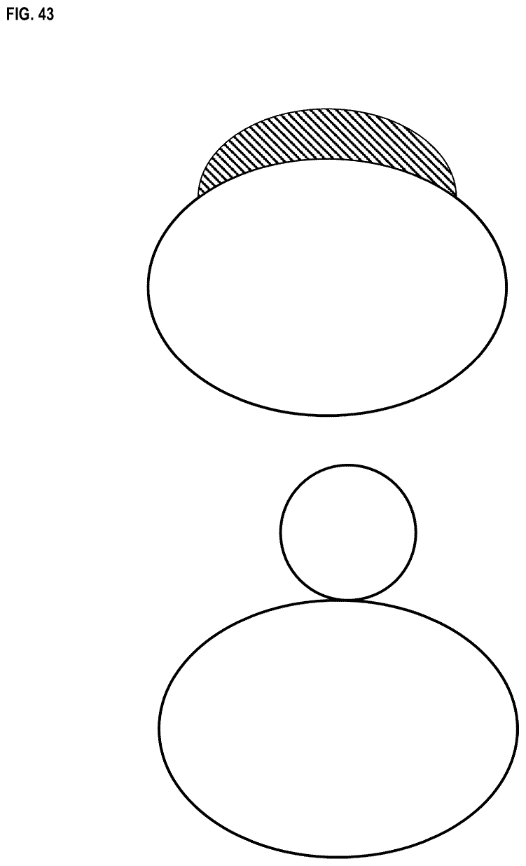

In embodiments, a variety of techniques focused on using polymers to generate 3D materials can be used to synthesize GRPs. For example, in embodiments, snowmen-shaped anisotropic Janus particles are described in KANG and HONCIUC, “Influence of Geometries on the Assembly of Snowman-Shaped Janus Nanoparticles”, ACS Nano, Vol. 12, No. 4:2018: pp. 3741-3750, which is hereby incorporated by reference in its entirety. For example, in embodiments and in reference to FIGS. 43A-43B, a prototypical “snowman particle” is illustrated, i.e., with two parts, shown as spheres or hemispheres or portions of hemispheres, with the bottom portion larger than the top portion, although the dimensions can be altered. In embodiments, such particles can be manufactured from poly(tert-butyl acrylate)-poly(3-(triethoxysilyl)propyl methacrylate) (PtBA-PTPM).

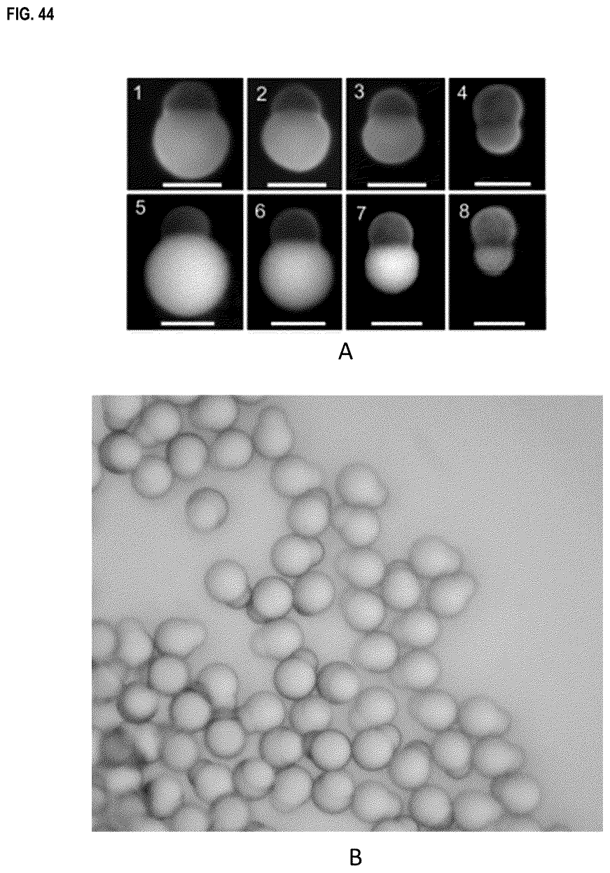

In embodiments, the synthesis of snowmen-shaped GRPs is via the formation of Janus particles. In embodiments, Janus particles are a type of particle characterized by having two distinct regions or “faces” with different physical and/or chemical properties. In embodiments, the two faces of Janus particles can have different surface chemistry, size, shape, or polarity, which makes them useful in a variety of applications, including drug delivery, catalysis, and self-assembly. In embodiments, snowmen-shaped Janus particles (JPs) are attractive, because they are a unique class of anisotropic materials that are simple, but for which all the structural parameters can be completely controlled. In embodiments, referring to FIG. 44A, each lobe in these anisotropic particles can be independently tuned in their dimensions and chemical compositions. In embodiments, Janus particle-based GRPs can be synthesized at large scale, and under surfactant-free conditions. In embodiments, snowman-type Janus particles can be manufactured according to the methods of WALTHER and MÜLLER, “Janus Particles: Synthesis, Self-Assembly, Physical Properties, and Applications,” Chem. Rev., Vol. 113, 2013: pp. 5194-5261; VOGEL et al. “Advances in Colloidal Assembly: The Design of Structure and Hierarchy in Two and Three Dimensions,” Chem. Rev., Vol. 115, 2015: pp. 6265-6311; TANG et al., “Large Scale Synthesis of Janus Submicrometer Sized Colloids by Seeded Emulsion Polymerization,” Macromolecules, Vol. 43, 2010: pp. 5114-5120; and PHAM et al., “Synthesis of Polymeric Janus Nanoparticles and Their Application in Surfactant-Free Emulsion Polymerizations,” Polym. Chem. Vol. 6, 2015: pp. 426-435, each of which is hereby incorporated by reference in their entirety.

In embodiments, GRPs are comprised of a Janus particle with three or more distinct “faces,” or surfaces with three or more optical properties, sometimes referred to as “Ashura particles.” In embodiments, such particles are manufactured, for example as described in Hirai, et al., “Ashura Particles: Experimental and Theoretical Approaches for Creating Phase-Separated Structures of Ternary Blended Polymers in Three-Dimensionally Confined Spaces,” ACS Omega, Vol. 4, 2019: pp. 13106-13, the entirety of which is hereby incorporated by reference in its entirety. In embodiments, GRPs with three or more optical properties (Ashura particles) are produced using one or more materials comprising poly(1,4-isoprene) (PI), polystyrene (PS), poly(tert-butyl methacrylate) (PtBA), amino-terminated poly(butadinene) (PBNH2-37k), poly(ferrocenyl dimethylsilane) (PFeS), amino-terminated poly(butadinene) (PBNH₂-14k), poly(methyl methacrylate) (PMMA), or amino-terminated polystyrene (PSNH₂), among other materials described herein.

In embodiments, GRPs are manufactured from latex polymer snowmen-shaped particles, for example, using MAGSPHERE (micron-sized latex polymer particle), 15 μm diameter particle size, as shown in FIG. 44B. In embodiments, GRPs can be manufactured from, in non-limiting examples, polystyrene latex polymer, carboxylated latex polymer, aminated latex polymer, colored polystyrene polymer (dye-infused and/or pigment-infused), colored polystyrene-based carboxylated latex polymer (dye-infused and/or pigment-infused), fluorescent polystyrene-based polymers, fluorescent polystyrene-based carboxylated latex polymers, fluorescent aminated polystyrene-based polymer, surfactant-free polystyrene, carboxylated surfactant-free polymer, polymethyl methacrylate (PMMA) latex polymer, divinylbenzene (DVB)-crosslinked polystyrene latex polymer.

In embodiments, GRPs are manufactured via additive manufacturing, also known as 3D printing (referred to herein as “3DP”), a process of creating 3-dimensional (3D) objects by subsequent addition of layers of molten material via a printer device compatible with a variety of materials including plastics, polymers, ceramics, metals, etc. In embodiments, 3DP allows for the creation of complex shapes and structures that would be difficult to produce with traditional manufacturing methods. In embodiments, a digital model of the object is created using computer-aided design (CAD) software (e.g., as shown in the STL images of FIGS. 1M-1P, 11A-11B, 17A-17C, 18B-18E, 36A-36B, 37A-37B, 38A-38B, 39A-39B, and 40A-40B). In embodiments, the printer reads the digital model and adds successive layers of material, such as plastic, metal, or biological material, until the object is complete to the specifications described in the digital model. Additive manufacturing, in embodiments, can be used to print a wide range of materials, including plastics/polymers, metals, ceramics, composites, and biological substances, as well as more complex materials such as paper, wood, wax, and food.

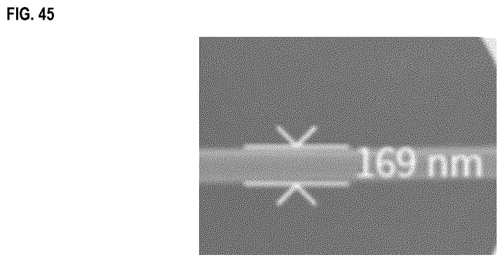

In embodiments, 3DP has benefits over traditional manufacturing methods, including reduced waste, faster production times, and greater design flexibility. There are currently seven general classes of 3D printing methods: material extrusion, vat polymerization, powder bed fusion, material jetting, binder jetting, directed energy deposition, and sheet lamination. In embodiments, the size of dimensions available using 3DP depend on the specific type of 3D printing technology and the capabilities of the printers used; however, in general, the largest dimensions available using 3DP can be several meters in length, width, and height, and the smallest dimensions available using 3DP can be in the range of micrometers to sub-micrometers, achieved using advanced 3D printing technologies, such as stereolithography (SLA), digital light processing (DLP), or two-photon polymerization (2PP), which can print with high precision and high resolution. For example, in embodiments, commercial 3D printers based on 2-photon polymerization (2PP) are available through UPNANO to produce polymeric objects spanning 12 orders of magnitude, from centimeters to nanometers in size. In embodiments, FIG. 45 shows a 3DP feature with a width of 169 nm printed using an UPNANO printer. Likewise, in embodiments, the NANO DIMENSION 3D printers, including the DragonFly IV prints metal particles and dielectric inks with spatial resolution of 18 μm (x) by 18 μm (y) by 10 μm (z), which is used to generate GRPs.

In embodiments, GRPs can be 3D printed onto a substrate surface (e.g., such as a glass slide) and be released from the substrate surface via several methods. In embodiments, 3D printed GRPs can be removed by mechanical separation (e.g., with a razor). In embodiments, for example during scalable manufacturing, GRPs can also be released by chemical separation (e.g., via applying a solvent), thermal separation (e.g., by heating), ultrasonic separation (e.g., by sonication), and/or by vacuum release. Depending on the 3D printer used, the method of 3D printing, the composition of the GRP, and the type of substrate used, additional methods for release are known to those skilled in the art.

A variety of MRPT have been fabricated by 3DP, for example in non-limiting embodiments, at least processes for manufacture of MRPTs and other tilting objects can be found in ZHAO et al., “Make it swing: Fabricating personalized roly-poly toys,” Computer Aided Geometric Design, Vol. 43, 2016: pp. 226-236; and PERELMAN, et al., “The Roly-Poly Mouse: Designing a Rolling Input Device Unifying 2D and 3D Interaction”, Association for Computing Machinery, 2015: pp. 327-336, doi: 10.1145/2702123.2702244, both of which are hereby incorporated by reference in their entirety.

In embodiments, GRPs are generated using techniques for 3D printing, including but not limited to, fused deposition modeling (FDM), fused filament fabrication (FFF), stereolithography (SLA), two photon polymerization, multi-photon lithography, selective laser sintering (SLS), binder jetting (BJ), direct energy deposition (DED), digital light process (DLP), liquid crystal display (LCD), polymer jetting (PolyJet), multi-jet fusion (MJF), direct metal laser sintering (DMLS), electron beam melting (EBM), laminated object manufacturing (LOM), continuous liquid interface production (CLIP), electron beam melting, and digital light processing (DLP).

In embodiments, GRPs include one or more substrate materials, as described herein. In embodiments, the one or more substrate materials is porous and/or hollow. In embodiments, methods of manufacturing include doping the one or more substrate materials with a denser material. In embodiments, the denser material is infused, embedded, or otherwise placed into a bottom portion of the particle. In embodiments, generating the particle includes joining at least two substrate materials, where the two substrate materials differ in density.

In embodiments, the one or more substrate materials is transparent to at least a portion of the visible electromagnetic (EM) spectrum. In embodiments, the one or more transparent substrate materials includes glass, quartz, plastic, polyethylene terephthalate, polycarbonate, polymethyl methacrylate (acrylic), polyethylene, polyurethane, polypropylene, thermoplastic elastomers (TPE), acrylonitrile butadiene styrene (ABS), epoxies and epoxy-based photoresists, hydrogels, cyclic olefin copolymer (COC) cyclic olefin polymer (COP), poly dimethyl siloxane (PDMS), poly ether ester ketone (PEEK), polyetherimide (ULTEM) and/or nylon.

In embodiments, the one or more substrate materials has a thickness of about or at least about 50 nm, is about or at least about 100 nm, is about or at least about 500 nm, about or at least about 1 μm, is about or at least about 10 μm, is about or at least about 100 μm, about or at least about 1 mm, about or at least about 5 mm, or about or at least about 10 mm

In embodiments, methods of manufacturing GRPs herein includes disposing one or more optically active agents onto and/or into the one or more substrate materials that comprise the GRPs. In embodiments, the one or more substrate materials is porous, where the one or more optically active agents is disposed into the pores of the substrate material. In embodiments, the one or more optically active agents is applied to one or more surfaces of the GRP. In embodiments, the one or more optically active agents comprise a color in the visible electromagnetic spectrum comprising an extinction, reflection, or scattering at a wavelength from about or at least about 350 nm to about or at least about 800 nm. In embodiments, the color is one or more of white, black, red, orange, yellow, green, blue, indigo, and/or violet.

The one of more optically active agents for manufacturing GRPs herein, in embodiments, can include any optically active agents, as described herein, including dyes, pigments (organic and/or inorganic), nanoparticles, fluorescent materials, metal and/or metallic materials, plasmonic materials, etc.

In embodiments, several approaches to applying optical properties can be used, and several surfaces of the GRP can have optical properties applied to them. For example, in embodiments, while the GRP of FIG. 33F illustrate bottom portions that were made to be a different color (i.e., darker) than the top portions, corresponding to the design and operation articulated in FIGS. 14-16, there are a number of means by this could be accomplished. First, in embodiments, the bottom portion can be painted after released from the substrate it was printed on. In embodiments, this can be performed with a mask for the top portion, or without a mask, and can be done by hand painting, airbrushing, dip coating, among other methods of applying color to a GRP. Alternatively, in embodiments, the painting or coloration of the bottom portion can be done while one or many GRPs are still attached to the substrate.

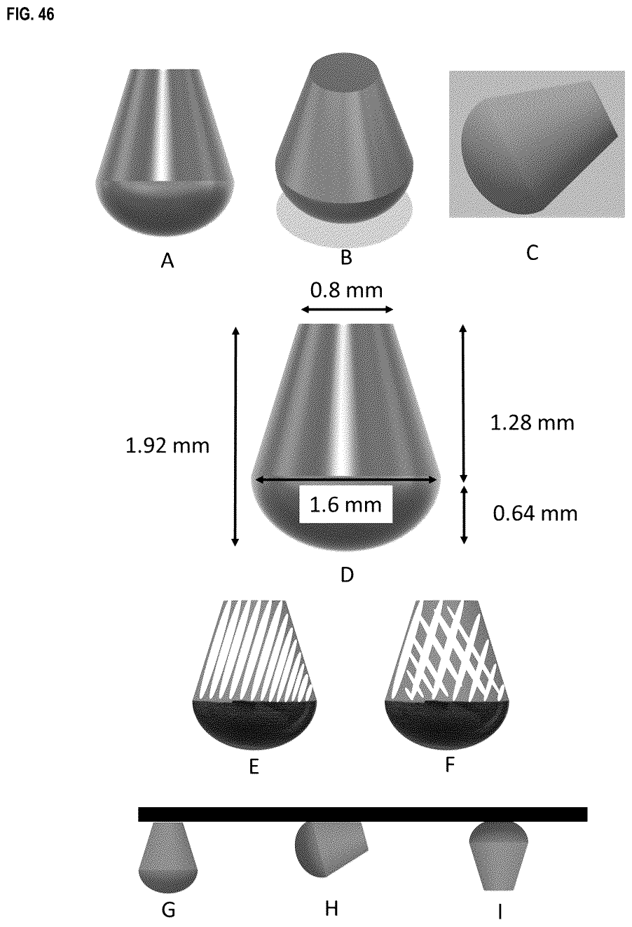

For example, in embodiments and in reference FIGS. 46A-46I, illustrative diagrammatical representations of GRPs designed to be fabricated by 3D printing as shown. In embodiments, FIGS. 46A-46C shows the CAD designs from different perspectives and orientations. In embodiments, FIG. 46D shows illustrative GRP dimensions of 1.92 mm in height, 1.6 mm in width at the widest point, among other dimensions.

In embodiments, and as illustrated in FIGS. 46E-46F, a gyroid infill can be included into at least a portion of the internal portion of the GRP, for example as shown in the top portion of the GRP, where the white space indicates cross-section of hollowed out density. In embodiments, the gyroid infill is a 3D geometry composed of intersecting 2D wavy lines that created a strong, robust pattern on the internal portion of the GRP. Gyroid infills, in embodiments, are used in manufacturing 3D-printed objects to conserve on materials while maintaining overall strength and rigidity of the object. In embodiments, the smaller amount of internal material used to construct the gyroid infill is used to maintain the external shape while lowering the density in the top portion relative to the bottom portion of the GRP. In embodiments, the internal portion can have other infill patterns used in 3D printing, which are geometries of the GRP internal portion used for distributing material to control the CoM and porosity, such as grid infills (e.g., as illustrated in the top portion of the GRP of FIG. 46F), cubic infills, triangular infills, octet infills, lightning infills, among other infill patterns, and/or combinations thereof. In embodiments, gyroid infills impart porosity as described in FIG. 10.

In embodiments and in reference to FIGS. 46G-46I, three different orientations in which GRPs can be additively printed onto a substrate are shown. In embodiments, when GRPs are 3D printed in an orientation as shown in FIG. 46G, the entire substrate can be dipped into a solution that coats the exposed surface, e.g., a bottom portion, top portion, and/or side portion. In embodiments, the solution contains the source of color (e.g., a dye, pigment, stain, etc.), or a reagent that leads to a change in color in the material. In embodiments, GRPs can be printed in an orientation as shown in FIG. 46I, where they can be dip-coated, leading to coloration of the top portion of the GRP. In embodiments, GRPs can be manufactured with one or more sides coated with an optical property (e.g., color), such as those shown in FIG. 12, by dip coating of one or more GRPs fabricated on the substrate, for example with an orientation as shown in FIG. 46H. Persons skilled in the art, with the benefit of this disclosure in its entirety, will understand that FIGS. 46G, 46H, and 46I represent only three of the many possible orientations in which GRPs can be fabricated using 3D printing. Likewise, in embodiments, because the printing area can be on the order of 20 mm×20 mm (although the area can be much larger), and because the GRP can be on the order of about or at least about 0.1 mm to about or at least about 2 mm in size, it is possible to print many GRPs on a single substrate at once, where each can be in a different orientation, or the same orientation, depending on the needs of the fabrication process.

In embodiments, there are several different optical-property coating processes in which different colors can be introduced to different portions/surfaces of the GRPs. For example, in embodiments these methods include photochemical approaches, photonic approaches, chemical approaches, electrical approaches, magnetic approaches, or mechanical approaches. For example, a mechanical approach can include abrading or roughening at least one portion of the surface of a GRP to provide a differential reflectivity in relation to another part, e.g., as shown in the GRPs of FIG. 24.

Alternatively, in embodiments, different colors and patterns of coloration can be integrated into the GRP during the 3D printing process, for instance by using different colored printing materials (e.g., resins, polymers, particles, plastics, etc.). For example, in embodiments, multi-extrusion 3D printing involves using a printer with multiple extruders, where each extruder can be loaded with a different color filament, and the printer switches between them during the printing process to achieve a desired color, or pattern of colors. Likewise, in embodiments, 3D printing filaments can contain multiple colors, where as the filament is extruded, the colors blend together to create a unique coloring pattern. Additionally, in embodiments, certain composite 3D printing materials can be reacted with acid to change color, which is an example of a chemical approach to selectively apply an optical property to a GRP.

While the different colors present in the GRPs illustrated in FIGS. 46E and 46F correspond to the top portion and the bottom portion of the GRPs, this is intended as a non-limiting example, and in embodiments, other coloring patterns are possible. For example, in embodiments, the GRP illustrated in FIG. 46D has a height of 1.92 mm, where dip coating (or other means of coloring) can be used to introduce different colors to the bottom portion to a level of 0.06 mm (3% of the height), or 0.12 mm (6%), or 0.24 mm (12%), or 0.64 mm (33%, corresponding to the entire bottom part), or to any other height level, where the color changes along the height (or width) of the GRP.

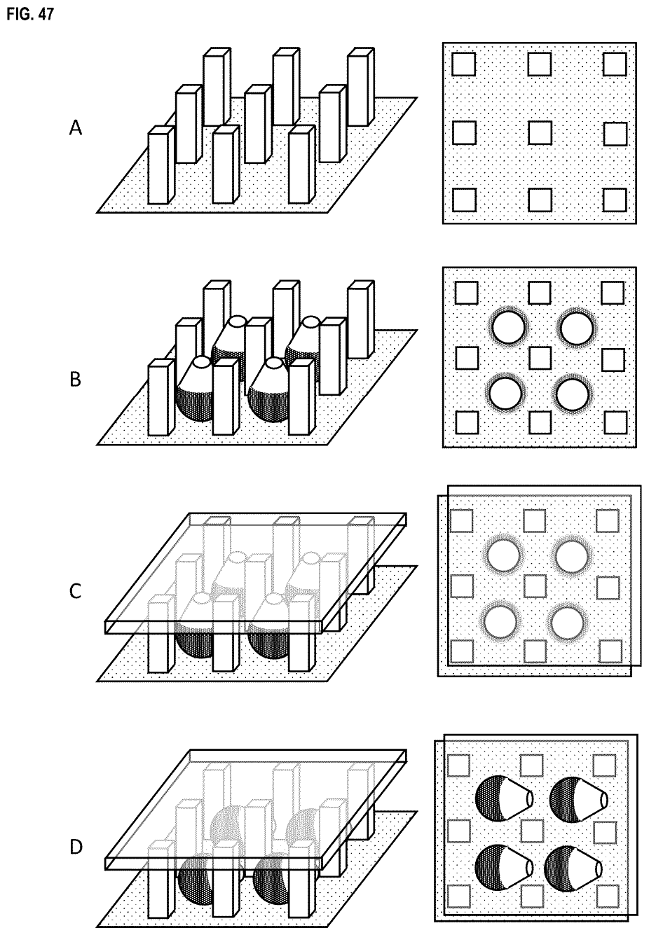

In embodiments, GRPs can be further manufactured into an array contained within a top substrate and a bottom substrate, e.g., as illustrated in FIG. 33. In embodiments, and in reference to FIG. 47, the fabrication of one such array is illustrated with a tilted side and top views of non-limiting components and assemblies. For example, in embodiments, FIG. 47A shows a square, bottom substrate with a 3×3 array of posts. In embodiments, this bottom substrate can be the surface of an object, can be opaque, semi-transparent, or can be transparent. In embodiments, the bottom substrate can be any shape, and can contain any number of posts, indentations, and the like, arranged in any pattern of spacing. In embodiments, such a substrate can be fabricated by 3D printing, or can be manufactured using various forms of lithography, by microcontact printing, by injection molding, by micro-injection molding, or by any other method as described herein. In embodiments, the posts are the same material as the bottom substrate and/or are the same color; alternatively, in embodiments, the posts are a different material than the bottom substrate and/or are a different color. In embodiments, the posts are transparent, semi-transparent, or opaque. In embodiments, and in reference to FIG. 47B, GRPs can rest at stationary equilibrium within the four spaces that are bounded by posts, for example, the 4 GRPs bounded by the 9 posts in the square pattern. In embodiments, several methods can be used for placing GRPs into arrays, e.g., into the post-containing substrate, including in non-limiting examples, placement, settling, shaking, gravity settling, etc. In embodiments, the posts are slightly taller than the GRPs; however, as described above, any height of posts can be used by which motion of the GRPs is not impacted by the presence of a top substrate.

In embodiments, a transparent top substrate can be added, e.g., as shown in FIGS. 47C and 47D. In embodiments, contact can be made between the top substrate and the posts, where the top substrate can be held in place by glue, adhesive, pressure, adhesion, or by any other means by which two materials can be fastened. In embodiments, the top substrate can be composed of a material that is transparent to at least a portion of the visible EM spectrum (e.g., transparent to light in the range of 350 nm to 800 nm), including in non-limiting examples, glass, plastic, quartz, sapphire, gel, etc. In embodiments, the top substrate can be a variety of thicknesses, as described herein. In embodiments, the top substrate can be planar or non-planar, and can adopt a variety of shapes, e.g., such as conforming to the surface of an object the GRPs are intended to cover.

In embodiments, and in reference to FIG. 47D, the assembly of FIG. 47C is illustrated with the GRPs tilted. In embodiments, a force can be imparted (e.g., a jerk, shake, tilt, etc.) causing the GRPs to move (e.g., tilt) between the posts to the right; however, the GRPs can equally tilt between any pair of posts (e.g., to the left, toward the top, or toward the bottom). In embodiments, depending upon the choice of GRPs used, an observer looking through the top substrate and an observer looking through the bottom substrate will observe the same blend or pattern of colors; however, in embodiments, such as with the GRPs depicted in FIG. 33, the array can be manufactured such that the observers looking through the top substrate and the bottom substrate could observe different colors.

Methods of manufacturing GRPs herein, in embodiments, include formulating the GRP into a foil, film, thin plastic, and/or paper substrate, material, and/or surface. In embodiments, the foil, film, thin plastic, and/or paper substrate, material, and/or surface is suitable to be affixed to, or embedded in, an object.

In embodiments, methods of manufacturing GRPs herein can include applying the GRP to a surface, for example to the bottom surface of a well or plate.

Methods of manufacturing GRPs herein, in embodiments, include formulating the GRP into a fiber, thread, yarn, and/or twine substrate, material, and/or surface. In embodiments, the fiber, thread, yarn, and/or twine substrate, material, and/or surface is suitable to be woven into an article of clothing, a cloth, and/or a tarp.

Methods of manufacturing GRPs herein, in embodiments, include formulating the GRP into a fluid, suspension, ink, liquid film, and/or adhesive substrate, material, and/or surface. In embodiments, the fluid, suspension, ink, liquid film, and/or adhesive substrate, material, and/or surface is suitable to be applied to an object.

### Sensors and Biosensors

In aspects, described herein are GRPs that are useful for a variety of applications for detection of species or molecules (e.g., an analyte, antigen, biomarker, cell, pathogen, ionic species, etc.) or evaluating a sample, e.g., for the presence of heavy metal contamination, water, food, or beverage contaminant, presence of a bacterium, virus, pathogen, or any other substance, species, or bio-analyte. In embodiments, the sampling and/or detection is discontinuous; in embodiments, the sampling and/or detection is continuous.

In embodiments, the GRP is manufactured into a sensor (e.g., a biosensor) for detecting one or more analytes comprising a plurality of particles disposed onto a reaction membrane (the plurality of particles including any GRP, as described herein), a sample pad configured to receive a volume of the sample and flow the sample over the reaction membrane, where each of the plurality of particles are conjugated to one or more mass detection labels configured to bind the one or more analytes, and where as the sample is flowed over the plurality of particles on the reaction membrane, the one or mass detection labels binds the one or more analytes in the sample, causing a shift in the mass of the plurality of particles, which results in a movement in the plurality of particles, and wherein the movement elicits a change in an optical property proportional to the binding of the one or more analytes.

In embodiments, the sensor provides a colorimetric change as a function of GRP binding to analytes, and thus as a function of movement of the GRP due to the mechanical force of binding and mass shift. In embodiments, the GRPs on the sensor tip onto a stable equilibrium (distinct from their upright equilibrium) which reveals the color change.

For example, in embodiments, the fin-shaped GRP design as substantially depicted in FIGS. 11 and 36 is used in a sensor application, and is manufactured on size scales from nanometers to millimeters.

In embodiments, the one or more fins are surface-coated with a binding agent (e.g., on one or more portions of the external sides—the top, bottom, or side edge of each fin). In embodiments, the binding agent includes, in non-limiting examples, immobilized antibodies or antibody-format binding molecules, aptamers, or another binding molecule. In embodiments, the antibody or antibody-format binding agent be selected from a monoclonal antibody, polyclonal antibody, antibody fragment, Fab, Fab′, Fab′-SH, F(ab′)2, Fv, single chain Fv (scFv), diabody, nanobody, linear antibody, bispecific antibody, multi-specific antibody, chimeric antibody, humanized antibody, human antibody, and fusion protein comprising the antigen-binding portion of an antibody or antibody format, and the like. In embodiments, the binding molecule includes recombinant proteins that include, for example cell receptors, extracellular domains that bind and/or scavenge sugars (e.g., glucose, lactose, xylose, etc.), amino acids, ions (e.g., calcium, potassium, iron, etc.), and/or ligands for detecting a variety of analytes or antigens in a sample, or for conjugation to the GRP surface.

In embodiments, the binding agent can be a nucleic acid, or a nucleic-based binding molecule, including but not limited to DNA, RNA, modified DNA, modified RNA, aptamers and/or locked nucleic acids.

Methods for immobilizing binding molecules onto surfaces, e.g., by using a variety of surface chemical treatments are well known, for example as described in Wang & Jin, “Silicon surface modification with a mixed silanes layer to immobilize proteins for biosensor with imaging ellipsometry,” Colloids Surf. B 34, 2004: pp. 173-177; Vashist, “Comparison of 1-ethyl-3-(3-dimethylaminopropyl) carbodiimide based strategies to crosslink antibodies on amine-functionalized platforms for immunodiagnostic applications,” Diagnostics, Vol. 2, 2012: pp. 23-33; Vashist, et al., “One-step antibody immobilization-based rapid and highly-sensitive sandwich ELISA procedure for potential in vitro diagnostics,” Sci Rep Vol. 4, No. 4407, (2014); U.S. Pat. Nos. 7,577,470; and 7,813,780, each of which are hereby incorporated by reference in their entirety. For example, in embodiments, a well-known biological conjugation pair can include systems using streptavidin-biotin linkage, maleimide-based reactions, and carbodiimide-based reactions.

In embodiments, GRPs described herein are applied to a surface, for example to the bottom surface of a well or plate, or to the surface of a test strip. In embodiments, a sample is applied to the GRP-coated well, plate, test strip, etc. In embodiments, the sample includes a biological sample, for instance in non-limiting examples, blood, sera, plasma, bone marrow, lymph, saliva, sputum, mucus, respiratory or nasal secretion, oropharyngeal swab, nasopharyngeal swab, oral swab, ductal lavage, bronchoalveolar lavage, cerebrospinal fluid, skin swab, vaginal swab, gastric juice, ascites, peritoneal fluid, pleural fluid, gynecological fluids, pus, perspiration, tears, urine, or stool. In embodiments, the sample includes a homogenized biopsy, tissue, or cell sample, for example from a tumor. In embodiments, the sample includes a water sample, for example to analyze contaminants in a water source. In embodiments, the sample includes foodstuffs and/or surfaces for storing or preparing foodstuffs, including beverages, homogenized animal products intended for consumption, samples taken from a surface that is used for preparing food, etc. In embodiments, the sample includes samples taken to evaluate for residues originating from contaminants from explosives, oil spills, hydrocarbons, soil contamination, and the like.

In embodiments, the signal transduction mechanism for sensing/detection is a change in mass. In embodiments, the concentration of the analyte or molecule the GRP binds in a sample is proportional to the degree of optical change.

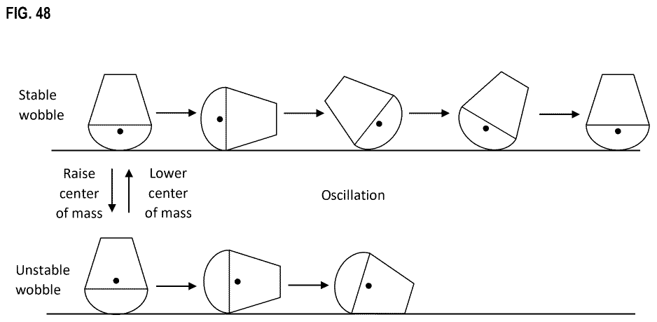

In embodiments and in reference to FIG. 48, a non-limiting, diagrammatic representations of stable and unstable GRPs illustrates the impact of the position of center of mass relative to radius of curvature on GRP stability. In embodiments, when the center of mass is below the radius of curvature, the wobble motion of the GRP is stable and repeatable. In contrast, in embodiments, when the center of mass exists (or is moved to a position) above the radius of curvature, the wobble motion can be irreversible: if tipped to far, the GRP rests permanently on its side.

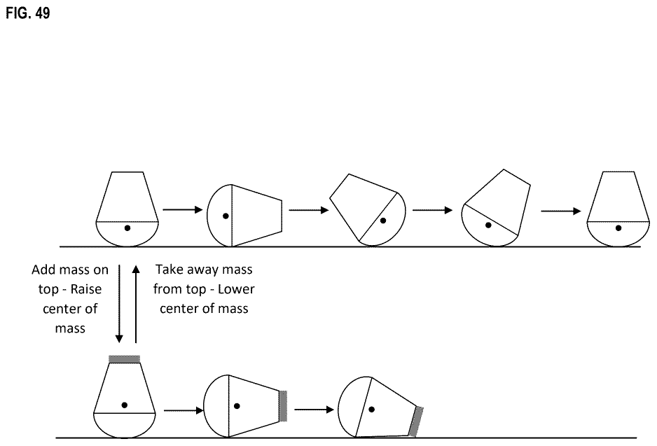

In embodiments and in reference to FIG. 49, a change in mass in the appropriate position can transform a stable GRP to an unstable GRP. For example, in FIG. 49, the mass is added to the top of the GRP and as a consequence, the tipped GRP no longer wobbles but rather comes to rest on its side. It should be clear to those skilled in the art that changes in mass in any part of a GRP (top, bottom, interior, exterior, side) will have an impact on its wobble characteristics and response to gravity.

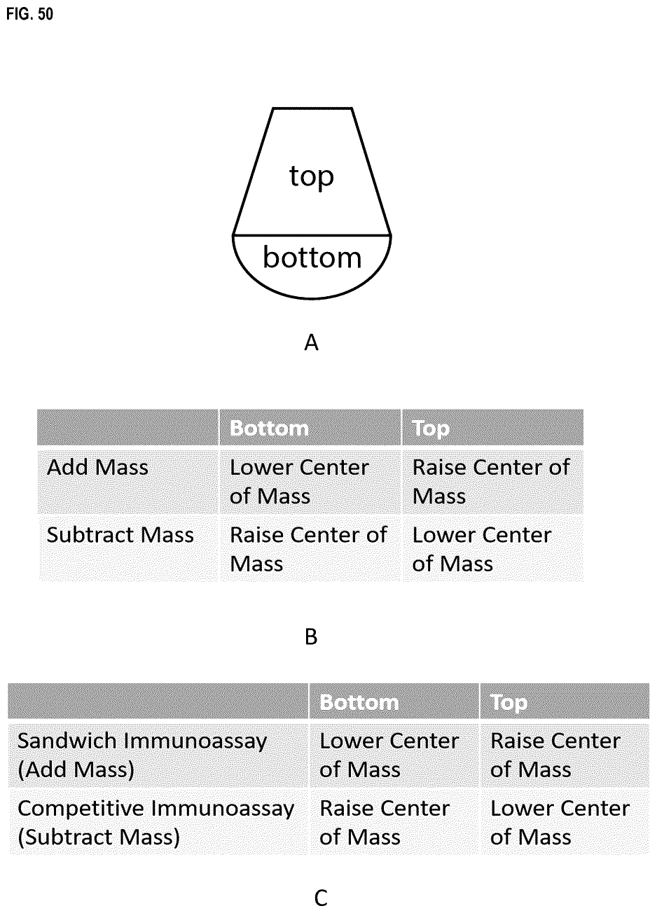

In embodiments, the translation of this principle into immunoassays is shown in FIGS. 50-52. In embodiments and in reference to FIG. 50A, a side view of a GRP with a line at the radius of curvature delineating top (above the radius of curvature) and bottom (below the radius of curvature) sections of the GRP is illustrated. In embodiments and in reference to FIG. 50B, a table outlines how adding or subtracting mass (in general) to the top and bottom of a GRP affects its center of mass.

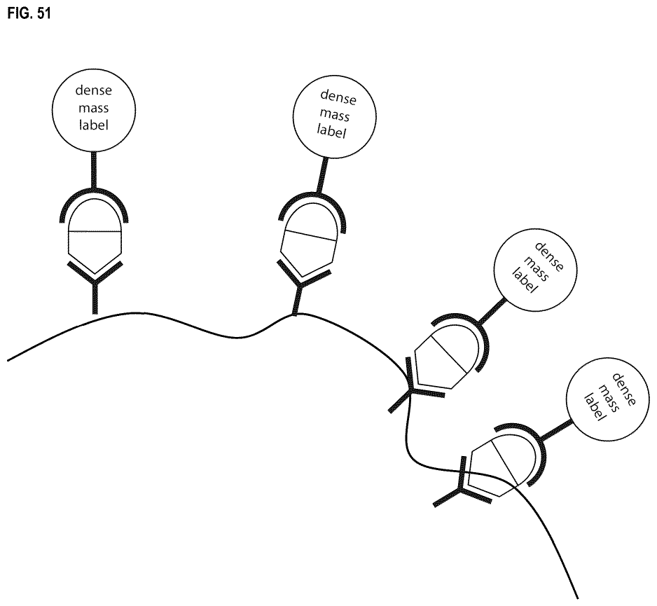

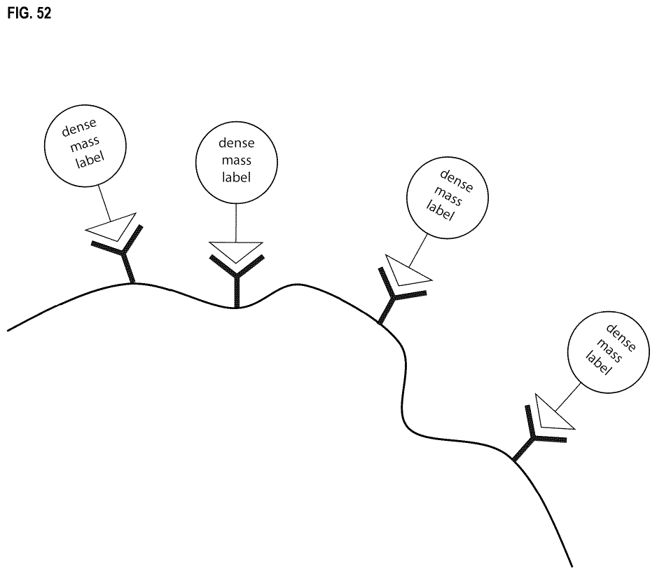

In the context of immunoassays, in embodiments, sandwich assays involve the binding of a second or secondary antibody to an antigen or target that has been captured by a first antibody (e.g., here confined to a surface as shown in FIG. 51). In embodiments, the binding of the secondary antibody adds mass to the surface, and this mass change can be amplified by the use of dense mass label. In embodiments, if the mass is added to the bottom of the GRP, the center of mass is lowered, while if added to the top, the center of mass is raised (e.g., as outlined in FIG. 50C). In embodiments, for competitive immunoassays (e.g., as illustrated in FIG. 52), the displacement of a high mass-labelled antigen (by the target) leads to a loss in mass. In embodiments, a loss in mass in the top of the GRP will lower the center of mass, while a loss of mass in the bottom of the GRP will raise the mass.

In embodiments, by careful tuning of the center of mass of GRPs, it becomes possible to develop a GRP-based biosensor with very low limits of detection. Specifically, in embodiment, in a GRP where the center of mass is just below the radius of curvature, the gravity-responsive wobble will be stable, and at equilibrium, an observer will see the top part of a GRP. In embodiments, a change in mass to the top part of the GRP will render the particle unstable, and in response to sufficient stimulus, the particle GRP will rest on its side, and an observer will see the sides of the GRP or GRPs. In embodiments, the sides of the GRP are a different color from the top, the GRP functions as a colorimetric sensor.

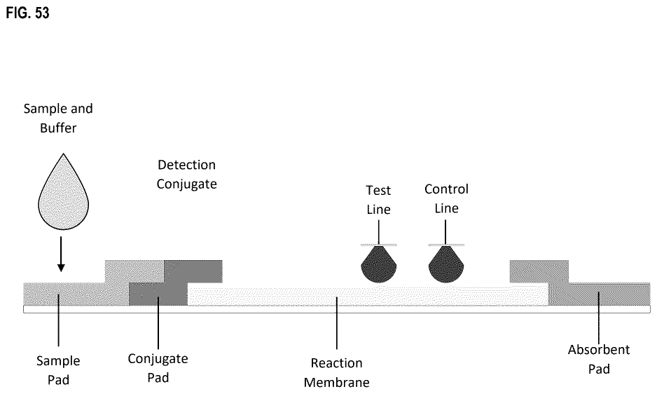

In embodiments, depending on the shape, size, design, surface area, internal area, and composition, as well as the location of the center of mass, very small changes in mass will lead to a change in the stability of GRP, from a stable wobble to a tipped state. For example, in embodiments and in reference to FIGS. 11 and 36, the 7-fin GRPs illustrated provide additional surface area for attachment of a biosensing layer. In embodiments, a 60-nm Au nanoparticle is used as a mass label on a GRP with dimensions on the order of 1-2 mm, with the appropriate positioning of the center of mass, a sandwich immunoassay of the format described, for example in FIGS. 53, 54A-54I, 55A-55C, 56A-56B, and 57A-57B, leads to a change from stable to unstable wobble with a particle sub-monolayer coverage of about or less than about 10%, 5%, 4%, 3%, 2%, 1%, 0.5%, 0.4%, 0.3%, 0.2%, 0.1%, 0.05%, 0.04%, 0.03%, 0.02%, to about or less than about 0.01%. In embodiments, more massive labels and smaller GRPs lead to more sensitive detections; in principle, binding of a single analyte and associated dense mass label could lead to the stable-unstable transition, or vice versa.

In embodiments, the mass labels used could comprise metals such as gold (Au), silver (Ag), platinum (Pt), nickel (Ni), iron (Fe), palladium (Pd), tungsten (W), tantalum (Ta), osmium (Os), iridium (Ir), lead (Pb), or any metal or combination of metals or alloy, such as BaTiO₃, SnO₂, PbO₂, TiO₂, or any metal oxide. In embodiments, mass labels comprise a dimension of about or less than about 10 nm, 20 nm, 30 nm, 40 nm, 50 nm, 60 nm, 70 nm, 80 nm, 90 nm, 100 nm, 120 nm, 140 nm, 160 nm, 180 nm, or 200 nm, or 300 nm, or 400 nm, or 500 nm, or 1,000 nm, or 2,000 nm, to about or less than about 3,000 nm.

In embodiments, a GRP at equilibrium (e.g., upright and stable) displays one color, and in the tipped (unstable) position, displays a different color. In embodiments, the upright color is green, and the tipped color is red. In embodiments, the tipped color is green, and the upright color is red.

In embodiments, GRPs are used in any type of biosensing device, vessel, or format, including but not limited to tubes, well plates (e.g., single well, 4-well, 8-well, 12-well, 96-well, 384-well, or higher), lateral flow devices, microfluidic devices, disposable devices, and non-disposable devices or formats. In embodiments and in reference to FIGS. 53-57, the use of GRPs in lateral flow devices and/or test strips is illustrated. In embodiments, the GRP-based sensor includes one or more of a reaction membrane, sample pad, conjugate pad connecting the sample pad and reaction membrane, and an absorbent pad opposite the conjugate pad. In embodiments, one or more of the sample pad, reaction membrane, conjugate pad, and absorbent pad are composed of materials that enable the wicking or movement of a liquid sample across the GRP array embedded in the reaction membrane. In embodiments, the materials are congruent to commercially-available materials for test kits, test strips, and other diagnostic materials.

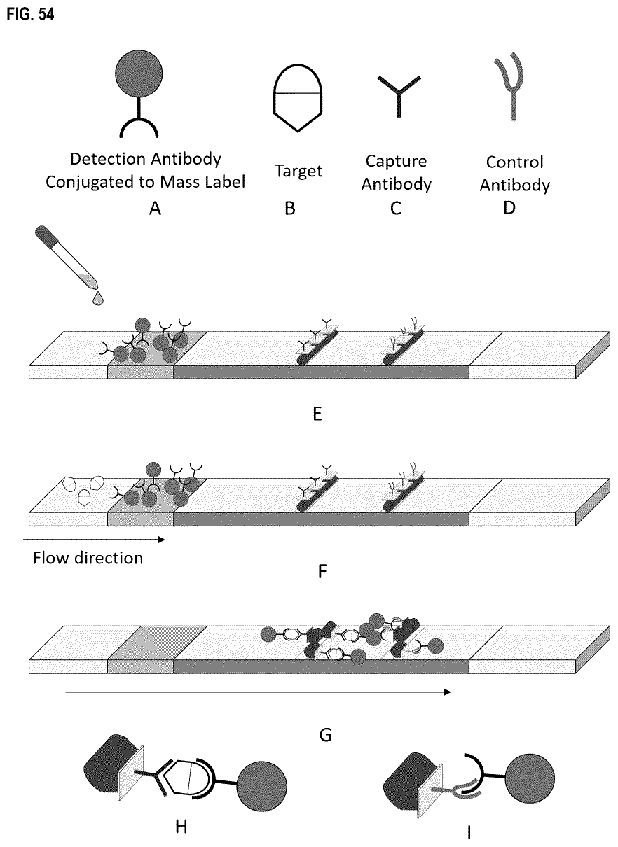

In embodiments, a GRP-based lateral flow sensor is constructed and uses the principles of detection, for example, as described in Koczula and Galotta, “Lateral flow assays,” Essays in Biochemistry, Vol. 60, (2016): pp. 111-120, incorporated by reference herein in its entirety. In embodiments, FIG. 53 depicts a lateral flow assay format, in which the colored components typically present for the test line and control line comprise GRPs. In embodiments, FIG. 54 depicts a lateral flow immunoassay, where immobilized capture antibodies are bound to a GRP (e.g., FIG. 54H) and control antibodies are also bound to a GRP (e.g., FIG. 54I). In this example, in embodiments, the top of the GRP is a first color (e.g., shown as light gray) relative to the sides of the GRP which are a second color (e.g., shown as black). In embodiments, the GRPs at the test line and control line are configured to tip (e.g., become unstable) upon binding of the antigen/detection antibody-mass label complex (at the test line) and upon binding of the detection antibody-mass label conjugate (at the control line). In embodiments, the shape of this GRP enables it to be tipped either to the left or to the right, among other directions.

In embodiments, the sensor includes a plurality of control particles (e.g., comprised of GRPs, as described herein) also disposed onto the reaction membrane. In embodiments, each control particle has one or more mass detection labels that are i) not configured to bind the one or more analytes that the plurality of particles bind, and ii) provide a control signal. In embodiments, the control signal is the same as the change in optical property of the analyte-specific plurality of particles (e.g., both the analyte-specific GRP and control GRP exhibit the same color change, for example, they both appear green when upright and stationary and tilt to reveal red, or vice versa).

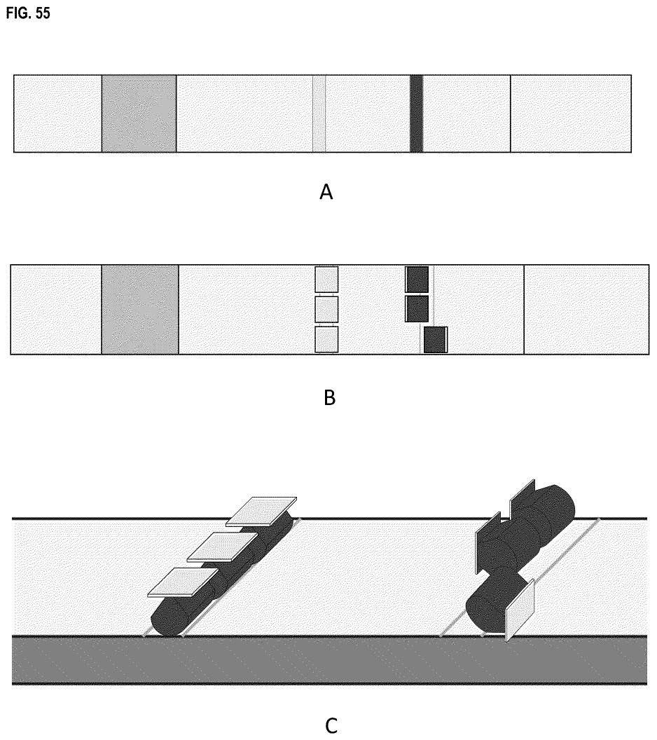

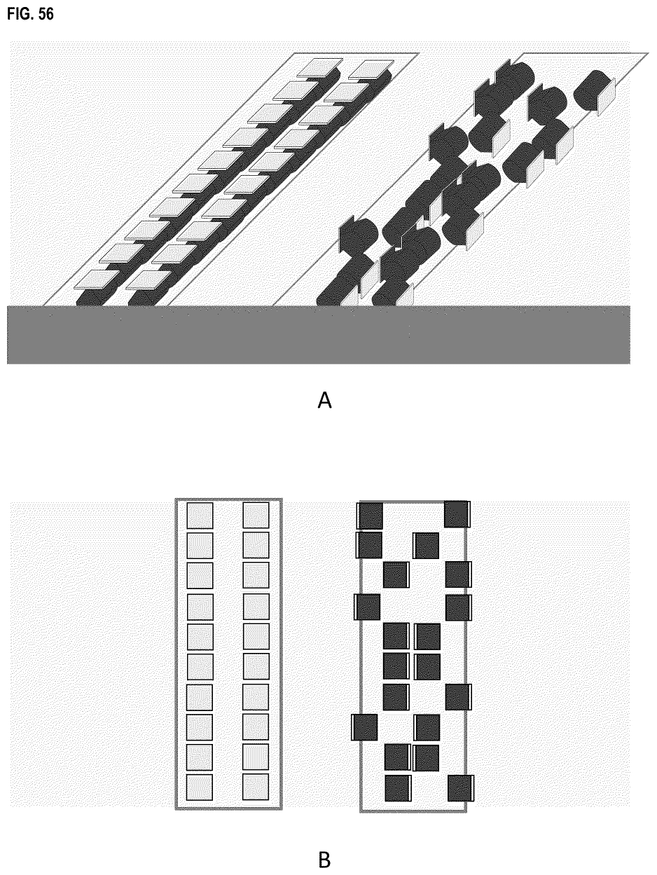

In embodiments and in reference to FIGS. 55A-55C and 56A-56B, an illustration of the result of a negative test (e.g., absence of the target analyte) for a device and immunoassay, e.g., like that of FIG. 54, is shown. In embodiments, after the solution containing the target analyte has flowed past the test and control lines, and the device is agitated (e.g., shaken, tipped, or agitated) and then returned to the horizontal position. In embodiments, at the test line, the absence of analyte leads to no binding of the mass-dense label to GRPs in that region, whereas the detection antibody-mass label complex from the conjugate pad binds to the test line (e.g., via the control antibody, typically anti-species). In embodiments, this results in unstable, where tipped GRPs present a different color, indicating a result.

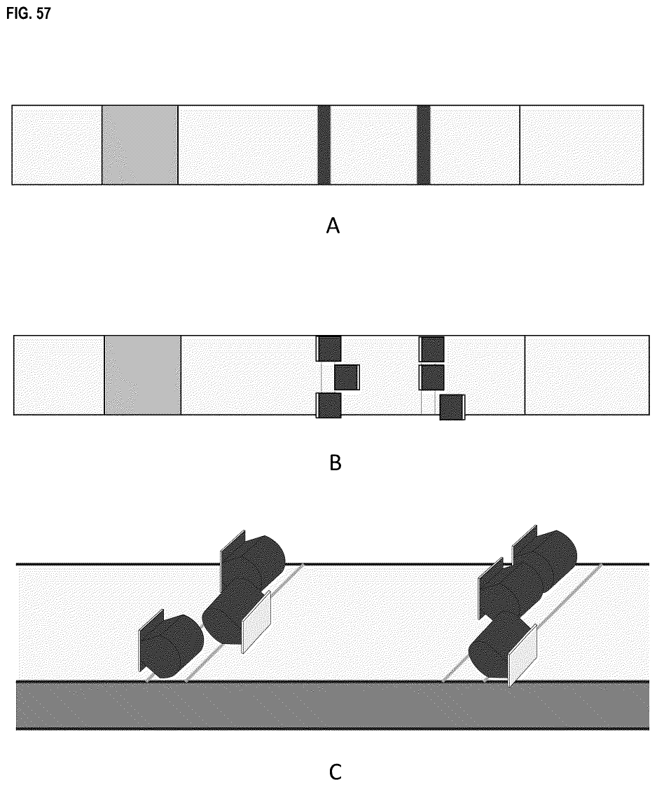

In embodiments and in reference to FIGS. 57A-57C, an illustration of the result of a positive test (e.g., the presence of the target analyte) for the device and immunoassay, e.g., like that of FIG. 54, is shown. In the presence of the target analyte, the antibody-mass label complex is immobilized on the GRP at the test line, moving the GRP's center of mass to above the radius of curvature, and making it unstable, such that (like at the control line), it remains in the tipped orientation, and presents the same color change as the control line.

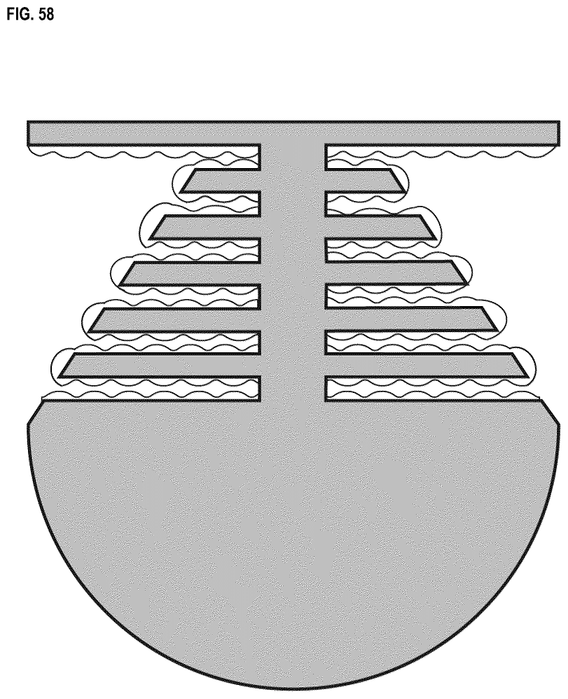

In embodiments, the sensing elements of GRPs designed to act as biosensors are positioned anywhere on the exterior or interior surface of the GRP. For example, in embodiments, FIG. 58 illustrates immobilization of a biomolecular capture film in the top portion of a multi-finned GRP, such that addition of mass (via target capture) to the top portion of the GRP moves the center of mass to above the radius of curvature. In embodiments, surface features of the GPR (e.g., fins) increase the surface area for binding.

In embodiments, the target bound by the GRP and/or the biomolecular capture film is a protein, peptide, nucleic acid (e.g., DNA, RNA, or modified DNA or RNA), lipid, sugar (e.g., blood sugar), metabolite, cell (e.g., diseased cell, cancer cell, cell with a particular biomarker or expression profile), pathogen (e.g., virus or viral capsid or envelope proteins, antigen, bacterium, fungus, spore, mycoplasma, etc.), biomarker, ionic species, heavy metal, and any substance containing or including biomolecules.

In embodiments, the sample includes one or more of blood, sera, plasma, bone marrow, lymph, saliva, sputum, mucus, respiratory or nasal secretion, oropharyngeal swab, nasopharyngeal swab, oral swab, ductal lavage, bronchoalveolar lavage, cerebrospinal fluid, skin swab, vaginal swab, gastric juice, ascites, peritoneal fluid, pleural fluid, gynecological fluids, pus, perspiration, tears, urine, stool; homogenized biopsy, tissue, or cell sample; a tumor sample; a water sample; a sample of foodstuffs and/or surfaces for storing or preparing foodstuffs, beverages, homogenized animal products intended for consumption, samples taken from a surface that is used for preparing food, and soil samples.

In embodiments, the biomolecular capture film comprises a sub-monolayer, a monolayer, or multiple layers. In embodiments, the thickness of such a capture film is about or at least about 1 nm, 2 nm, 3 nm, 4 nm, 5 nm, 10 nm, 20 nm, 30 nm, 50 nm, 100 nm, 200 nm, 500 nm, 1 μm, 2 μm, or about or at least about 10 μm or more. In embodiments, the biomolecular capture film is designed to capture one target analyte, two target analytes, or more than two target analytes. In embodiments, the biomolecular capture film is a solution or fluid that comprises one or more analyte-binding molecules that is dipped, coated, sprayed, or otherwise applied to at least a portion of the surface of a GRP to apply the analyte-binding molecules to a specific portion of the GRP.

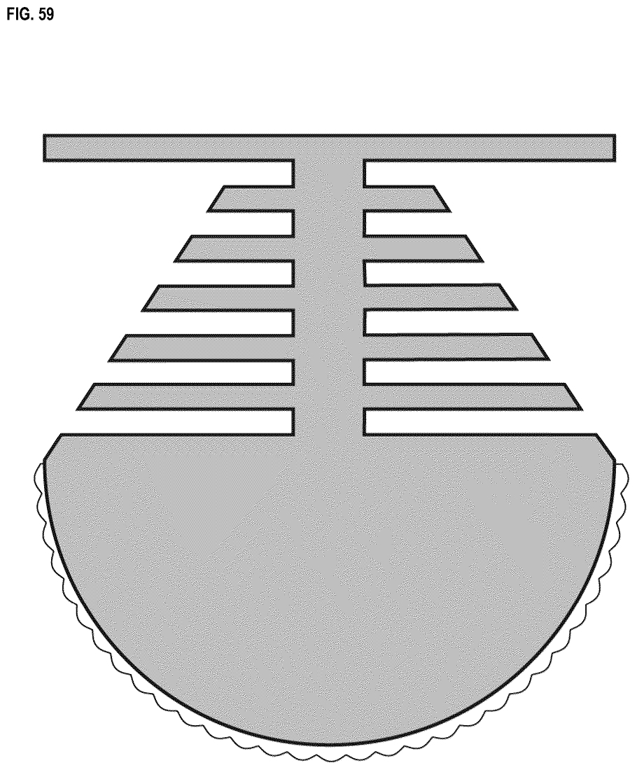

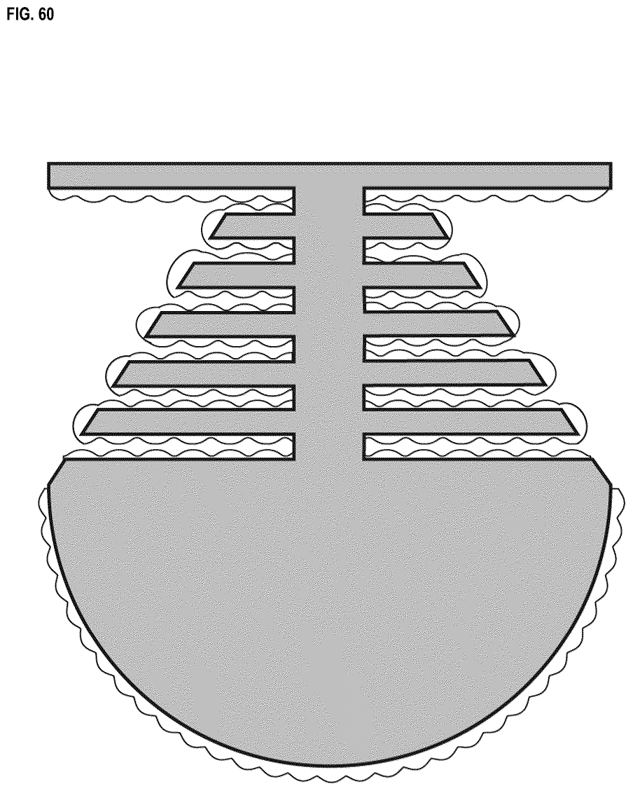

In embodiments and in reference to FIGS. 59-60, two non-limiting alternative geometries for location of the biomolecular capture film on a GRP are shown. In embodiments, the film is located on the bottom part of the GRP (e.g., as shown FIG. 59), or the film is located over the bottom and fins of the GRP (e.g., as shown in FIG. 60).

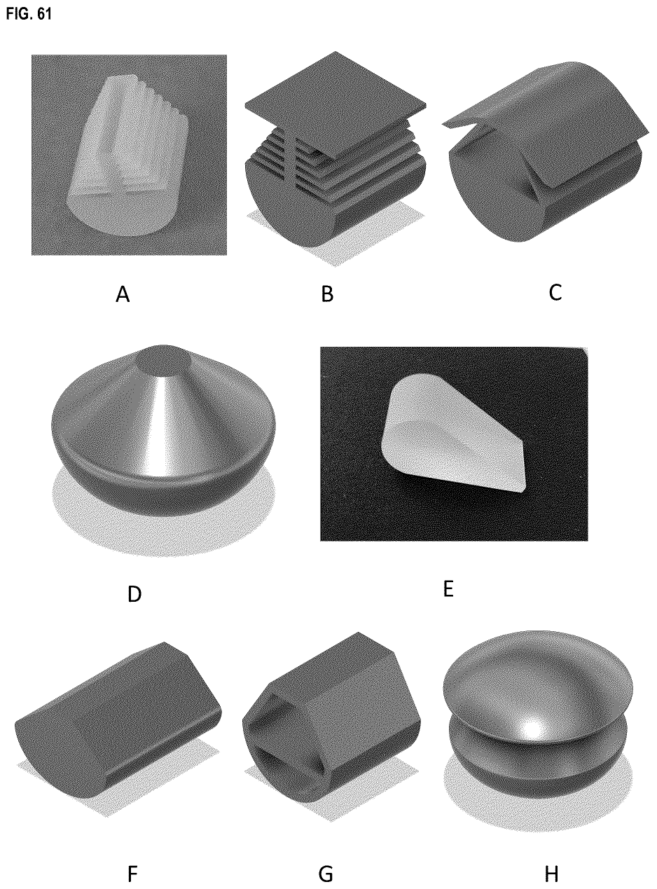

In embodiments and in reference to, FIGS. 53-60 refer to GRPs with flat tops, but a wide variety of GRP shapes are amenable to incorporation into biosensors. In embodiments, FIG. 61 shows a variety of possible GRP shapes and geometries for use in biosensor applications, including but not limited to, GRPs that are cylindrical or elliptical, or cylindrical or spherical or wedge-shaped, and with flat tops, curved tops, and no tops.

Likewise, in embodiments, while FIGS. 53, 54E-54G, 55A-55C, 56A-56B, and 57A-57C illustrate GRPs in planar arrays or films for sensor or biosensor applications, there are alternative implementations of gravity-responsive particles. For example, in embodiments, a solution-based GRP sensor biosensor, comprises a Janus (2-sided) spherical particle, or an Ashura (3-sided JP) particle, in which each hemisphere is a different color. In embodiments, the Janus particle includes a biomolecule-functionalized mass label. In embodiments, one portion of the JP (corresponding to one color) contains a biomolecular capture film, as described herein. In embodiments, the Janus particle is spherical, and the two hemispheres are of equivalent density. Accordingly, in embodiments, the center of mass is exactly at the radius of curvature (in this case, the diameter), and there is no preferred orientation. Thus, in embodiments, the JP adopts any orientation.

In embodiments, binding of one or more copies of a target analyte to the biomolecular capture film leads to immobilization of one or more antibody-mass label conjugates, increasing the mass of that hemisphere and moving the particle's center of mass off the diameter and into the hemisphere containing the mass labels. In embodiments, the force of gravity then acts on the JP, rolling or moving it to the lowest energy orientation (e.g., which in this case, corresponds to tipping onto its side). In embodiments, to an observer looking from above, in the initial state, the JP adopt a variety of orientations (meaning a mixture of the two colors is observed); whereas after binding of target, only one color is observed (e.g., all JPs tilted to one side, showing a different color).

In embodiments, JPs are in solution or the particles are immobilized onto a surface, or sandwiched between two or more substrates.

In embodiments, the a biosensor based on a 3-state GRP comprises a shape that resembles a “mushroom”. In embodiments, a mushroom-shaped GRP, e.g., as observed from the top, exhibits three distinct equilibrium states; in a first state, the mushroom GRP rests on its bottom; in a second state, the mushroom GRP is inverted, resting on its “cap” or top; and in the third state, the mushroom particle is on its side, with both the cap and the bottom in contact with the surface the GRP rests upon. In embodiments, a sensing or biosensing layer is applied to the cap or to the bottom of the mushroom-shaped GRPs.

In embodiments, sGRPs described herein (as well as any other GRPs described herein) are applied to a surface, for example to the bottom surface of a well or plate. In embodiments, a sample is applied to the sGRP-coated well, plate, etc.

In embodiments, the fins, top, or detents introduce grooves on the sides of the sGRP that provide increased surface area for binding, e.g., for applications where the sGRP function as a biological/chemical sensor. In embodiments, the fins, top, or detents of the sGRP increase the surface area of the sGRP such that binding elicits a mass shift large enough to tilt the sGRP past the critical angle to allow the sGRP to rest on its side. In embodiments, the interior portions/surfaces of the fins, top, or detents on the sGRP are coated with an optical agent such that tipping results in a change of optical property. In embodiments, the concentration of the analyte or molecule the sGRP binds in a sample is proportional to the degree of optical change.

In embodiments, sGRPs with fins or detents are suitable for a variety of applications where the sGRP is used for sampling of molecules (e.g., an analyte, antigen, biomarker, cell, etc.) or evaluating a sample, e.g., for the presence of heavy metal contamination, water, food, or beverage contaminant, presence of a pathogen, diagnosis of a patient sample, etc.

Machine Reading of GRPs and/or sGRPs

In aspects, described herein are GRPs that are useful for a variety of applications, such as sensing, biosensing, and/or authentication. In embodiments, GRPs are used for generating quantitative data, and are suitable to be detected, or read, using a reader or detector.

In embodiments, described herein is a method of authenticating an object using a detectable GRP signal, where the method comprises providing an object having an array of GRP particles (e.g., any as described herein) disposed thereon, applying a force to the array of particles to cause a movement in the array of particles which elicits a change in an optical property in the array of particles, and detecting the change in the optical property as a function of the movement of the array of particles. In embodiments, the method allows an object to be verified for is authenticity and/or identity based on moving it, applying a magnet, etc., where doing so causes an optical property change that is observable by human vision or detectable using a device.

In embodiments, the object includes one or more materials such as paper, plastic, glass, metal, fabric, wood, a window, an electronic device, a computer chip, construction materials, and/or human or animal tissue or skin. In embodiments, the object is documentation, artwork, or paper currency. The method applies to objects that, in embodiments, have one or more regions that are substantially planar, non-planar, convex, concave, or without a well-defined shape, where the array of particles are located on a surface and/or substrate on an interior surface of the object and/or on an exterior surface of the object.

In embodiments, the method includes applying a force to cause movement (induce an optical signal) from the GRPs using gravity (e.g., reorienting the position relative to gravity), mechanical force (e.g., shaking, agitation, jerking, tilting, etc.), or magnetic force (e.g., applying a magnet, turning on an electromagnetic device, etc.).

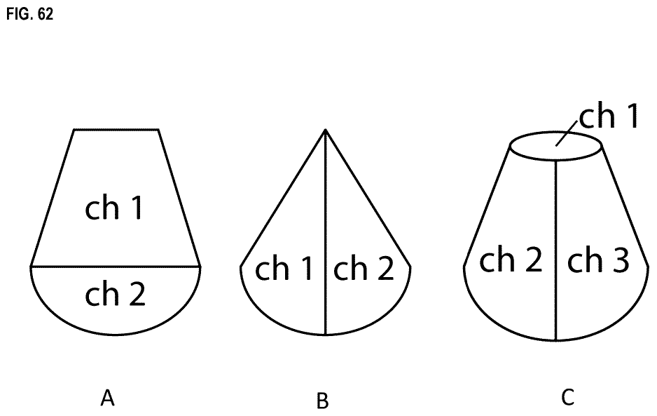

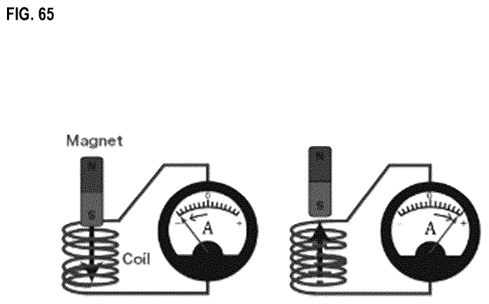

In embodiments and in reference to FIGS. 65A-65C, three different GRPs of various shapes, each comprising two or more materials with different optical signals are shown. In embodiments, the different optical signals are denoted by the various optical channels (ch) on each GRP. In embodiments and in reference to FIG. 62A, the top section of the GRP has a ch 1 optical signal, while the bottom has a ch 2 optical signal. In embodiments and in reference to FIG. 62B, the left side of the GRP is associated with ch 1, and the right side with ch 2. In embodiments and in reference to FIG. 62C, there are three different optical signatures: one for the top of the GRP (ch1), one for the left side (ch2), and one for the right side (ch3). In embodiments, different signals are detectable as a function of time depending on the position of the detector and the motion of the GRP.

In embodiments, the methods includes a change in the optical property of one or more color in the visible electromagnetic spectrum with an extinction, reflection, or scattering at a wavelength from about or at least about 350 nm to about or at least about 800 nm. This includes, in embodiments, one or more color of white, black, red, orange, yellow, green, blue, indigo, violet, or a color shade or hue therebetween. In embodiments, the change in optical property is detectable by human vision.

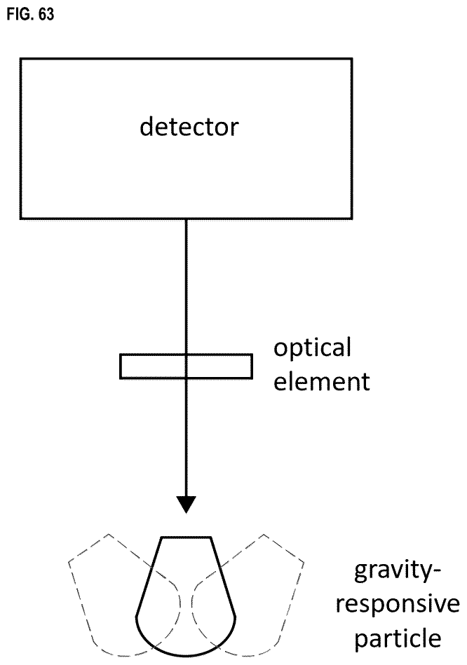

In embodiments and in reference to FIG. 63, an illustrative detector setup is shown, where an optical element is used with a detector, which includes but not limited to a spectrometer, a filter, a window, a grating, a beam splitter, a polarizer, a collimator, a birefringent element, a prism, a bandpass filter, an aperture, or a lens, with respect to a GRP (e.g., an array of GRPs, or an object with GRPs), such that at equilibrium, the detector is seeing any signal that emanates from the top of the particle, but as the GRP moves, the optical properties of the other portions are shown.

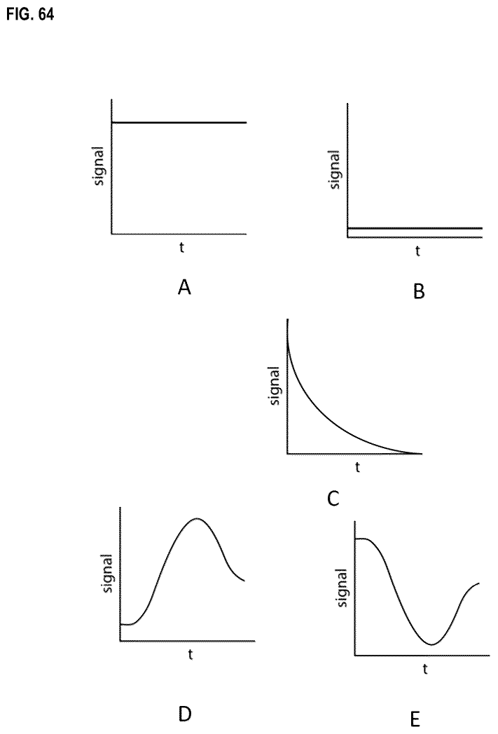

In embodiments, in detectors of biosensor authentication applications, the detected signal falls into one of a small number of signal pattens, for example, such as those depicted in FIGS. 64A-64C. In embodiments and in reference to FIG. 64A, a constant (high) signal is shown, in FIG. 64B a constant (low) signal is shown. In embodiments and in reference to FIG. 64C, an exponentially decaying signal (not shown is the corresponding exponentially increasing signal) is shown. In embodiments, GRPs are suitable to exhibit novel optical signatures, for example, as shown in FIG. 64D which depicts a signal that rises then falls, and FIG. 64E which depicts a signal that falls and then rises; these signals are suitable to oscillate as a function of time along with the motion of GRPs. In embodiments, these are understood to be partial or complete optical signatures of wobbling GRPs.

In embodiments, the detecting is performed as a function of the movement and as a function of time, where the GRP authenticity signal provides a signal function, which is comparable to a standard signal (e.g., a standard GRP array known to provide the expected signal).

In embodiments, the complexity in optical signatures of oscillating GRPs are dependent on the placement of optical channels and its movement properties, which in turn are defined by shape, size, center of mass, friction, optical agents, etc. Accordingly, in embodiment, GRPs with unique, oscillating optical signatures are suitable for methods and uses herein. Likewise, in embodiments, for a given composition of GRP, that optical signatures should be identical between individual GRPs.

### Electromagnetic Vibrational Energy Capture

In aspects, described herein are uses for GRPs in electromagnetic vibrational energy capture devices. For example, Faraday's Law states that motion of a magnet in an out of coil will induce a voltage, for example as illustrated in FIG. 65. In embodiments, this concept is used to produce electromagnetic vibrational energy harvesters (EMVEHs) using GRPs, for example as described in Muscat, et al. “Electromagnetic Vibrational Energy Harvesters: A Review,” Sensors, Vol. 22, No. 15, 2022:5555, incorporated herein by reference in its entirety.

EMVEHs are macroscopic, bulky objects, measuring tens to hundreds of centimeters in size, and are characterized by poor efficiency. In embodiments, GRPs are used in the design of new type of EMVEH, for example as illustrated in FIGS. 66A-66C, 70A-70C, and 7I.

In embodiments, the electromagnetic vibrational energy capture device comprises one or more gravity responsive particles (GRPs), where each GRP has a shape and a center of mass (CoM) that enables motion between a plurality of positions when a force is applied, where the GRP comprises magnetic material (e.g., a magnet), where the magnet on the GRP moves as a function of the motion between the plurality of positions. In embodiments, the device includes one or more coils configured to induct an electric current, where the one or more GRPs is arranged relative to the one or more coils such that the motion between the plurality of positions from the applied force inducts an electrical current in the one or more coils, converting the force applied to the one or more GRPs into the electric current. In embodiments, the GRP is any described herein, and the shape and the CoM of the one or more GRPs enables relaxation to a stationary position from the plurality of positions from gravitational force.

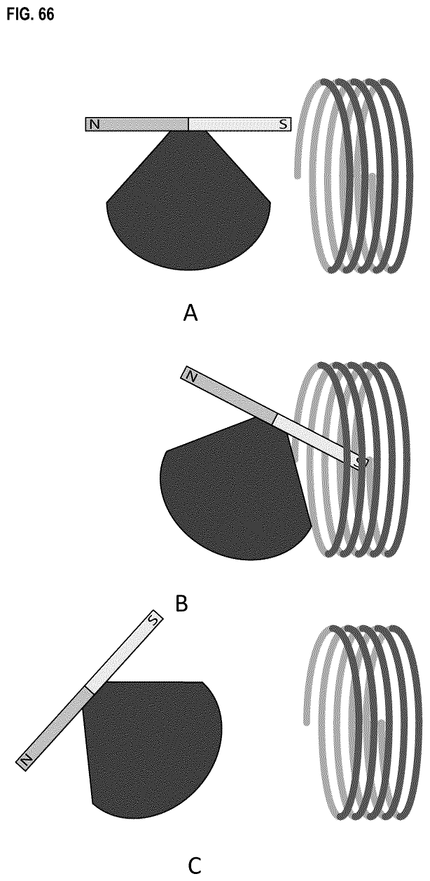

In embodiments and in reference to FIG. 66, the basic operation of such a device is illustrated, where the GRP functions as the moving magnetic component whose movement in response to mechanical agitation (e.g., gravity, agitation, tilting, etc.) is used to induce a current which is harvested. In embodiments and in reference to FIG. 66A, magnetic material, such as a magnet (e.g., a permanent magnet), is affixed to the top of a GRP, which is close proximity to a coil. In embodiment, tilting or shaking or tipping initiates motion of the GRP, which brings the magnet within the coil (inducing a current, e.g., as shown in FIG. 66B). In embodiments, the magnetic material is affixed to the top, bottom, and/or side of the one or more GRPs. In embodiments, gravity-induced motion of the GRP to the other end of its oscillation moves the magnet out of the coil (e.g., as shown in FIG. 66C) inducing a negative current (e.g., movement in the other direction). In embodiments, as long as the GRP is in motion, there will be current in the coil.

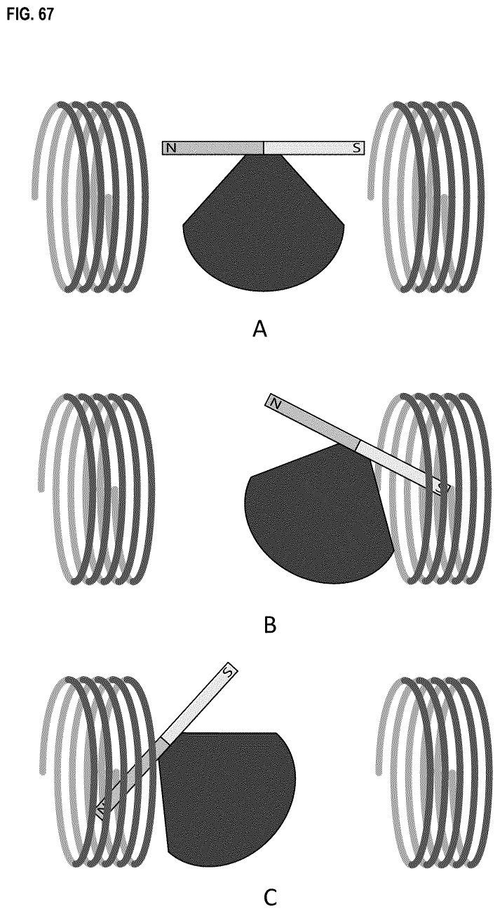

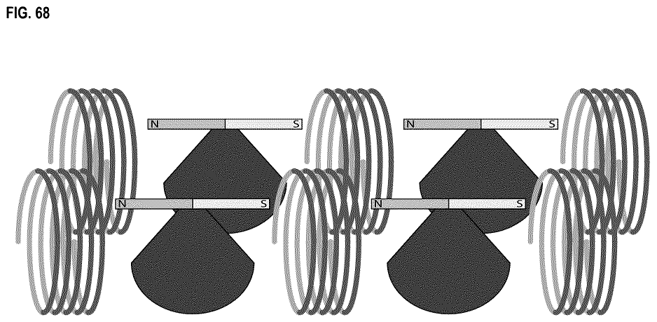

In embodiments and in reference to FIG. 67, the same concept as in FIG. 66 is illustrated, but with two independent coils, one to the left and right of the GRP, such that motion of the GRP induces current in both wires simultaneously. In embodiments and in reference to FIG. 68, the concept of FIG. 67 is suitable to be extended to an array of GRPs, each surrounded by two coils.

In embodiments, the electromagnetic vibrational energy capture device includes one coil for each GRP, or two or more coils for each GRP. In embodiments, the electromagnetic vibrational energy capture device includes a housing that contains the one or more GRPs and the one or more coils. In embodiments, the electromagnetic vibrational energy capture device comprises an array of GRPs arranged relative to an array of coils.

In embodiments, the electromagnetic vibrational energy capture device one or more elements (e.g., such as batteries) in electric communication with the one or more coils configured to store an electrical charge from the electrical current inducted in the one or more coils.

### Compositions

In embodiments, described herein are compositions comprising GRPs. In embodiments, the composition includes GRPs formulated into a foil, film, thin plastic, and/or paper substrate, material, and/or surface. In such embodiments, the GRPs can be present in a number of GRPs per area, for example, at about or at least about 10⁶ GRP/mm², about or at least about 10⁵ GRP/mm², about or at least about 10⁴ GRP/mm², about or at least about 1,000 GRP/mm², about or at least about 100 GRP/mm², about or at least about 50 GRP/mm², about or at least about 10 GRP/mm², about or at least about 5 GRP/mm², about or at least about 1 GRP/mm² or fewer, including ranges and amounts therein.

In embodiments, the composition includes GRPs formulated into a fiber, thread, yarn, and/or twine substrate, material, and/or surface. In such embodiments, the GRPs can be present in a number of GRPs per distance in length, for example, at about or at least about 50,000 GRP/mm, about or at least about 10,000 GRP/mm, about or at least about 1,000 GRP/mm, about or at least about 500 GRP/mm, about or at least about 100 GRP/mm, about or at least about 50 GRP/mm, about or at least about 10 GRP/mm, about or at least about 5 GRP/mm, about or at least about 1 GRP/mm, about or at least about 0.5 GRP/mm, or about or at least about 0.1 GRP/mm, or fewer, including ranges and amounts therein.

In embodiments, the composition includes GRPs formulated into a fluid, suspension, ink, liquid film, and/or adhesive substrate, material, and/or surface. In such embodiments, the GRPs can be present in mass per volume, for example at about or at least about 0.001 mg/mL, about or at least about 0.01 mg/ml, about or at least about 0.1 mg/ml, about or at least about 1.0 mg/mL, about or at least about 10 mg/mL, about or at least about 50 mg/mL, about or at least about 100 mg/mL, about or at least about 150 mg/ml, about or at least about 200 mg/mL, about or at least about 250 mg/mL, about or at least about 300 mg/ml, about or at least about 350 mg/mL, or about or at least about 400 mg/ml or more.

Alternatively, described herein, in embodiments, are objects which have GRPs applied to them. In embodiments, the composition includes a consumer good with GRPs incorporated therein, for example, packaging with GRPs incorporated therein, fabrics with GRPs woven therein, paper/foil products coated with GRPs, etc.

In embodiments, the composition includes an object imbued with GRPs as a security measure, for example for authentication of paper currency, authenticity markers of documents, and the like. In embodiments, the composition includes cosmetics, tattoos, and/or semi-permanent makeup imbued with GRPs, for example GRPs that are about or at least about 10 μm and smaller, which can be used to confer color-changing properties to the cosmetics, tattoos, and/or semi-permanent makeup. In embodiments, the composition includes GRPs as obscurants, for example, with GRPs “sandwiched” between two or more substrates (e.g., glass) for use in windows, mirrors, and/or doors.

Accordingly, the present disclosure provides, in part, color-changing film compositions comprising (i) one or more color-changing, gravity-responsive particle, (ii) substrates upon which the gravity-responsive particles rest, and (iii) optically transparent surfaces above the gravity-responsive particles. In embodiments, the substrate includes any described herein.

In embodiments, disclosed herein is a method of establishing the authenticity of an object of value comprising (i) associating the color-changing, GRP film with an object, (ii) manipulating the object to increase the gravitational potential energy of the GRPs in the film, where (iii) the force of gravity on the particles leads to a change in color, and (iv) detecting the change in color. In embodiments, the object includes any described herein.

### Kits

In embodiments, the compositions (e.g., GRP paper/foil, fluid, solution, suspension, fiber, thread, etc.) of the present disclosure are assembled into a kit. In embodiments, the kit comprises GRPs in one or more formulations described herein for application to one or more objects. In embodiments, the kit comprises one or more of a detector, optical device, magnet, other device used for the use of GRPs herein. In embodiments, the kit comprises an object imbued with GRPs, such as a well, plate, or sensor (e.g., biosensor).

The kit described herein may include one or more containers housing components for performing the methods described herein and optionally instructions for use. Any of the kits described herein may further comprise components needed for performing the manufacturing methods described herein. Each component of the kits, where applicable, may be provided in liquid form (e.g., in solution, suspension, ink, paint, etc.) or in solid form, (e.g., dry powders, paper, foil, fiber, etc.). In embodiments, some of the components are reconstitutable or otherwise processible (e.g., GRPs in powder/granule form that can be resuspended in one or more solvents/fluids to be applied to an object), for example, by the addition of a suitable solvent or other species (for example, water, ink, or paint), which may or may not be provided with the kit.

In embodiments, the kits may optionally include instructions and/or promotion for use of the components provided. As used herein, “instructions” can define a component of instruction and/or promotion, and typically involve written instructions on or associated with packaging of the disclosure. Instructions also can include any oral or electronic instructions provided in any manner such that a user will clearly recognize that the instructions are to be associated with the kit, for example, audiovisual (e.g., videotape, DVD, etc.), Internet, and/or web-based communications, etc. As used herein, “promoted” includes all methods of doing business including methods of education, engineering instruction, scientific inquiry, discovery or development, academic research, manufacturing, chemical, cosmetic, and pharmaceutical industry activity including sales, and any advertising or other promotional activity including written, oral, and electronic communication of any form, associated with the disclosure. Additionally, the kits may include other components depending on the specific application, as described herein.

The kits may have a variety of forms, such as a blister pouch, a shrink wrapped pouch, a vacuum sealable pouch, a sealable thermoformed tray, or a similar pouch or tray form, with the accessories loosely packed within the pouch, one or more tubes, containers, a box, or a bag.

Without further elaboration, it is believed that one skilled in the art can, based on the above description, utilize the present disclosure to its fullest extent. The following specific embodiments are, therefore, to be construed as merely illustrative, and not limiting of the remainder of the disclosure in any way whatsoever.

### EXAMPLES

### Example 1: Manufacture of Gravity Responsive Particle (GRP) by 3D Printing

An additive manufacturing, 3D printing-based approach was used to manufacture GRPs from the STL image model shown in FIG. 46D. The GRP was made from a polymer-based resin material compatible with an UPNANO 3D-printing instrument, equipped with a 10× objective, on a glass substrate that measured 20 mm×20 mm in size. FIGS. 46A, 46B, and 46C show the design of the GRP from various perspectives. FIGS. 46G, 46H, and 46l show possible printing orientations.

The GRP was comprised of two geometrical portions, a top portion, which is a truncated cylinder and a bottom portion, which is a hemispheroid. The outer surface of the GRP was smooth, but could be manufactured with varying degrees of roughness, as described herein. The GRP was released from the glass substrate by mechanical separation (e.g., removed with a razor), but other methods of separation can be used, as described herein.

FIG. 46D summarizes the dimensions of the manufactured GRP, where the height measured 1.92 mm, and the width at the intersection of the top portion and bottom portion measured 1.6 mm. The top portion comprised ⅔ of the overall height, while the bottom portion comprised ⅓ of the overall height. The top surface of the truncated cone was flat (i.e., parallel to the surface that the vertex in the bottom part contacts), and the width of the top surface measured 0.8 mm, or ½ the width of the GRP at its widest point. The GRP measured approximately 3 mm³ in volume. The GRP manufactured in this example is intended to be illustrative, and those skilled in the art will recognize that a variety of shapes, sizes, and compositions of GRPs can be made by 3D printing.

There are many ways to control the spatial distribution of mass in a GRP such that the center of mass (CoM) lies below the radius of curvature, as described herein. One approach is to introduce pores or hollow areas in the top portion of the GRP to lessen its density relative to the bottom portion. Two different infill patterns to lower the CoM were tested. FIG. 46E illustrates a cross-section of a gyroid infill pattern in the top portion of the GRP, where the white space indicates a hollowed-out density. The gyroid is a 3D geometry composed of intersecting 2D wavy lines that created a strong, robust pattern on the internal portion of the GRP. Gyroid infills in 3D-printed objects conserve on materials while maintaining the overall strength and rigidity of the object. Here, the smaller amount of internal material, while maintaining the same external shape, led to a lower density in the top portion relative to the bottom portion of the GRP. Another possible 3D-printed infill pattern that could be used, the grid infill, is illustrated in the top portion of the GRP of FIG. 46F.

The GRPs of FIGS. 46E and 46F illustrate bottom portions that were made to be a different color (i.e., darker) than the top portions, corresponding to the design and operation articulated in FIGS. 3 and 4. There are a number of methods that can be employed to apply optical properties to a GRP, as described herein.

While the different colors present in the GRPs illustrated in FIGS. 46E and 46F correspond to the top portion and the bottom portion of the GRPs, this is intended as a non-limiting example, and other coloring patterns are possible. For example, the manufactured GRP illustrated in FIG. 46D has a height of 1.92 mm, where dip coating (or other means of coloring) can be used to introduce different colors to the bottom portion to a level of 0.06 mm (3% of the height), or 0.12 mm (6%), or 0.24 mm (12%), or 0.64 mm (33%, corresponding to the entire bottom part), or to any other height level, where the color changes along the height (or width) of the GRP.

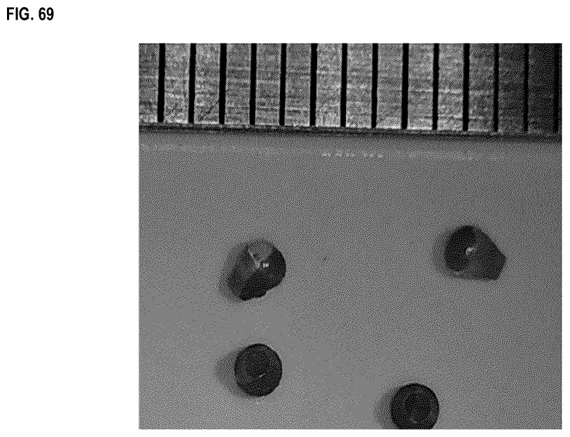

After manufacture of the GRP of FIG. 46D, using the orientation illustrated FIG. 46G, and using the infill pattern of FIG. 46F, the particles were released from the glass substrate with a razor, and characterized by optical microscopy as shown in FIG. 69. The existence of the infill pattern in the top portion of the particles lead to a lighter shade in the top section of the particle that is easily visualized, such that the particles correspond to the differential coloring shown in for the GRP of FIG. 46F.

### Example 2: Manufacture of a Hollow Gravity Responsive Particle (GRP) by 3D Printing

A GRP prototype was 3D-printed using a stereolithography (SLA) method with polycarbonate-like translucent/clear (ACCURA 60). The prototype, e.g., as illustrated in FIGS. 38A-38D, had a half cylindrical bottom portion with a diameter of 1 cm and a depth of 1 cm. The outer walls are 0.75 mm thick and the two sides of the design at either end of the cylinder are open. The side walls incline at an upward angle to a height of 5 mm above the half cylinder, 3 mm towards the center, and are joined with a 4 mm wide flat, horizontal top. A horizontal wall across the shape is placed with the top 1 mm above the center point and the bottom 1.78 mm below the center point.

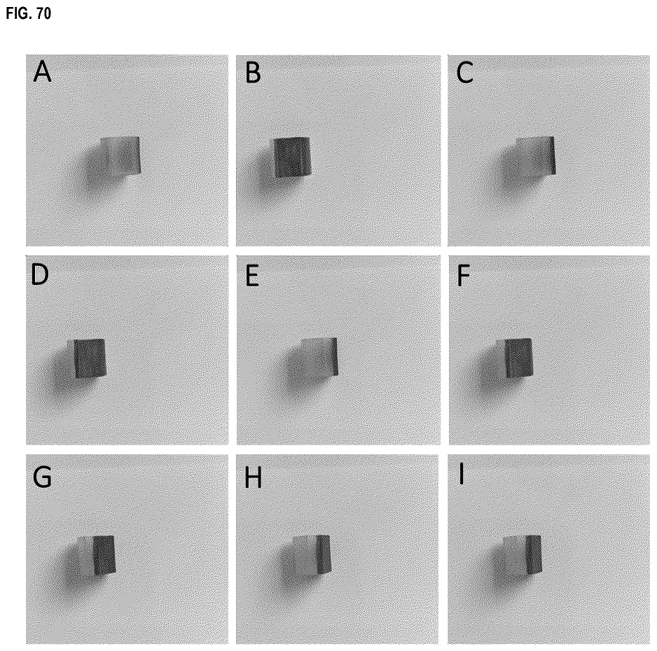

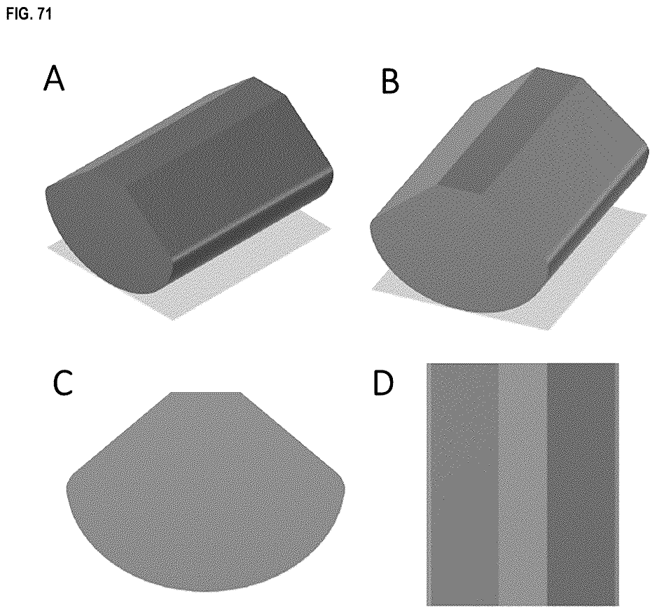

The prototype was painted with 2 different optical agents and recorded and imaged using an OPQPQ digital microscope. The GRP was tilted to one direction and released, moving through a variety of angles, and showing different optical properties, e.g., color, due to each optical agent as observed from the top. As shown in FIGS. 70A-70I, when viewed from the top, a lighter-color was observed as the GRP tilted to the right (e.g., as observed in FIG. 70A), and a darker-color was observed as the GRP tilted to the left (e.g., as observed in FIG. 70B). The GRP tilted in an undulating side-to-side motion revealing the optical property painted onto each of the two sides. The movement and subsequent optical changes are depicted chronologically in FIGS. 70A-70I over the course of a 9.35 second wobble cycle until the GRP rested at stationary equilibrium (e.g., as observed in FIG. 70I).

### Example 3: Manufacture of an Elliptic Cylindrical Gravity Responsive Particle (GRP) by 3D Printing

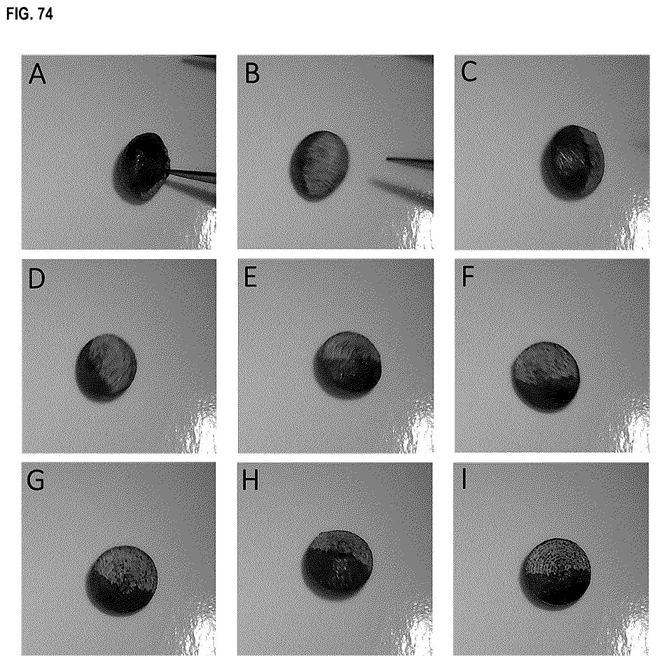

A GRP prototype was 3D-printed using a Form 3 printer (industrial-quality stereolithography (SLA), FormLabs) with FormLabs Grey resin (liquid plastic photopolymer). The prototype, e.g., as illustrated in FIGS. 74A-74D, had a half elliptic cylindrical bottom portion with a horizontal radius of 8 mm, a vertical radius of 6.4 mm, and a depth of 2 cm. The prototype was fully solid. The outer walls incline at an upward angle to a height of 5 mm above the half elliptic cylinder, 6 mm towards the center, and are joined with a 4 mm wide flat, horizontal top.

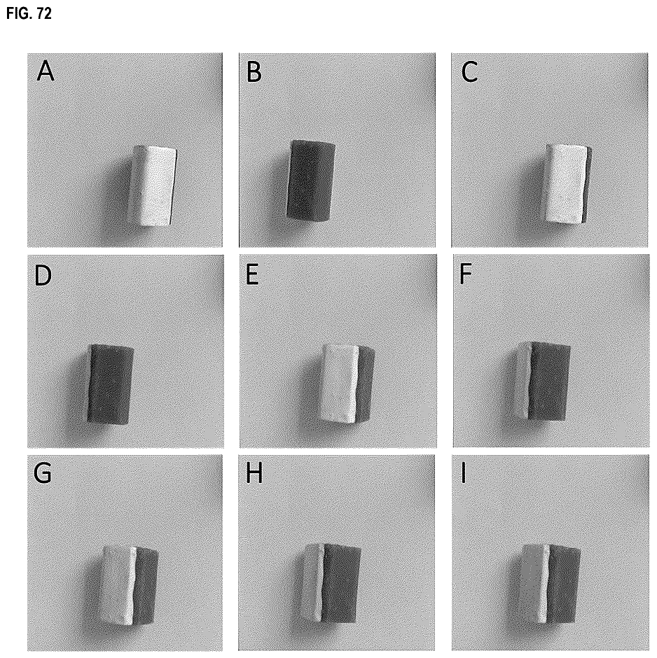

The prototype was painted with 1 optical agent-allowing the optical property of the Grey resin to be the optical agent on the non-painted portions- and recorded and imaged using an OPQPQ digital microscope. The GRP was tilted to one direction and released, moving through a variety of angles, and showing different optical properties, e.g., color, due to showing each optical agent as observed from the top. As shown in FIGS. 72A-72I, when viewed from the top, a lighter-color was observed as the GRP tilted to the right (e.g., as observed in FIG. 72A), and a darker-color was observed as the GRP tilted to the left (e.g., as observed in FIG. 72B). The GRP tilted in an undulating side-to-side motion revealing the optical property of each of the two sides. The movement and subsequent optical change is depicted chronologically in FIGS. 72A-72I over the course of a 4.9 second wobble cycle until the GRP rested at stationary equilibrium (e.g., as observed in FIG. 72I).

### Example 4: Manufacture of a Semi-Ellipsoid Gravity Responsive Particle (GRP) by 3D Printing

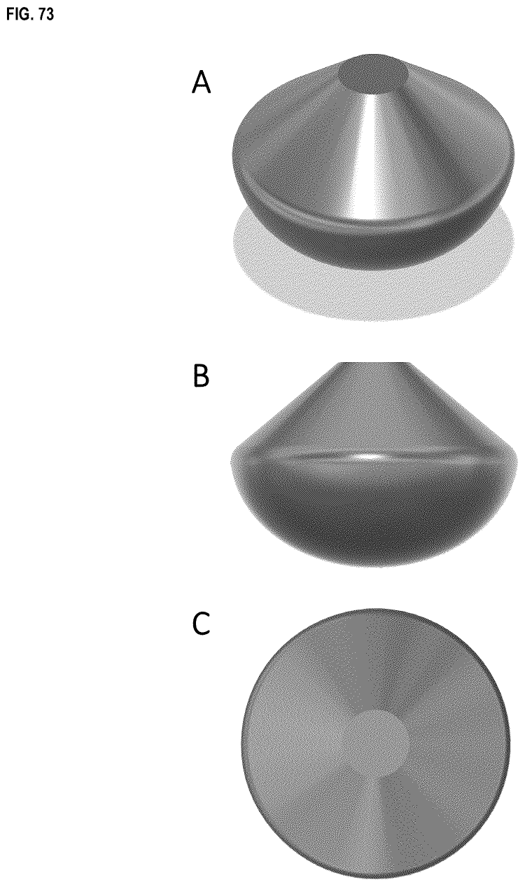

A GRP prototype was 3D-printed using a Multi Jet Fusion (MJF) 3D printer with polyamide 12 (PA12; Nylon 12). The prototype, e.g., as illustrated in FIGS. 73A-73C, had a semi-ellipsoid bottom portion with a z-axis radius of 1.92 mm, and x and y axes radii of 2.4 mm. The prototype was fully solid. The top of the prototype was a horizontal circle with a radius of 0.6 mm centered and 1.5 mm above the top point of the semi-ellipsoid. Conical walls incline at an upward angle of about 39.806° to connect the two circles. A slight fillet was added around the larger circle's connection line between the semi-ellipsoid and the conical walls.

The prototype was painted with 1 optical agent-allowing the optical property of PA12 to be the optical agent on the non-painted portions- and recorded and imaged using an OPQPQ digital microscope. The GRP was tilted to one direction using forceps and released from its maximal tilt position and recorded for its ability to tilt, moving through a variety of angles, and showing different optical properties, e.g., color, due to showing each optical agent as observed from the top. As shown in FIGS. 74A-74I, when viewed from the top, a darker-color was observed as the GRP tilted to the right (e.g., as observed in FIG. 74A), and a lighter-color was observed as the GRP tilted to the left (e.g., as observed in FIG. 74B). Due to semi-ellipsoid shape of the bottom portion of the GRP, the optical property of each of the two colored sides was observed as the GRP tilted in an undulating side-to-side motion. The movement and subsequent optical change is depicted chronologically in FIGS. 74A-74I over the course of a 3.35 second wobble cycle until the GRP rested at stationary equilibrium (e.g., as observed in FIG. 74I).

### Example 5: Manufacture of a Semi-Ellipsoid Gravity Responsive Particle (GRP) by 3D Printing

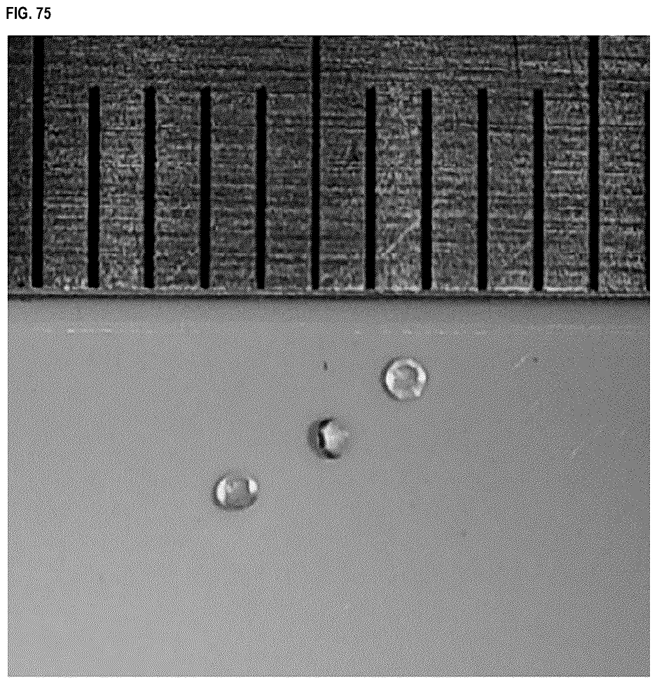

A GRP particle was 3D-printed using HTL yellow resin. The particle, e.g., as shown by the photographic image (acquired with OPQPQ digital microscope) in FIG. 75, had a semi-ellipsoid bottom portion with a z-axis radius of 0.28 mm, and x and y axes radii of 0.35 mm. The prototype was fully solid. The top of the prototype was a horizontal circle with a radius of 0.088 mm centered and 0.22 mm above the top point of the semi-ellipsoid. Conical walls incline at an upward angle of about 39.806° to connect the two circles. A slight fillet was added around the larger circle's connection line between the semi-ellipsoid and the conical walls.

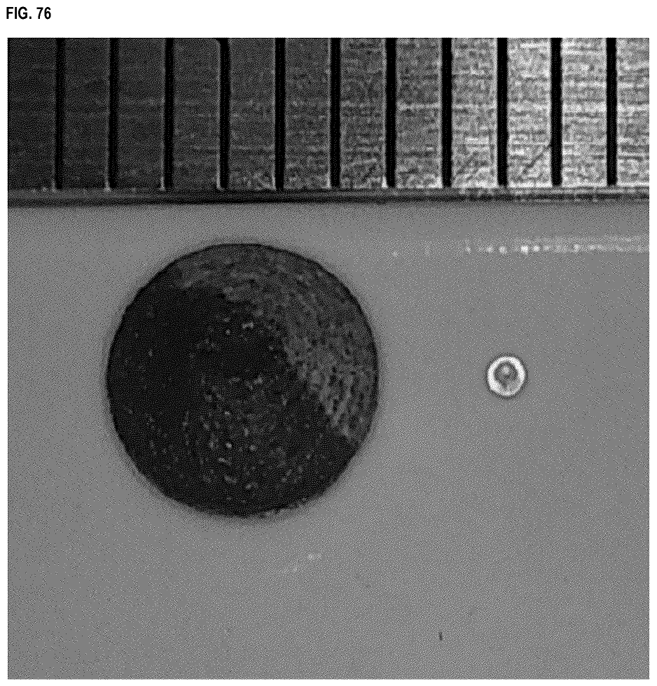

Using an OPQPQ digital microscope, and as shown in FIG. 76, the GRP was imaged in relation to a ruler with millimeter tick marks, and demonstrated a size of about 0.7 mm in comparison to a GRP prototype (right, 4.8 mm), as described in Example 5 and illustrated in FIGS. 73A-73C and 74A-74I. The GRP (pictured left in FIG. 76) is approximately 6-fold smaller in scale. Both prototypes were printed with the same design, but at different scales and with different materials. The GRP of FIGS. 75-76 illustrates the ability to use 3D printing to generate particles on the sub-mm scale.

### Example 6: Manufacture of a Fin-Shaped Gravity Responsive Particle (GRP) by 3D Printing

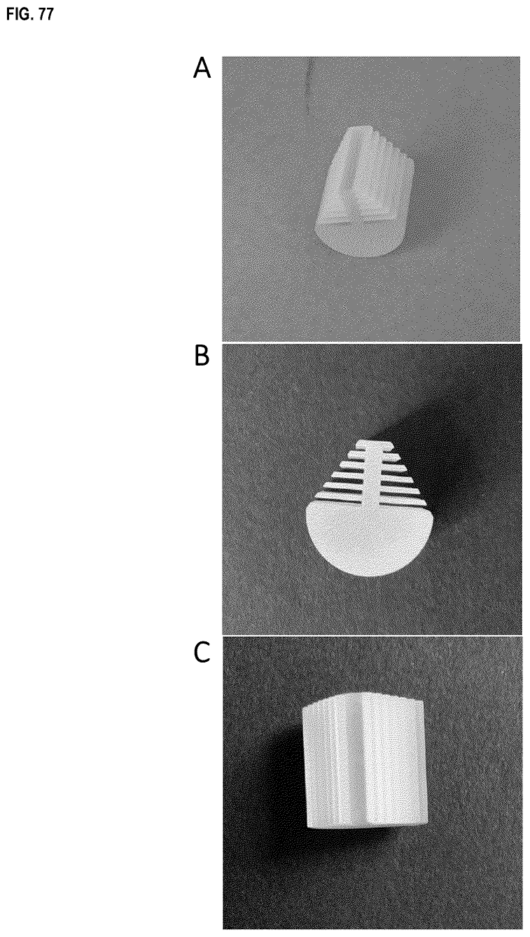

A fin-shaped GRP prototype was 3D-printed using stereolithography (SLA) method using polycarbonate-like translucent/clear (ACCURA 60). The prototype, e.g., as illustrated in FIGS. 11A-11D, and characterized by photography in FIGS. 77-77C, had a half-cylindrical bottom portion with a diameter of 1 cm and a depth of 1 cm. The central column was 1.25 cm wide and 5.69 mm tall. Each fin and gap between fins was 0.44 mm wide. The top surface of the topmost fins are 0.625 mm long, each extending outward 1.25 mm from the center. The outer edge of the fins and their corresponding lengths follow a diagonal line from the top fin to the outer point of the half cylinder that the bottommost fins rest upon. The prototype was imaged using a dual 12 megapixel (MP) wide-angle camera (f/1.8 aperture).

### Example 7: Manufacture of a Wide-Top, Fin-Shaped Gravity Responsive Particle (GRP) by 3D Printing

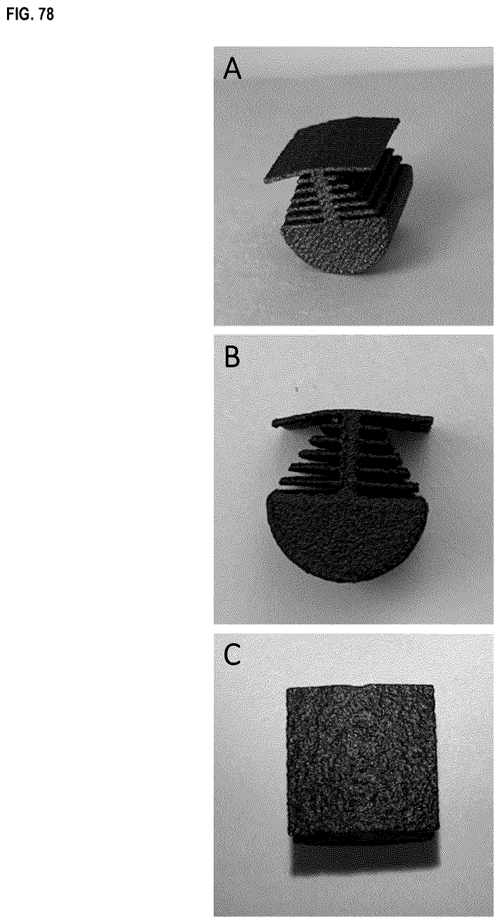

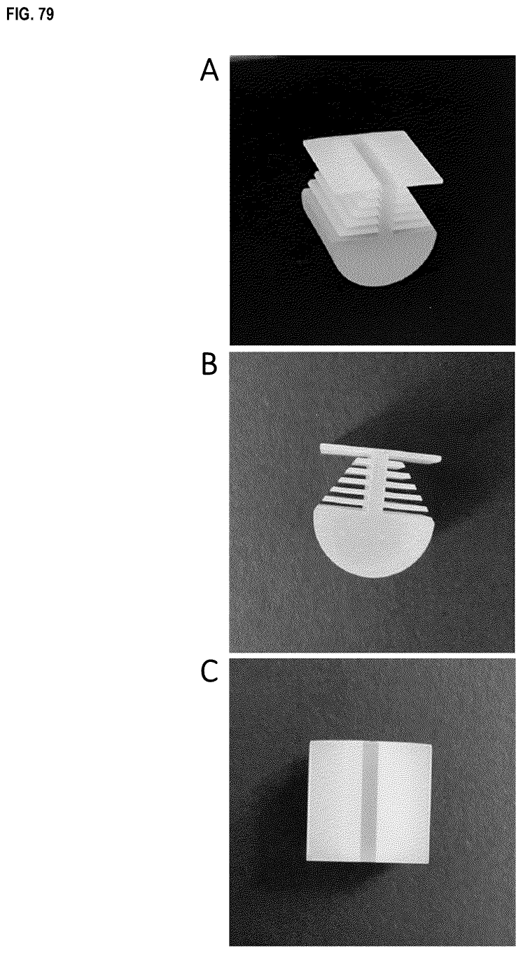

Fin-shaped GRP particles were 3D-printed using a using a Multi Jet Fusion (MJF) 3D printer with polyamide 12 40% glass-filled back (PA12; Nylon 12) (FIGS. 78A-78C), or by using a stereolithography (SLA) method using polycarbonate-like translucent/clear (ACCURA 60) (FIGS. 79A-79C). Each particle was imaged using a dual 12 megapixel (MP) wide-angle camera (f/1.8 aperture).

The prototype, e.g., as illustrated in FIGS. 36A-36D, had a half-cylindrical bottom portion with a diameter of 1 cm and a depth of 1 cm. The central column was 1.25 cm wide and 5.69 mm tall. Each fin and gap between fins was 0.44 mm wide. The topmost fins were 4.375 mm long, extending outward 5 mm from the center, spanning the 1 cm diameter. The next set of fins down from the topmost set was 1.2 mm long. The outer edge of the fins and their corresponding lengths follow a diagonal line from the second topmost fins to the outer point of the half cylinder of the bottommost fins.

The 3D-printed particles, e.g., as illustrated in FIGS. 78A-78C and FIGS. 79A-79C, demonstrated the effectiveness of Multi Jet Fusion (MJF) and stereolithography (SLA) methods in manufacturing fin-shaped GRP prototypes. As imaged, prototypes are viewed as resting on a horizontal surface.

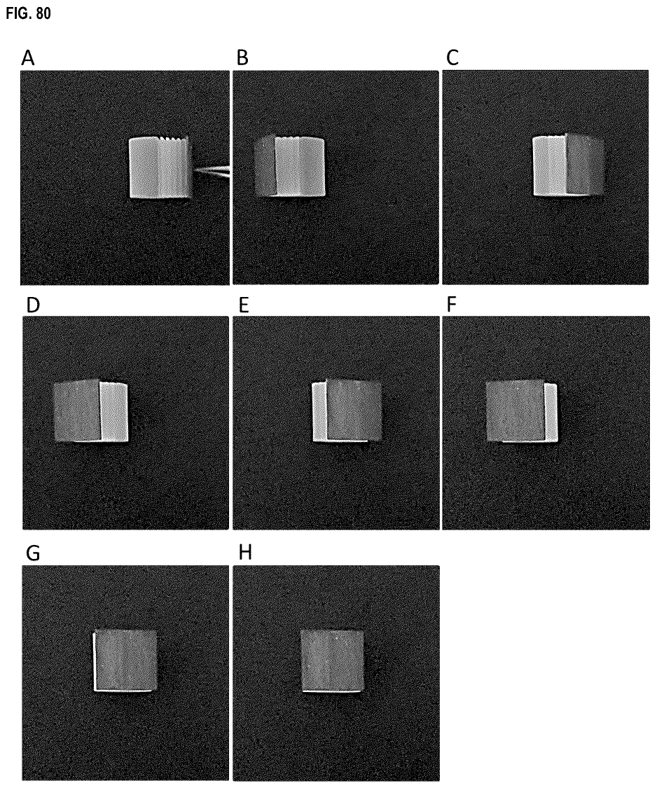

The 3D-printed GRP of FIGS. 79A-79C, as illustrated in FIGS. 80A-80H, had its top painted with a thin layer acrylic paint, which is shown oscillating in motion chronologically from a top-down view. As shown in FIG. 80A, the prototype could be fully tipped to its right by a pair of tweezers, where FIG. 80B shows the prototype wobble to its left, which oscillated in a back-and-forth throughout its full 7.07 second wobble cycle until it rests at equilibrium in FIG. 80H.

### Example 8: Manufacture of Sawtooth Gravity Responsive Particles (sGRPs) by 3D Printing

An additive manufacturing, 3D printing-based approach was used to manufacture sGRP prototypes from the STL image models shown in FIGS. 37A-37D, 39A-39D, and 40A-40D. Each prototype was imaged using a dual 12 megapixel (MP) wide-angle camera (f/1.8 aperture).

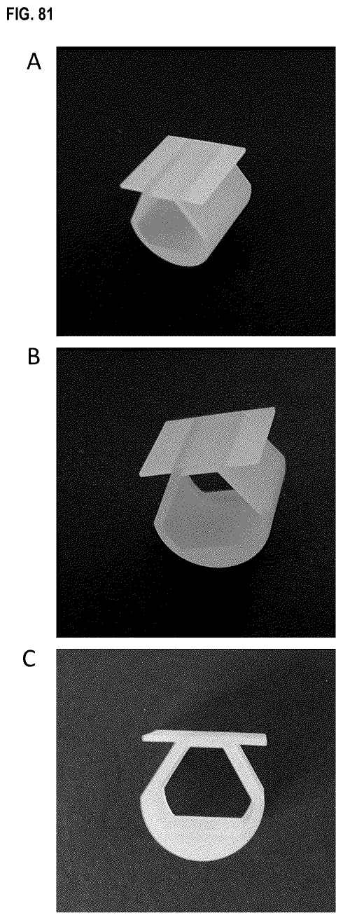

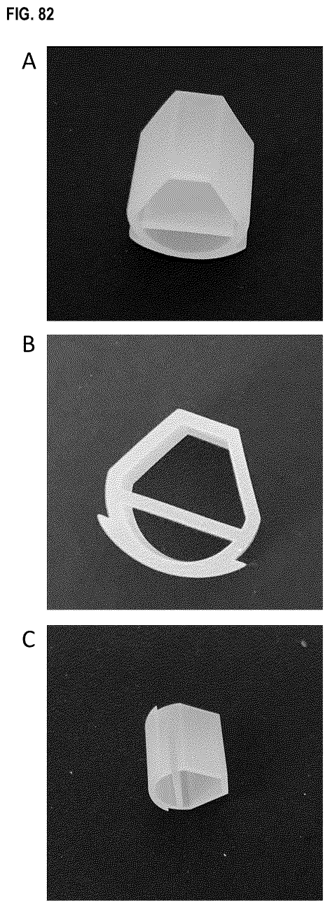

FIGS. 81A-84C illustrate a high-fidelity synthesis of the design articulated in FIG. 37. As shown in FIGS. 82A-82C, an sGPR was designed from the STL images depicted in FIGS. 39A-39D which exhibited tilting behavior through at least one axis. A single jagged detent on each side was added to act as a catch which stabilized the sGRP on its side when tipped past its critical angle. This prototype was printed using stereolithography with Polycarbonate-Like Translucent/Clear (Accura 60). The design had one set of detents or “sawteeth” added to each side. The sawteeth were made by adding a portion of an elliptic cylinder with a curvature slightly wider than the initial shape that cut off 2 mm in height with a horizontal path that went back to the initial cylinder.

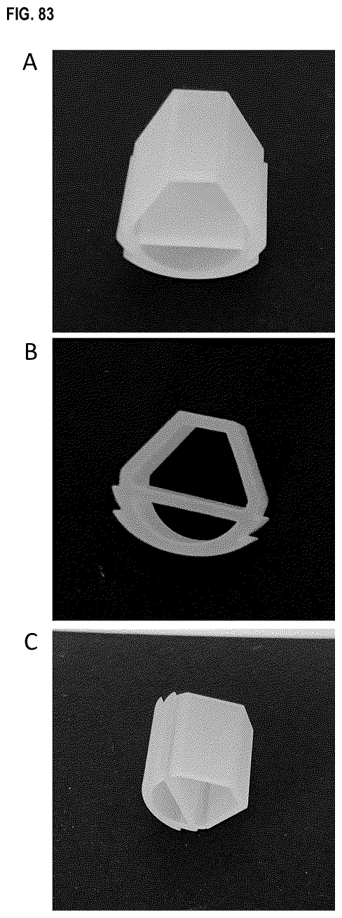

As shown in FIGS. 83A-83C, an sGPR was designed from the STL images depicted in FIGS. 40A-40D which exhibited vertical rectangles that showed the three flat surfaces of the upper half's walls. Two jagged detents on each side were added to act as a catch which stabilized the sGRP on its side when tipped past its critical angle. This prototype was printed using stereolithography with Polycarbonate-Like Translucent/Clear (Accura 60). The design had two sets of detents or “sawteeth” added to each side. The sawteeth were made by adding a portion of an elliptic cylinder with a curvature slightly wider than the initial shape that cuts off. The first started from the bottom and cut off 2 mm in height with a horizontal path that went back to the initial cylinder. The second started 0.75 mm up from the bottom and had a curvature in between the bottom and cylinder that cut off at 3.7 mm in height.

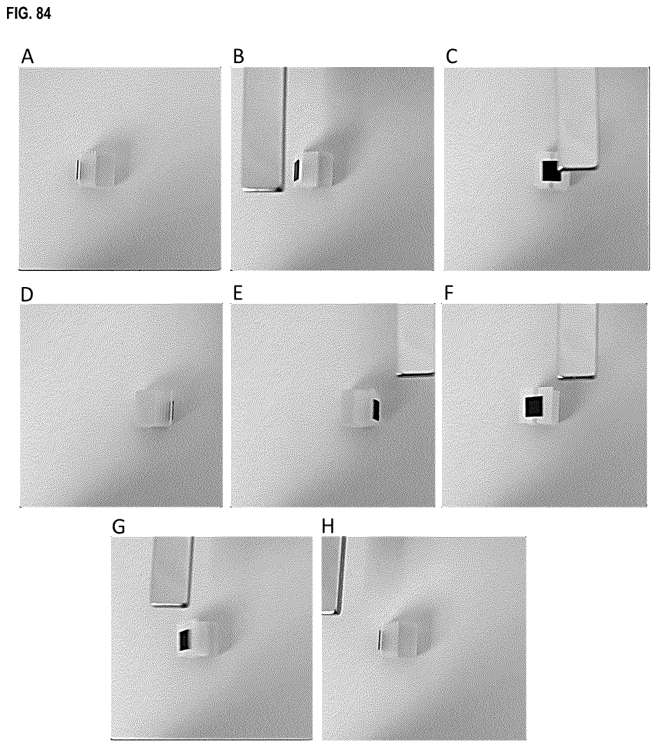

As shown in FIGS. 84A-84H, a sGRP was designed from the STL images depicted in FIGS. 36A-36D. The prototype was printed using stereolithography with Polycarbonate-Like Translucent/Clear (Accura 60). The design had a horizontal top bar placed across the center of the prototype, which added a solid section from the bottom of the cylinder up to a horizontal plane 2.172 mm above the bottom of the prototype. The top extended to cover a 1 cm×1 cm area with a thickness of 0.4 mm. As shown in FIGS. 84A-84H, the particle was painted on one side with a thin layer of acrylic paint with a medium sized magnet affixed to its top. The images in FIGS. 84A-84H depict the motion chronologically from a top-down view. In this instance, the magnet had a mass that lifted the center of mass above the radius of curvature. Accordingly, FIG. 84A depicts the particle rested on its left side. FIGS. 84B-84D show a magnetic stimulus applied using a small bar magnet moving from left to right, slightly above the particle. As the magnet moved, the magnetic force tilted the prototype up until its critical angle, as seen in FIG. 84D, after which the prototype tipped over onto its right side where it remained at rest without the presence of a magnet in FIG. 84E. FIGS. 84F-84H again show a process where the magnet moved the prototype from right to left, until the prototype tipped past its critical angle and rested once again on its left side in FIG. 84H.

### Example 9: Magnetically-Actuated Gravity-Responsive Particle (GRP)

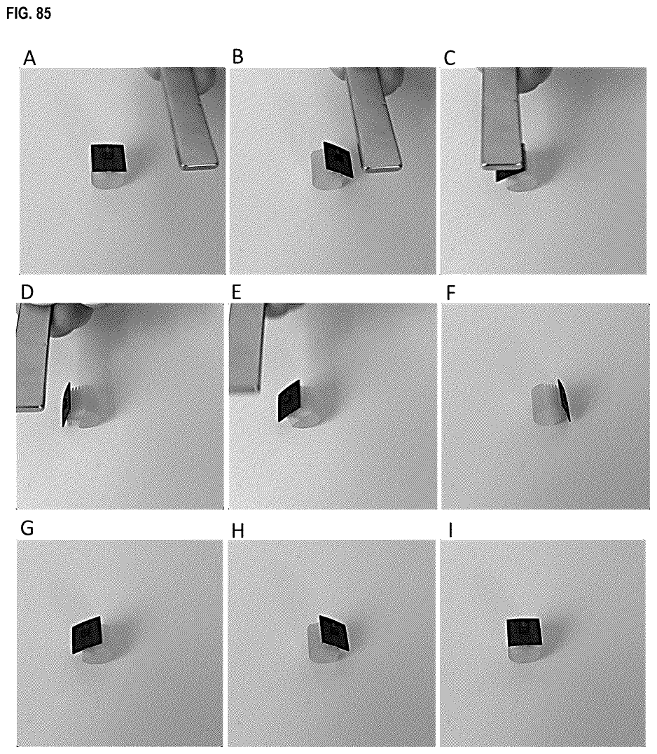

The prototype of FIG. 78, e.g., as illustrated in a top-down view in FIGS. 85A-85H, had its top painted with a thin layer acrylic paint with a thin magnetic material affixed to the top portion. The paint and magnet are light enough that the center of mass stays below the radius of curvature and the prototype stays upright at equilibrium, e.g., as shown in FIG. 85A. The prototype could be drawn to either side using a magnet to not affect its motion, e.g., as shown in FIGS. 85B-85D. As the magnet was moved across the prototype, it tipped the to the side. FIG. 85E-H illustrate that as the magnet was pulled away to no longer exert a magnetic field, that the prototype was capable of oscillating in a wobble motion, showing various points of directional change throughout the wobble cycle until the prototype rested at equilibrium in FIG. 85I.

### Example 10: Fabrication of an Encapsulated Gravity Responsive Particle (GRP) Array

GRPs, for example as manufactured in Example 1, can be further manufactured into an array contained within a top substrate and a bottom substrate, e.g., as illustrated in FIG. 33. FIG. 47 illustrates the fabrication of one such array, with tilted side and top views of the components and assemblies. FIG. 47A illustrates the fabrication of one such array with a tilted side and top views of non-limiting components and assemblies. For example, FIG. 47A shows a square, bottom substrate with a 3×3 array of posts. This bottom substrate can be the surface of an object, can be opaque, semi-transparent, or can be transparent. The bottom substrate can be any shape, and can contain any number of posts, indentations, and the like, arranged in any pattern of spacing. Such a substrate can be fabricated by 3D printing, or can be manufactured using various forms of lithography, by microcontact printing, by injection molding, by micro-injection molding, or by any other method as described herein. The posts can be the same material as the bottom substrate and/or can be the same color; alternatively, the posts can be a different material than the bottom substrate and/or can be a different color. The posts can be transparent, semi-transparent, or opaque. In reference to FIG. 47B, GRPs can rest at stationary equilibrium within the four spaces that are bounded by posts, for example, the 4 GRPs bounded by the 9 posts in the square pattern. Several methods can be used for placing GRPs into arrays, e.g., into the post-containing substrate, including in non-limiting examples, placement, settling, shaking, gravity settling, etc. The posts can be slightly taller than the GRPs, for example for affixing the top substrate to the posts; however, as described above, any height of posts can be used by which motion of the GRPs is not impacted by the presence of a top substrate.

After the GRPs are placed, a transparent top substrate can be added, e.g., as shown in FIGS. 47C and 47D. Contact can be made between the top substrate and the posts, where the top substrate can be held in place by glue, adhesive, pressure, adhesion, or by any other means by which two materials can be fastened. The top substrate can be composed of a material that is transparent to at least a portion of the visible EM spectrum (e.g., transparent to light in the range of 350 nm to 800 nm), including in non-limiting examples, glass, plastic, quartz, sapphire, gel, etc. The top substrate can be a variety of thicknesses, as described herein. The top substrate can be planar or non-planar, and can adopt a variety of shapes, e.g., such as conforming to the surface of an object the GRPs are intended to cover.

In reference to FIG. 47D, the assembly of FIG. 47C is illustrated with the GRPs tilted. A force can be imparted (e.g., a jerk, shake, tilt, etc.) causing the GRPs to move (e.g., tilt) between the posts to the right; however, the GRPs can equally tilt between any pair of posts (e.g., to the left, toward the top, or toward the bottom). Depending upon the choice of GRPs used, an observer looking through the top substrate and an observer looking through the bottom substrate will observe the same blend or pattern of colors; however, such as with the GRPs depicted in FIG. 33, the array can be manufactured such that the observers looking through the top substrate and the bottom substrate could observe different colors.

### Example 11: Gravity Responsive Particle (GRP)-Based Mass Sensor

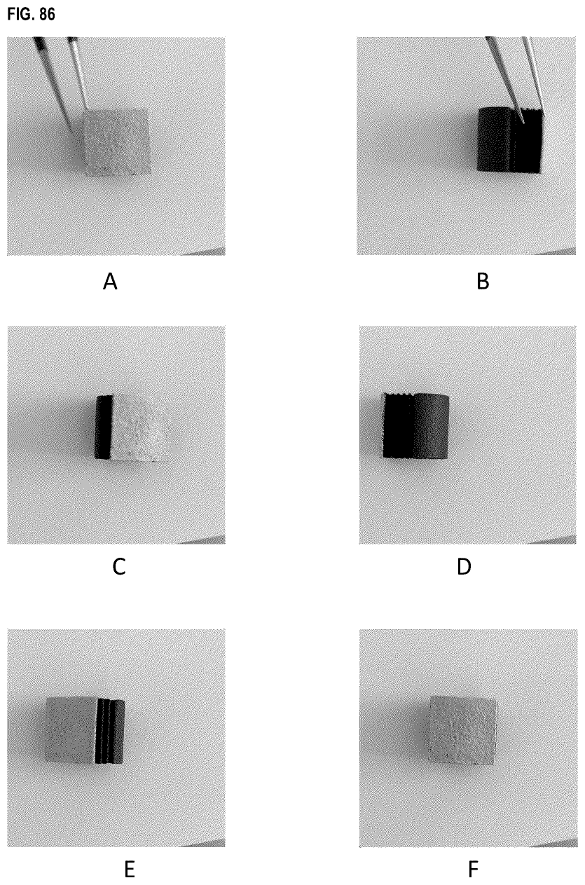

To demonstrate the principle of mass-based sensing based on GRPs, the center of mass a fin-shaped GRP was changed by adding mass to the top section of the particle, causing a transition from stable wobble motion in response to gravity to an unstable (permanent) tipped state. FIGS. 86A-86F depict photographic images from a top-down view of a fin-shaped GRP with its top painted with one (1) thin layer of white acrylic paint, shown oscillating in motion chronologically. FIG. 86A shows the GRP at rest. FIG. 86B shows the GRP fully tipped to its right by a pair of tweezers. The tip raises the center of gravity of the GRP, but because the center of mass is below the radius of curvature, the particle wobbles. FIGS. 86C-86E show the oscillatory motion resulting from removal of the tweezers from the tipped GRP of FIG. 86B. FIG. 86F shows the GRP after return to equilibrium.

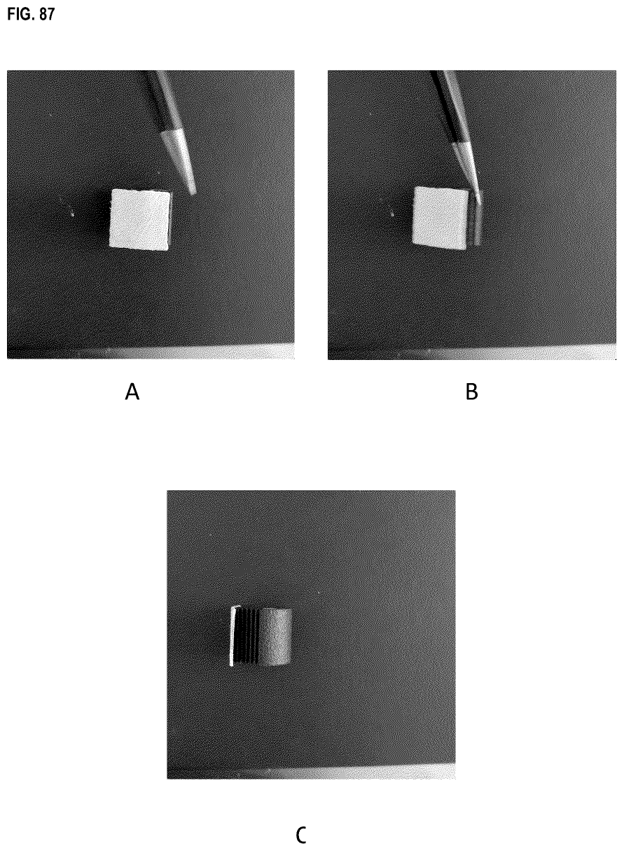

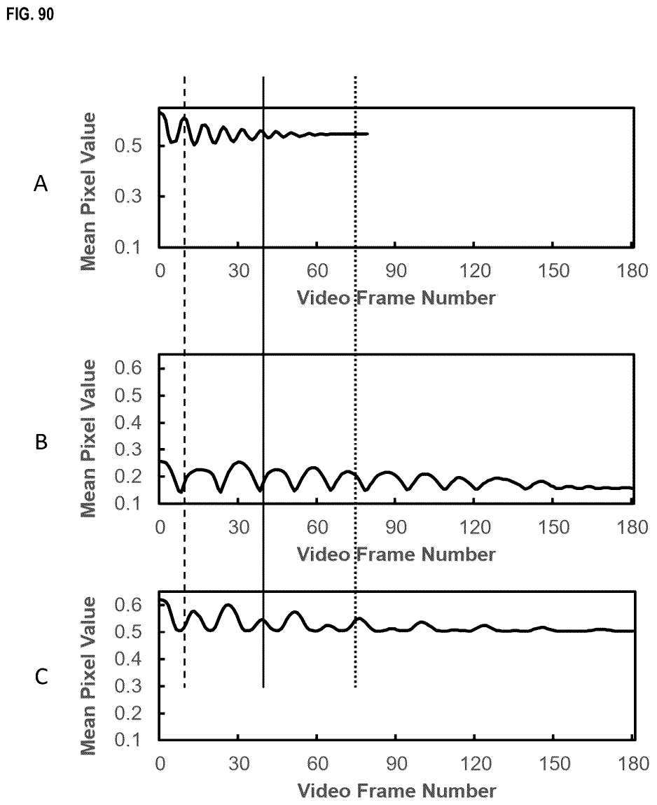

FIGS. 87A-87C depict photographic images of the fin-shaped GRP of FIG. 86, with four (4) additional thin layers of acrylic white paint painted on its top, to make a total of five (5) layers. As shown in FIG. 87A-87C, the mass of the additional four layers of optical agent (paint) to the top surface of the GRP was sufficient to change the GRP's center of mass relative to its radius of curvature such that when tilted from equilibrium far enough from its center, past the critical angle, the prototype titled and rested on its side, unable to wobble back due to the heavier top from the layers of paint, e.g., as illustrated in FIG. 90C. The color of the resting particle (at equilibrium) with one layer of paint before (FIG. 86A) and after (FIG. 86F) after a mechanical stimulation is white in both cases; in contrast, the after the addition of extra mass, the particle is white prior to stimulation (FIG. 87A), but black after stimulation (FIG. 87C).

The data, inter alia, demonstrate that GRPs are suitable as mass-based sensors where differences in mass on the surface of GRPs, relative to the center of mass and radius of curvature, effect the wobble characteristics, which are tunable based on the design of the GRP.

### Example 12: Machine-Readable Gravity Responsive Particle

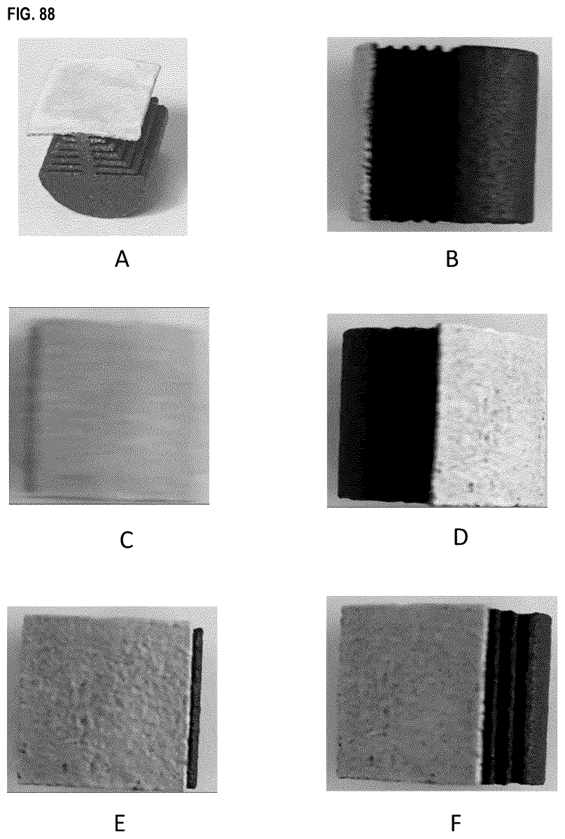

To demonstrate machine readability of GRPs, a black GRP with a white painted top was put into motion. FIG. 88A depicts a non-limiting image of a GRP with a painted top taken from an upwards forward angle. The motion was initiated by manually tipping the GRP to the edge of its range of motion using a pair of tweezers, followed by release. FIGS. 88B-88F show various screenshots from a video taken from a top-down view used to track the color change of a GRP throughout its 7-second movement cycle.

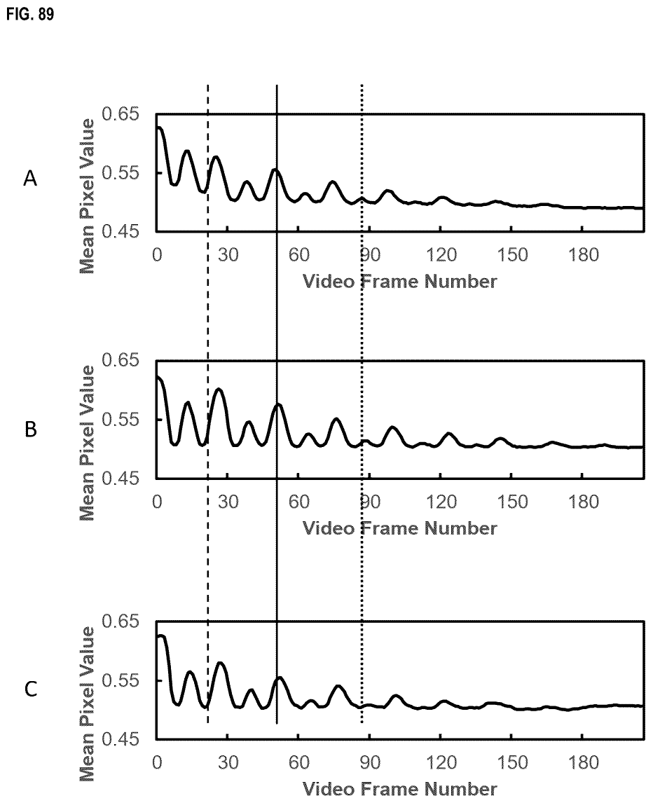

For each frame of a video capturing the movement of the black/white GRP of FIGS. 88A-88F throughout its movement, the mean pixel value was calculated (pure black=1, pure white=0). The resulting plot of mean pixel value as a function of video frame number (e.g., time) is shown averaged from three replicated with aligned video in FIGS. 89A-89C.

The data of FIGS. 89A-89C demonstrate in several respects: (1) the plots have the same general shape, showing oscillation between mean pixel values of 0.5 and 0.65, where this value is alterable with different GRP shapes and colors; (2) the spacing between peaks and troughs of the functions is identical, both within a given plot and between plots for the GRP tested; (3) the overall duration of wobble movement between particles is similar; and (4) any given frame number (e.g., using the 3 plotted guide lines as non-limiting examples), the relative value of the mean pixel intensity is approximately the same (e.g., peak, trough, rising, falling).

The experiment was repeated using three different sized and shaped GRPs, with the results plotted in FIG. 90A-90C. The experiments were performed using the same video capture device and in triplicate. The plots of different GRPs demonstrate different capturable signals. The duration of the wobbles for each different GRP is different, as is the dynamic range of the mean pixel values, the spacing of the peaks/troughs, and the relative value of mean pixel intensity at a given frame number.

The data, inter alia, demonstrate that GRPs are suitable to generate machine-readable signals, e.g., as shown in FIGS. 89A-89C and 90A-90C and that the signals are tunable and unique based on the wobble characteristic of a given design of GRP, but remain identical for each particle of a given design, and distinct from movement patterns of GRPs with different designs.

### Definitions

The following definitions are used in connection with the disclosure disclosed herein. Unless defined otherwise, all technical and scientific terms used herein have the same meaning as commonly understood to one of skill in the art to which this disclosure belongs.

As used herein, “a,” “an,” or “the” can mean one or more than one.

Further, the term “about” when used in connection with a referenced numeric indication means the referenced numeric indication plus or minus up to 10% of that referenced numeric indication. For example, the language “about 50” covers the range of 45 to 55.

As referred to herein, all compositional percentages are by weight of the total composition, unless otherwise specified. As used herein, the word “include,” and its variants, is intended to be non-limiting, such that recitation of items in a list is not to the exclusion of other like items that may also be useful in the compositions and methods of this technology. Similarly, the terms “can” and “may” and their variants are intended to be non-limiting, such that recitation that an embodiment can or may comprise certain elements or features does not exclude other embodiments of the present technology that do not contain those elements or features.

Although the open-ended term “comprising,” as a synonym of terms such as including, containing, or having, is used herein to describe and claim the disclosure, the present disclosure, or embodiments thereof, may alternatively be described using alternative terms such as “consisting of” or “consisting essentially of.”

In embodiments, as used herein, the words “preferred” and “preferably” refer to embodiments of the technology that afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the technology.

In embodiments, the disclosure is directed to the following embodiments:

Embodiment 1. A gravity responsive particle (GRP) comprising: a shape and a center of mass (CoM) that enables motion between a plurality of positions when a force is applied, wherein the shape and the CoM enables relaxation to a stationary position from the plurality of positions from gravitational force; and one or more optically active agents, wherein the GRP exhibits a change in an optical property of the one or more optically active agents as a function of the motion between the plurality of positions.

Embodiment 2. The gravity responsive particle of embodiment 1, wherein the GRP is about or at least about 20 nm to about or at least about 10 mm in size.

Embodiment 3. The gravity responsive particle of embodiment 1 or 2, wherein the GRP is about or at least about 20 nm, about or at least about 50 nm, about or at least about 100 nm, about or at least about 200 nm, about or at least about 300 nm, about or at least about 400 nm, about or at least about 500 nm, about or at least about 600 nm, about or at least about 700 nm, about or at least about 800 nm, about or at least about 900 nm, about or at least about 1 μm, about or at least about 5 μm, about or at least about 10 μm, about or at least about 50 μm, about or at least about 100 μm, about or at least about 200 μm, about or at least about 300 μm, about or at least about 400 μm, about or at least about 500 μm, about or at least about 600 μm, about or at least about 700 μm, about or at least about 800 μm, about or at least about 900 μm, about or at least about 1 mm, about or at least about 2 mm, about or at least about 3 mm, about or at least about 4 mm, about or at least about 5 mm, or about or at least about 10 mm.

Embodiment 4. The gravity responsive particle of any one of embodiments 1-3, wherein the GRP comprises a size in a range from about 2 μm to about 200 μm.

Embodiment 5. The gravity responsive particle of any one of the preceding embodiments, wherein the shape comprises one or more geometries.

Embodiment 6. The gravity responsive particle of embodiment 5, wherein the one or more geometries comprises one or more of a roly-poly shape, fin-shaped, mushroom-shaped, truncated teardrop shape, champagne flute shape, wine glass shape, round-bottomed doll shape, tilting doll shape, tumbler shape, wobbly toy shape, wobble doll shape, round-bottomed toy shape, egg-shaped shape, paraboloid, prolate hemispheroid, oblate hemispheroid, hemispherical, elliptical, trigonal pyramid, pentagonal pyramid, hexagonal pyramid, a regular shape with a truncated tops, a truncated square pyramid, a truncated cone, and/or a truncated cone where the top plane and bottom plane are not parallel.

Embodiment 7. The gravity responsive particle of any one of the preceding embodiments, wherein the shape is a 3-dimensional shape.

Embodiment 8. The gravity responsive particle of embodiment 7, wherein the 3-dimensional shape is concave.

Embodiment 9. The gravity responsive particle of embodiment 7, wherein the 3-dimensional shape is convex.

Embodiment 10. The gravity responsive particle of any one of the preceding embodiments, wherein the shape comprises a surface area ratio of a first optically active agent to a second optically active agent.

Embodiment 11. The gravity responsive particle of embodiment 10, wherein the surface area ratio of the first optically active agent to the second optically active agent; or the surface area ratio of the second optically active agent to the first optically active agent is about or at least about 0.1, about or at least about 0.2, about or at least about 0.3, about or at least about 0.4, about or at least about 0.5, about or at least about 0.6, about or at least about 0.7, about or at least about 0.8, about or at least about 0.9, or about or at least about 1.0.

Embodiment 12. The gravity responsive particle of any one of the preceding embodiments, wherein the shape is asymmetrical.

Embodiment 13. The gravity responsive particle of one any embodiments 1-11, wherein the shape comprises one axis of symmetry, two axes of symmetry, three axes of symmetry, or four or more axes of symmetry.

Embodiment 14. The gravity responsive particle of any one of embodiments 1-11, wherein the shape comprises at least one plane of symmetry.

Embodiment 15. The gravity responsive particle of any one of embodiments 1-11, wherein the shape comprises glide reflection symmetry.

Embodiment 16. The gravity responsive particle of any one of the preceding embodiments, wherein the GRP comprises an internal portion.

Embodiment 17. The gravity responsive particle of embodiment 16, wherein the internal portion comprises a material having a singular specific gravity and/or density.

Embodiment 18. The gravity responsive particle of embodiment 16, wherein the internal portion comprises at least two materials having different specific gravities and/or densities.

Embodiment 19. The gravity responsive particle of any one of embodiments 16-18, wherein the internal portion comprises at least a portion that is hollow and/or porous.

Embodiment 20. The gravity responsive particle of any one of embodiments 16-19, wherein the internal portion comprises at least a portion that comprises a gyroid infill, grid infill, cubic infill pattern, triangular infill, octet infill, lightning infill, and/or a combination thereof.

Embodiment 21. The gravity responsive particle of any one of the preceding embodiments, comprising two or more optically active agents, each exhibiting at least one distinct optical state.

Embodiment 22. The gravity responsive particle of any one of the preceding embodiments, wherein the force that is applied comprises a mechanical force that is not a gravitational force.

Embodiment 23. The gravity responsive particle of any one of embodiments 1-21, wherein the force that is applied comprises a gravitational force.

Embodiment 24. The gravity responsive particle of any one of the preceding embodiments, wherein the motion is a pendulum motion oscillating between the plurality of positions and the stationary position.

Embodiment 25. The gravity responsive particle of embodiment 24, wherein the oscillating motion comprises a wobble motion comprising oscillations around a pitch axis and a yaw axis.

Embodiment 26. The gravity responsive particle of any embodiment 25, wherein the wobble motion comprises movement through the several orientations relative to a direction of a force gravity.

Embodiment 27. The gravity responsive particle of any one of the preceding embodiments, wherein the motion is a tilt displacement motion between the plurality of positions and the stationary position.

Embodiment 28. The gravity responsive particle of any one of the preceding embodiments, wherein the motion is an angular displacement motion between the plurality of positions and the stationary position.

Embodiment 29. The gravity responsive particle of any one of the preceding embodiments, wherein the motion occurs along a plane in two dimensions and/or in three dimensions.

Embodiment 30. The gravity responsive particle of any one of the preceding embodiments, wherein the center of mass (CoM) resides below a radius of curvature.

Embodiment 31. The gravity responsive particle of any one of embodiments 1-29, wherein the center of mass (CoM) does not reside below a radius of curvature.

Embodiment 32. The gravity responsive particle of any one of the preceding embodiments, wherein the GRP has a ratio of distance between a center of curvature and the location of vertices (μ) of about or at least about 1/8, about or at least about 1/7, about or at least about 1/6, about or at least about 1/5, about or at least about 1/4, about or at least about 2/7, about or at least about 1/3, about or at least about 3/8, about or at least about 2/5, about or at least about 3/7, about or at least about 1/2, about or at least about 4/7, about or at least about 3/5, about or at least about 5/8, about or at least about 2/3, about or at least about 5/7, about or at least about 3/4, about or at least about 4/5, about or at least about 5/6, or about or at least about 6/7.

Embodiment 33. The gravity responsive particle of any one of the preceding embodiments, wherein the GRP comprises two optically active agents, three optically active agents, four optically active agents, or five or more optically active agents.

Embodiment 34. The gravity responsive particle of any one of the preceding embodiments, wherein the one or more optically active agents comprise a color in the visible electromagnetic spectrum comprising an extinction, reflection, or scattering at a wavelength from about or at least about 350 nm to about or at least about 800 nm; and/or wherein the GRP exhibits no extinction, reflection, or scattering at a wavelength from about or at least about 350 nm to about or at least about 800 nm during the stationary position or during at least a portion of the motion between the plurality of positions; and/or wherein the GRP only exhibits extinction, reflection, or scattering at a wavelength from about or at least about 350 nm to about or at least about 800 nm during the stationary position or during at least a portion of the motion between the plurality of positions.

Embodiment 35. The gravity responsive particle of embodiment 34, wherein the color is one or more of white, black, red, orange, yellow, green, blue, indigo, and violet.

Embodiment 36. The gravity responsive particle of any one of the preceding embodiments, wherein the one or more optically active agents comprises a dye.

Embodiment 37. The gravity responsive particle of embodiment 36, wherein the dye comprises one or more of Rhodamine B, Congo Red, Crystal Violet, Methylene Blue, Acridine Orange, Nile Red, Malachite Green, Eosin Y, Cresol Red, Fluorescein, and Indigo.

Embodiment 38. The gravity responsive particle of any one of the preceding embodiments, wherein the one or more optically active agents comprises a pigment.

Embodiment 39. The gravity responsive particle of embodiment 38, wherein the pigment comprises one or more of Titanium White (PW6), Zinc White (PW4), Carbon Black (PBk7), Mars Black (PBk11), Iron Oxide Red (PR101), Cadmium Red (PR108), Alizarin Crimson (PR83), Cadmium Orange (PO20), Cadmium Yellow (PY35),Lemon Yellow (PY3), Chromium Green Oxide (PG17), Phthalo Green (PG7), Ultramarine Blue (PB29), Cobalt Blue (PB28), Cerulean Blue (PB35), Prussian Blue (PB27), Burnt Sienna (PBr7), Raw Umber (PBr7), Raw Sienna (PBr7), and Yellow Ochre (PY43).

Embodiment 40. The gravity responsive particle of embodiment 38, wherein the pigment is an organic pigment.

Embodiment 41. The gravity responsive particle of embodiment 38, wherein the pigment is an inorganic pigment.

Embodiment 42. The gravity responsive particle of embodiment 40 or 41, wherein the organic pigment or inorganic pigment is a white pigment.

Embodiment 43. The gravity responsive particle of embodiment 42, wherein the white pigment is one or more of lead white (2PbCO₃·Pb(OH)₂), kaolin, silica (SiO₂), titanium dioxide (TiO₂/rutile and anatase), zinc oxide (ZnO), zinc sulfide (ZnS), and lithopone (ZnS+BaSO₄).

Embodiment 44. The gravity responsive particle of embodiment 40 or 41, wherein the organic pigment or inorganic pigment is a black pigment.

Embodiment 45. The gravity responsive particle of embodiment 44, wherein the black pigment is one or more of coal (charcoal), groutite (α-MnOOH), manganite (γ-MnOOH), hausmannite (Mn₃O₄), carbon black, iron oxide black (Fe₃O₄), and spinel black (CuCr₂O₄).

Embodiment 46. The gravity responsive particle of embodiment 38 or 39, wherein the organic pigment or inorganic pigment is a colored pigment.

Embodiment 47. The gravity responsive particle of embodiment 46, wherein the colored pigment comprises a yellow pigment.

Embodiment 48. The gravity responsive particle of embodiment 47, wherein the yellow pigment comprises one or more of yellow ochre (α-FeOOH), auric pigment (As₂S₃), lead ochre (PbO), lead tin yellow (Pb₂SnO₄, PbSn₂SiO₇), Naples yellow (Pb(SbO₃)₂), zinc yellow (Zn₂CrO₄), Indian yellow (C₁₉H₁₆O₁₀), iron oxide yellow (α-FeOOH), chromium titanium yellow ((Ti,Cr,Sb)O₂), nickel titanium yellow ((Ti,Ni,Sb)O₂), lead yellow (PbCrO₄), cadmium yellow (CdS), and bismuth yellow (BiVO₄).

Embodiment 49. The gravity responsive particle of embodiment 46, wherein the colored pigment comprises a red pigment.

Embodiment 50. The gravity responsive particle of embodiment 49, wherein the red pigment comprises one or more of red ocher (α-Fe₂O₃), Terra di Siena (α-Fe₂O₃), vermilion (HgS), lead red (Pb₃O₄), alizarin madder varnish, alizarin red (C₁₄H₈O₄), iron oxide red (α-Fe₂O₃), molybdate red (Pb(Cr,S,Mo)O₄), and cadmium red (Cd(S,Se).

Embodiment 51. The gravity responsive particle of embodiment 46, wherein the colored pigment comprises a green pigment.

Embodiment 52. The gravity responsive particle of embodiment 51, wherein the green pigment comprises one or more of green earth (Fe silicates), Schweinfurt green (C₄H₆As₆Cu₄O₁₆), chromium oxide green (Cr₂O₃), chromium oxide hydrate green (CrOOH), and cobalt green (Co₂TiO₄).

Embodiment 53. The gravity responsive particle of embodiment 46, wherein the colored pigment comprises a blue pigment.

Embodiment 54. The gravity responsive particle of embodiment 53, wherein the blue pigment comprises one or more of lazurite (lapis lazuli), Egyptian blue (CaCuSi₄O₁₀), azurite (2CuCO₃·Cu(OH)₂), malachite (CuCO₃·Cu(OH)₂), cobalt blue (CoAl₂O₄), Cobalt blue (CoAl₂O₄), ultramarine blue: (Na₆Al₆Si₆O₂₄ (NaSn)), and iron blue (K[FeIIIFeII(CN)₆]·xH₂O).

Embodiment 55. The gravity responsive particle of embodiment 46, wherein the colored pigment comprises a brown pigment.

Embodiment 56. The gravity responsive particle of embodiment 55, wherein the brown pigment comprises one or more of burnt umber (Fe₂O₃·xMnO₂), brown ocher (α-Fe₂O₃+Mn oxides), and limonite (mixture of different Fe oxides).

Embodiment 57. The gravity responsive particle of embodiment 56, wherein the pigment is one or more of an oxide or oxide hydroxide pigment (TiO₂, ZnO, α-Fe₂O₃, α-FeOOH, γ-Fe₂O₃, Fe₃O₄, Cr₂O₃, CrOOH, PbO, Pb₃O₄, Mn₃O₄, —MnOOH, Sb₂O₃), a complex oxide pigment (CoAl₂O₄, CuCr₂O₄, Co₂TiO₄, (Ti,Ni,Sb)O₂, (Ti,Cr,Sb)O₂), a carbonate hydroxide pigment (2PbCO₃·Pb(OH)₂, 2CuCO₃·Cu(OH)₂, CuCO₃·Cu(OH)₂), a sulfide/selenide pigment (ZnS, CdS, Cd(S,Se), CdSe, γ-Ce₂S₃, HgS, As₂S₃), a chromate/molybdate pigment (PbCrO₄, Pb(Cr,S)O₄, Pb(Cr,S,Mo)O₄, ZnCrO₄, BaCrO₄, SrCrO₄), a vanadate pigment (BiVO₄, 4BiVO₄·3BizMoO₆), a stannate pigment (Pb₂SnO₄, PbSn₂SiO₇, CozSnO₄, CoSnO₃), a phosphate pigment (Co₃(PO₄)₂), an antimonate pigment (Pb(SbO₃)₂), an arsenate pigment (Cu(AsO₃)₂), an ultramarine pigment (Na₆Al₆Si₆O₂₄(NaSn)), a hexacyanidoferrate/hexacyanoferrate pigment (K[FeIIIFeII(CN)₆]·xH₂O (x=14-16)), an oxonitride pigment (CaTaO₂N, LaTaON₂), an elemental-based pigment (C, Al, Cu, Cu/Zn, Au), a spinel-based pigment, and a rutile-based metal pigment.

Embodiment 58. The gravity responsive particle of embodiment 41, wherein the inorganic pigment is one or more of a transparent effect pigment, goniochromatic pigments, pearlescent pigment, metallic pigment, interference pigment, metallic effect pigment, fluorescent pigment, luminescent pigment, phosphorescent pigment, magnetic pigment, and anticorrosive pigment.

Embodiment 59. The gravity responsive particle of embodiment 58, wherein the metallic pigment comprises one or more of aluminum, bronze, and copper metallic pigment.

Embodiment 60. The gravity responsive particle of embodiment 58, wherein the pearlescent pigment comprises one or more of mica, titanium dioxide, and bismuth oxychloride.

Embodiment 61. The gravity responsive particle of embodiment 58, wherein the fluorescent pigment comprises one or more fluorescent dye and pigment comprising a fluorescent mineral.

Embodiment 62. The gravity responsive particle of embodiment 58, wherein the phosphorescent pigment comprises zinc sulfide and/or strontium aluminate.

Embodiment 63. The gravity responsive particle of embodiment 58, wherein the interference pigment comprises titanium dioxide-coated mica and/or aluminum oxide-coated mica.

Embodiment 64. The gravity responsive particle of any one of the preceding embodiments, wherein the one or more optically active agents comprises an anisotropic particle.

Embodiment 65. The gravity responsive particle of embodiment 64, wherein the anisotropic particle comprises a nanoparticle of the one or more metals, optionally comprising a nanorod of one or more of gold (Au), silver (Au), and aluminum (AI).

Embodiment 66. The gravity responsive particle of any one of the preceding embodiments, wherein the one or more optically active agents comprises a plasmonic material.

Embodiment 67. The gravity responsive particle of embodiment 66, wherein the plasmonic material comprises a pigment, particle, foil, and/or film.

Embodiment 68. The gravity responsive particle of embodiment 66, wherein the plasmonic material comprises a polymer-film loaded with noble metal nanoparticles.

Embodiment 69. The gravity responsive particle of embodiment 58, wherein the goniochromatic pigment comprises aluminum coated with magnesium fluoride embedded in chromium.

Embodiment 70. The gravity responsive particle of any one of the preceding embodiments, wherein the GRP comprises one or more roughness features.

Embodiment 71. The gravity responsive particle of embodiment 70, wherein the one or more roughness features is a variation in a surface smoothness that alters the degree of reflectivity of the surface at one or more wavelengths.

Embodiment 72. The gravity responsive particle of embodiment 70 or 71, wherein the one or more roughness features is regularly or irregularly shaped.

Embodiment 73. The gravity responsive particle of any one of embodiments 70-72, wherein the one or more roughness features appears in a regular pattern and an irregular pattern.

Embodiment 74. The gravity responsive particle of any one of the preceding embodiments, wherein the GRP is disposed on a surface and/or substrate.

Embodiment 75. The gravity responsive particle of embodiment 74, wherein the surface and/or substrate is a window, computer chip, glass surface, fabric, plastic, paper, wood, construction material, and/or human or animal tissue or skin.

Embodiment 76. The gravity responsive particle of embodiment 74 or 75, wherein the surface and/or substrate is planar or non-planar.

Embodiment 77. The gravity responsive particle of any one of embodiments 74-76, wherein the surface and/or substrate comprises at least a portion that is convex, concave, or without a well-defined shape.

Embodiment 78. The gravity responsive particle of any one of embodiments 74-77, wherein the surface and/or substrate is on an interior surface of an object, an exterior surface of an object, or both, and wherein the object is a non-GRP object.

Embodiment 79. The gravity responsive particle of any one of the preceding claims, wherein the GRP comprises one or more magnetic materials.

Embodiment 80. The gravity responsive particle of embodiment 79, wherein the magnetic material is affixed to at least a portion of the surface of the GRP.

Embodiment 81. The gravity responsive particle of embodiment 79 or 80, wherein the magnetic material is affixed to the top surface, optionally wherein the magnetic material changes the CoM relative to the curvature of radius.

Embodiment 82. The gravity responsive particle of any one of embodiments 79-81, wherein the magnetic material is ferromagnetic, ferrimagnetic, antiferromagnetic, diamagnetic, paramagnetic, superparamagnetic, and/or antiferromagnetic.

Embodiment 83. The gravity responsive particle of any one of embodiments 79-82, wherein the magnetic material comprises one or more of an inorganic, organic, carbon-based, or biomolecule-based magnetic material.

Embodiment 84. The gravity responsive particle of any one of embodiments 79-83, wherein the magnetic material comprises one or more of iron (Fe), cobalt (Co), nickel (Ni), zinc (Zn), manganese (Mn), chromium (Cr), samarium (Sm), alloys or oxides thereof; alloys, intermetallic, and/or oxides of Fe, Co, Ni, Zn, Mn, Sm; oxides are of iron, Fe₂O₃, FeO, and/or Fe₃O₄; ferrite material and/or doped materials of Co, Ni, Zn, and/or Mn:FexOy, and/or magnetitetetracyanoethylene (TCNE) salts, [Fe(C₅Me₅)2]+[TCNE]·-, Li[TCNE], [MnIITPP][TCNE]· (TPP=tetraphenylporphyrin), [FeII(TCNE)(NCMe)₂][FeIIICl₄], MnII(TCNE)I(OH₂), MnII(TCNE)[C₄(CN)₈]_{1/2}, Fe(TCNE)[C₄(CN)₈]₁₂, MnII(TCNE)_{3/2}(I₃)_{1/2}, VII[TCNE]ₓ (x≈2), C₇H₅ClN₃Se₄, magnetic organic polymers, and polymer-bonded magnets.

Embodiment 85. The gravity responsive particle of any one of embodiments 79-84, wherein the GRP responds to a magnetic stimulus.

Embodiment 86. The gravity responsive particle of any one of the preceding embodiments, wherein the GRP is formulated into a foil, film, thin plastic, and/or paper substrate, material, and/or surface.

Embodiment 87. The gravity responsive particle of embodiment 86, wherein the foil, film, thin plastic, and/or paper substrate, material, and/or surface is suitable to be affixed to, or embedded in, an object.

Embodiment 88. The gravity responsive particle of any one of embodiments 1-85, wherein the GRP is formulated into a fiber, thread, yarn, and/or twine substrate, material, and/or surface.

Embodiment 89. The gravity responsive particle of embodiment 88, wherein the fiber, thread, yarn, and/or twine substrate, material, and/or surface is suitable to be woven into an article of clothing, a cloth, and/or a tarp.

Embodiment 90. The gravity responsive particle of any one of embodiments 1-85, wherein the GRP is formulated into a fluid, suspension, ink, liquid film, and/or adhesive substrate, material, and/or surface.

Embodiment 91. The gravity responsive particle of embodiment 90, wherein the fluid, suspension, ink, liquid film, and/or adhesive substrate, material, and/or surface is suitable to be applied to an object.

Embodiment 92. The gravity responsive particle of any one of embodiments 87-91, wherein the surface and/or substrate comprises indentations and/or divots.

Embodiment 93. The gravity responsive particle of embodiment 92, wherein the indentations and/or divots are arranged in an array.

Embodiment 94. The gravity responsive particle of embodiment 92 or 93, wherein the GRP is disposed in and/or on the indentations and/or divots.

Embodiment 95. The gravity responsive particle of any one of embodiments 74-78 or 86-94, wherein the surface and/or substrate comprises pillars, posts, and/or stops.

Embodiment 96. The gravity responsive particle of embodiment 95, wherein the GRP is disposed in and/or on the pillars, posts, and/or stops.

Embodiment 97. The gravity responsive particle of any one of embodiments 74-78 or 86-94, wherein the surface and/or substrate comprises one or more grooves.

Embodiment 98. The gravity responsive particle of embodiment 97, wherein the GRP is disposed in and/or on the one or more grooves.

Embodiment 99. The gravity responsive particle of any one of the preceding embodiments, wherein the GRP is positioned between a first substrate and a second substrate.

Embodiment 100. The gravity responsive particle of embodiment 99, wherein at least one of the first substrate and the second substrate comprises a material that is transparent to at least a portion of the visible electromagnetic (EM) spectrum.

Embodiment 101. The gravity responsive particle of embodiment 100, wherein the material comprises glass, quartz, plastic, polyethylene terephthalate, polycarbonate, polymethyl methacrylate (acrylic), polyethylene, polyurethane, polypropylene, thermoplastic elastomers (TPE), acrylonitrile butadiene styrene (ABS), epoxies and epoxy-based photoresists, hydrogels, cyclic olefin copolymer (COC) cyclic olefin polymer (COP), poly dimethyl siloxane (PDMS), poly ether ester ketone (PEEK), polyetherimide (ULTEM) and/or nylon.

Embodiment 102. The gravity responsive particle of embodiment 100 or 101, wherein the material comprises a thickness of about or at least about 50 nm, is about or at least about 100 nm, is about or at least about 500 nm, about or at least about 1 μm, is about or at least about 10 μm, is about or at least about 100 μm, about or at least about 1 mm, about or at least about 5 mm, or about or at least about 10 mm.

Embodiment 103. The gravity responsive particle of any one of the preceding embodiments, wherein the GRP changes color as a function of the motion.

Embodiment 104. The gravity responsive particle of any one of the preceding embodiments, wherein the GRP comprises at least a first surface with a shape that is complementary to a shape of a second surface of the GRP.

Embodiment 105. The gravity responsive particle of any one of embodiments 74-78 or 86-104, wherein the surface and/or substrate comprises one or more a lubricant, surface treatment, coating, and/or polishing agent; or at least one of the first substrate and the second substrate comprises one or more a lubricant, surface treatment, coating, and polishing agent.

Embodiment 106. The gravity responsive particle of embodiment 105, wherein the one or more lubricant, surface treatment, coating, and polishing agent comprises polytetrafluoroethylene (PTFE), hydroxylated self-assembled monolayers, vitreous enamel, ceria (cerium oxide), ceramics, anodized metals, and/or silica.

Embodiment 1000. A gravity responsive particle (GRP) comprising: a shape and a center of mass (CoM) that enables motion between a plurality of positions when a force is applied, wherein the shape and the CoM enables relaxation to a stationary position from the plurality of positions from gravitational force; and one or more optically active agents, wherein the GRP exhibits a change in an optical property of the one or more optically active agents as a function of the motion between the plurality of positions, and wherein the GRP comprises one or more fin-shaped portions above the CoM.

Embodiment 2000. A sawtooth gravity responsive particle (sGRP) comprising: a shape comprising a center of mass (CoM) that resides at or above a radius of curvature that when a force is applied to tilt the sGRP between a tilt angle of 0° to θ_{crit}, the shape enables motion between a plurality of positions of 0° to θ_{crit}, wherein θ_{crit} is a critical angle, tilting past which results in movement of the sGRP to an equilibrium position on a side surface that is distinct from an upright equilibrium position; and one or more optically active agents, wherein the sGRP exhibits a change in an optical property of the one or more optically active agents as a function of relaxation to the equilibrium position on the side surface.

Embodiment 2001. The sawtooth gravity responsive particle of embodiment 2000, wherein the side surface is configured to rest on a side surface of a second sGRP comprising a congruent shape and/or a different shape.

Embodiment 2002. The sawtooth gravity responsive particle of embodiment 2000 or 2001, wherein the motion between the plurality of positions of 0° to θ_{crit} is an angular displacement.

Embodiment 2003. The sawtooth gravity responsive particle of embodiment 2002, wherein the 0° angle is relative to a plane passing through the center of mass (CoM) and perpendicular to a surface the sGRP is resting upon.

Embodiment 2004. The sawtooth gravity responsive particle of embodiment 2002, wherein the motion resembles or is substantially similar to an oscillating motion or a tilt displacement.

Embodiment 2005. The sawtooth gravity responsive particle of embodiment 2004, wherein the oscillating motion comprises a pendulum motion oscillating between the plurality of positions.

Embodiment 2006. The sawtooth gravity responsive particle of embodiment 2004, wherein the oscillating motion comprises a wobble motion comprising oscillations around a pitch axis and a yaw axis.

Embodiment 2007. The sawtooth gravity responsive particle of embodiment 2006, wherein the wobble motion comprises movement through a plurality of orientations relative to a direction of the force.

Embodiment 2008. The sawtooth gravity responsive particle of any one of embodiments 2000-2007, wherein the motion occurs along a plane in two dimensions and/or in three dimensions.

Embodiment 2009. The sawtooth gravity responsive particle of any one of embodiments 2000-2008, wherein the critical angle (θ_{crit}) is about or less than about 5°, about or less than about 10°, about or less than about 15°, about or less than about 20°, about or less than about 25°, about or less than about 30°, about or less than about 35°, about or less than about 40°, about or less than about 45°, about or less than about 50°, about or less than about 55°, about or less than about 60°, about or less than about 65°, about or less than about 70°, or about or less than about 75°, relative to the plane passing through the center of mass (CoM) and perpendicular to a surface the sGRP is resting upon.

Embodiment 3000. A method of manufacturing a GRP of any one of embodiments 1-106, a fin GRP of embodiment 1000, or a sGRP of any one of claims 2000-2009, comprising: generating a particle from one or more substrate materials, the particle comprising a shape and a center of mass (CoM) that enables motion between a plurality of positions when a force is applied, wherein the shape and the CoM enables the particle to relax to a stationary position from the plurality of positions from gravitational force.

Embodiment 3001. The method of embodiment 3000, wherein generating the particle comprises forming the particle by assembling, gluing, screwing, and/or affixing of two or more components; injection molding, and/or micro-injection molding; self-assembly, adsorption, coacervation, and/or mixing; polymerization, extrusion, and/or manipulation of polymers; additive manufacturing, CNC machining (Computer Numerical Control machining), urethane casting, microcontact printing, dip pen lithography, beam pen lithography, photolithography, e-beam lithography, and/or 3D printing.

Embodiment 3002. The method of embodiment 3000 or 3001, wherein generating the particle comprises forming the particle by injecting molten plastic, metal, and/or polymer-based material into a mold cavity.

Embodiment 3004. The method of embodiment 3002, wherein generating the particle comprises forming the particle by 3D printing.

Embodiment 3005. The method of embodiment 3004, wherein 3D printing comprises performing one or more of fused deposition modeling (FDM), fused filament fabrication (FFF), stereolithography (SLA), two photon polymerization, multi-photon lithography, selective laser sintering (SLS), binder jetting (BJ), direct energy deposition (DED), digital light process (DLP), liquid crystal display (LCD), polymer jetting (PolyJet), multi-jet fusion (MJF), direct metal laser sintering (DMLS), electron beam melting (EBM), laminated object manufacturing (LOM), continuous liquid interface production (CLIP), electron beam melting, and digital light processing (DLP).

Embodiment 3006. The method of any one of embodiments 3000-3005, wherein the one or more substrate materials comprises one or more metals, ceramics, thermally responsive polymers, and resins.

Embodiment 3007. The method of any embodiment 3006, wherein the one or more thermally responsive polymers and/or resins comprise one or more of poloxamers, polycarbonate and/or polycarbonate-like polymers (e.g., polycarbonate-like translucent/clear resin, polyamide (polyamide 12 (PA12), nylon 12, glass-filed polyamide), photoresins, styrene-butadiene block copolymers, polymethylmethacrylate, polybutylmethacrylate, plasticized polyvinyl chloride, plasticized nylon, plasticized polyethylene terephthalate, polyethylene, polyacrylonitrile, polychlorotrifluoroethylene, poly-4,4′-isopropylidenediphenylene carbonate, polyethylene vinyl ester, polyvinyl chloride-diethyl fumarate, poly(1,4-isoprene) (PI), polystyrene (PS), poly(tert-butyl methacrylate) (PtBA), amino-terminated poly(butadinene) (PBNH2-37k), poly(ferrocenyl dimethylsilane) (PFeS), amino-terminated poly(butadinene) (PBNH₂-14k), poly(methyl methacrylate) (PMMA), amino-terminated polystyrene (PSNH₂), and combinations thereof.

Embodiment 3008. The method of any one of embodiments 3000-3007, wherein generating the particle comprises forming Janus particles comprising the one or more substrate materials, or forming Ashura particles comprising the one or more substrate materials.

Embodiment 3009. The method of embodiment 3008, wherein the one or more substrate materials comprises one or more of poly(tert-butyl acrylate)-poly(3-(triethoxysilyl)propyl methacrylate) (PtBA-PTPM), polystyrene latex polymer, carboxylated latex polymer, aminated latex polymer, colored polystyrene polymer (dye-infused and/or pigment-infused), colored polystyrene-based carboxylated latex polymer (dye-infused and/or pigment-infused), fluorescent polystyrene-based polymers, fluorescent polystyrene-based carboxylated latex polymers, fluorescent aminated polystyrene-based polymer, surfactant-free polystyrene, carboxylated surfactant-free polymer, polymethyl methacrylate (PMMA) latex polymer, and divinylbenzene (DVB)-crosslinked polystyrene latex polymer.

Embodiment 3010. The method of any one of embodiments 3000-3009, wherein the particle and/or one or more substrate materials comprises an internal portion.

Embodiment 3011. The method of embodiment 3010, wherein the internal portion comprises a material having a singular specific gravity and/or density.

Embodiment 3012. The method of embodiment 3010, wherein the internal portion comprises at least two materials having different specific gravities and/or densities.

Embodiment 3013. The method of any one of embodiments 3010-3012, wherein the internal portion comprises at least a portion that is hollow and/or porous.

Embodiment 3014. The method of any one of embodiments 3010-3013, wherein the internal portion comprises at least a portion that comprises a gyroid infill, grid infill, cubic infill pattern, triangular infill, octet infill, lightning infill, and/or a combination thereof.

Embodiment 3015. The method of any one of embodiments 3012-3014, comprising doping the one or more substrate materials with a denser material.

Embodiment 3016. The method of any embodiment 3015, wherein the denser material is infused, embedded, or otherwise placed into a bottom portion of the particle.

Embodiment 3017. The method of any one of embodiments 3000-3016, wherein generating the particle comprises joining at least two substrate materials, wherein the two substrate materials differ in density.

Embodiment 3018. The method of any one of embodiments 3000-3017, wherein the one or more substrate materials is transparent to at least a portion of the visible electromagnetic (EM) spectrum.

Embodiment 3019. The method of claim embodiment 3018, wherein the one or more substrate materials comprises glass, quartz, plastic, polyethylene terephthalate, polycarbonate, polymethyl methacrylate (acrylic), polyethylene, polyurethane, polypropylene, thermoplastic elastomers (TPE), acrylonitrile butadiene styrene (ABS), epoxies and epoxy-based photoresists, hydrogels, cyclic olefin copolymer (COC) cyclic olefin polymer (COP), poly dimethyl siloxane (PDMS), poly ether ester ketone (PEEK), polyetherimide (ULTEM) and/or nylon.

Embodiment 3020. The method of any one of embodiments 3000-3019, wherein the one or more substrate materials comprises a thickness of about or at least about 50 nm, is about or at least about 100 nm, is about or at least about 500 nm, about or at least about 1 μm, is about or at least about 10 μm, is about or at least about 100 μm, about or at least about 1 mm, about or at least about 5 mm, or about or at least about 10 mm.

Embodiment 3021. The method of any one of embodiments 3000-3020, comprising disposing one or more optically active agents onto and/or into the particle and/or the one or more substrate materials.

Embodiment 3022. The method of embodiment 3021, wherein the one or more substrate materials is porous, and one or more optically active agents is disposed therein.

Embodiment 3023. The method of embodiment 3021, wherein disposing the one or more optically active agents comprises painting, airbrushing, dip coating, abrading, and/or roughening one or more surfaces of the GRP.

Embodiment 3024. The method of embodiment 3021, wherein disposing the one or more optically active agents comprises 3D printing the particle with one or more colored printing materials.

Embodiment 3025. The method of embodiment 3024, wherein the one or more colored printing materials comprises a resin, polymer, particle, and/or plastic.

Embodiment 3026. The method of any one of embodiments 3021-3025, wherein the particle comprises two or more optically active agents, each exhibiting at least one distinct optical state.

Embodiment 3027. The method of any one of embodiments 3021-3026, wherein the one or more optically active agents comprise a color in the visible electromagnetic spectrum comprising an extinction, reflection, or scattering at a wavelength from about or at least about 350 nm to about or at least about 800 nm.

Embodiment 3028. The method of embodiment 3027, wherein the color is one or more of white, black, red, orange, yellow, green, blue, indigo, and violet.

Embodiment 3029. The method of any one of embodiments 3000-3028, wherein the one or more optically active agents comprises a dye.

Embodiment 3030. The method of embodiment 3029, wherein the dye comprises one or more of Rhodamine B, Congo Red, Crystal Violet, Methylene Blue, Acridine Orange, Nile Red, Malachite Green, Eosin Y, Cresol Red, Fluorescein, and Indigo.

Embodiment 3031. The method of any one of embodiments 3021-3030, wherein the one or more optically actives agent comprises a pigment.

Embodiment 3032. The method of embodiment 3031, wherein the pigment comprises one or more of Titanium White (PW6), Zinc White (PW4), Carbon Black (PBK7), Mars Black (PBk11), Iron Oxide Red (PR101), Cadmium Red (PR108), Alizarin Crimson (PR83), Cadmium Orange (PO20), Cadmium Yellow (PY35),Lemon Yellow (PY3), Chromium Green Oxide (PG17), Phthalo Green (PG7), Ultramarine Blue (PB29), Cobalt Blue (PB28), Cerulean Blue (PB35), Prussian Blue (PB27), Burnt Sienna (PBr7), Raw Umber (PBr7), Raw Sienna (PBr7), and Yellow Ochre (PY43).

Embodiment 3033. The method of embodiment 3031, wherein the pigment is an organic pigment.

Embodiment 3034. The method of embodiment 3031, wherein the pigment is an inorganic pigment.

Embodiment 3035. The method of any embodiment 3033 or 3034, wherein the organic pigment or inorganic pigment is a white pigment.

Embodiment 3036. The method of embodiment 3035, wherein the white pigment is one or more of lead white (2PbCO₃·Pb(OH)₂), kaolin, silica (SiO₂), titanium dioxide (TiO₂/rutile and anatase), zinc oxide (ZnO), zinc sulfide (ZnS), and lithopone (ZnS+BaSO₄).

Embodiment 3037. The method of embodiment 3033 or 3034, wherein the organic pigment or inorganic pigment is a black pigment.

Embodiment 3038. The method of embodiment 3037, wherein the black pigment is one or more of coal (charcoal), groutite (α-MnOOH), manganite (γ-MnOOH), hausmannite (Mn₃O₄), carbon black, iron oxide black (Fe₃O₄), and spinel black (CuCr₂O₄).

Embodiment 3039. The method of embodiment 3033 or 3034, wherein the organic pigment or inorganic pigment is a colored pigment.

Embodiment 3040. The method of embodiment 3039, wherein the colored pigment comprises a yellow pigment.

Embodiment 3041. The method of embodiment 3040, wherein the yellow pigment comprises one or more of yellow ochre (α-FeOOH), auric pigment (As₂S₃), lead ochre (PbO), lead tin yellow (Pb₂SnO₄, PbSn₂SiO₇), Naples yellow (Pb(SbO₃)₂), zinc yellow (Zn₂CrO₄), Indian yellow (C₁₉H₁₆O₁₀), iron oxide yellow (α-FeOOH), chromium titanium yellow ((Ti,Cr,Sb)O₂), nickel titanium yellow ((Ti,Ni,Sb)O₂), lead yellow (PbCrO₄), cadmium yellow (CdS), and bismuth yellow (BiVO₄).

Embodiment 3042. The method of embodiment 3039, wherein the colored pigment comprises a red pigment.

Embodiment 3043. The method of embodiment 3042, wherein the red pigment comprises one or more of red ocher (α-Fe₂O₃), Terra di Siena (α-Fe₂O₃), vermilion (HgS), lead red (Pb₃O₄), alizarin madder varnish, alizarin red (C₁₄H₈O₄), iron oxide red (α-Fe₂O₃), molybdate red (Pb(Cr,S,Mo)O₄), and cadmium red (Cd(S,Se)).

Embodiment 3044. The method of embodiment 3039, wherein the colored pigment comprises a green pigment.

Embodiment 3045. The method of embodiment 3044, wherein the green pigment comprises one or more of green earth (Fe silicates), Schweinfurt green (C₄H₆As₆Cu₄O₁₆), chromium oxide green (Cr₂O₃), chromium oxide hydrate green (CrOOH), and cobalt green (Co₂TiO₄).

Embodiment 3046. The method of embodiment 3039, wherein the colored pigment comprises a blue pigment.

Embodiment 3047. The method of any embodiment 3046, wherein the blue pigment comprises one or more of lazurite (lapis lazuli), Egyptian blue (CaCuSi₄O₁₀), azurite (2CuCO₃·Cu(OH)₂), malachite (CuCO₃·Cu(OH)₂), cobalt blue (CoAl₂O₄), Cobalt blue (CoAl₂O₄), ultramarine blue: (Na₆Al₆Si₆O₂₄(NaSn)), and iron blue (K[FeIIIFeII(CN)₆]·xH₂O).

Embodiment 3048. The method of embodiment 3039, wherein the colored pigment comprises a brown pigment.

Embodiment 3049. The method of embodiment 3048, wherein the brown pigment comprises one or more of burnt umber (Fe₂O₃·xMnO₂), brown ocher (α-Fe₂O₃+Mn oxides), and limonite (mixture of different Fe oxides).

Embodiment 3050. The method of embodiment 3031, wherein the pigment is one or more of an oxide or oxide hydroxide pigment (TiO₂, ZnO, α-Fe₂O₃, α-FeOOH, γ-Fe₂O₃, Fe₃O₄, Cr₂O₃, CrOOH, PbO, Pb₃O₄, Mn₃O₄, —MnOOH, Sb₂O₃), a complex oxide pigment (CoAl₂O₄, CuCr₂O₄, Co₂TiO₄, (Ti,Ni,Sb)O₂, (Ti,Cr,Sb)O₂), a carbonate hydroxide pigment (2PbCO₃·Pb(OH)₂, 2CuCO₃·Cu(OH)₂, CuCO₃·Cu(OH)₂), a sulfide/selenide pigment (ZnS, CdS, Cd(S,Se), CdSe, γ-Ce₂S₃, HgS, As₂S₃), a chromate/molybdate pigment (PbCrO₄, Pb(Cr,S)O₄, Pb(Cr,S,Mo)O₄, ZnCrO₄, BaCrO₄, SrCrO₄), a vanadate pigment (BiVO₄, 4BiVO₄·3Bi₂MoO₆), a stannate pigment (Pb₂SnO₄, PbSn₂SiO₇, Co₃SnO₄, CoSnO₃), a phosphate pigment (Co₃(PO₄)₂), an antimonate pigment (Pb(SbO₃)₂), an arsenate pigment (Cu(AsO₃)₂), an ultramarine pigment (Na₆Al₆Si₆O₂₄(NaSn)), a hexacyanidoferrate/hexacyanoferrate pigment (K[FeIIIFeII(CN)₆]·xH₂O (x=14-16)), an oxonitride pigment (CaTaO₂N, LaTaON₂), an elemental-based pigment (C, Al, Cu, Cu/Zn, Au), a spinel-based pigment, and a rutile-based metal pigment.

Embodiment 3051. The method of embodiment 3034, wherein the inorganic pigment is one or more of a transparent effect pigment, goniochromatic pigment, pearlescent pigment, metallic pigment, interference pigment, metallic effect pigment, fluorescent pigment, luminescent pigment, phosphorescent pigment, magnetic pigment, and anticorrosive pigment.

Embodiment 3052. The method of embodiment 3051, wherein the metallic pigment comprises one or more of aluminum, bronze, and copper metallic pigment.

Embodiment 3053. The method of embodiment 3051, wherein the pearlescent pigment comprises one or more of mica, titanium dioxide, and bismuth oxychloride.

Embodiment 3054. The method of embodiment 3051, wherein the fluorescent pigment comprises one or more fluorescent dye and/or pigment comprising a fluorescent mineral.

Embodiment 3055. The method of embodiment 3051, wherein the phosphorescent pigment comprises zinc sulfide and/or strontium aluminate.

Embodiment 3056. The method of embodiment 3051, wherein the interference pigment comprises titanium dioxide-coated mica and/or aluminum oxide-coated mica.

Embodiment 3057. The method of any one of embodiments 3021-3056, wherein the one or more optically active agents comprises an anisotropic particle.

Embodiment 3058. The method of embodiment 3057, wherein the anisotropic particle comprises a nanoparticle of the one or more metals, optionally comprising a nanorod of one or more of gold (Au), silver (Au), and aluminum (Al).

Embodiment 3059. The method of any one of embodiments 3021-3058, wherein the one or more optically active agents comprises a plasmonic material.

Embodiment 3060. The method of embodiment 3059, wherein the plasmonic material comprises a pigment, particle, foil, and/or film.

Embodiment 3061. The method of embodiment 3060, wherein the plasmonic material comprises a polymer-film loaded with noble metal nanoparticles.

Embodiment 3062. The method of embodiment 3051, wherein the goniochromatic pigment comprises aluminum coated with magnesium fluoride embedded in chromium.

Embodiment 3063. The method of any one of embodiments 3000-3062, wherein the one or more substrate materials and/or the particle comprises one or more roughness features.

Embodiment 3064. The method of embodiment 3063, wherein the one or more roughness features is a variation in the smoothness of a surface of the particle that alters the degree of reflectivity of the surface at one or more wavelengths.

Embodiment 3065. The method of embodiment 3063 or 3064, wherein the one or more roughness features is regularly or irregularly shaped.

Embodiment 3066. The method of any one of embodiments 3063-3065, wherein the one or more roughness features appears in a regular pattern and/or an irregular pattern.

Embodiment 3067. The method of any one of embodiments 3063-3066, comprising applying the one or more roughness features to a surface of the particle by abrading and/or roughening the particle.

Embodiment 3068. The method of any one of embodiments 3000-3067, comprising formulating the GRP into a foil, film, thin plastic, and/or paper substrate, material, and/or surface.

Embodiment 3069. The method of embodiment 3068, wherein the foil, film, thin plastic, and/or paper substrate, material, and/or surface is suitable to be affixed to, or embedded in, an object.

Embodiment 3070. The method of any one of embodiments 3063-3065, comprising formulating the GRP into a fiber, thread, yarn, and/or twine substrate, material, and/or surface.

Embodiment 3071 The method of embodiment 3070, wherein the fiber, thread, yarn, and/or twine substrate, material, and/or surface is suitable to be woven into an article of clothing, a cloth, and/or a tarp.

Embodiment 3072. The method of any one of embodiments 3063-3065, comprising formulating the GRP into a fluid, suspension, ink, liquid film, and/or adhesive substrate, material, and/or surface.

Embodiment 3073. The method of embodiment 3072, wherein the fluid, suspension, ink, liquid film, and/or adhesive substrate, material, and/or surface is suitable to be applied to an object.

Embodiment 4000. A sensor for detecting one or more analytes in a sample comprising: a plurality of particles disposed onto a reaction membrane, wherein the plurality of particles comprise: i) one or more gravity responsive particles (GRPs) of any one of embodiments 1-107, ii) a fin GRP of embodiment 1000, iii) one or more sawtooth gravity responsive particles (sGRPs) of any one of embodiments 2000-2009, and/or iv) one or more GRPs manufactured from the method of any one of embodiments 3000-3073, and a sample pad configured to receive a volume of the sample and flow the sample over the reaction membrane, wherein each of the plurality of particles are conjugated to one or more mass detection labels configured to bind the one or more analytes; and wherein as the sample is flowed over the plurality of particles on the reaction membrane, the one or mass detection labels binds the one or more analytes in the sample, causing a shift in the mass of the plurality of particles, which results in a movement in the plurality of particles, and wherein the movement elicits a change in an optical property proportional to the binding of the one or more analytes.

Embodiment 4001. The sensor of embodiment 4000, wherein the change in the optical property is a change in color.

Embodiment 4002. The sensor of embodiment 4000 or 4001, wherein the movement is a tipping onto a stable equilibrium distinct from an upright equilibrium.

Embodiment 4003. The sensor of any one of embodiments 4000-4002, further comprising a plurality of control particles disposed onto the reaction membrane, wherein the plurality of control particles comprise one or more mass detection labels and is i) not configured to bind the one or more analytes that the plurality of particles bind, and ii) provide a control signal, optionally wherein the control signal is the same as the change in optical property of the plurality of particles.

Embodiment 4004. The sensor of any one of embodiments 4000-4003, wherein the plurality of particles and/or the plurality of control particles comprise a first color when upright and a second color after the movement.

Embodiment 4005. The sensor of embodiment 4004, wherein the first color is green and the second color is red; or wherein the first color is red and the second color is green.

Embodiment 4006. The sensor of any one of embodiments 4000-4005, wherein the plurality of particles and/or the plurality of control particles comprise fins, detents, or grooves that increase a surface area for binding.

Embodiment 4007. The sensor of any one of embodiments 4000-4006, wherein the one or more mass detection labels comprises one or more of an antibody, antibody-format binding molecule, aptamer, metal oxide particle, and metal particle.

Embodiment 4008. The sensor of embodiment 4007, wherein the one or more mass detection labels comprise an antibody or antibody-format molecule.

Embodiment 4009. The sensor of embodiments 4007 or 4008, wherein the antibody or antibody-format molecule comprises one or more of a monoclonal antibody, polyclonal antibody, antibody fragment, Fab, Fab′, Fab′-SH, F(ab′)2, Fv, single chain Fv (scFv), diabody, nanobody, linear antibody, bispecific antibody, multi-specific antibody, chimeric antibody, humanized antibody, human antibody, and fusion protein comprising an antigen-binding portion of an antibody.

Embodiment 4010. The sensor of embodiments 4007, wherein the metal comprises one or more of as gold (Au), silver (Ag), platinum (Pt), nickel (Ni), iron (Fe), palladium (Pd), tungsten (W), tantalum (Ta), osmium (Os), iridium (Ir), lead (Pb BaTiO₃, SnO₂, PbO₂, and TiO₂.

Embodiment 4011. The sensor of embodiments 4000-4010, wherein the one or more mass detection labels comprise a dimension of about or at least about 10 nm, about or at least about 20 nm, about or at least about 30 nm, about or at least about 40 nm, about or at least about 50 nm, about or at least about 60 nm, about or at least about 70 nm, about or at least about 80 nm, about or at least about 90 nm, about or at least about 100 nm, about or at least about 120 nm, about or at least about 140 nm, about or at least about 160 nm, about or at least about 180 nm, about or at least about 200 nm, about or at least about 300 nm, about or at least about 400 nm, about or at least about 500 nm, about or at least about 1,000 nm, about or at least about 2,000 nm, or about or at least about 3,000 nm.

Embodiment 4012. The sensor of any one of embodiments 4000-4011, wherein the one or more mass detection labels are attached to the plurality of particles and/or the plurality of control particles using a biomolecular capture film.

Embodiment 4013. The sensor of embodiment 4012, wherein the biomolecular capture film comprises a thickness of about or at least about 1 nm, about or at least about 2 nm, about or at least about 3 nm, about or at least about 4 nm, about or at least about 5 nm, about or at least about 10 nm, about or at least about 20 nm, about or at least about 30 nm, about or at least about 50 nm, about or at least about 100 nm, about or at least about 200 nm, about or at least about 500 nm, about or at least about 1 μm, about or at least about 2 μm, or about or at least about 10 μm.

Embodiment 4014. The sensor of any one of embodiments 4000-4013, wherein the sensor further comprises a conjugate pad connecting the sample pad with the reaction membrane and/or an absorbent pad at the end of the reaction membrane opposite of the sample pad.

Embodiment 4015. The sensor of any one of embodiments 4000-4014, wherein the one or more analytes comprise one or more of a protein, peptide, nucleic acid, DNA, RNA, lipid, sugar, metabolite, cell, capsid, antigen, biomarker, ionic species, heavy metal, pathogen, bacterium, virus, and any substance containing or including biomolecules.

Embodiment 4016. The sensor of any one of embodiments 4000-4015, wherein the sample comprises one or more of blood, sera, plasma, bone marrow, lymph, saliva, sputum, mucus, respiratory or nasal secretion, oropharyngeal swab, nasopharyngeal swab, oral swab, ductal lavage, bronchoalveolar lavage, cerebrospinal fluid, skin swab, vaginal swab, gastric juice, ascites, peritoneal fluid, pleural fluid, gynecological fluids, pus, perspiration, tears, urine, stool; homogenized biopsy, tissue, or cell sample; a tumor sample; a water sample; a sample of foodstuffs and/or surfaces for storing or preparing foodstuffs, beverages, homogenized animal products intended for consumption, samples taken from a surface that is used for preparing food, and soil samples.

Embodiment 4017. The sensor of any one of embodiments 4000-4016, wherein the plurality of particles and/or the plurality of control particles are arranged in an array on the reaction membrane, optionally wherein the array comprises one or more lines on the reaction membrane visible by human vision.

Embodiment 5000. A method of authenticating an object using a detectable gravity responsive particle (GRP) signal, the method comprising: providing an object comprising an array of particles comprising: i) one or more gravity responsive particles (GRPs) of any one of embodiments 1-107, ii) a fin GRP of embodiment 1000, iii) one or more sawtooth gravity responsive particles (sGRPs) of any one of embodiments 2000-2009, and/or iv) one or more GRPs manufactured from the method of any one of embodiments 3000-3073; applying a force to the array of particles to cause a movement in the array of particles which elicits a change in an optical property in the array of particles; and detecting the change in the optical property as a function of the movement of the array of particles.

Embodiment 5001. The method of embodiment 5000, wherein the object comprises paper, plastic, glass, metal, fabric, wood, a window, an electronic device, a computer chip, construction materials, and/or human or animal tissue or skin.

Embodiment 5002. The method of embodiment 5000 or 5001, wherein the object comprises documentation, optionally paper currency.

Embodiment 5003. The method of any one of embodiments 5000-5002, wherein the object surface comprises one or more regions that are substantially planar, non-planar, convex, concave, or without a well-defined shape.

Embodiment 5004. The method of any one of embodiments 5000-5003, wherein the array of particles are located on a surface and/or substrate on an interior surface of the object and/or on an exterior surface of the object.

Embodiment 5005. The method of any one of embodiments 5000-5004, wherein the force comprises gravity, mechanical force, or magnetic force.

Embodiment 5006. The method of any one of embodiments 5000-5005, wherein applying the force comprises moving the object relative to the direction of gravity and/or applying a magnetic field.

Embodiment 5007. The method of any one of embodiments 5000-5006, wherein the change in the optical property comprises a change in one or more color in the visible electromagnetic spectrum comprising an extinction, reflection, or scattering at a wavelength from about or at least about 350 nm to about or at least about 800 nm.

Embodiment 5008. The method of embodiment 5007, wherein the one or more color comprises one or more of white, black, red, orange, yellow, green, blue, indigo, violet, or a color shade or hue therebetween.

Embodiment 5009. The method of embodiments 5000-5008, wherein the change in optical property is detectable by human vision.

Embodiment 5010. The method of any one of embodiments 5000-5009, wherein the array of particles is arranged in a pattern, optionally comprising one or more shape, symbol, letter, number, picture, image, or message; and/or wherein the change in the optical property that is detected is substantially in the arrangement of the array of particles.

Embodiment 5010. The method of any one of embodiments 5000-5010, wherein detecting the change in the optical property comprises using one or more of a camera, spectrometer, filter, window, grating, beam splitter, polarizer, collimator, birefringent element, prism, bandpass filter, aperture, or lens to detect an optical signal emanating from the object.

Embodiment 5011. The method of any one of embodiments 5000-5010, wherein the detecting is performed as a function of the movement and as a function of time.

Embodiment 5012. The method of any one of embodiments 5000-5011, further comprising comparing the change in the optical property to a standard signal, wherein the comparison verifies the authenticity of the object.

Embodiment 6000. An electromagnetic vibrational energy capture device, comprising: one or more gravity responsive particles (GRPs), wherein each GRP comprises: a shape and a center of mass (CoM) that enables motion between a plurality of positions when a force is applied; and a magnet material, wherein the magnet on the GRP moves as a function of the motion between the plurality of positions; and one or more coils configured to induct an electric current, wherein the one or more GRPs is arranged relative to the one or more coils such that the motion between the plurality of positions from the applied force inducts an electrical current in the one or more coils, converting the force applied to the one or more GRPs into the electric current.

Embodiment 6001. The electromagnetic vibrational energy capture device of embodiment 6000, wherein the shape and the CoM of the one or more GRPs enables relaxation to a stationary position from the plurality of positions from gravitational force.

Embodiment 6002. The electromagnetic vibrational energy capture device of embodiment 6000 or 6001, wherein the magnetic material comprises a magnet, optionally affixed to the top, bottom, and/or side of the one or more GRPs.

Embodiment 6003. The electromagnetic vibrational energy capture device of any one of embodiments 6000-6002, wherein the electromagnetic vibrational energy capture device comprises one coil for each GRP, or two or more coils for each GRP.

Embodiment 6004. The electromagnetic vibrational energy capture device of any one of embodiments 6000-6003, wherein the force comprises gravity or a mechanical force, optionally wherein the mechanical force is agitation, shaking, vibration, or tilting.

Embodiment 6005. The electromagnetic vibrational energy capture device of any one of embodiments 6000-6004, wherein the motion of the one or more GRPs causes movement of each magnet into and out of the one or more coils, optionally wherein the movement into the one or more coils induces a positive current, and movement out of the one or more coils induces a negative current, or wherein the movement into the one or more coils induces a negative current, and movement out of the one or more coils induces a positive current.

Embodiment 6006. The electromagnetic vibrational energy capture device of any one of embodiments 6000-6005, further comprising a housing that contains the one or more GRPs and the one or more coils.

Embodiment 6007. The electromagnetic vibrational energy capture device of any one of embodiments 6000-6006, wherein the electromagnetic vibrational energy capture device comprises an array of GRPs arranged relative to an array of coils.

Embodiment 6008. The electromagnetic vibrational energy capture device of any one of embodiments 6000-6007, further comprising one or more elements in electric communication with the one or more coils configured to store an electrical charge from the electrical current inducted in the one or more coils.

Embodiment 6009. The electromagnetic vibrational energy capture device of embodiment 6008, wherein the one or more elements comprises one or one batteries.

### EQUIVALENTS

While the disclosure has been described in connection with specific embodiments thereof, it will be understood that it is capable of further modifications and this application is intended to cover any variations, uses, or adaptations of the disclosure following, in general, the principles of the disclosure and including such departures from the present disclosure as come within known or customary practice within the art to which the disclosure pertains and as may be applied to the essential features hereinbefore set forth and as follows in the scope of the appended claims.

Those skilled in the art will recognize, or be able to ascertain, using no more than routine experimentation, numerous equivalents to the specific embodiments described specifically herein. Such equivalents are intended to be encompassed in the scope of the following claims.

### INCORPORATION BY REFERENCE

All patents and publications referenced herein are hereby incorporated by reference in their entireties.

The publications discussed herein are provided solely for their disclosure prior to the filing date of the present application. Nothing herein is to be construed as an admission that the present disclosure is not entitled to antedate such publication by virtue of prior disclosure.

As used herein, all headings are simply for organization and are not intended to limit the disclosure in any manner. The content of any individual section may be equally applicable to all sections.

What is claimed is:

1. A gravity responsive particle (GRP) comprising:
a. a shape and a center of mass (CoM) that enables motion between a plurality of positions when a force is applied, wherein the shape and the CoM enables relaxation to a stationary position from the plurality of positions from gravitational force; and
b. one or more optically active agents, wherein the GRP exhibits a change in an optical property of the one or more optically active agents as a function of the motion between the plurality of positions.

2. The gravity responsive particle of claim 1, wherein the GRP is about or at least about 20 nm to about or at least about 10 mm in size.

3. The gravity responsive particle of any claim 1 or 2, wherein the shape is a 3-dimensional shape.

4. The gravity responsive particle of any one of claims 1-3, wherein the GRP comprises an internal portion, and wherein the internal portion comprises a material having a singular specific gravity and/or density; or wherein the internal portion comprises at least two materials having different specific gravities and/or densities.

5. The gravity responsive particle of claim 4, wherein the internal portion comprises at least a portion that is hollow and/or porous.

6. The gravity responsive particle of any one of the preceding claims, comprising two or more optically active agents, each exhibiting at least one distinct optical state; or wherein the GRP comprises two optically active agents, three optically active agents, four optically active agents, or five or more optically active agents.

7. The gravity responsive particle of any one of the preceding claims, wherein the force that is applied comprises a mechanical force that is not a gravitational force; a magnetic force; and/or a gravitational force.

8. The gravity responsive particle of any one of the preceding claims, wherein the center of mass (CoM) resides below a radius of curvature, or wherein the center of mass (CoM) does not reside below a radius of curvature.

9. The gravity responsive particle of any one of the preceding claims, wherein the one or more optically active agents comprise a color in the visible electromagnetic spectrum comprising an extinction, reflection, or scattering at a wavelength from about or at least about 350 nm to about or at least about 800 nm; and/or
wherein the GRP exhibits no extinction, reflection, or scattering at a wavelength from about or at least about 350 nm to about or at least about 800 nm during the stationary position or during at least a portion of the motion between the plurality of positions; and/or
wherein the GRP only exhibits extinction, reflection, or scattering at a wavelength from about or at least about 350 nm to about or at least about 800 nm during the stationary position or during at least a portion of the motion between the plurality of positions.

10. The gravity responsive particle of claim 9, wherein the color is one or more of white, black, red, orange, yellow, green, blue, indigo, violet, and a color shade or hue therebetween.

11. The gravity responsive particle of any one of the preceding claims, wherein the GRP changes color as a function of the motion.

12. The gravity responsive particle of any one of the preceding claims, wherein the GRP comprises one or more roughness features.

13. The gravity responsive particle of any one of the preceding claims, wherein the GRP comprises one or more magnetic materials, optionally affixed to at least a portion of the surface of the GRP; and wherein the GRP responds to a magnetic stimulus.

14. The gravity responsive particle of claim 13, wherein the magnetic material is affixed to the top surface, optionally wherein the magnetic material changes the CoM relative to the curvature of radius.

15. The gravity responsive particle of any one of the preceding claims, wherein the GRP is disposed on a surface and/or substrate, and/or wherein the surface and/or substrate is a window, computer chip, glass surface, fabric, plastic, paper, wood, construction material, and/or human or animal tissue or skin.

16. The gravity responsive particle of any one of the preceding claims, wherein the GRP is formulated into a foil, film, thin plastic, and/or paper substrate, material, and/or surface; and/or wherein the foil, film, thin plastic, and/or paper substrate, material, and/or surface is suitable to be affixed to, or embedded in, an object.

17. The gravity responsive particle of any one of the preceding claims, wherein the GRP is formulated into a fluid, suspension, ink, liquid film, and/or adhesive substrate, material, and/or surface; and/or wherein the fluid, suspension, ink, liquid film, and/or adhesive substrate, material, and/or surface is suitable to be applied to an object.

18. The gravity responsive particle of any one of claims preceding claims, wherein the GRP is positioned between a first substrate and a second substrate; and/or wherein at least one of the first substrate and the second substrate comprises a material that is transparent to at least a portion of the visible electromagnetic (EM) spectrum.

19. A gravity responsive particle (GRP) comprising:
a shape and a center of mass (CoM) that enables motion between a plurality of positions when a force is applied, wherein the shape and the CoM enables relaxation to a stationary position from the plurality of positions from gravitational force; and
one or more optically active agents, wherein the GRP exhibits a change in an optical property of the one or more optically active agents as a function of the motion between the plurality of positions, and
wherein the GRP comprises one or more fin-shaped portions above the CoM.

20. A sawtooth gravity responsive particle (sGRP) comprising:
a shape comprising a center of mass (CoM) that resides at or above a radius of curvature that when a force is applied to tilt the sGRP between a tilt angle of 0° to θ_{crit}, the shape enables motion between a plurality of positions of 0° to θ_{crit}, wherein θ_{crit} is a critical angle, tilting past which results in movement of the sGRP to an equilibrium position on a side surface that is distinct from an upright equilibrium position; and
one or more optically active agents, wherein the sGRP exhibits a change in an optical property of the one or more optically active agents as a function of relaxation to the equilibrium position on the side surface.

21. A method of manufacturing a gravity responsive particle (GRP) of any one of claims 1-19, or a sawtooth gravity responsive particle (sGRP) of claim 20, comprising:
generating a particle from one or more substrate materials, the particle comprising a shape and a center of mass (CoM) that enables motion between a plurality of positions when a force is applied, wherein the shape and the CoM enables the particle to relax to a stationary position from the plurality of positions from gravitational force.

22. The method of claim 21, wherein generating the particle comprises forming the particle by 3D printing, assembling, gluing, screwing, and/or affixing of two or more components; injection molding, micro-injection molding; self-assembly, adsorption, coacervation, mixing; polymerization, extrusion, manipulation of polymers; additive manufacturing, Computer Numerical Control (CNC) machining, urethane casting, microcontact printing, dip pen lithography, beam pen lithography, photolithography, and/or e-beam lithography.

23. The method of claim 22, wherein generating the particle comprises forming the particle by 3D printing, optionally wherein 3D printing comprises performing one or more of fused deposition modeling (FDM), fused filament fabrication (FFF), stereolithography (SLA), two photon polymerization, multi-photon lithography, selective laser sintering (SLS), binder jetting (BJ), direct energy deposition (DED), digital light process (DLP), liquid crystal display (LCD), polymer jetting (PolyJet), multi-jet fusion (MJF), direct metal laser sintering (DMLS), electron beam melting (EBM), laminated object manufacturing (LOM), continuous liquid interface production (CLIP), electron beam melting, and digital light processing (DLP).

24. The method of any one of claims 21-23, wherein the one or more substrate materials comprises one or more metals, ceramics, thermally responsive polymers, and resins.

25. The method of any one of claims 21-24, wherein generating the particle comprises forming Janus particles comprising the one or more substrate materials, or forming Ashura particles comprising the one or more substrate materials.

26. The method of any one of claims 21-25, wherein the particle and/or one or more substrate materials comprises an internal portion; and/or wherein the internal portion comprises at least a portion that is hollow and/or porous.

27. The method of any one of claims 21-26, comprising disposing one or more optically active agents onto and/or into the particle and/or the one or more substrate materials.

28. The method of claim 27, wherein disposing the one or more optically active agents comprises painting, airbrushing, dip coating, abrading, and/or roughening one or more surfaces of the GRP; or wherein disposing the one or more optically active agents comprises 3D printing the particle with one or more colored materials.

29. The method of any one of claims 21-28, comprising formulating the GRP into a foil, film, thin plastic, and/or paper substrate, material, and/or surface; and/or wherein the foil, film, thin plastic, and/or paper substrate, material, and/or surface is suitable to be affixed to, or embedded in, an object.

30. A gravity responsive particle (GRP) film comprising:
an array of particles comprising a plurality of GRPs of any one of claims 1-19, a plurality of sGRPs of claim 20, or a plurality of GRPs produced by the method of any one of claims 21-29; and
a first substrate and a second substrate, wherein at least a portion of a surface of the first substrate and/or the second substrate comprises a material that is transparent to at least a portion of the visible electromagnetic (EM) spectrum,
wherein the array is positioned between the first substrate and the second substrate, and
wherein the film exhibits a change in an optical property as a function of the movement of the array of particles.

31. A sensor for detecting one or more analytes in a sample comprising:
a plurality of particles comprising:
i) one or more gravity responsive particles (GRPs) of any one of claims 1-19,
ii) one or more sawtooth gravity responsive particles (sGRPs) of claim 20, and/or
ii) one or more GRPs manufactured from the method of any one of claims 21-29; and
one or more mass detection labels on the surface of the plurality of particles configured to bind the one or more analytes,
wherein the one or mass detection labels binds the one or more analytes in the sample, causing a shift in the mass of the plurality of particles, which results in a movement in the plurality of particles, and wherein the movement elicits a change in an optical property proportional to the binding of the one or more analytes.

32. The sensor of claim 31, wherein the plurality of particles is disposed onto a reaction membrane; and/or wherein the sensor comprises a sample pad configured to receive a volume of the sample and flow the sample over the reaction membrane.

33. The sensor of claim 31 or 32, wherein the change in the optical property is a change in color; and/or wherein the movement is a tipping onto a stable equilibrium distinct from an upright equilibrium.

34. The sensor of any one of claims 31-33, further comprising a plurality of control particles comprising one or more mass detection labels, wherein the plurality of control particles are i) not configured to bind the one or more analytes that the plurality of particles bind, and ii) provide a control signal, optionally wherein the control signal is the same as the change in optical property of the plurality of particles.

35. The sensor of any one of claims 31-34, wherein the plurality of particles and/or the plurality of control particles are arranged in an array on the reaction membrane, optionally wherein the array comprises one or more lines on the reaction membrane visible by human vision.

36. The sensor of any one of claims 31-35, wherein the one or more mass detection labels comprises one or more of an antibody, antibody-format binding molecule, metal oxide particle, and metal particle; and/or wherein the one or more mass detection labels are attached to the plurality of particles and/or the plurality of control particles using a biomolecular capture film.

37. The sensor of any one of claims 31-36, wherein the one or more analytes comprise one or more of a protein, peptide, nucleic acid, DNA, RNA, lipid, sugar, metabolite, cell, capsid, antigen, biomarker, ionic species, heavy metal, pathogen, bacterium, virus, and any substance containing or including biomolecules.

38. The sensor of any one of claims 31-37, wherein the sample comprises one or more of blood, sera, plasma, bone marrow, lymph, saliva, sputum, mucus, respiratory or nasal secretion, oropharyngeal swab, nasopharyngeal swab, oral swab, ductal lavage, bronchoalveolar lavage, cerebrospinal fluid, skin swab, vaginal swab, gastric juice, ascites, peritoneal fluid, pleural fluid, gynecological fluids, pus, perspiration, tears, urine, stool; homogenized biopsy, tissue, or cell sample; a tumor sample; a water sample; a sample of foodstuffs and/or surfaces for storing or preparing foodstuffs, beverages, homogenized animal products intended for consumption, samples taken from a surface that is used for preparing food, and soil samples.

39. A method of authenticating an object using a detectable gravity responsive particle (GRP) signal, the method comprising:
providing an object comprising an array of particles comprising:
i) one or more gravity responsive particles (GRPs) of any one of claims 1-19,
ii) one or more sawtooth gravity responsive particles (sGRPs) of claim 20, and/or
ii) one or more GRPs manufactured from the method of any one of claims 21-29;
applying a force to the array of particles to cause a movement in the array of particles which elicits a change in an optical property in the array of particles; and
detecting the change in the optical property as a function of the movement of the array of particles.

40. The method of claim 39, wherein the object comprises paper, plastic, glass, metal, fabric, wood, a window, an electronic device, a computer chip, construction materials, and/or human or animal tissue or skin; and/or wherein the object comprises documentation, optionally paper currency.

41. The method of claim 39 or 40, wherein the array of particles is arranged in a pattern, optionally comprising one or more shape, symbol, letter, number, picture, image, or message; and/or wherein the change in the optical property that is detected is substantially in the arrangement of the array of particles.

42. The method of any one of claims 39-41, wherein the force comprises gravity, a mechanical force that is not gravity, or magnetic force; and/or wherein applying the force comprises moving the object relative to the direction of the force.

43. The method of any one of claims 39-42, wherein the change in optical property is detectable by human vision; and/or wherein detecting the change in the optical property comprises using one or more of a camera, spectrometer, filter, window, grating, beam splitter, polarizer, collimator, birefringent element, prism, bandpass filter, aperture, or lens to detect an optical signal emanating from the object.

44. The method of any one of claims 39-43, further comprising comparing the change in the optical property to a standard signal, wherein the comparison verifies the authenticity of the object.

45. An electromagnetic vibrational energy capture device, comprising:
one or more gravity responsive particles (GRPs), wherein each GRP comprises:
a. a shape and a center of mass (CoM) that enables motion between a plurality of positions when a force is applied; and
b. a magnet material, wherein the magnet on the GRP moves as a function of the motion between the plurality of positions; and
one or more coils configured to induct an electric current,
wherein the one or more GRPs is arranged relative to the one or more coils such that the motion between the plurality of positions from the applied force inducts an electrical current in the one or more coils, converting the force applied to the one or more GRPs into the electric current.
